(19) United States
(12) Patent Application Publication
(10) Pub. No.: US 2025/0138425 A1
(43) Pub. Date: May 1, 2025

(54) POSITIVE RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Masahiro Fukushima, Joetsu-shi (JP); Tatsuya Yamahira, Joetsu-shi (JP); Masaki Ohashi, Joetsu-shi (JP)

(73) Assignee: Shin-Etsu Chemical Co., Ltd., Tokyo (JP)

(21) Appl. No.: 18/918,378

(22) Filed: Oct. 17, 2024

(30) Foreign Application Priority Data
Oct. 31, 2023 (JP) 2023-186658
Apr. 15, 2024 (JP) 2024-065075

(51) Int. Cl. G03F 7/039; G03F 7/004; G03F 7/20

(52) U.S. Cl. CPC G03F 7/0397; G03F 7/0045; G03F 7/0048; G03F 7/2006

(57) ABSTRACT

A positive resist composition is provided comprising a base polymer comprising repeat units (a) having a substituted or unsubstituted carboxy group and a substituted or unsubstituted phenolic hydroxy group, repeat units (b) having an acid labile group, and repeat units (c) consisting of a sulfonic acid anion bonded to the polymer backbone and a sulfonium or iodonium cation. It exhibits a high sensitivity and resolution and forms a pattern of satisfactory profile with reduced edge roughness or dimensional variation.

### CROSS-REFERENCE TO RELATED APPLICATIONS

This non-provisional application claims priority under 35 U.S.C. § 119 (a) on Patent Application Nos. 2023-186658 and 2024-065075 filed in Japan on Oct. 31, 2023 and Apr. 15, 2024, respectively, the entire contents of which are hereby incorporated by reference.

### TECHNICAL FIELD

This invention relates to a positive resist composition and a patterning process using the composition.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5- or 3-nm node by the lithography using EUV of wavelength 13.5 nm has been implemented in a mass scale. Studies are made on the application of EUV lithography to 2 nm node devices of the next generation and 14 Å node devices of the next-but-one generation. IMEC in Belgium announced its successful development of 2 Å node devices.

As the feature size reduces, image blurs due to acid diffusion become a problem. To insure resolution for fine patterns with a size of 45 nm et seq., not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

A triangular tradeoff relationship among sensitivity, resolution, and edge roughness has been pointed out. Specifically, a resolution improvement requires to suppress acid diffusion whereas a short acid diffusion distance leads to a decline of sensitivity.

The addition of an acid generator capable of generating a bulky acid is an effective means for suppressing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond, capable of generating a specific sulfonic acid. Patent Document 2 discloses a sulfonium salt having a sulfonic acid directly bonded to the backbone.

Patent Document 3 discloses a resist composition to which a polymer-bound acid generator of onium salt structure having an iodized anion bonded to the backbone is added. Due to the inclusion of iodine having substantial absorption of EUV, the decomposition efficiency of an acid generator during light exposure is increased, leading to a high sensitivity. As the number of photons absorbed increases, physical contrast is enhanced.

Patent Document 4 describes that a polymer having vinylsalicylic acid copolymerized is used for the purpose of controlling the electric charging of toner particles. Patent Document 5 describes a resist composition comprising a polymer having vinylsalicylic acid incorporated therein.

### CITATION LIST

Patent Document 1: JP-A 2006-045311 (U.S. Pat. No. 7,482,108)
Patent Document 2: JP-A 2006-178317
Patent Document 3: JP-A 2018-197853
Patent Document 4: JP-A 2011-137947
Patent Document 5: JP-A 2023-131926
Non-Patent Document 1: SPIE Vol. 6520 65203L-1 (2007)

### SUMMARY OF THE INVENTION

It is desired to have a positive resist material having a higher sensitivity than prior art positive resist materials and capable of reducing the line width roughness (LWR) of line patterns and improving the critical dimension uniformity (CDU) of hole patterns.

An object of the invention is to provide a positive resist composition which exhibits a higher sensitivity and resolution than prior art positive resist compositions and forms patterns of satisfactory profile with reduced LWR and improved CDU after exposure, and a pattern forming process using the same.

Positive resist compositions having a high resolution, reduced LWR and satisfactory CDU are currently demanded. The distance of acid diffusion must be minimized to meet the demand. When a polymer of sulfonium or iodonium salt structure having a sulfonic acid bonded to the polymer backbone is used as a base polymer, minimal acid diffusion is achievable. When iodine is incorporated in an acid generator, the absorption of more photons leads to an enhanced physical contrast, and direct excitation acts to reduce the diffusion of secondary electrons, thus exerting the effect of reducing image blur. The incorporation of iodine into the acid generator, however, invites a drop of alkaline solubility, sometimes leaving residues in the space regions of the pattern. When repeat units having a substituted or unsubstituted carboxy group and a substituted or unsubstituted phenolic hydroxy group (with the proviso that the repeat unit has at least one unsubstituted carboxy or phenolic hydroxy group) are further introduced into the polymer, the alkali dissolution rate is increased while preventing any swell, leading to improved LWR or CDU. When combined with the iodized acid generator, the polymer is effective as a base polymer for formulating a chemically amplified positive resist composition capable of forming a pattern of satisfactory profile without leaving residue defects in the space regions.

When repeat units having a carboxy or phenolic hydroxy group whose hydrogen atom is substituted by an acid labile group are further introduced for improving the dissolution contrast, there is obtained a positive resist composition which has a high sensitivity, a significantly high contrast of alkaline dissolution rate before and after light exposure, or a high sensitivity, a high acid diffusion suppressing effect, and a high resolution, and forms a pattern of satisfactory profile after exposure, with reduced edge roughness and dimensional variation. The resist composition is thus especially suited as a micropatterning resist material for the manufacture of ultra-LSIs and photomasks.

In one aspect, the invention provides a positive resist composition comprising a base polymer comprising repeat units (a) having a substituted or unsubstituted carboxy group and a substituted or unsubstituted phenolic hydroxy group, with the proviso that repeat unit (a) has at least one group selected from an unsubstituted carboxy group and an unsubstituted phenolic hydroxy group, repeat units (b) having an acid labile group, and repeat units (c) having a sulfonium or iodonium salt structure of a sulfonic acid bonded to the polymer backbone.

In one preferred embodiment, the repeat units (a) have the formula (a).

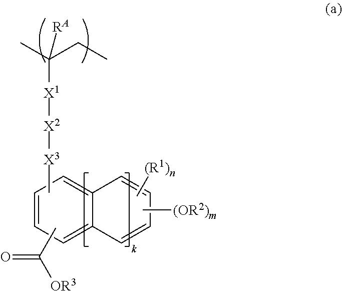

Herein k is 0 or 1, m is an integer of 1 to 4, n is an integer of 0 to 4,
RA is hydrogen or methyl,
X¹ is a single bond or ester bond,
X² is a single bond, C₁-C₁₀ saturated hydrocarbylene group, phenylene group or naphthylene group,
X³ is a single bond, ester bond, ether bond or carbonyl group,
R¹ is a C₁-C₄ alkyl group or halogen,
R² is hydrogen, a C₁-C₆ saturated hydrocarbyl group, C₂-C₇ saturated hydrocarbylcarbonyl group, or C₂-C₇ saturated hydrocarbyloxycarbonyl group,
R³ is hydrogen, a C₁-C₁₂ saturated hydrocarbyl group, or C₂-C₁₂ unsaturated hydrocarbyl group, the saturated hydrocarbyl group and unsaturated hydrocarbyl group may have at least one moiety selected from hydroxy, C₁-C₈ saturated hydrocarbyloxy moiety, and halogen, with the proviso that one or both of R² and R³ are hydrogen when m=1, and at least one of plural R² and R³ is hydrogen when m=2, 3 or 4.

In one preferred embodiment, the repeat units (b) include repeat units of at least one type selected from repeat units (b1) having the formula (b1) and repeat units (b2) having the formula (b2).

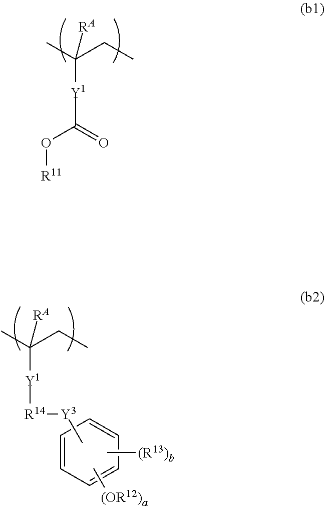

Herein R^{A} is each independently hydrogen or methyl,
Y¹ is a single bond, phenylene group, naphthylene group, or C₁-C₁₂ linking group containing at least one moiety selected from ester bond, ether bond and lactone ring, the phenylene group, naphthylene group, and linking group may contain at least one moiety selected from halogen, nitro, hydroxy, C₁-C₈ saturated hydrocarbyloxy moiety, C₂-C₈ saturated hydrocarbylcarbonyloxy moiety, and C₂-C₈ saturated hydrocarbyloxycarbonyloxy moiety,
Y² is a single bond, ester bond or amide bond,
Y³ is a single bond, ether bond or ester bond,
R¹¹ and R¹² each are an acid labile group,
R¹³ is fluorine, trifluoromethyl, cyano, or C₁-C₆ alkyl group,
R¹⁴ is a single bond or C₁-C₆ alkanediyl group in which some —CH₂— may be replaced by an ether bond or ester bond,
a is 1 or 2, b is an integer of 0 to 4, and a+b is from 1 to 5.

In one preferred embodiment, the repeat units (c) include repeat units of at least one type selected from repeat units having the formulae (c1) to (c5).

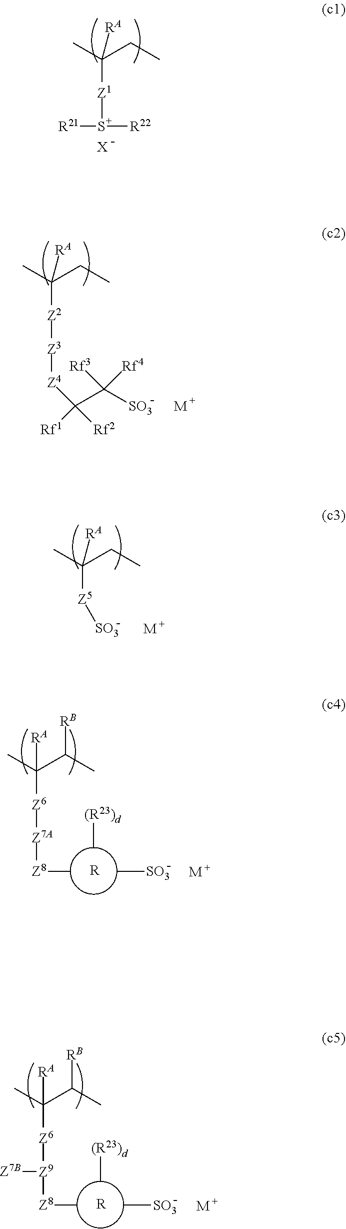

Herein R^{A} is each independently hydrogen or methyl,
R^{B} is each independently hydrogen or may form a ring with Z⁶,
Z¹ is a single bond, a C₁-C₆ aliphatic hydrocarbylene group, phenylene group, naphthylene group, or C₇-C₁₈ group obtained by combining the foregoing, or —O—Z¹¹—, —C(═O)—O—Z¹¹— or —C(═O)—NH—Z¹¹, Z¹¹ is a C₁-C₆ aliphatic hydrocarbylene group, phenylene group, naphthylene group, or C₇-C₁₈ group obtained by combining the foregoing, which may contain carbonyl, ester bond, ether bond or hydroxy,
Z² is a single bond or ester bond,
Z³ is a single bond, —Z³¹—C(═O)—O— or —Z³¹—O—, Z³¹ is a C₁-C₁₂ hydrocarbylene group, phenylene group, or C₇-C₁₈ group obtained by combining the foregoing, which may contain carbonyl, nitro, cyano, ester bond, ether bond, urethane bond, fluorine, iodine or bromine,
Z⁴ is a single bond, methylene or ethylene,
Z⁵ is a single bond, methylene, ethylene, phenylene, methylphenylene, dimethylphenylene, fluorinated phenylene, trifluoromethyl-substituted phenylene group, —O—Z⁵¹—, —C(═O)—O—Z⁵¹— or —C(═O)—NH—Z⁵¹—, Z⁵¹ is a C₁-C₆ aliphatic hydrocarbylene, phenylene, methylphenylene, dimethylphenylene, fluorinated phenylene, or trifluoromethyl-substituted phenylene group, which may contain carbonyl, ester bond, ether bond, hydroxy or halogen,
Z⁶ is a single bond, phenylene, naphthylene, ester bond or amide bond,
Z^{7A} is a single bond or a C₁-C₂₄ divalent organic group which may contain at least one element selected from halogen, oxygen, nitrogen, and sulfur,
Z^{7B} is a C₁-C₁₀ monovalent organic group which may contain at least one element selected from halogen, oxygen, nitrogen, and sulfur,
Z⁸ is a single bond, ether bond, ester bond, thioether bond or C₁-C₆ alkanediyl group,
Z⁹ is a C₁-C₁₂ trivalent organic group which may contain at least one element selected from oxygen, nitrogen, and sulfur,
Rf¹ to Rf⁴ are each independently hydrogen, fluorine or trifluoromethyl, at least one thereof being fluorine or trifluoromethyl, and Rf¹ and Rf², taken together, may form a carbonyl group,
R²¹ and R²² are each independently halogen or a C₁-C₂₀ hydrocarbyl group which may contain a heteroatom,
R²³ is a C₁-C₁₀ saturated hydrocarbyl group, C₆-C₁₀ aryl group, fluorine, iodine, trifluoromethoxy, difluoromethoxy, cyano or nitro,
the circle R is a C₆-C₁₀ (d+2)-valent aromatic hydrocarbon group,
d is an integer of 0 to 5,
X⁻ is a non-nucleophilic counter ion, and
M⁺ is a sulfonium or iodonium cation.

More preferably, Z³, Z^{7A}, Z^{7B} or M⁺ contains at least one iodine atom.

In one preferred embodiment, the base polymer further comprises repeat units (d) having an adhesive group which is selected from hydroxy, carboxy, lactone ring, carbonate, thiocarbonate, carbonyl, cyclic acetal, ether bond, ester bond, sulfonate ester bond, cyano, amide, —O—C(═O)—S—, and —O—C(═O)—NH—.

The positive resist composition may further comprise an acid generator, an organic solvent, a quencher, and/or a surfactant.

In another aspect, the invention provides a pattern forming process comprising the steps of applying the positive resist composition defined herein onto a substrate to form a resist film thereon, exposing the resist film to high-energy radiation, and developing the exposed resist film in a developer.

Typically, the high-energy radiation is i-line, KrF excimer laser, ArF excimer laser, EB or EUV of wavelength 3 to 15 nm.

### Advantageous Effects of Invention

Due to the good alkaline dissolution of exposed regions and the high decomposition efficiency of an acid generator, the positive resist composition exhibits a remarkable acid diffusion-suppressing effect, a high sensitivity, and high resolution, forms patterns of satisfactory profile with reduced LWR or improved CDU, causes neither footing nor residues in the space regions, and eliminates micro-bridges tying pattern features. Salicylic acid is effective for reducing any swelling of carboxy group in alkaline developer because its carboxy group and phenolic hydroxy group forms a hydrogen-bonding ring. The same holds true even when the carboxy group or phenolic hydroxy group has been substituted. When polymerizable salicylic acid is copolymerized, the resulting polymer has advantages including low swell and increased alkaline dissolution rate, which ensure satisfactory properties as mentioned above. Because of these advantages, the positive resist composition is suited as a micropatterning resist material for the manufacture of ultra-LSIs and photomasks by the EB lithography, and especially micropatterning resist material for the EB or EUV lithography. The positive resist composition is useful not only in the lithography for semiconductor circuit formation, but also in the formation of mask circuit patterns, micro-machines, and thin-film magnetic head circuits.

### DETAILED DESCRIPTION OF THE INVENTION

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In chemical formulae, Me stands for methyl, Ac stands for acetyl, and the broken line ( - - - ) designates a valence bond or point of attachment. As used herein, the term “fluorinated” refers to a fluorine-substituted or fluorine-containing compound or group, and the term “iodized” refers to an iodine-substituted or iodine-containing compound or group. The terms “group” and “moiety” are interchangeable.

The abbreviations and acronyms have the following meaning.
EB: electron beam
EUV: extreme ultraviolet
Mw: weight average molecular weight
Mn: number average molecular weight
Mw/Mn: molecular weight distribution or dispersity
GPC: gel permeation chromatography
PEB: post-exposure bake
PAG: photoacid generator
LWR: line width roughness
CDU: critical dimension uniformity

### [Positive Resist Composition]

One embodiment of the invention is a positive resist composition comprising a base polymer comprising repeat units (a) having a substituted or unsubstituted carboxy group and a substituted or unsubstituted phenolic hydroxy group, with the proviso that repeat unit (a) has at least one group selected from an unsubstituted carboxy group and an unsubstituted phenolic hydroxy group, repeat units (b) having an acid labile group, and repeat units (c) having a sulfonium or iodonium salt structure of a sulfonic acid bonded to the polymer backbone.

### [Base Polymer]

In a preferred embodiment, the repeat units (a) have the formula (a).

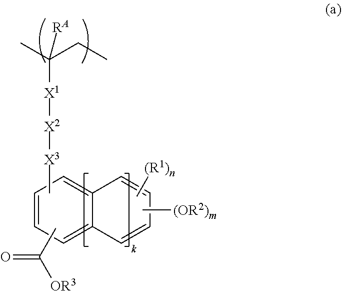

In formula (a), k is 0 or 1, m is an integer of 1 to 4, preferably 1, 2 or 3, more preferably 1 or 2, most preferably 1, and n is an integer of 0 to 4, preferably 0 or 1, more preferably 0.

In formula (a), R^{A} is hydrogen or methyl.

In formula (a), X¹ is a single bond or ester bond.

In formula (a), X² is a single bond, C₁-C₁₀ saturated hydrocarbylene group, phenylene group or naphthylene group. The saturated hydrocarbylene group may be straight, branched or cyclic. Examples of the hydrocarbylene group include C₁-C₁₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, and decane-1,10-diyl; and C₃-C₁₀ cyclic saturated hydrocarbylene groups such as cyclopentanediyl, cyclohexanediyl, norbornanediyl and adamantanediyl.

In formula (a), X³ is a single bond, ester bond, ether bond or carbonyl group,

In formula (a), R¹ is a C₁-C₄ alkyl group or halogen. Exemplary alkyl groups include methyl, ethyl, n-propyl, isopropyl, n-butyl, isobutyl, sec-butyl and tert-butyl.

In formula (a), R² is hydrogen, a C₁-C₆ saturated hydrocarbyl group, C₂-C₇ saturated hydrocarbylcarbonyl group, or C₂-C₇ saturated hydrocarbyloxycarbonyl group. The saturated hydrocarbyl group and the saturated hydrocarbyl moiety in the saturated hydrocarbylcarbonyl group and saturated hydrocarbyloxycarbonyl group may be straight, branched or cyclic. Examples thereof include C₁-C₆ alkyl groups such as methyl, ethyl, n-propyl, isopropyl, n-butyl, isobutyl, sec-butyl, tert-butyl, n-pentyl, tert-pentyl, neopentyl, and n-hexyl; C₃-C₆ cyclic saturated hydrocarbyl groups such as cyclopropyl, cyclobutyl, cyclopentyl, methylcyclopentyl and cyclohexyl; and combinations thereof. A plurality of R² may be identical or different when m=2, 3 or 4.

In formula (a), R³ is hydrogen, a C₁-C₁₂ saturated hydrocarbyl group, or C₂-C₁₂ unsaturated hydrocarbyl group. The saturated hydrocarbyl group and unsaturated hydrocarbyl group may have at least one moiety selected from hydroxy, C₁-C₈ saturated hydrocarbyloxy moiety, and halogen. The saturated hydrocarbyl group may be straight, branched or cyclic. Examples thereof include C₁-C₁₂ alkyl groups such as methyl, ethyl, n-propyl, isopropyl, n-butyl, isobutyl, sec-butyl, tert-butyl, n-pentyl, tert-pentyl, neopentyl, and n-hexyl; C₃-C₁₂ cyclic saturated hydrocarbyl groups such as cyclopropyl, cyclobutyl, cyclopentyl, methylcyclopentyl and cyclohexyl; and combinations thereof. The unsaturated hydrocarbyl group may be straight, branched or cyclic. Examples thereof include C₂-C₁₂ alkenyl groups such as vinyl, 1-propenyl, 2-propenyl, and isopropenyl; and C₂-C₁₂ alkynyl groups such as ethynyl, 1-propynyl and 2-propynyl. The saturated hydrocarbyl group and unsaturated hydrocarbyl group may be substituted with hydroxy, alkoxy or halogen. Exemplary substituted hydrocarbyl groups include monofluoroethyl, difluoroethyl, trifluoroethyl, hexafluoroisopropyl, monoiodoethyl, and monoiodopropyl.

It is noted that one or both of R² and R³ are hydrogen when m=1, and at least one of plural R² and R³ is hydrogen when m=2, 3 or 4.

Examples of the monomer from which repeat units (a) are derived are shown below, but not limited thereto. Herein R^{A} is as defined above.

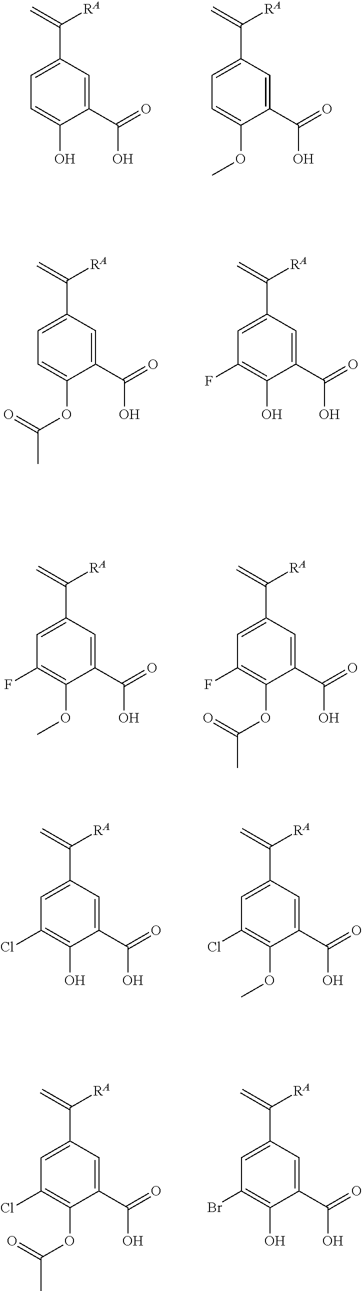

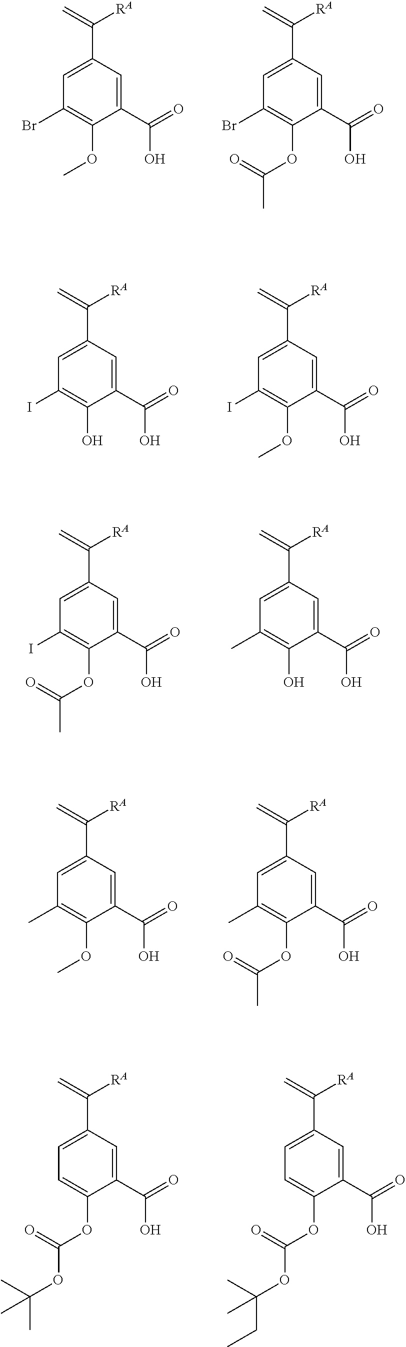

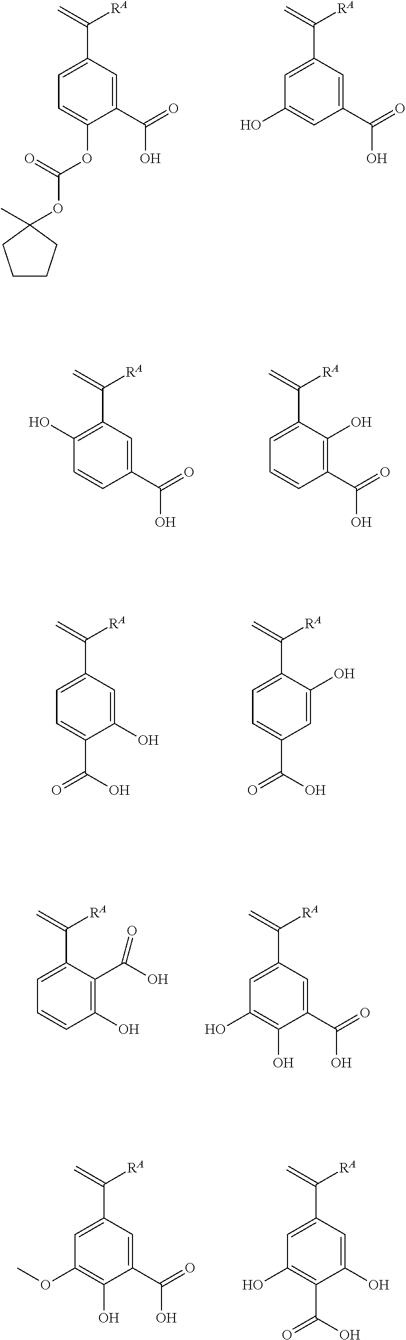

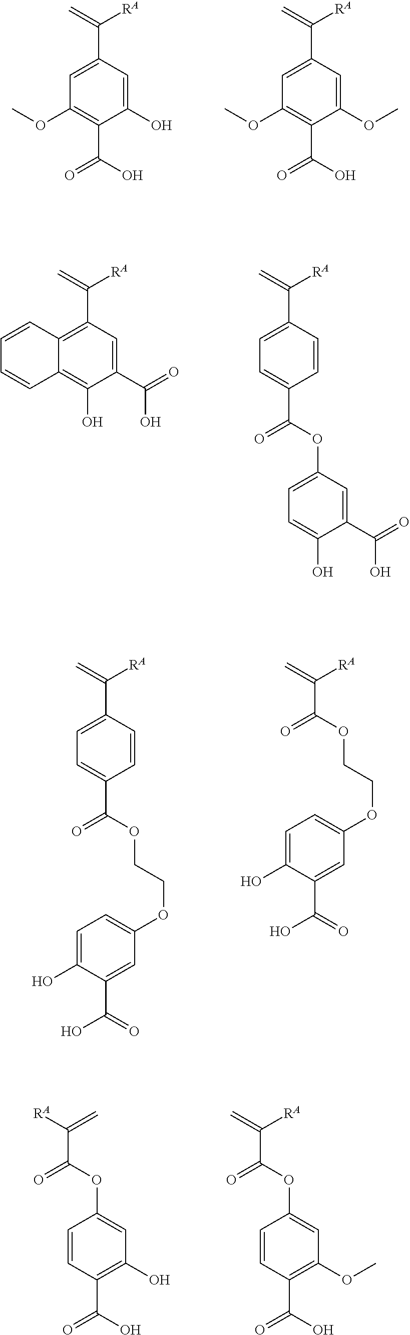

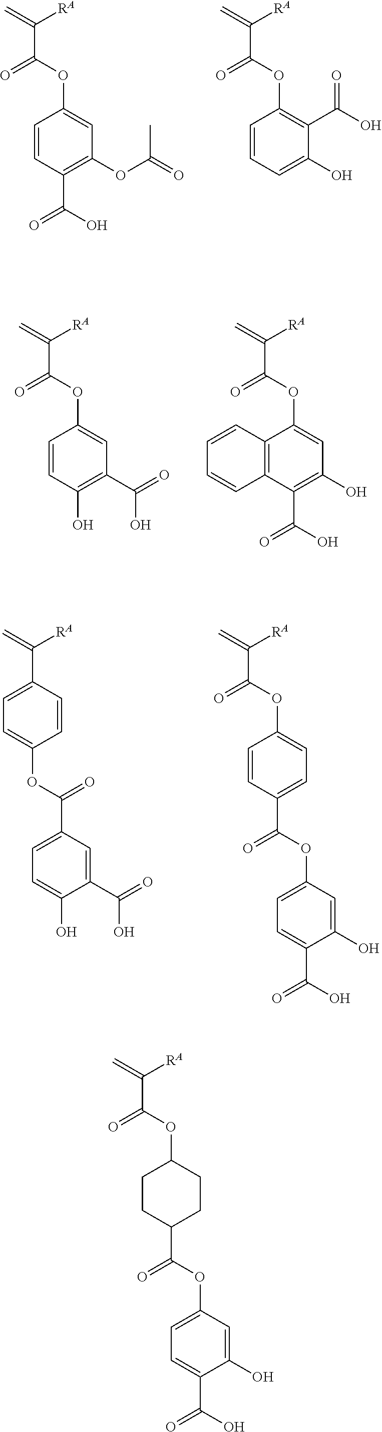

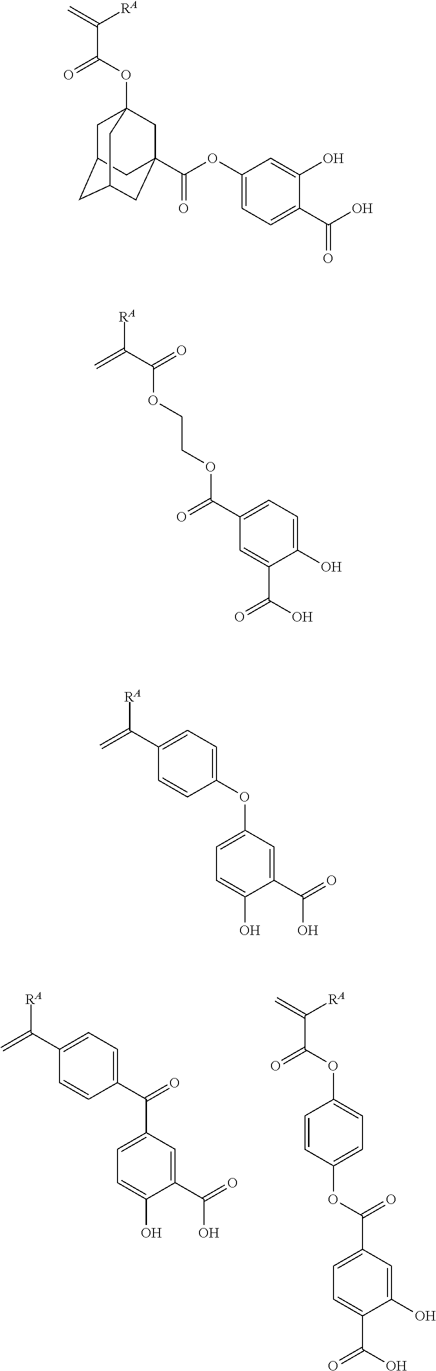

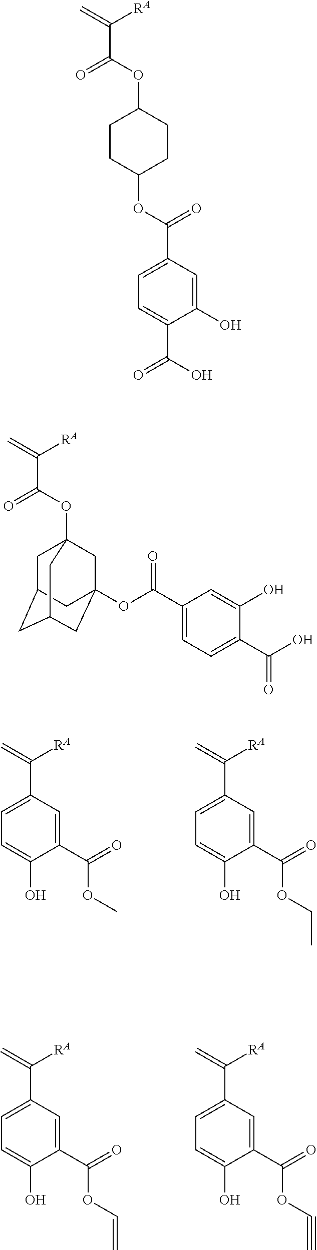

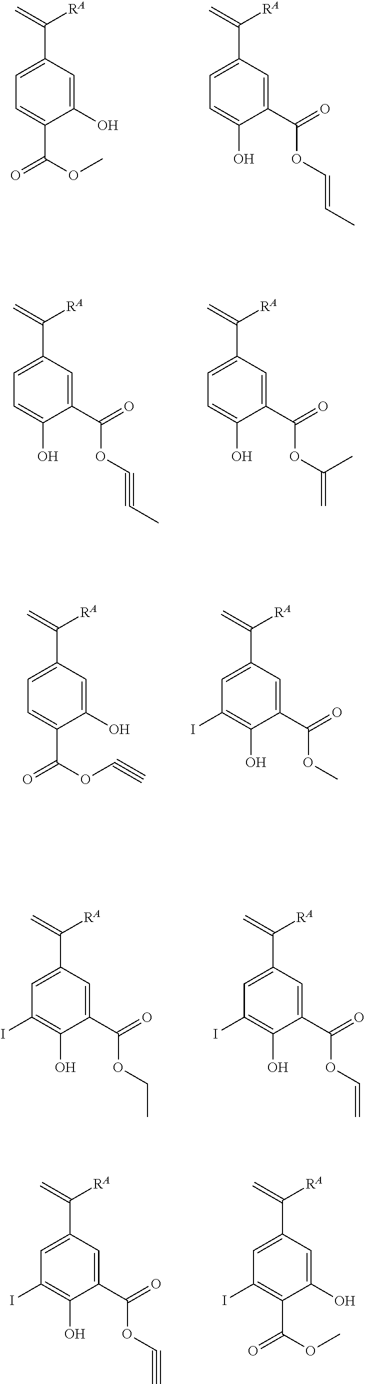

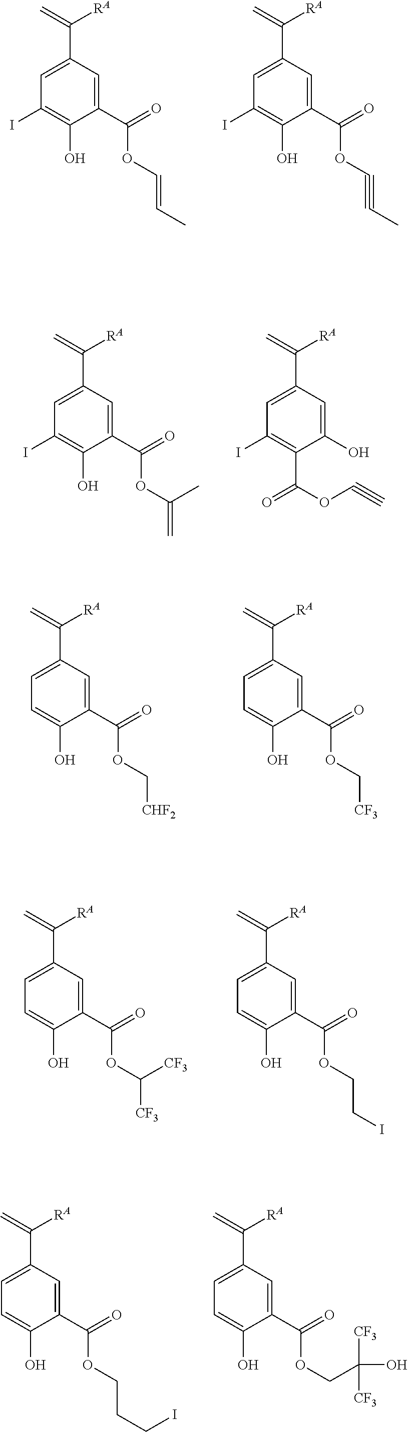

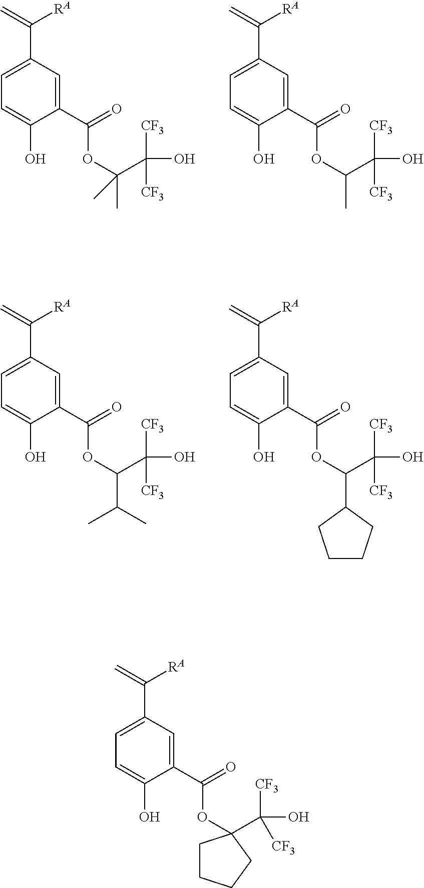

The repeat units (b) serve to enhance the dissolution contrast. Preferably, the repeat units (b) include repeat units of at least one type selected from repeat units (b1) having the formula (b1) and repeat units (b2) having the formula (b2).

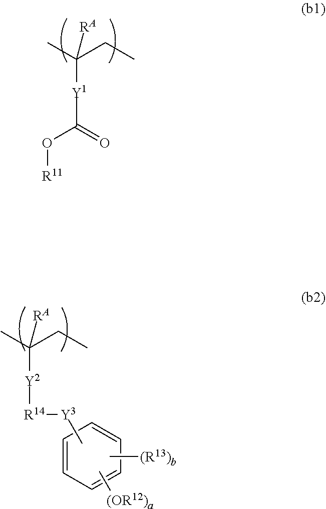

In formulae (b1) and (b2), R^{A} is each independently hydrogen or methyl. Y¹ is a single bond, phenylene group, naphthylene group, or C₁-C₁₂ linking group containing at least one moiety selected from ester bond, ether bond and lactone ring. The phenylene group, naphthylene group, and linking group may contain at least one moiety selected from halogen, nitro, hydroxy, C₁-C₈ saturated hydrocarbyloxy moiety, C₂-C₈ saturated hydrocarbylcarbonyloxy moiety, and C₂-C₈ saturated hydrocarbyloxycarbonyloxy moiety. Y² is a single bond, ester bond or amide bond. Y³ is a single bond, ether bond or ester bond. R¹¹ and R¹² each are an acid labile group. R¹³ is fluorine, trifluoromethyl, cyano, or C₁-C₆ alkyl group. R¹⁴ is a single bond or C₁-C₆ alkanediyl group in which some —CH₂— may be replaced by an ether bond or ester bond. The subscript “a” is 1 or 2, “b” is an integer of 0 to 4, and a+b is from 1 to 5.

Examples of the monomer from which repeat units (b1) are derived are shown below, but not limited thereto. Herein R^{A} and R¹¹ are as defined above.

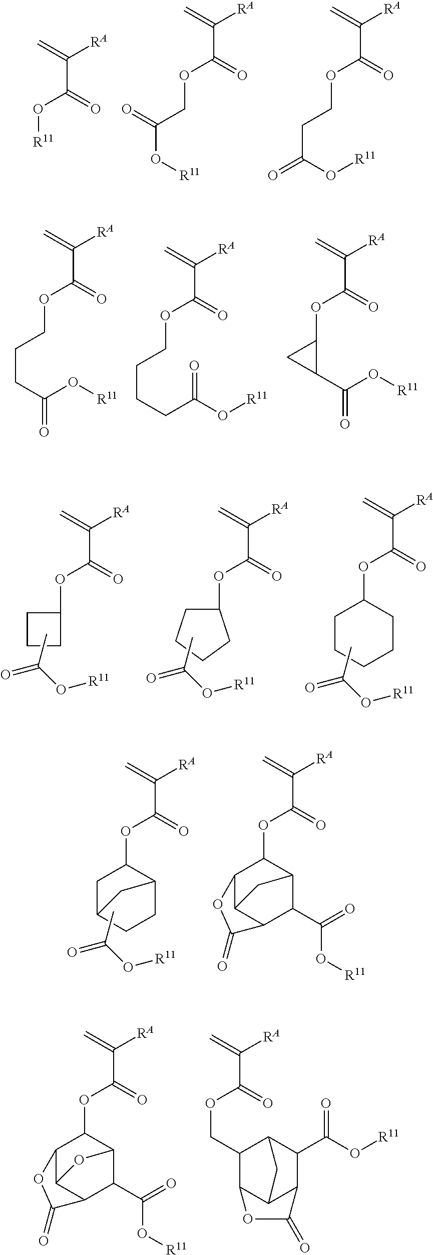

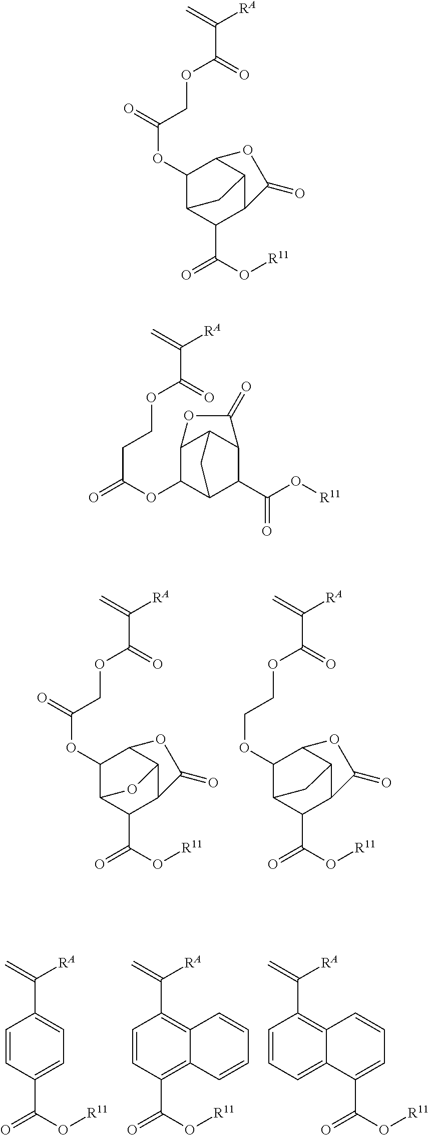

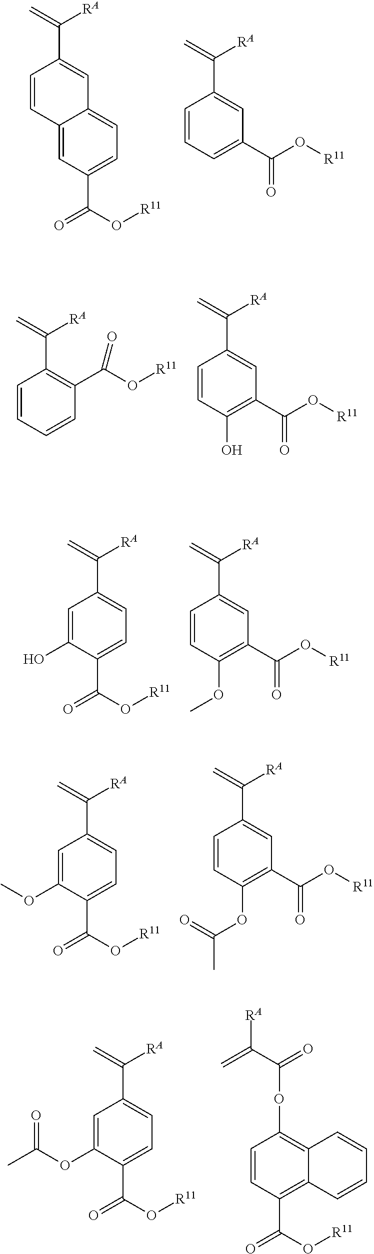

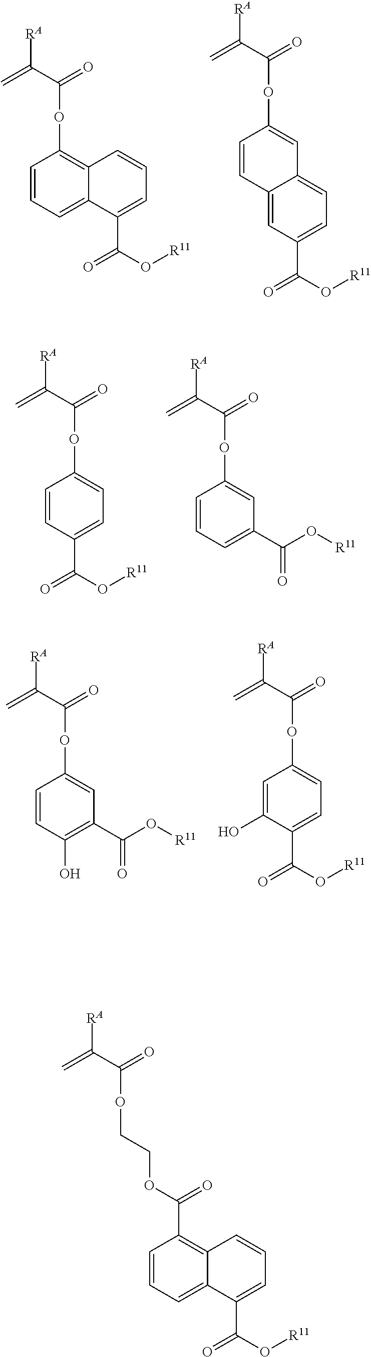

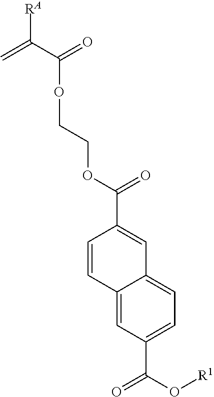

Examples of the monomer from which repeat units (b2) are derived are shown below, but not limited thereto. Herein R^{A} and R¹² are as defined above.

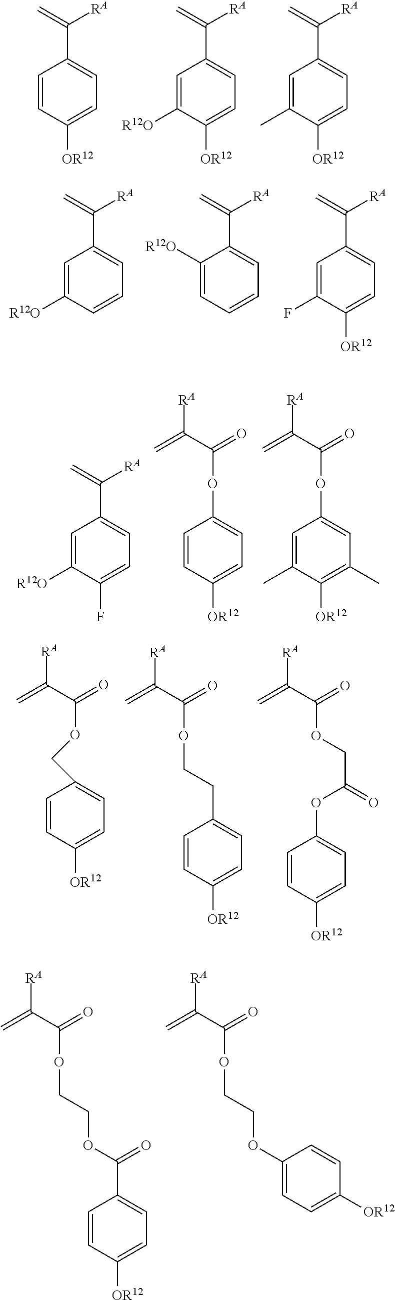

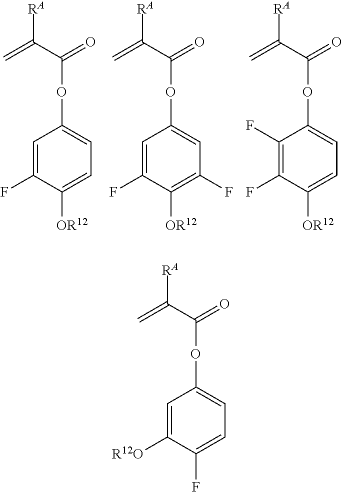

The acid labile group represented by R¹¹ or R¹² may be selected from a variety of such groups, for example, groups having the following formulae (AL-1) to (AL-3).

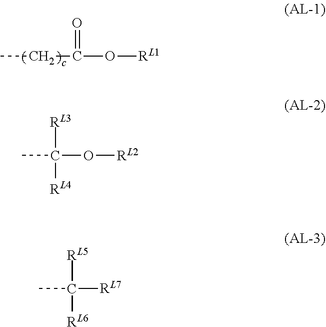

In formula (AL-1), “c” is an integer of 0 to 6. R^{L1} is a C₄-C₂₀, preferably C₄-C₁₅ tertiary hydrocarbyl group, a trihydrocarbylsilyl group in which each hydrocarbyl moiety is a C₁-C₆ saturated hydrocarbyl moiety, a C₄-C₂₀ saturated hydrocarbyl group containing a carbonyl moiety, ether bond or ester bond, or a group having formula (AL-3). It is noted that the tertiary hydrocarbyl group refers to a group obtained by eliminating hydrogen on tertiary carbon from a hydrocarbon.

Of the groups represented by R^{L1}, the tertiary hydrocarbyl group may be saturated or unsaturated and branched or cyclic, and examples thereof include tert-butyl, tert-pentyl, 1,1-diethylpropyl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, and 2-methyl-2-adamantyl. Examples of the trihydrocarbylsilyl group include trimethylsilyl, triethylsilyl and dimethyl-tert-butylsilyl. The saturated hydrocarbyl group containing a carbonyl moiety, ether bond or ester bond may be straight, branched or cyclic, preferably cyclic, and examples thereof include 3-oxocyclohexyl, 4-methyl-2-oxooxan-4-yl, 5-methyl-2-oxooxolan-5-yl, 2-tetrahydropyranyl and 2-tetrahydrofuranyl.

Examples of the acid labile group having formula (AL-1) include tert-butoxycarbonyl, tert-butoxycarbonylmethyl, tert-pentyloxycarbonyl, tert-pentyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl.

Other examples of the acid labile group having formula (AL-1) include groups having the formulae (AL-1)-1 to (AL-1)-10.

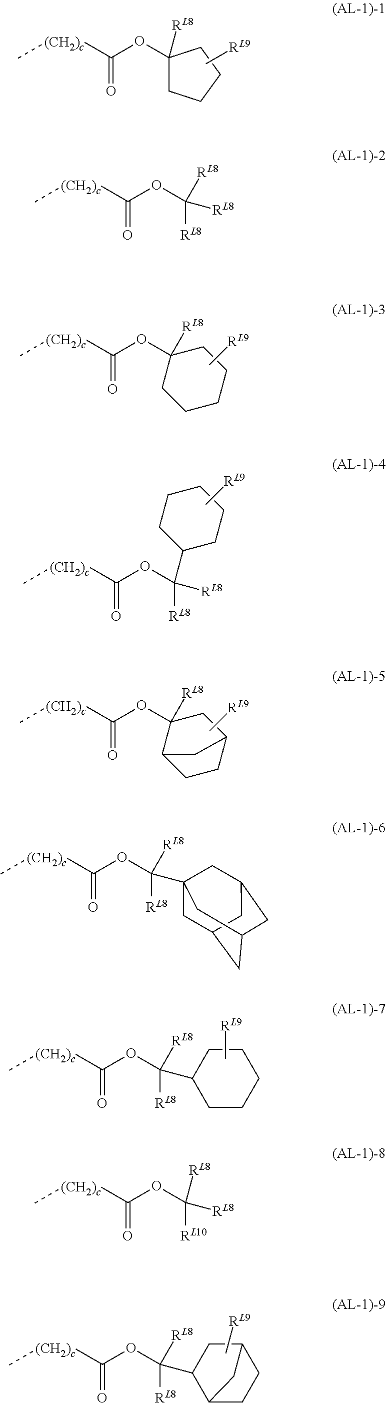

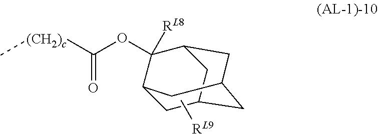

In formulae (AL-1)-1 to (AL-1)-10, “c” is as defined above. R^{L8} is each independently a C₁-C₁₀ saturated hydrocarbyl group or C₆-C₂₀ aryl group. R^{L9} is hydrogen or a C₁-C₁₀ saturated hydrocarbyl group. R^{L10} is a C₂-C₁₀ saturated hydrocarbyl group or C₆-C₂₀ aryl group. The saturated hydrocarbyl group may be straight, branched or cyclic.

In formula (AL-2), R^{L2} and R^{L3} are each independently hydrogen or a C₁-C₁₈, preferably C₁-C₁₀ saturated hydrocarbyl group. The saturated hydrocarbyl group may be straight, branched or cyclic and examples thereof include methyl, ethyl, n-propyl, isopropyl, n-butyl, isobutyl, sec-butyl, tert-butyl, cyclopentyl, cyclohexyl, 2-ethylhexyl and n-octyl.

In formula (AL-2), R^{L4} is a C₁-C₁₈, preferably C₁-C₁₀ hydrocarbyl group which may contain a heteroatom. The hydrocarbyl group may be saturated or unsaturated and straight, branched or cyclic. Inter alia, C₁-C₁₈ saturated hydrocarbyl groups are preferred, in which some hydrogen may be substituted by hydroxy, alkoxy, oxo, amino or alkylamino. Examples of the substituted saturated hydrocarbyl group are shown below.

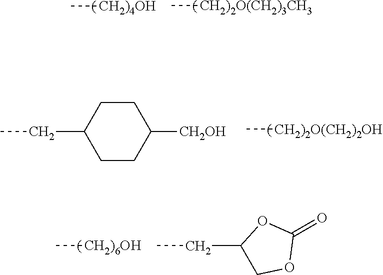

A pair of R^{L2} and R^{L3}, R^{L2} and R^{L4}, or R^{L3} and R^{L4} may bond together to form a ring with the carbon atom or carbon and oxygen atoms to which they are attached. R^{L2} and R^{L3}, R^{L2} and R^{L4}, or R^{L3} and R^{L4} which form a ring are each independently a C₁-C₁₈, preferably C₁-C₁₀ alkanediyl group. The ring thus formed is preferably of 3 to 10, more preferably 4 to 10 carbon atoms.

Of the acid labile groups having formula (AL-2), suitable straight or branched groups include those having formulae (AL-2)-1 to (AL-2)-69, but are not limited thereto.

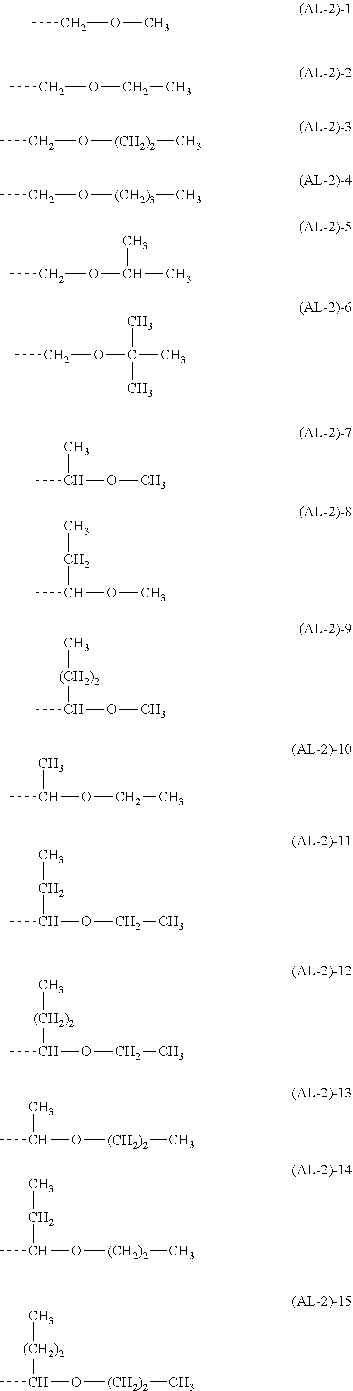

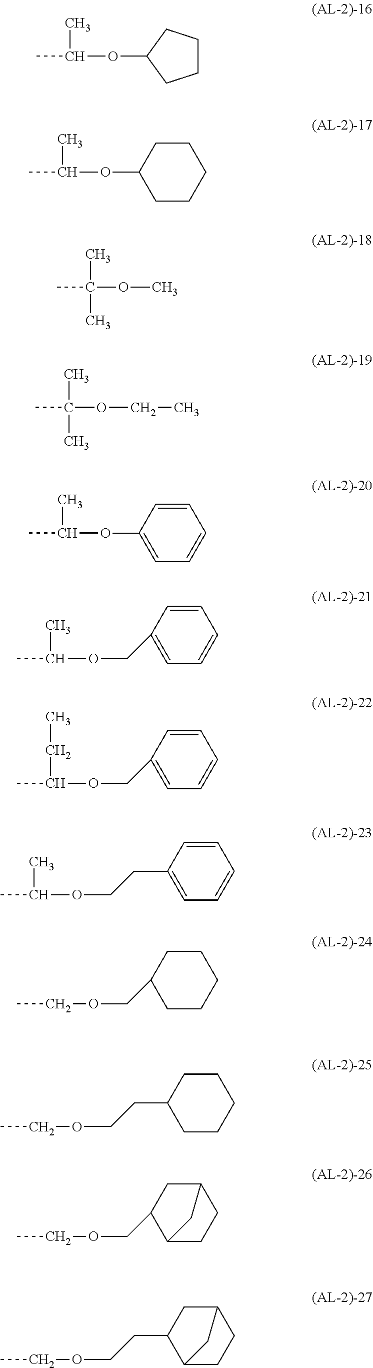

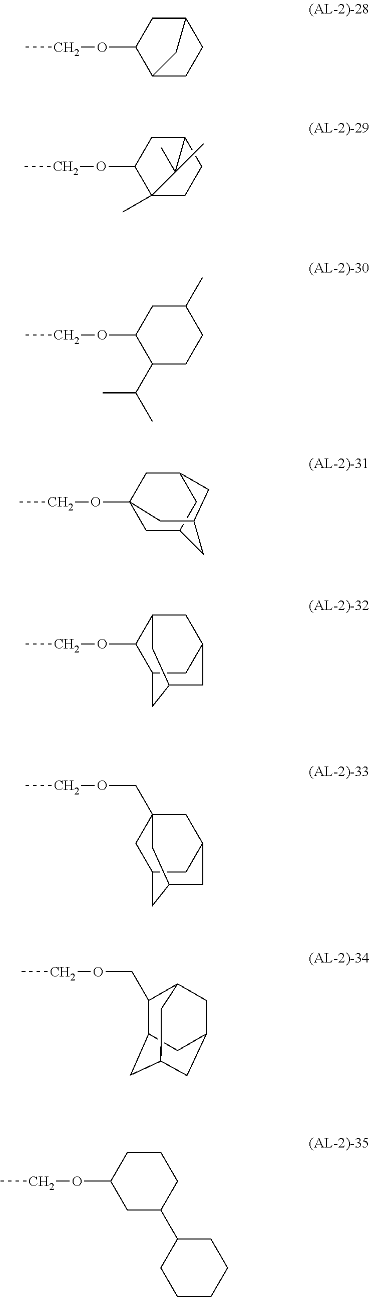

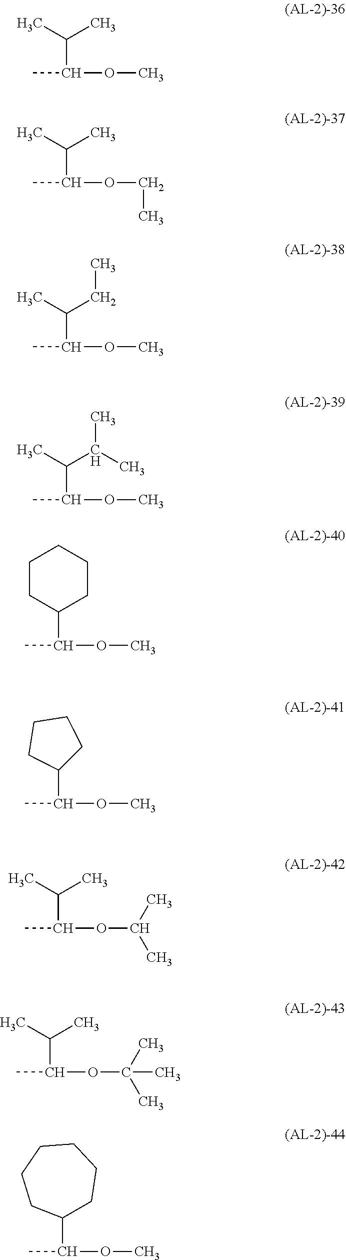

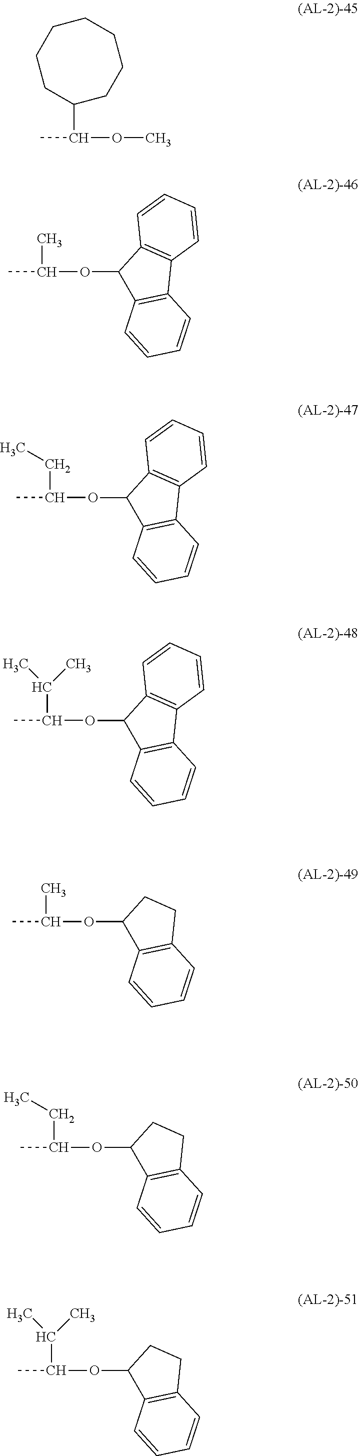

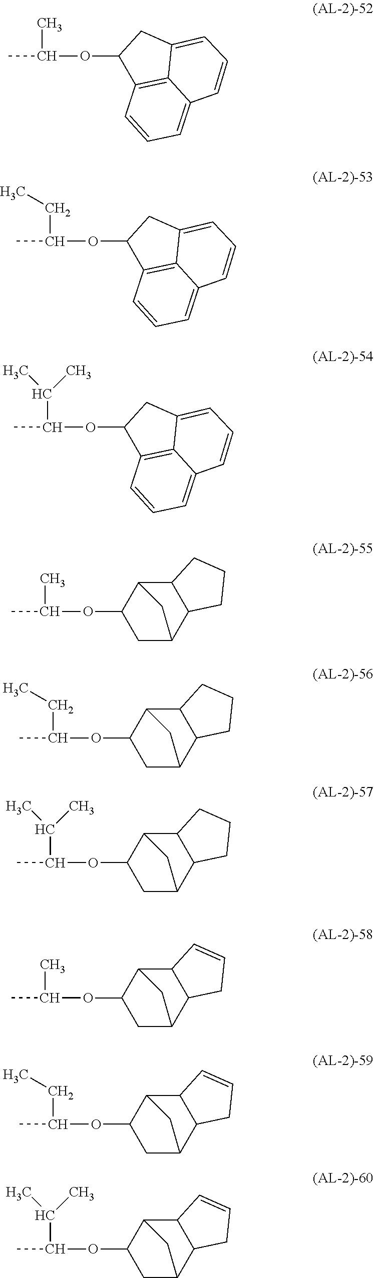

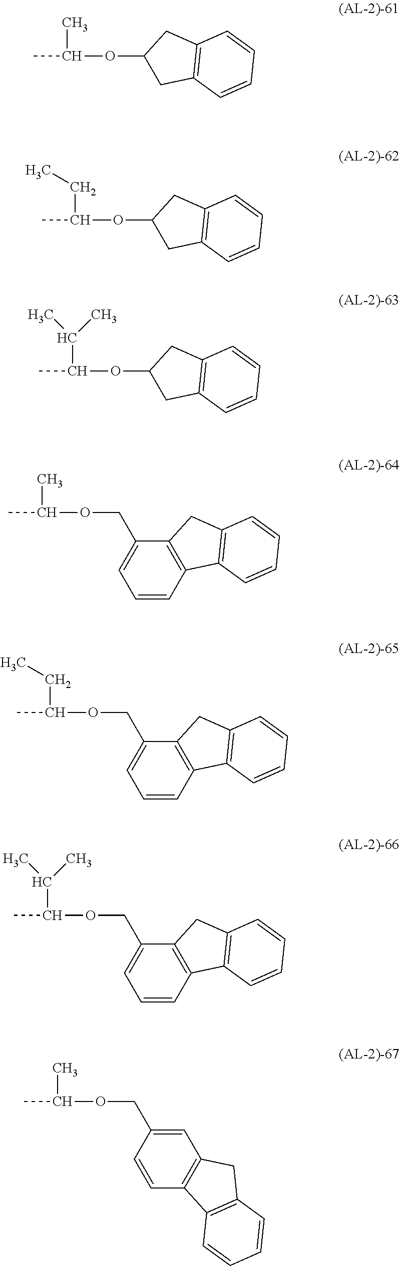

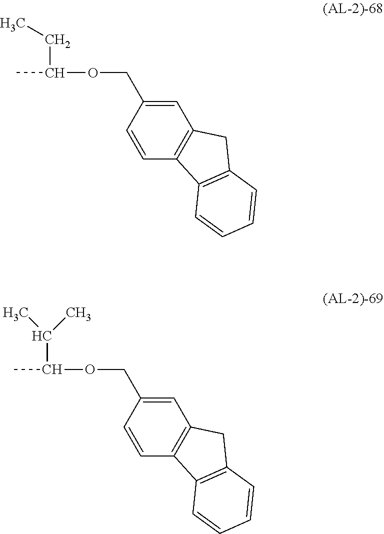

Of the acid labile groups having formula (AL-2), suitable cyclic groups include tetrahydrofuran-2-yl, 2-methyltetrahydrofuran-2-yl, tetrahydropyran-2-yl, and 2-methyltetrahydropyran-2-yl.

Also included are acid labile groups having the following formulae (AL-2a) and (AL-2b). With these acid labile groups, the base polymer may be crosslinked within the molecule or between molecules.

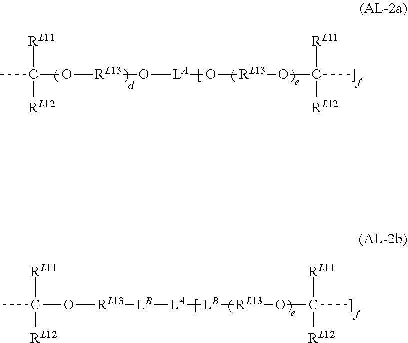

In formulae (AL-2a) and (AL-2b), R^{L11} and R^{Lc12} are each independently hydrogen or a C₁-C₈ saturated hydrocarbyl group which may be straight, branched or cyclic. Also, R^{L11} and R^{Lc12} may bond together to form a ring with the carbon atom to which they are attached, and in this case, R^{L11} and R^{Lc12} are each independently a C₁-C₈ alkanediyl group. R^{L13} is each independently a C₁-C₁₀ saturated hydrocarbylene group which may be straight, branched or cyclic. The subscripts d and e are each independently an integer of 0 to 10, preferably 0 to 5, and f is an integer of 1 to 7, preferably 1 to 3.

In formulae (AL-2a) and (AL-2b), L^{A} is a C₁-C₅₀ (f+1)-valent aliphatic saturated hydrocarbon group, C₃-C₅₀ (f+1)-valent alicyclic saturated hydrocarbon group, C₆-C₅₀ (f+1)-valent aromatic hydrocarbon group or C₃-C₅₀ (f+1)-valent heterocyclic group. In these groups, some constituent —CH₂— may be replaced by a heteroatom-containing moiety, or some carbon-bonded hydrogen may be substituted by a hydroxy, carboxy, acyl moiety or fluorine. L^{A} is preferably a C₁-C₂₀ saturated hydrocarbon group (e.g., saturated hydrocarbylene group, trivalent saturated hydrocarbon group or tetravalent saturated hydrocarbon group), or C₆-C₃₀ arylene group. The saturated hydrocarbon group may be straight, branched or cyclic. L^{B is —C(═O)—O—, —NH—C(═O)—O— or —NH—C(═O)—NH—.}

Examples of the crosslinking acetal groups having formulae (AL-2a) and (AL-2b) include groups having the formulae (AL-2)-70 to (AL-2)-77.

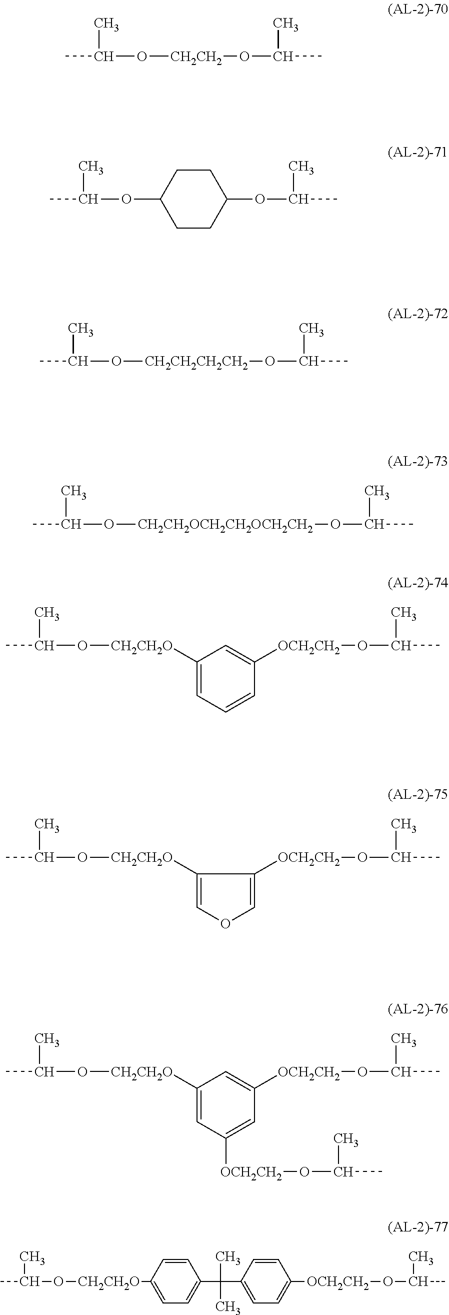

In formula (AL-3), R^{L5}, R^{L6} and R^{L7} are each independently a C₁-C₂₀ hydrocarbyl group which may contain a heteroatom such as oxygen, sulfur, nitrogen or fluorine. The hydrocarbyl group may be saturated or unsaturated and straight, branched or cyclic and examples thereof include C₁-C₂₀ alkyl groups, C₃-C₂₀ cyclic saturated hydrocarbyl groups, C₂-C₂₀ alkenyl groups, C₃-C₂₀ cyclic unsaturated hydrocarbyl groups, and C₆-C₁₀ aryl groups. A pair of R^{L5} and R^{L6}, R^{L5} and R^{L7}, or R^{L6} and R^{L7} may bond together to form a C₃-C₂₀ aliphatic ring with the carbon atom to which they are attached.

Examples of the group having formula (AL-3) include tert-butyl, 1,1-diethylpropyl, 1-ethylnorbornyl, 1-methylcyclopentyl, 1-ethylcyclopentyl, 1-isopropylcyclopentyl, 1-methylcyclohexyl, 2-(2-methyl) adamantyl, 2-(2-ethyl) adamantyl, and tert-pentyl.

Examples of the group having formula (AL-3) also include groups having the formulae (AL-3)-1 to (AL-3)-19.

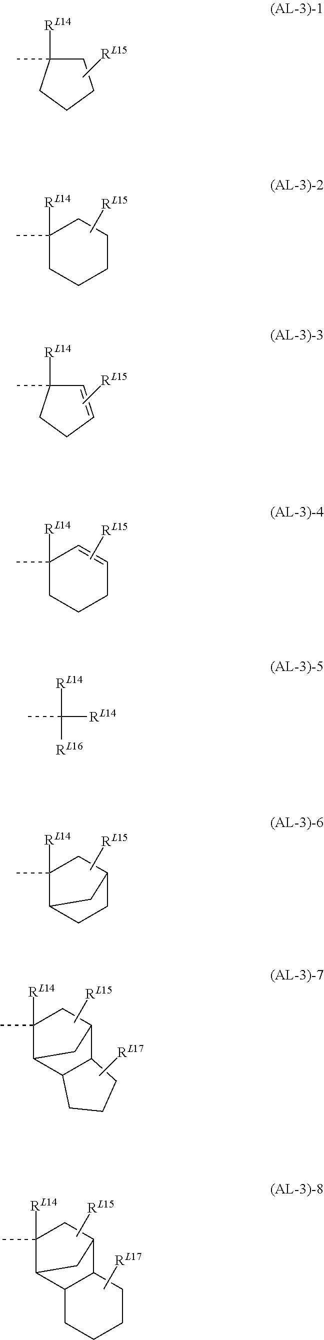

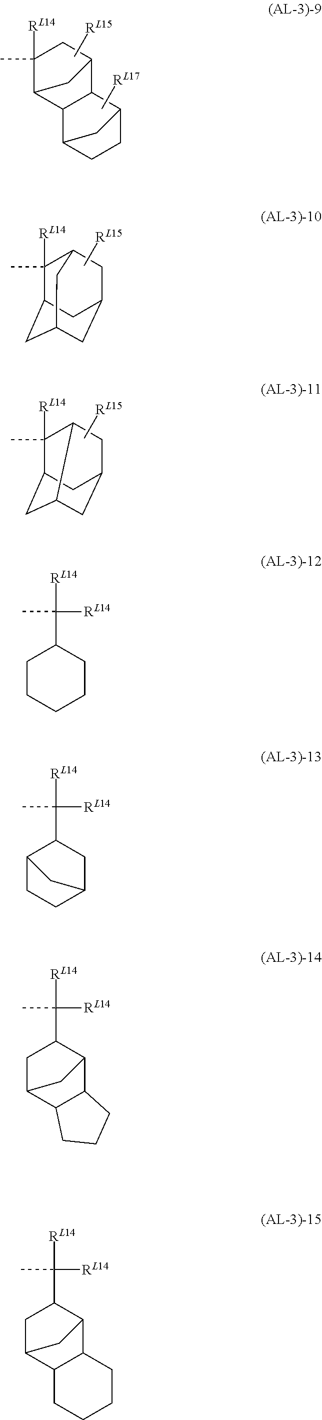

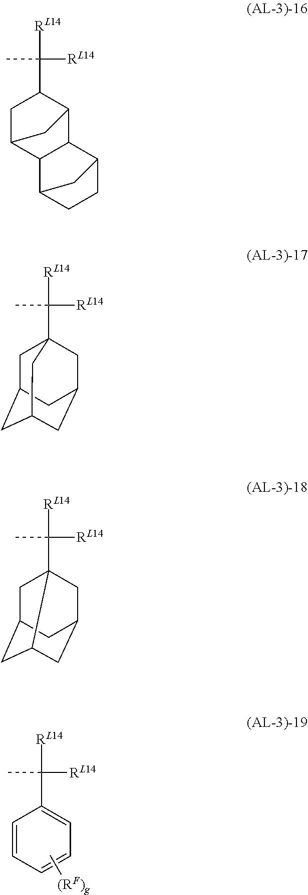

In formulae (AL-3)-1 to (AL-3)-19, R^{L14} is each independently hydrogen, a C₁-C₈ saturated hydrocarbyl group or C₆-C₂₀ aryl group. R^{L15} and R^{L17} are each independently hydrogen or a C₁-C₂₀ saturated hydrocarbyl group. R^{L16} is a C₆-C₂₀ aryl group. The saturated hydrocarbyl group may be straight, branched or cyclic. Typical of the aryl group is phenyl. R^{F} is fluorine or trifluoromethyl. The subscript g is an integer of 1 to 5.

Other examples of the acid labile group include groups having the formulae (AL-3)-20 and (AL-3)-21. With these acid labile groups, the base polymer may be crosslinked within the molecule or between molecules.

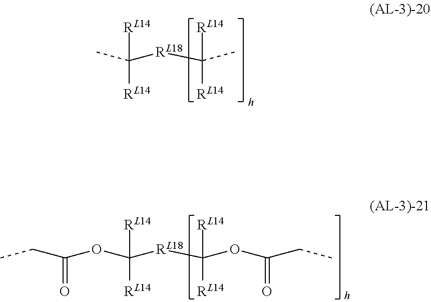

In formulae (AL-3)-20 and (AL-3)-21, R^{L14} is as defined above. R^{L18} is a C₁-C₂₀ (h+1)-valent saturated hydrocarbylene group or C₆-C₂₀ (h+1)-valent arylene group, which may contain a heteroatom such as oxygen, sulfur or nitrogen. The saturated hydrocarbylene group may be straight, branched or cyclic, and h is an integer of 1 to 3.

Examples of the monomer from which repeat units containing an acid labile group of formula (AL-3) are derived include (meth)acrylates (inclusive of exo-form structure) having the formula (AL-3)-22.

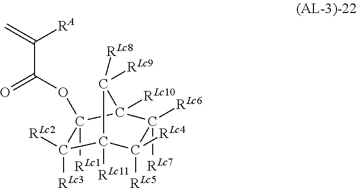

In formula (AL-3)-22, R^{A} is as defined above. R^{Lc1} is a C₁-C₈ saturated hydrocarbyl group or an optionally substituted C₆-C₂₀ aryl group; the saturated hydrocarbyl group may be straight, branched or cyclic. R^{Lc2} to R^{Lc11} are each independently hydrogen or a C₁-C₁₅ hydrocarbyl group which may contain a heteroatom; oxygen is a typical heteroatom. Suitable hydrocarbyl groups include C₁-C₁₅ alkyl groups and C₆-C₁₅ aryl groups. Alternatively, a pair of R^{Lc2} and R^{Lc3}, R^{Lc4} and R^{Lc6}, R^{Lc4} and R^{Lc7}, R^{Lc5} and R^{Lc7}, R^{Lc5} and R^{Lc11}, R^{Lc6} and R^{Lc10}, R^{Lc8} and R^{L9}, or R^{L9} and R^{Lc10}, taken together, may form a ring with the carbon atom to which they are attached, and in this event, the ring-forming group is a C₁-C₁₅ hydrocarbylene group which may contain a heteroatom. Also, a pair of R^{Lc2} and R^{Lc11}, R^{Lc8} and R^{Lc11}, or R^{L4} and R^{Lc6} which are attached to vicinal carbon atoms may bond together directly to form a double bond. The formula also represents an enantiomer.

Examples of the monomer having formula (AL-3)-22 are described in U.S. Pat. No. 6,448,420 (JP-A 2000-327633). Illustrative non-limiting examples of suitable monomers are given below. R^{A} is as defined above.

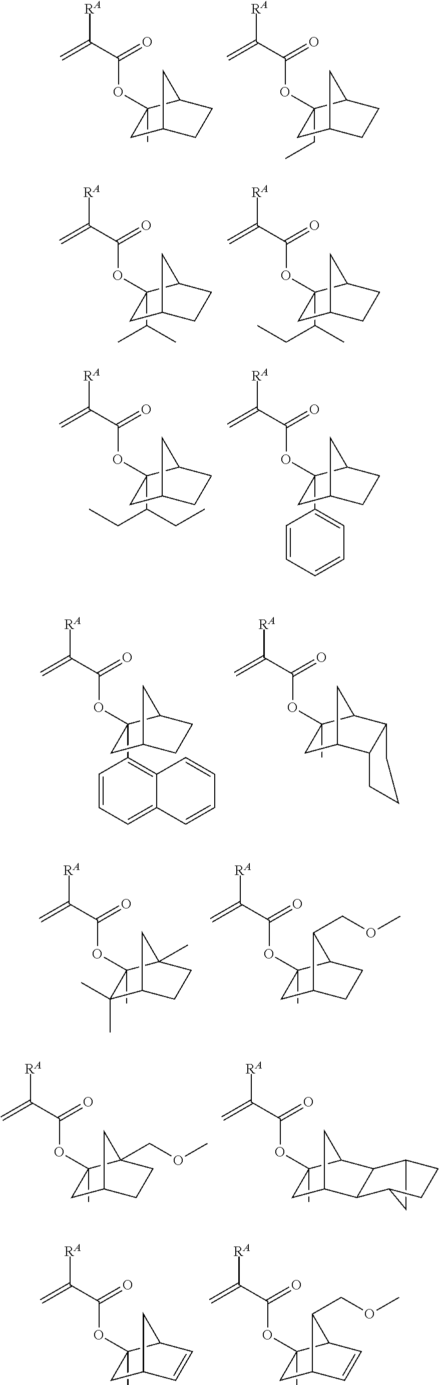

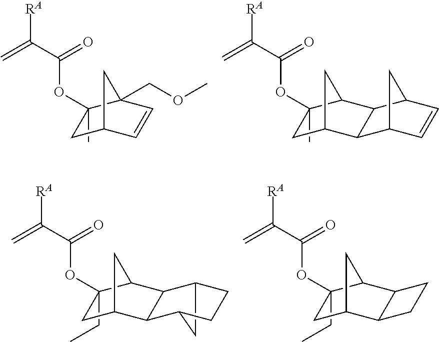

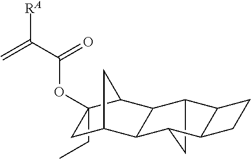

Examples of the monomer from which the repeat units having an acid labile group of formula (AL-3) are derived also include (meth)acrylate monomers having a furandiyl, tetrahydrofurandiyl or oxanorbornanediyl group as represented by the following formula (AL-3)-23.

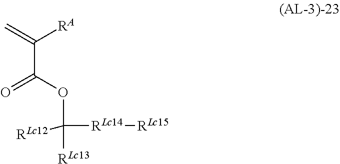

In formula (AL-3)-23, R^{A} is as defined above. R^{Lc12} and R^{Lc13} are each independently a C₁-C₁₀ hydrocarbyl group, or R^{Lc12} and R^{Lc13}, taken together, may form an aliphatic ring with the carbon atom to which they are attached. R^{Lc14} is furandiyl, tetrahydrofurandiyl or oxanorbornanediyl. R^{Lc15} is hydrogen or a C₁-C₁₀ hydrocarbyl group which may contain a heteroatom. The hydrocarbyl group may be straight, branched or cyclic, and examples thereof include C₁-C₁₀ saturated hydrocarbyl groups.

Examples of the monomer having formula (AL-3)-23 are shown below, but not limited thereto. Herein R^{A} is as defined above.

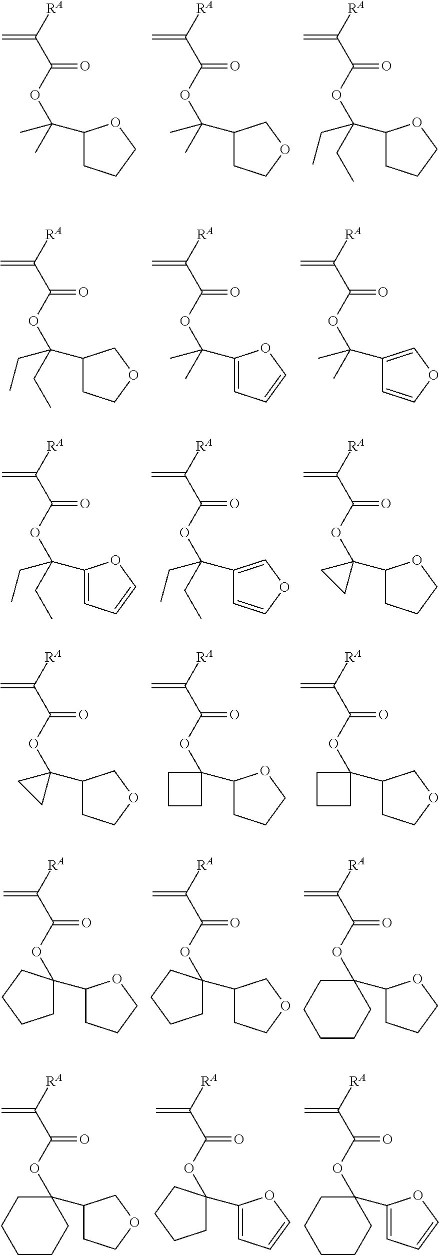

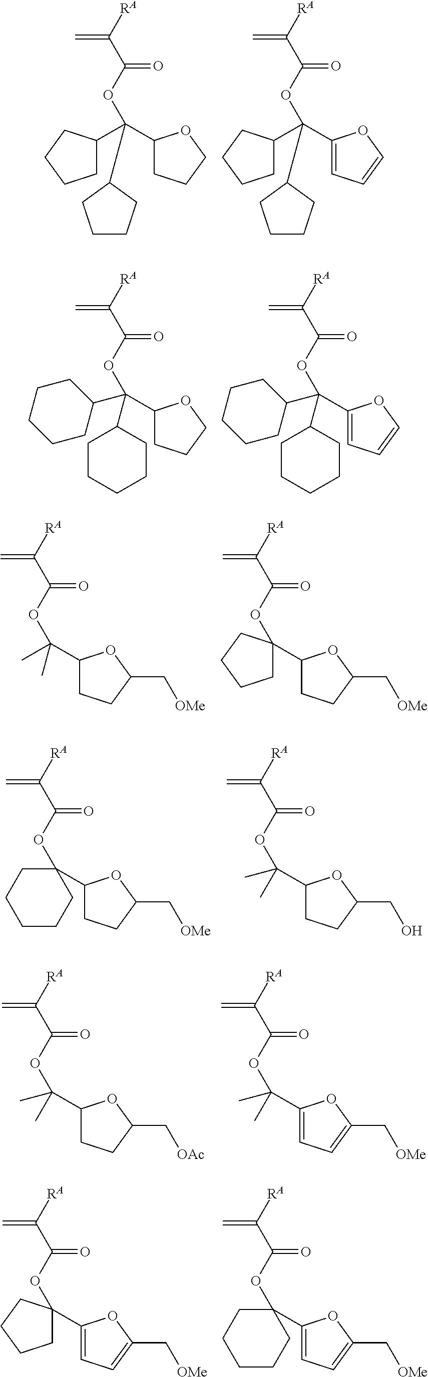

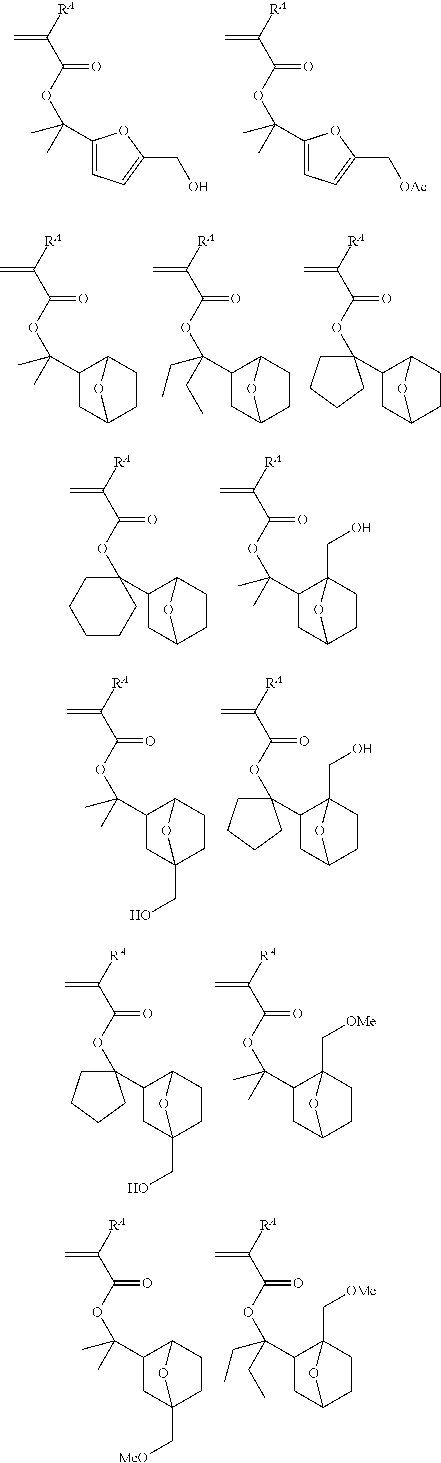

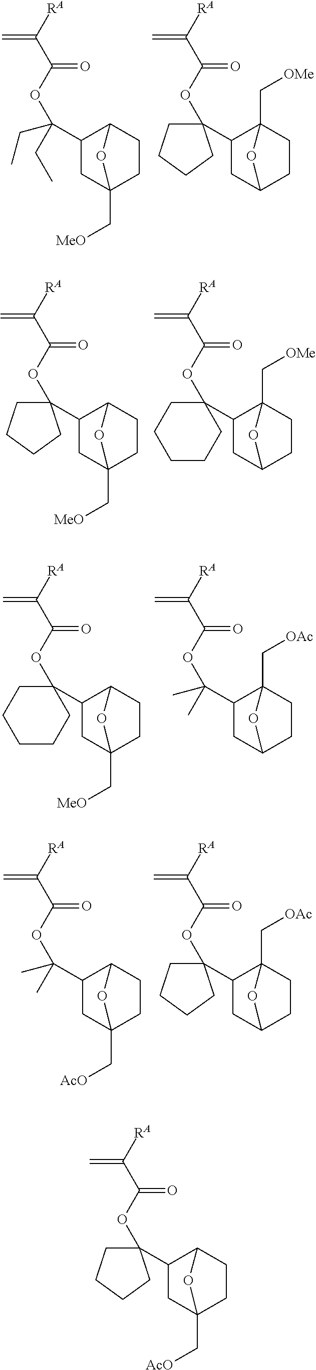

The repeat unit (c) functions as an acid generator. Preferably, the repeat units (c) include repeat units of at least one type selected from repeat units having the formulae (c1) to (c5).

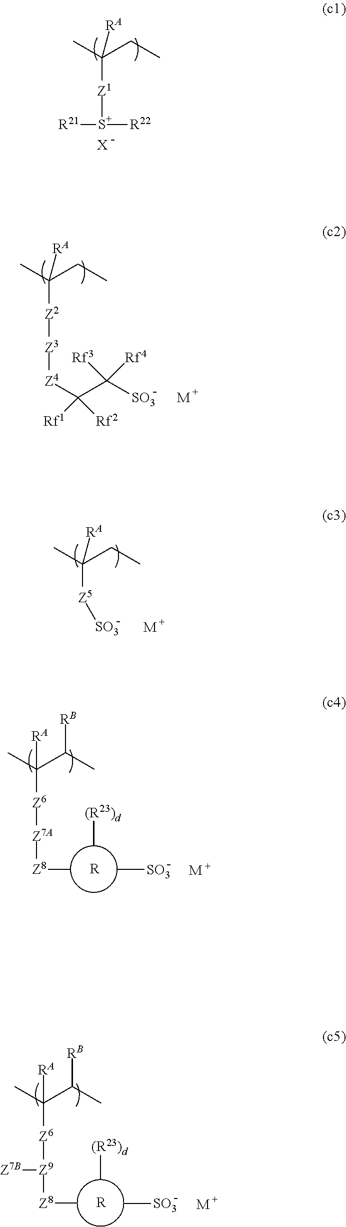

In formulae (c1) to (c3), R^{A} is each independently hydrogen or methyl.

In formula (c1), Z¹ is a single bond, a C₁-C₆ aliphatic hydrocarbylene group, phenylene group, naphthylene group, or C₇-C₁₈ group obtained by combining the foregoing, or —O—Z¹¹—, —C(═O)—O—Z¹¹— or —C(═O)—NH—Z¹¹—. Z¹¹ is a C₁-C₆ aliphatic hydrocarbylene group, phenylene group, naphthylene group, or C₇-C₁₈ group obtained by combining the foregoing, which may contain carbonyl, ester bond, ether bond or hydroxy.

In formula (c1), R²¹ and R²² are each independently halogen or a C₁-C₂₀ hydrocarbyl group which may contain a heteroatom. The hydrocarbyl group may be saturated or unsaturated and straight, branched or cyclic. Examples thereof are as will be described later for the C₁-C₂₀ hydrocarbyl group represented by R⁴¹ to R⁴⁵ in formulae (M1) and (M2).

Examples of the cation in the monomer from which repeat units (c1) are derived are shown below, but not limited thereto. Herein R^{A} is as defined above.

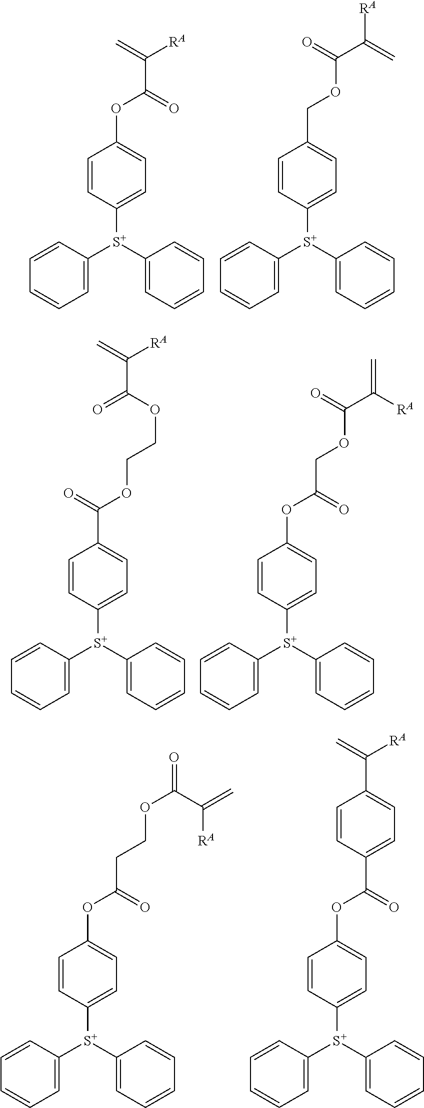

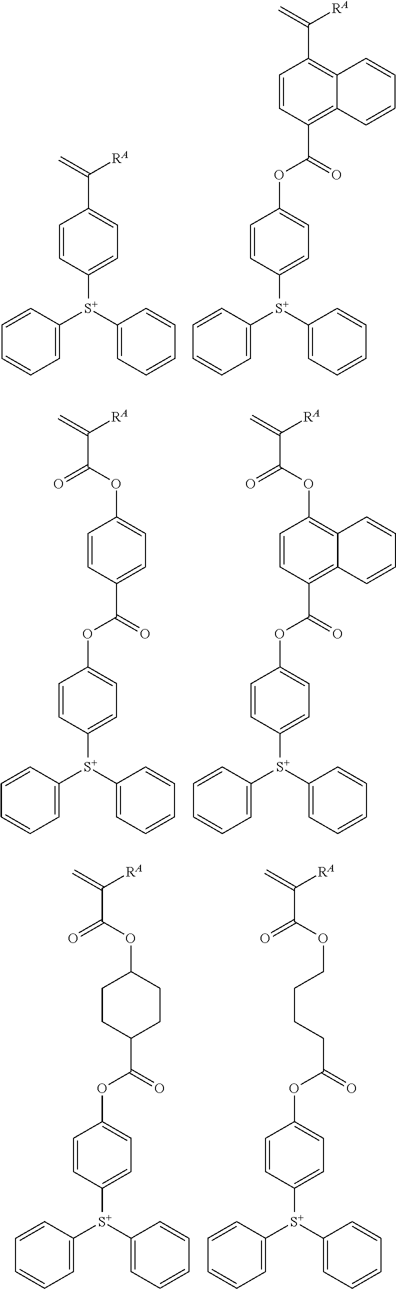

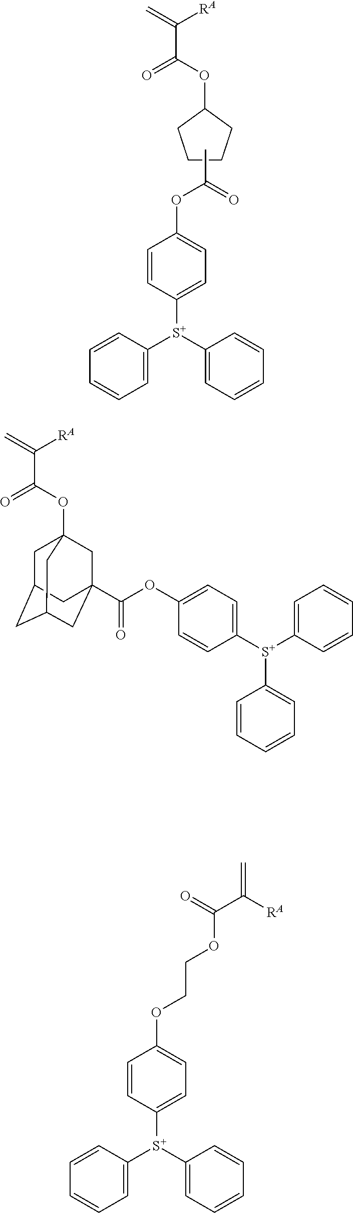

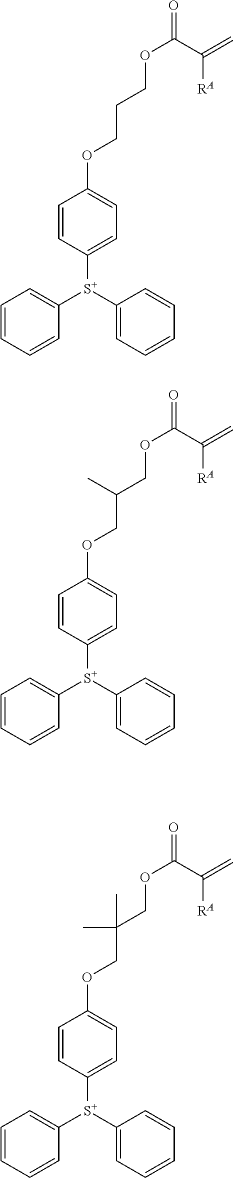

In formula (c1), X⁻ is a non-nucleophilic counter ion. Examples of the non-nucleophilic counter ion include halide ions such as chloride and bromide ions; fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkylsulfonate ions such as mesylate and butanesulfonate; imide ions such as bis(trifluoromethylsulfonyl)imide, bis(perfluoroethylsulfonyl)imide and bis(perfluorobutylsulfonyl)imide; and methide ions such as tris(trifluoromethylsulfonyl)methide and tris(perfluoroethylsulfonyl)methide.

Also included are sulfonate ions having fluorine substituted at a-position as represented by the formula (c1-1) and sulfonate ions having fluorine substituted at α-position and trifluoromethyl at β-position as represented by the formula (c1-2).

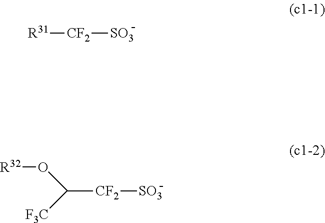

In formula (c1-1), R³¹ is hydrogen or a C₁-C₂₀ hydrocarbyl group which may contain an ether bond, ester bond, carbonyl moiety, lactone ring, or fluorine atom. The hydrocarbyl group may be saturated or unsaturated and straight, branched or cyclic.

In formula (c1-2), R³² is hydrogen, or a C₁-C₃₀ hydrocarbyl group or C₂-C₃₀ hydrocarbylcarbonyl group, which may contain an ether bond, ester bond, carbonyl moiety or lactone ring. The hydrocarbyl group and hydrocarbylcarbonyl group may be saturated or unsaturated and straight, branched or cyclic.

Anions having an iodized or brominated aromatic ring are also useful as the non-nucleophilic counter ion. These anions have the formula (c1-3).

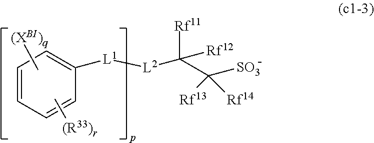

In formula (c1-3), p is an integer of 1 to 3, q is an integer of 1 to 5, r is an integer of 0 to 3, and q+r is from 1 to 5; preferably, q is an integer of 1 to 3, more preferably 2 or 3, and r is an integer of 0 to 2.

X^{BI} is iodine or bromine. A plurality of X^{BI} may be identical or different when p and/or q is 2 or more.

L¹ is a single bond, ether bond, ester bond, or a C₁-C₆ saturated hydrocarbylene group which may contain an ether bond or ester bond. The saturated hydrocarbylene group may be straight, branched or cyclic.
L² is a single bond or a C₁-C₂₀ divalent linking group when p=1, or a C₁-C₂₀ (p+1)-valent linking group when p=2 or 3. The linking group may contain an oxygen, sulfur or nitrogen atom.
R³³ is hydroxy, carboxy, fluorine, chlorine, bromine, amino group, or a C₁-C₂₀ hydrocarbyl, C₁-C₂₀ hydrocarbyloxy, C₂-C₂₀ hydrocarbylcarbonyl, C₂-C₂₀ hydrocarbyloxycarbonyl, C₂-C₂₀ hydrocarbylcarbonyloxy, or C₁-C₂₀ hydrocarbylsulfonyloxy group, which may contain fluorine, chlorine, bromine, hydroxy, amino or ether bond, or —N(R^{33A})(R^{33B}), —N(R^{33C})—C(═O)—R^{33D} or —N(R^{33C})—C(═O)—O—R^{33D}. R^{33A} and R^{33B} are each independently hydrogen or a C₁-C₆ saturated hydrocarbyl group. R^{33C} is hydrogen, or a C₁-C₆ saturated hydrocarbyl group which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. R^{33D} is a C₁-C₁₆ aliphatic hydrocarbyl group, C₆-C₁₂ aryl group or C₇-C₁₅ aralkyl group, which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy, and hydrocarbylsulfonyloxy groups may be straight, branched or cyclic. A plurality of R³³ may be identical or different when p and/or r is 2 or more.

Of these, R³³ is preferably hydroxy, —N(R^{33C})—C(═O)—R^{33D}, —N(R^{33C})—C(═O)—O—R^{33D}, fluorine, chlorine, bromine, methyl or methoxy.
Rf¹¹ to Rf¹⁴ are each independently hydrogen, fluorine or trifluoromethyl. At least one of Rf¹¹ to Rf¹⁴ is fluorine or trifluoromethyl. Rf¹¹ and Rf¹², taken together, may form a carbonyl group. More preferably, both Rf¹³ and Rf¹⁴ are fluorine.

Examples of the anion having formula (c1-3) are shown below, but not limited thereto. X^{BI} is as defined above.

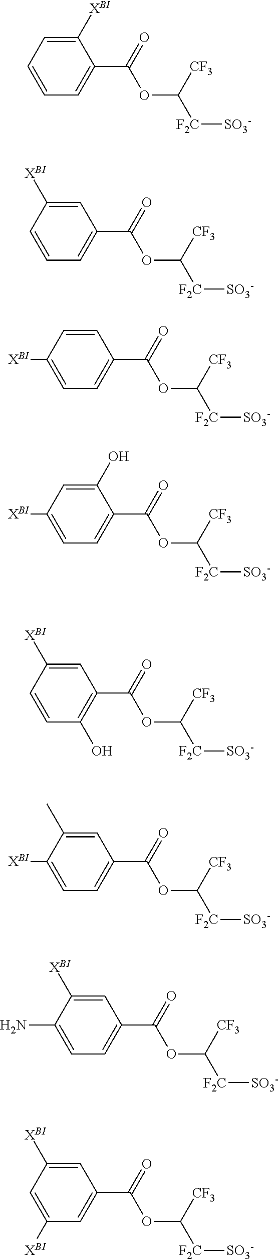

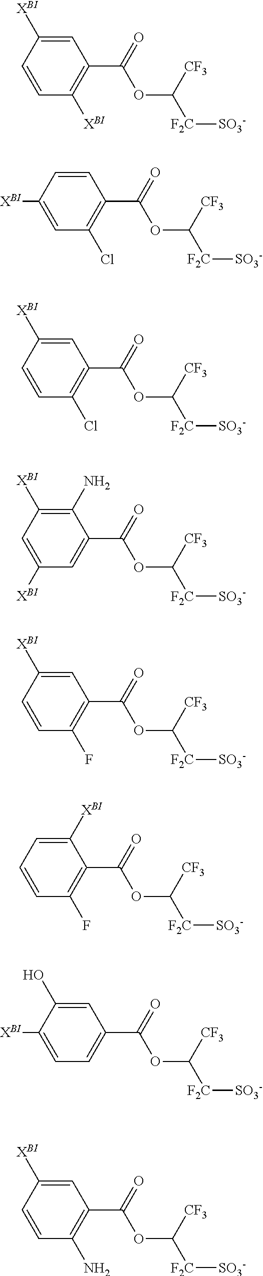

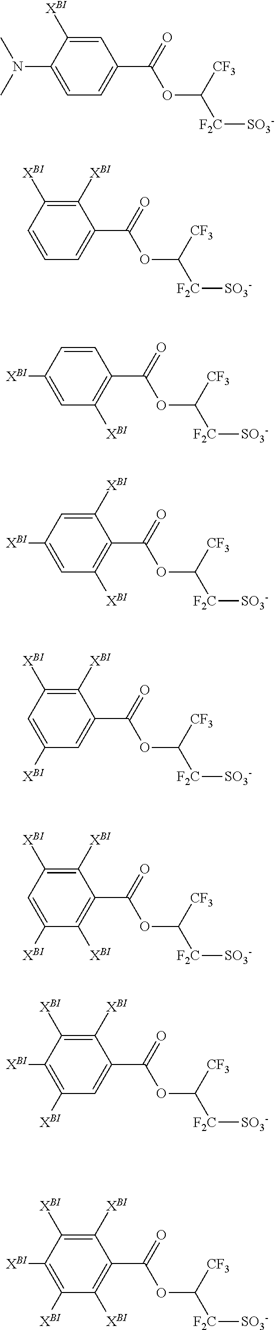

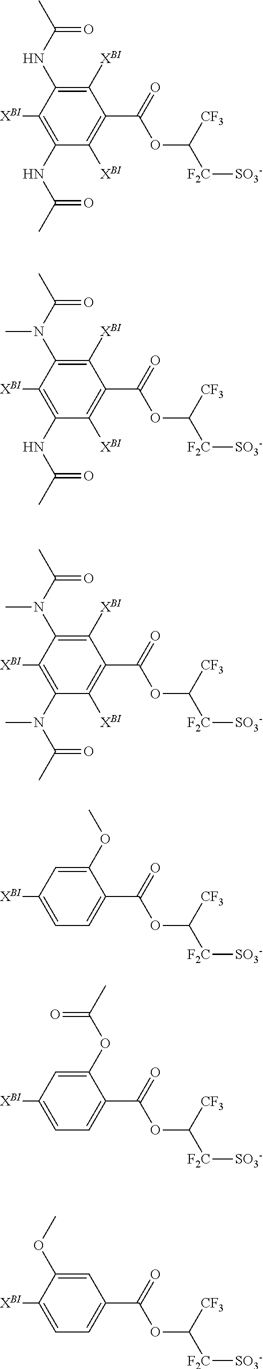

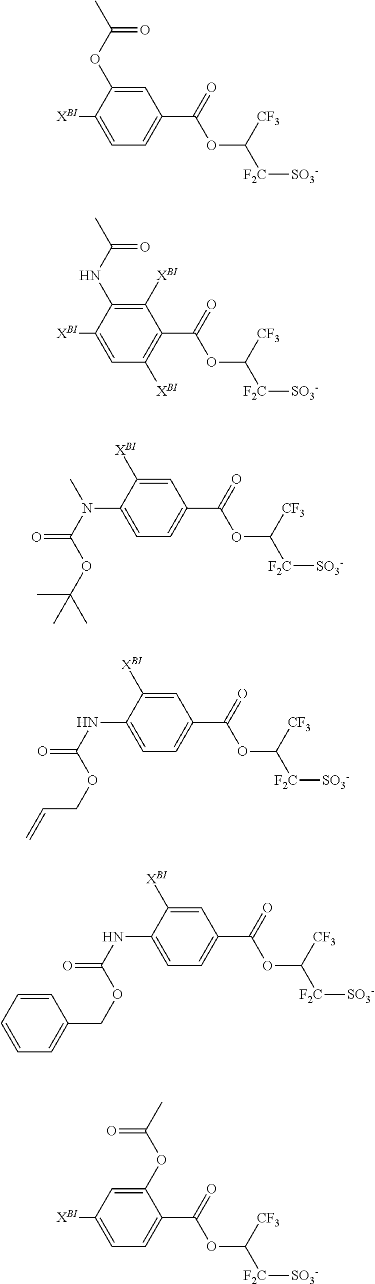

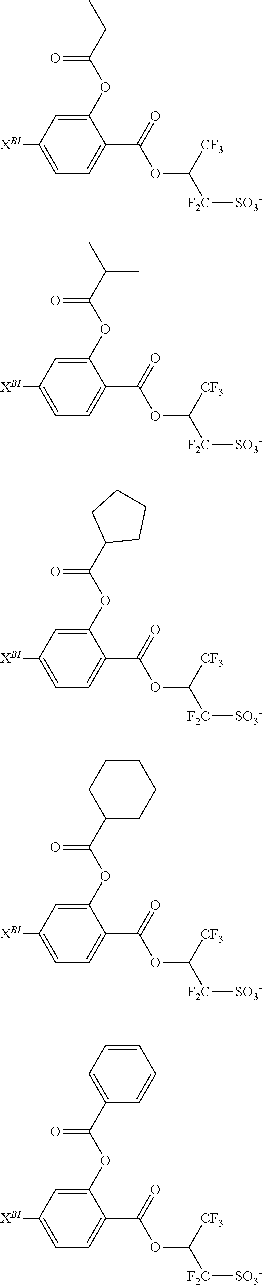

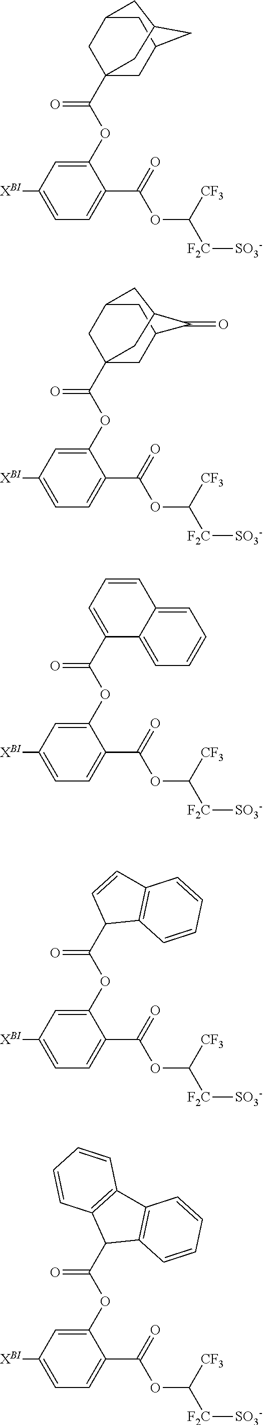

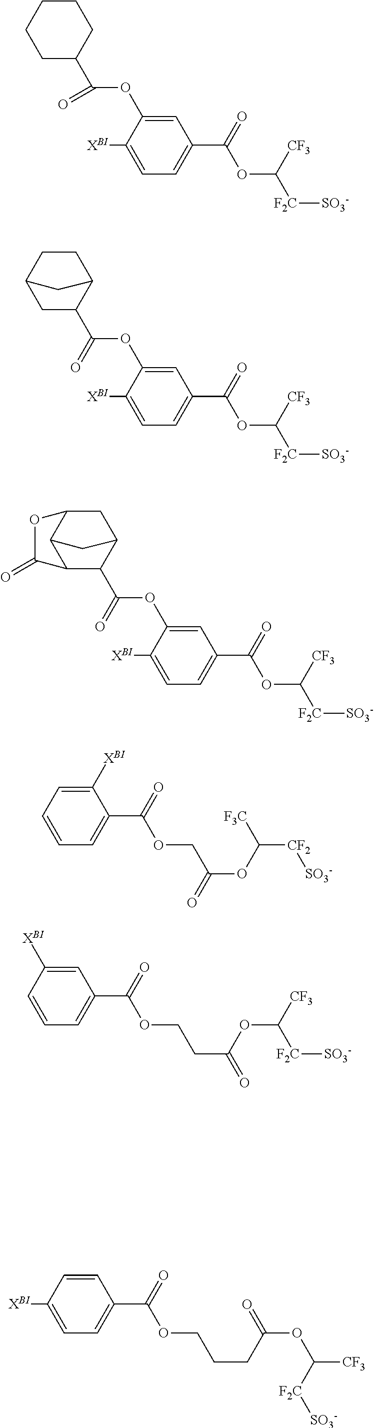

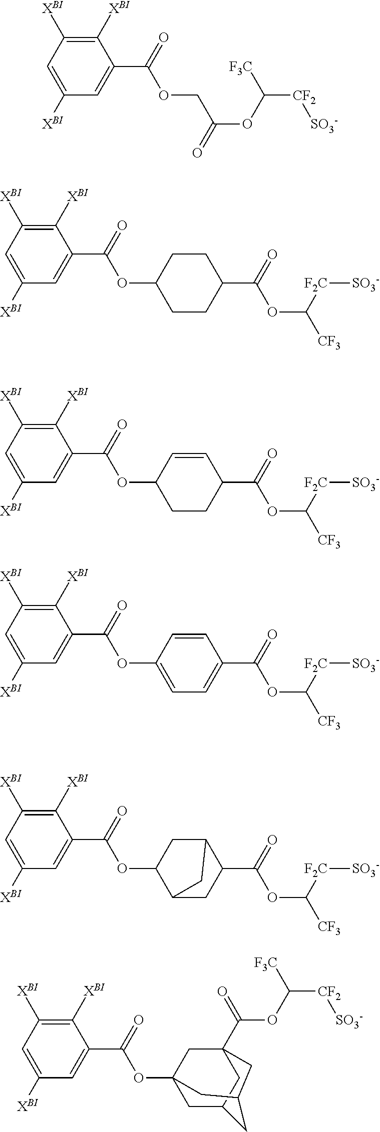

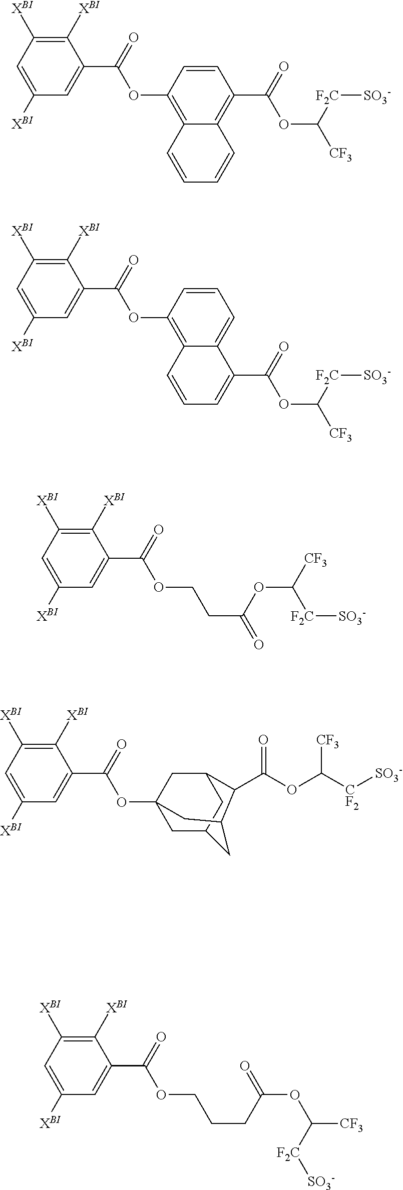

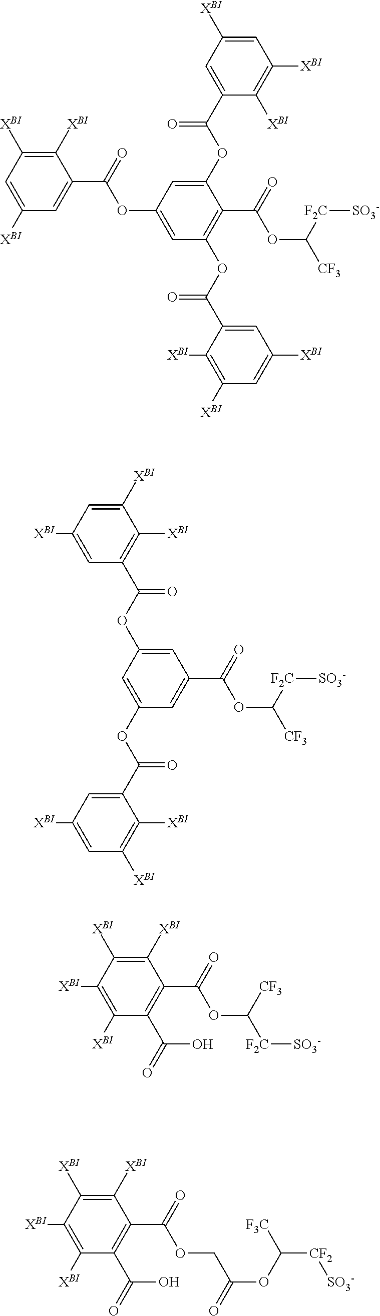

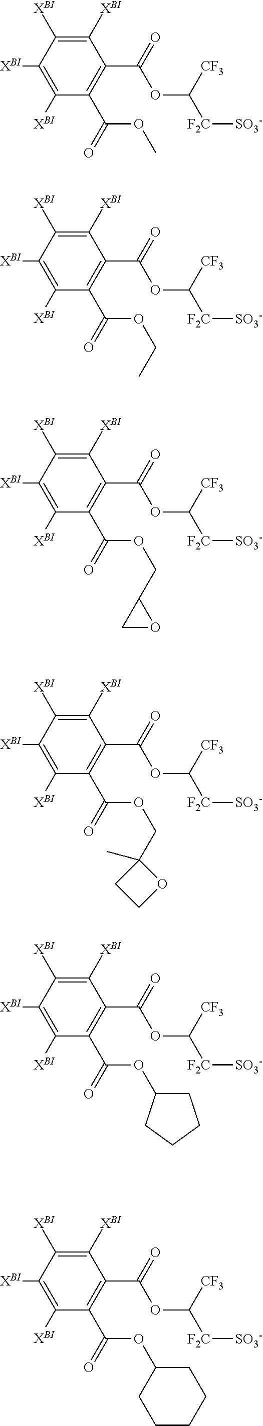

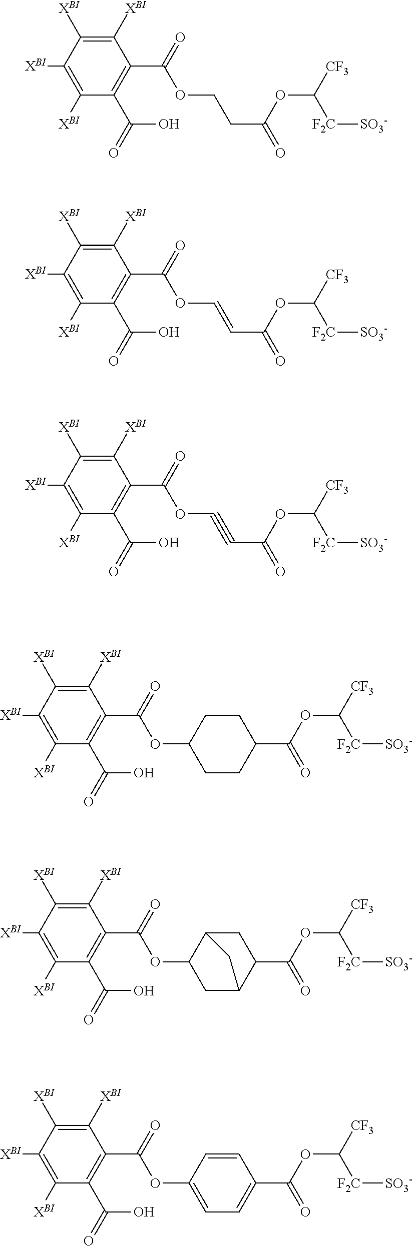

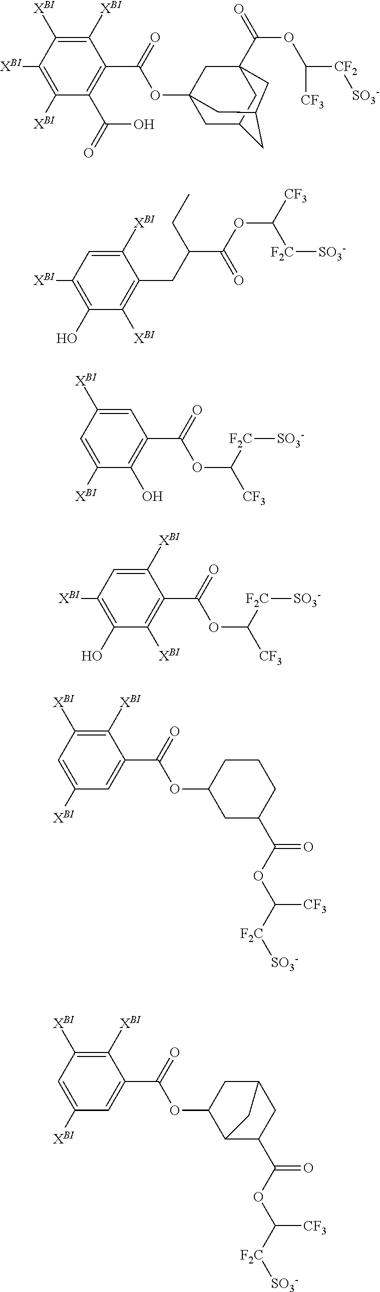

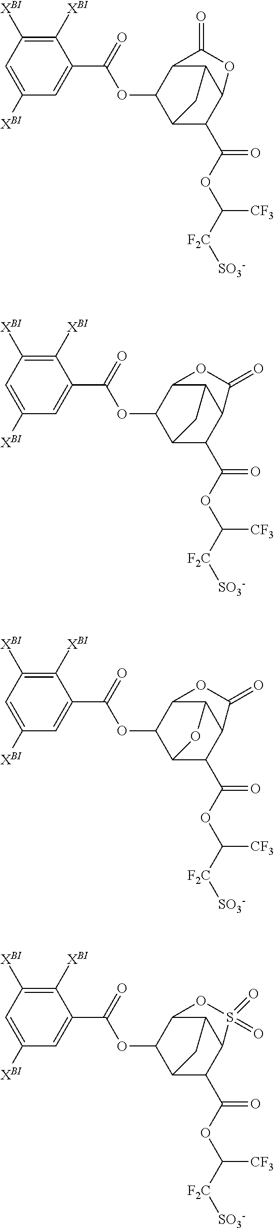

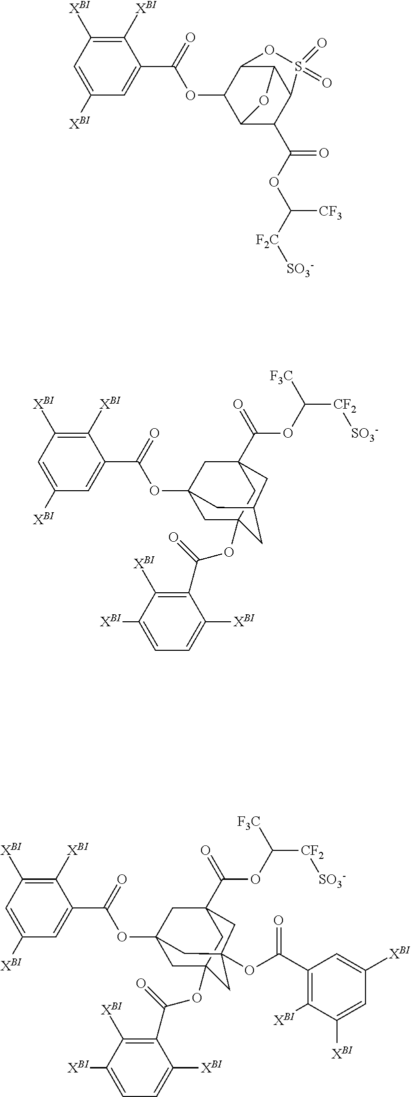

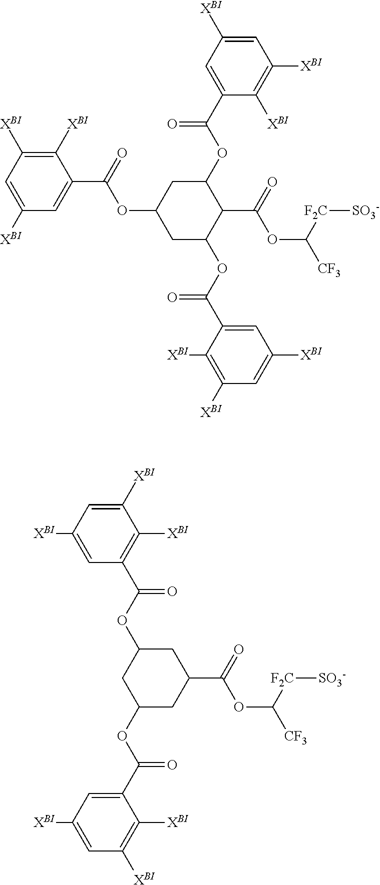

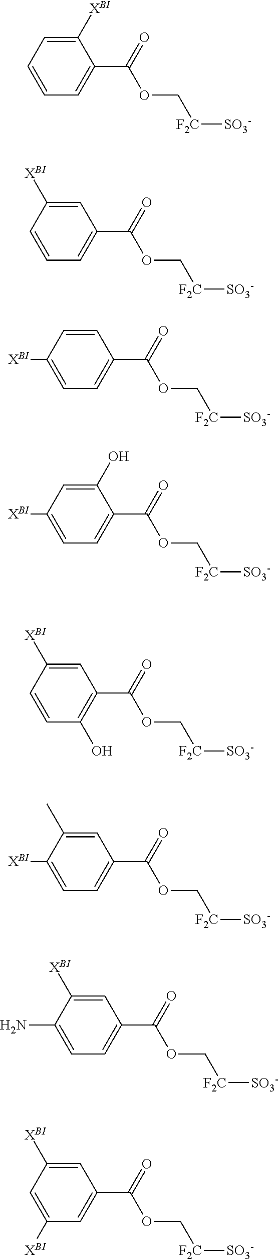

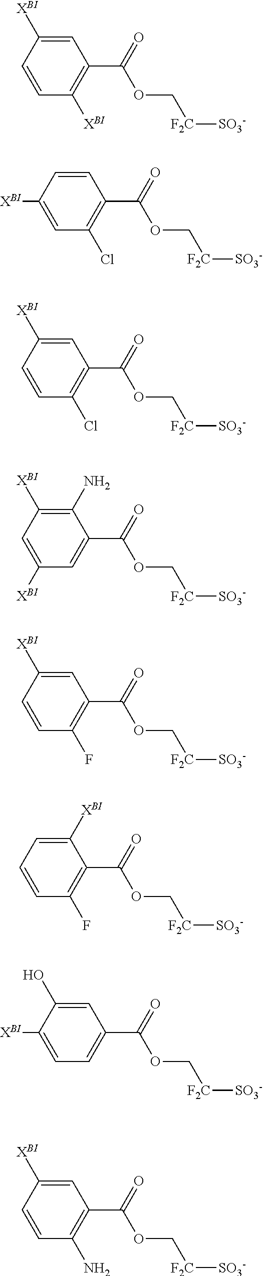

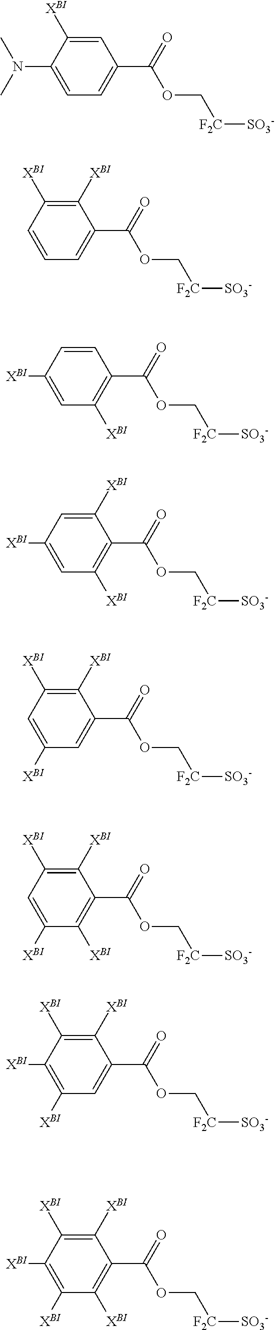

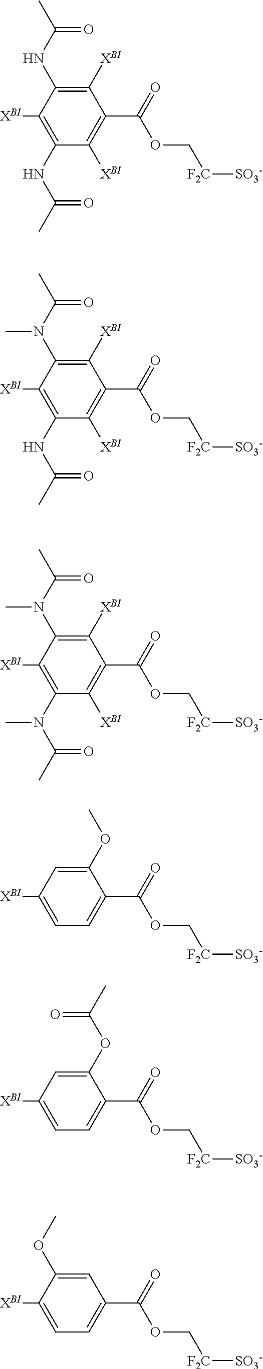

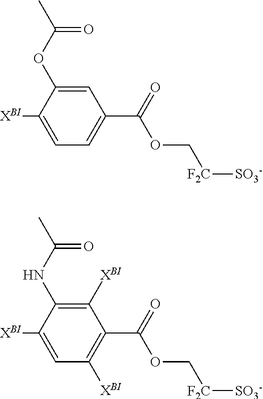

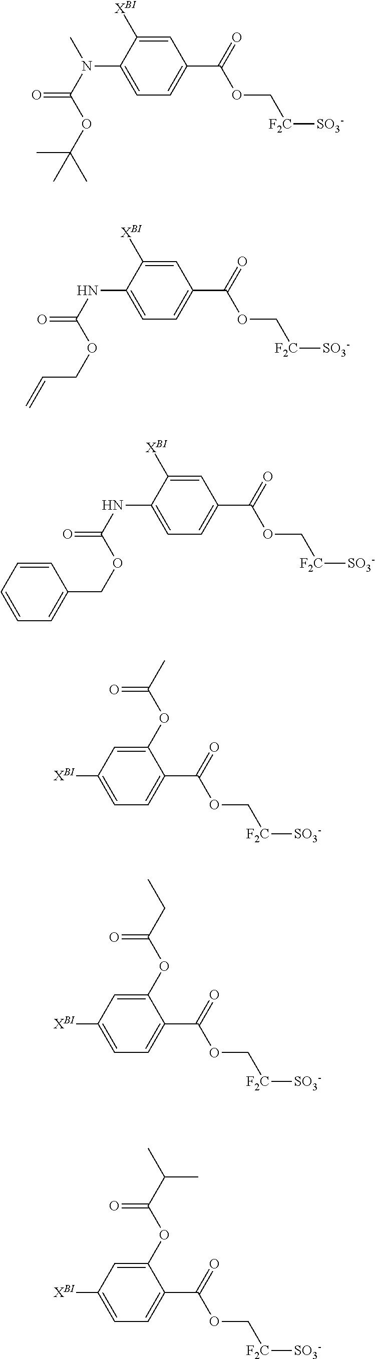

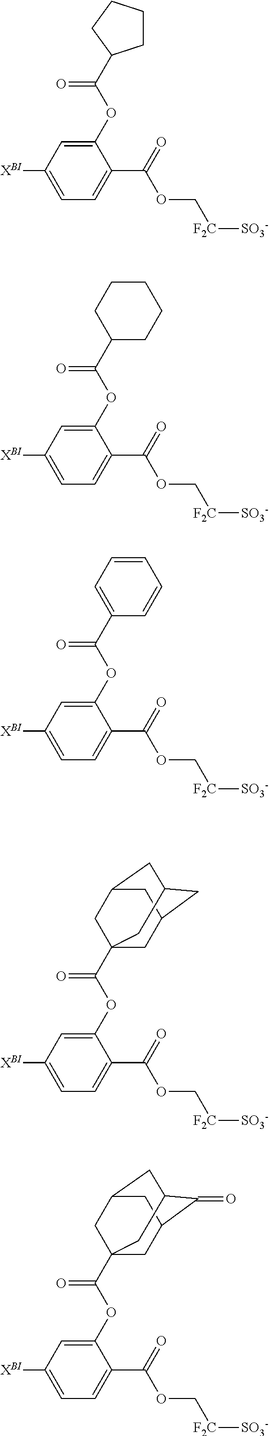

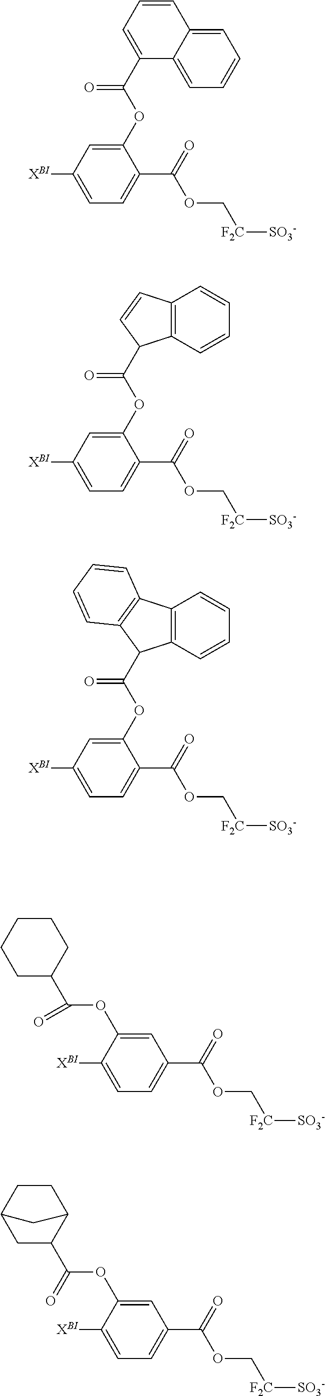

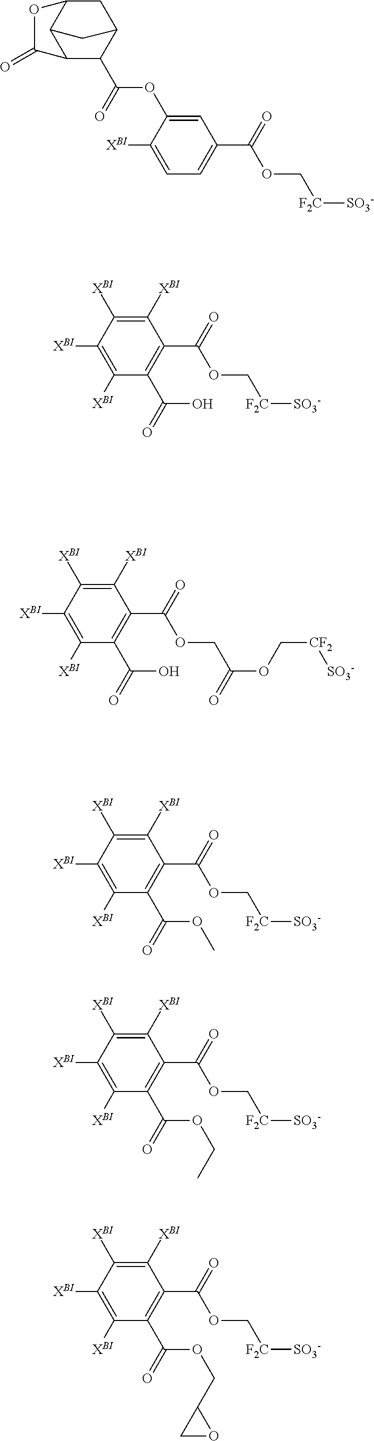

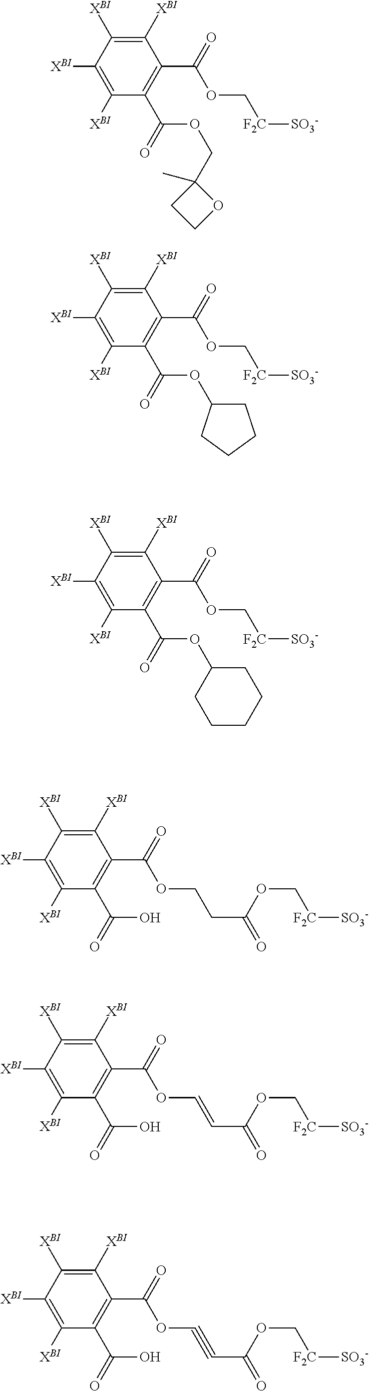

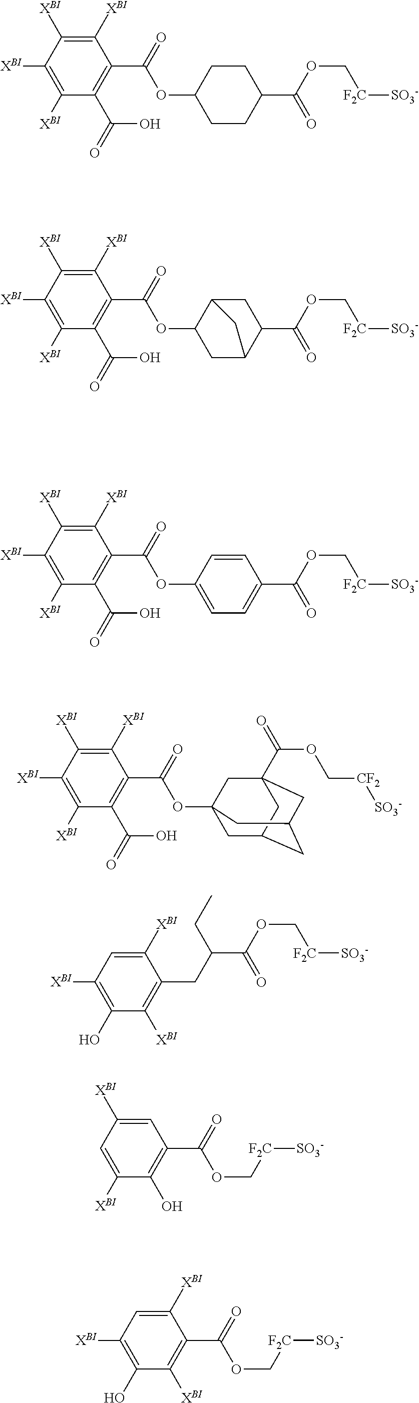

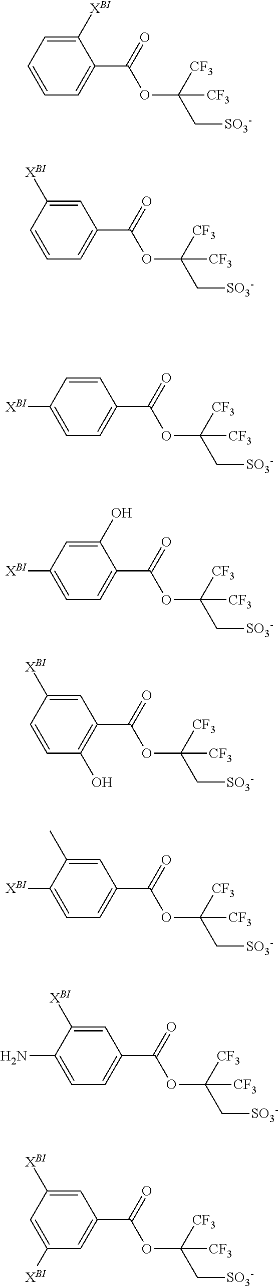

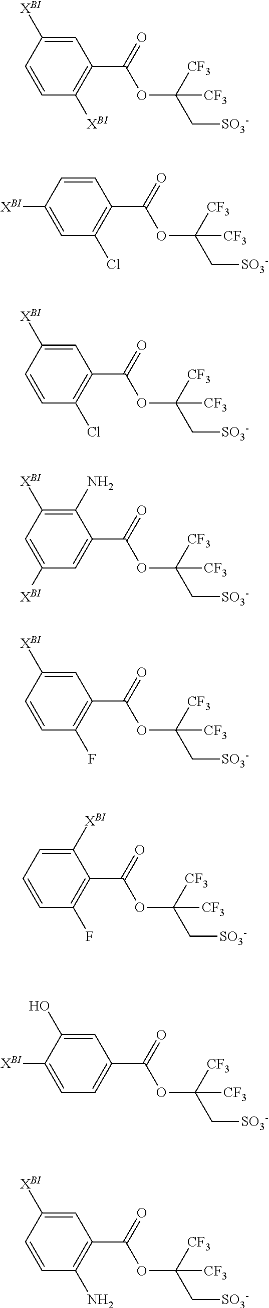

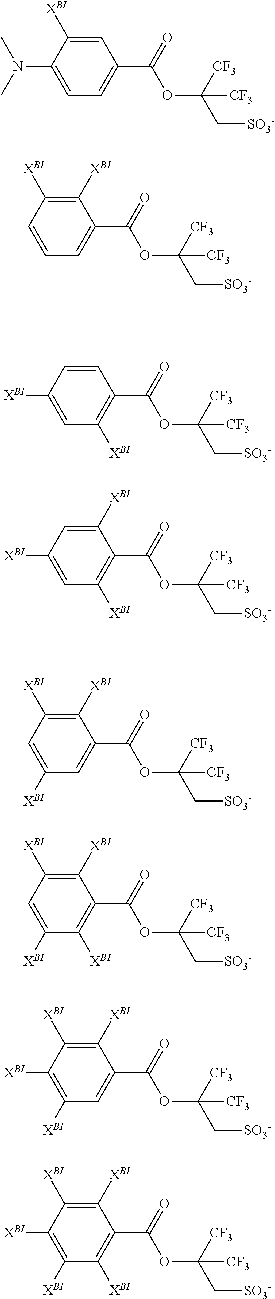

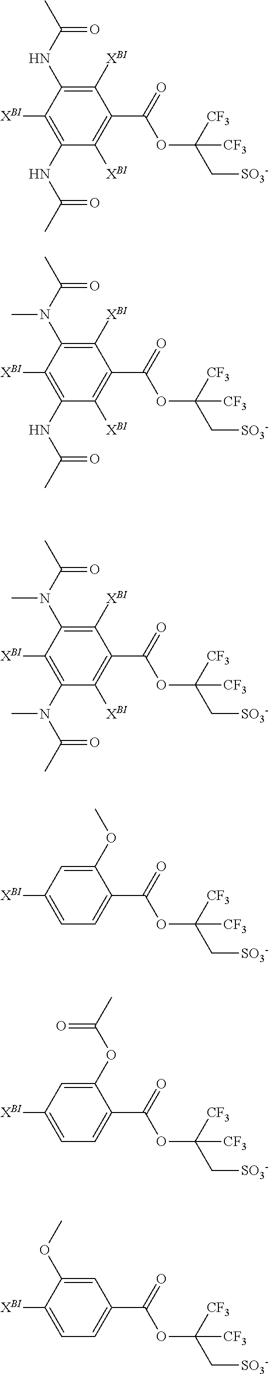

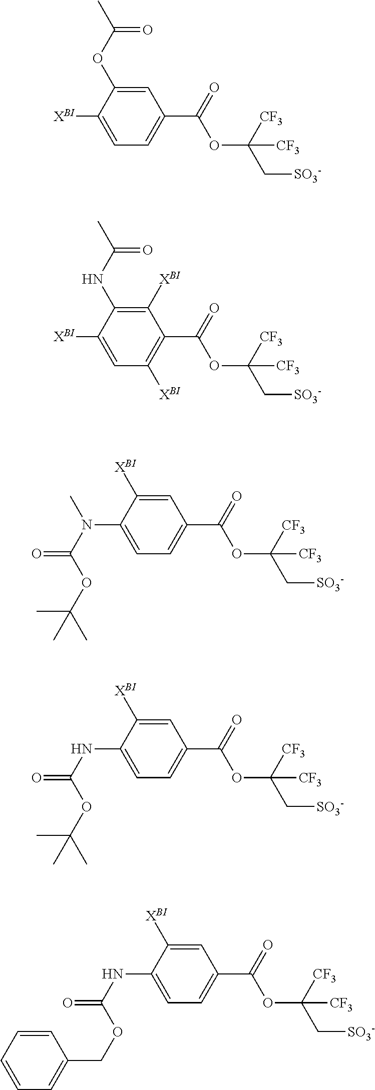

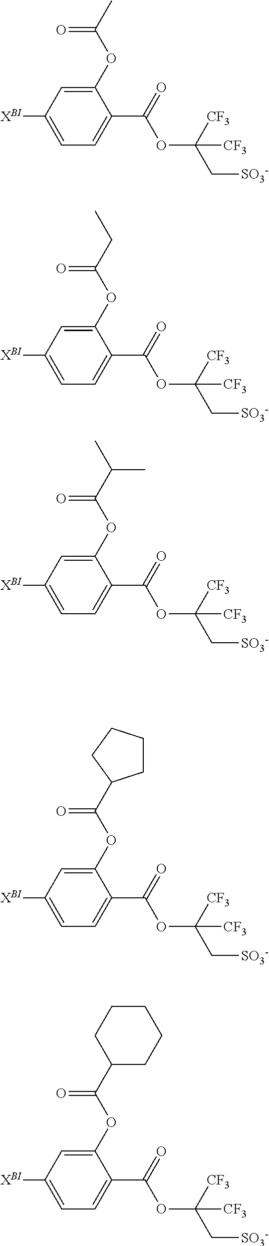

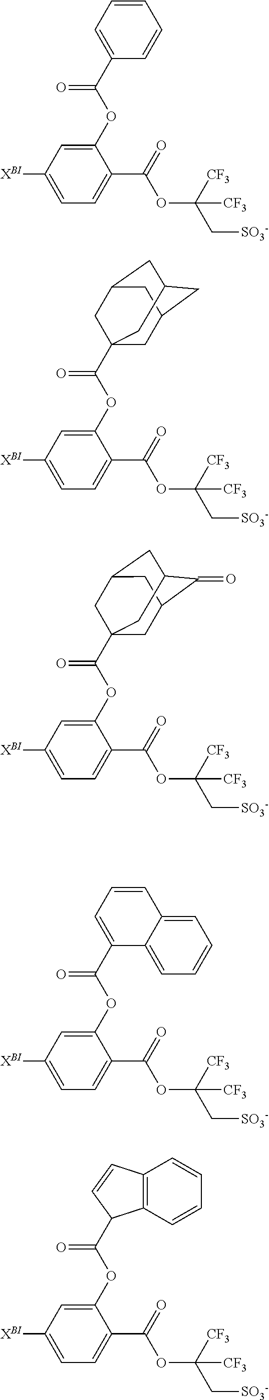

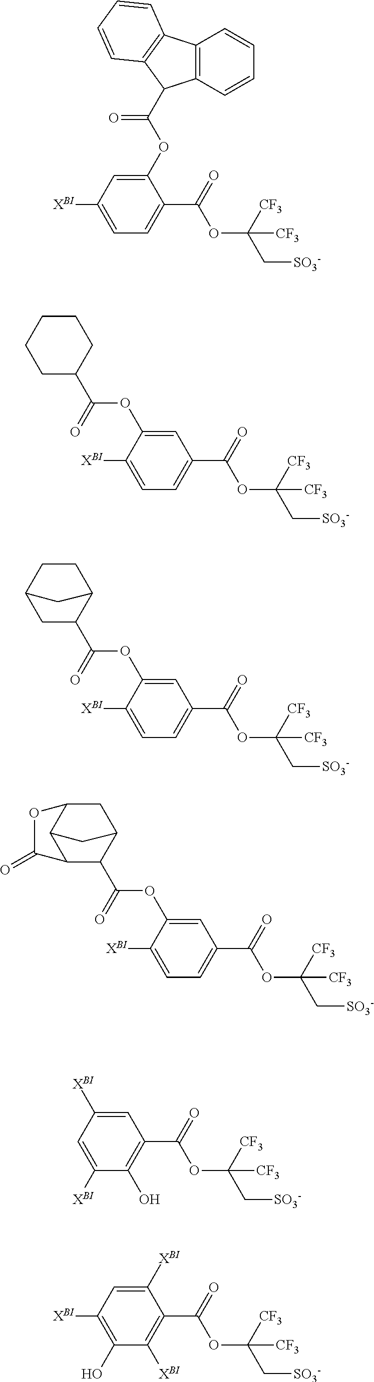

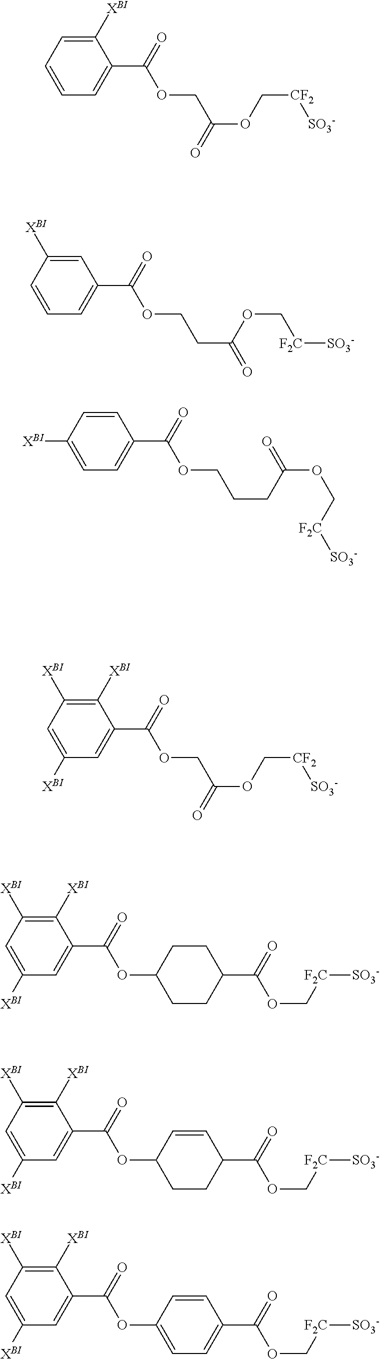

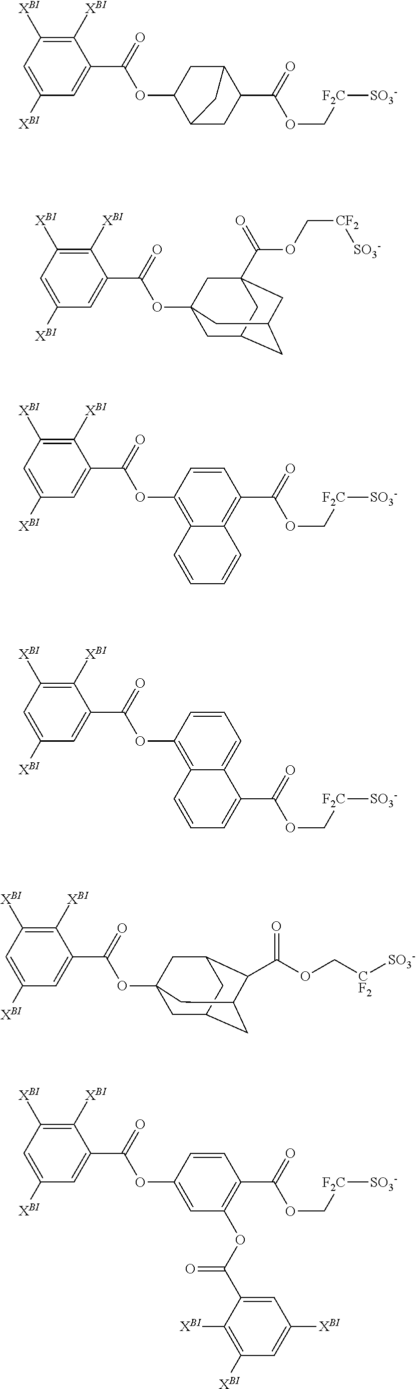

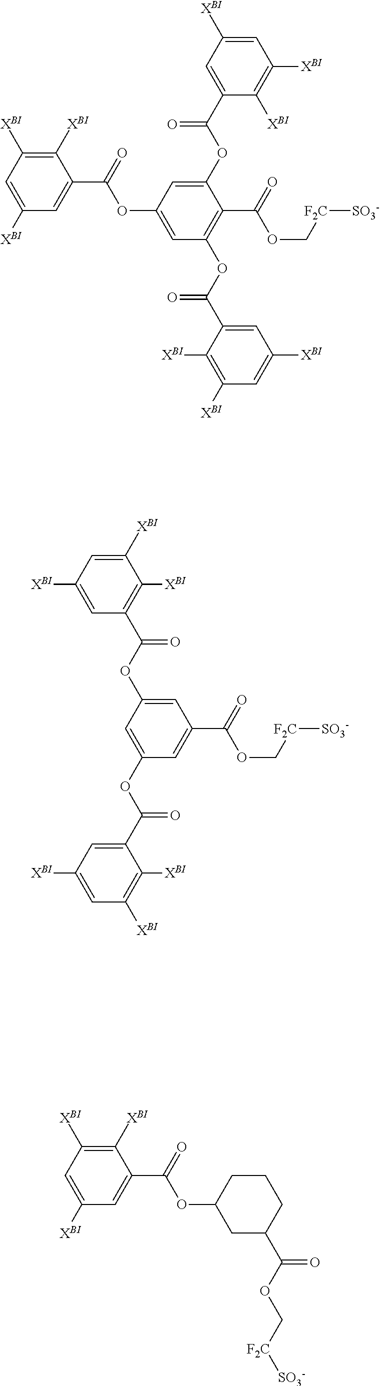

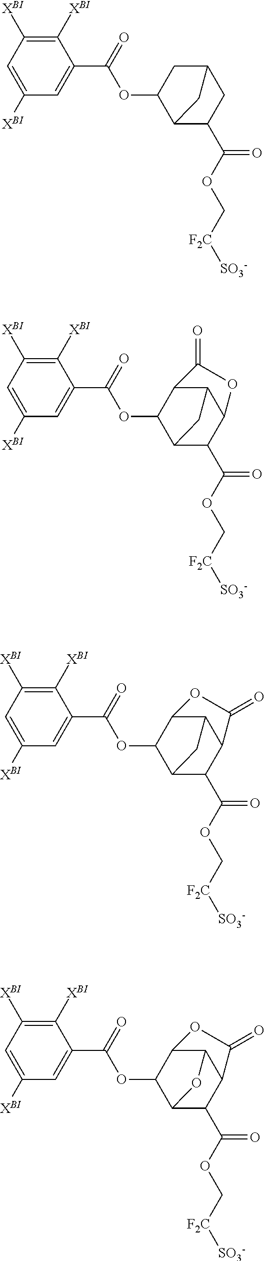

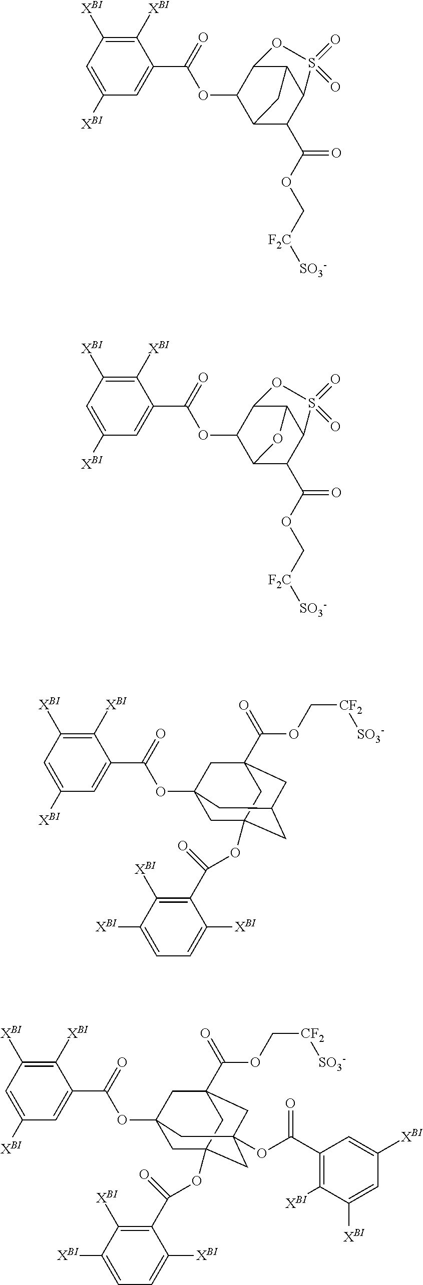

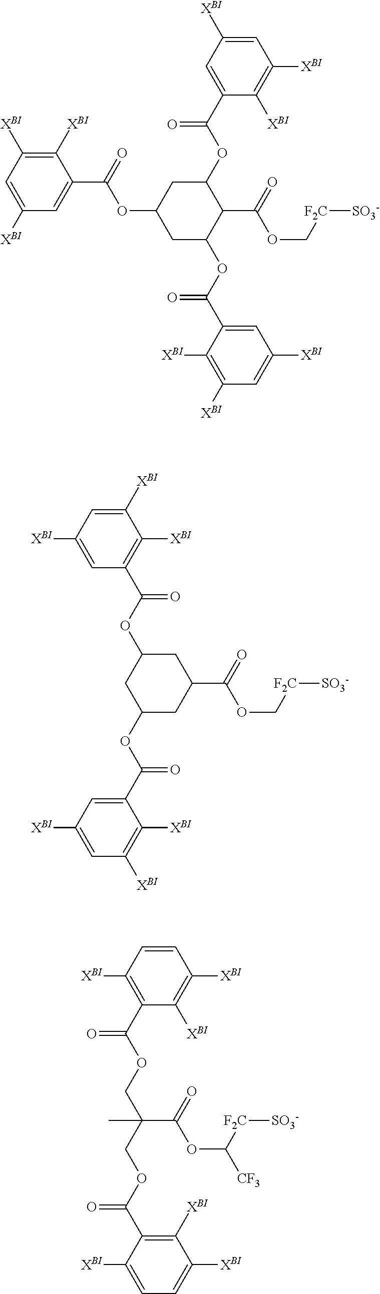

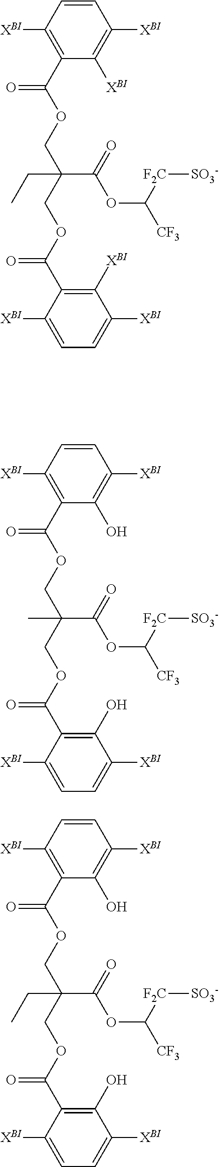

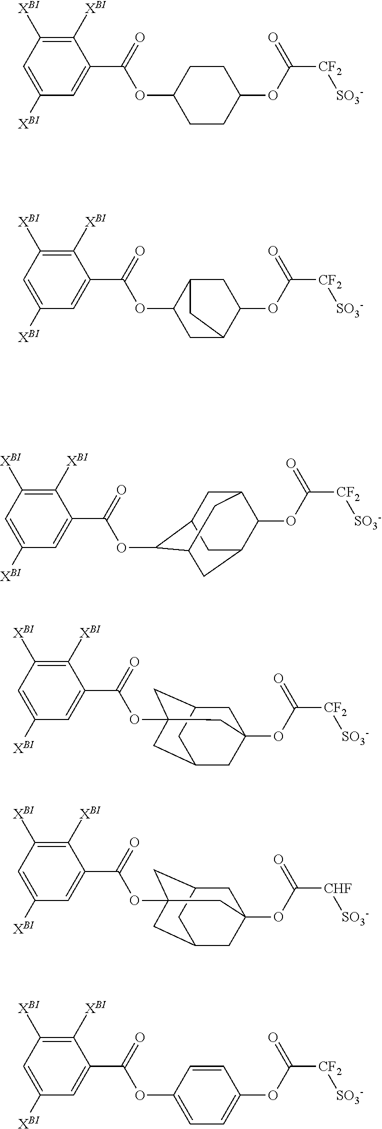

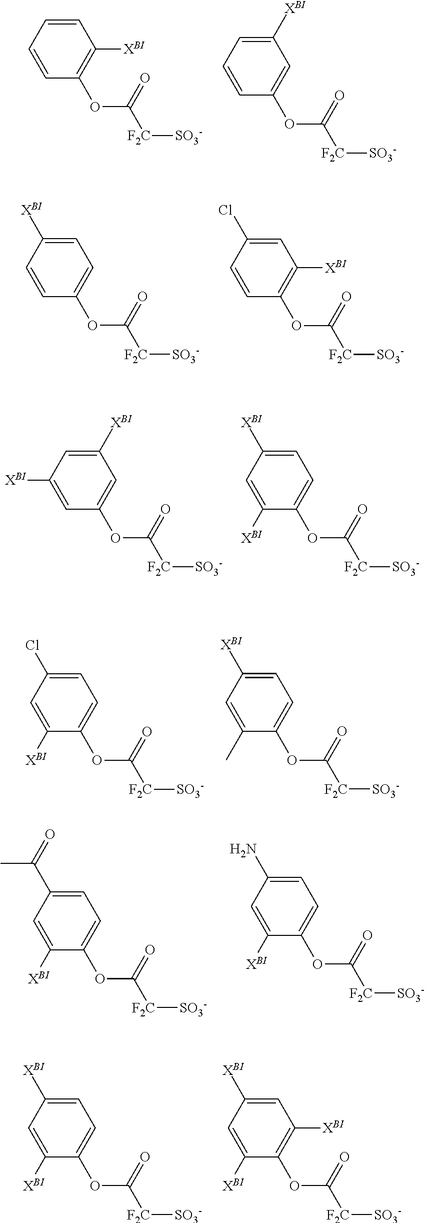

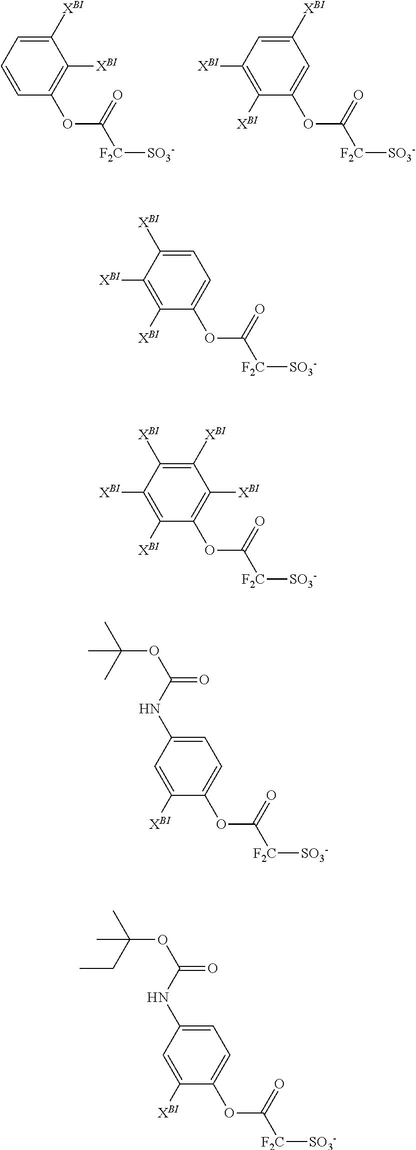

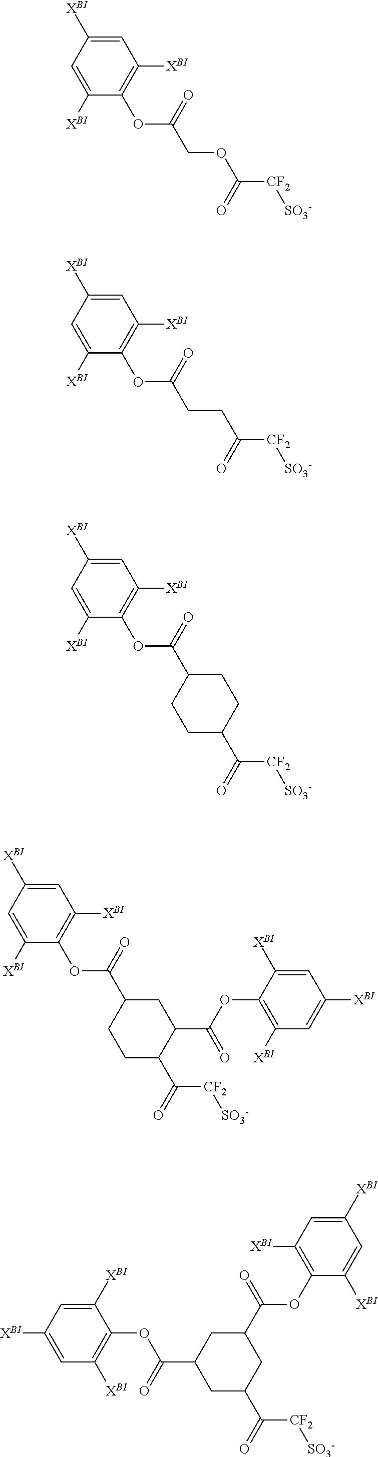

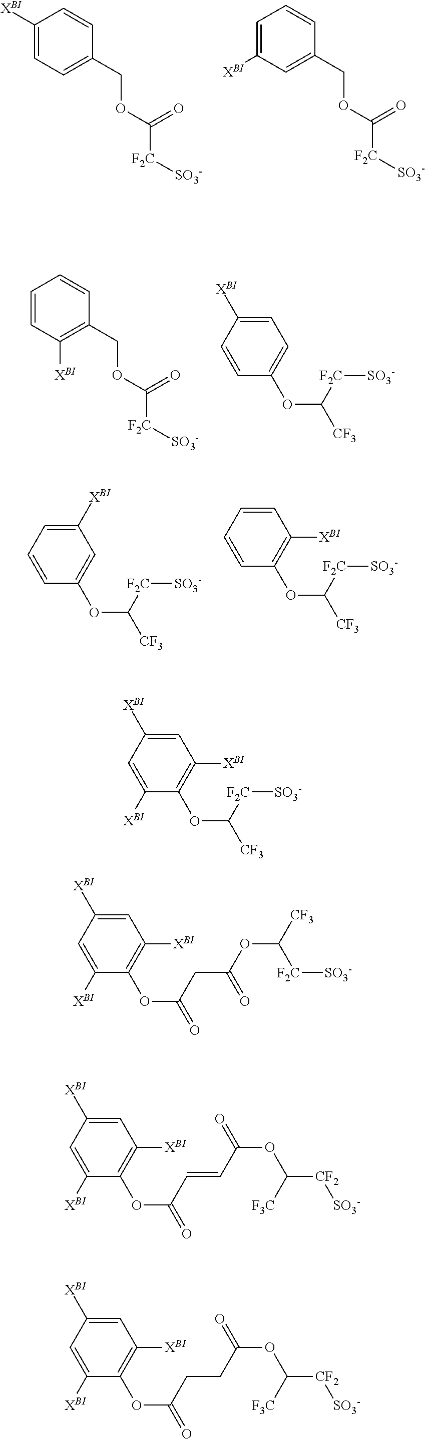

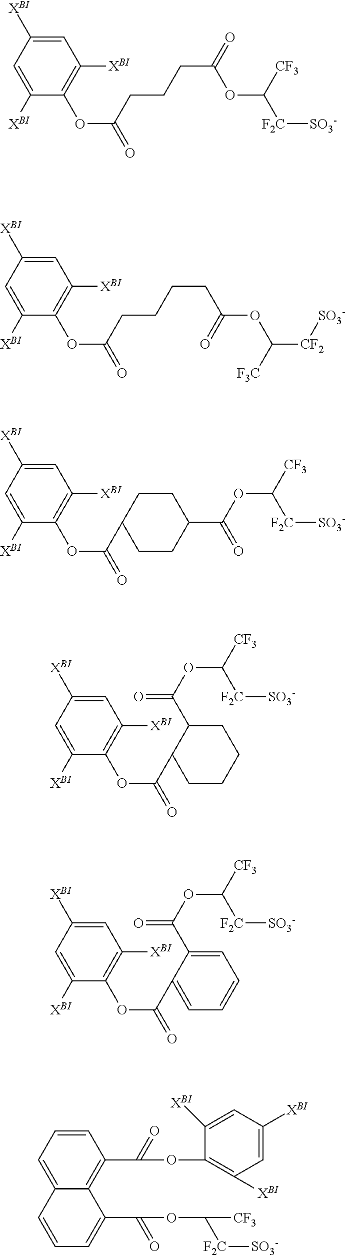

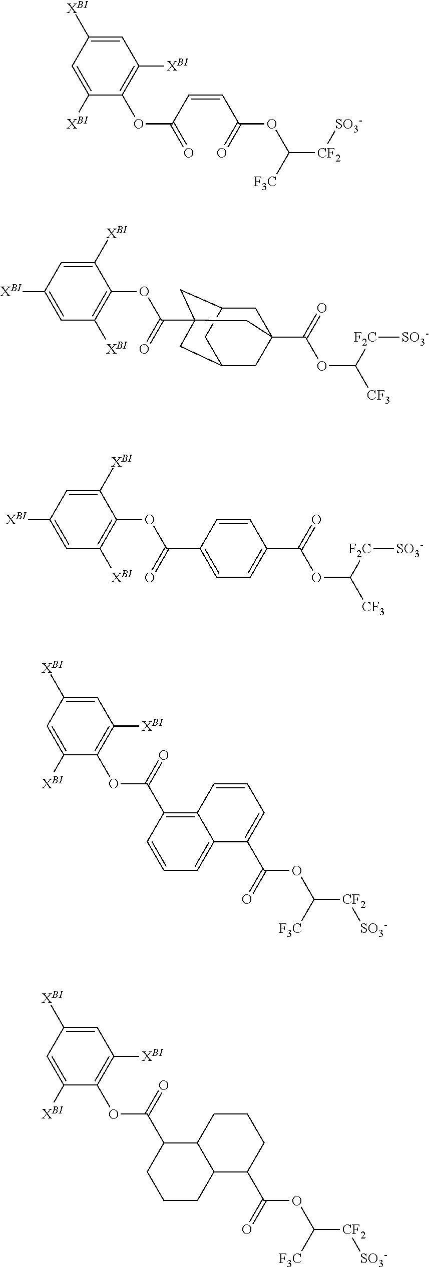

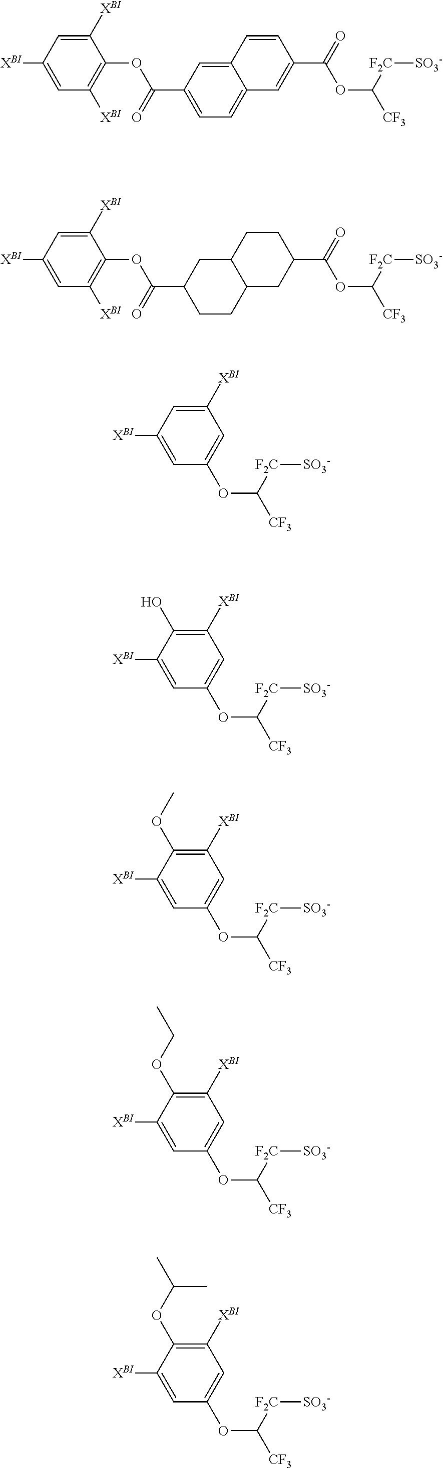

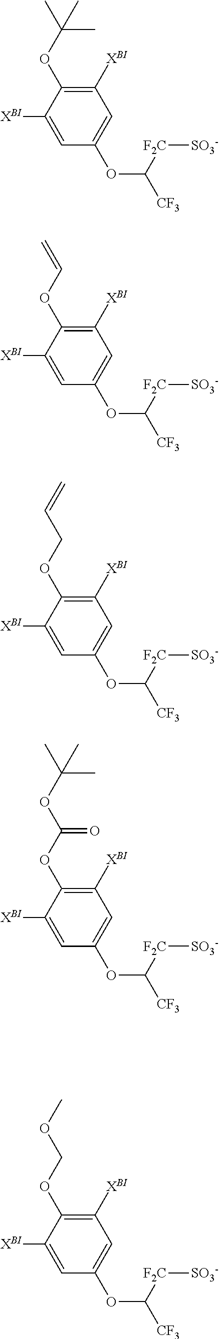

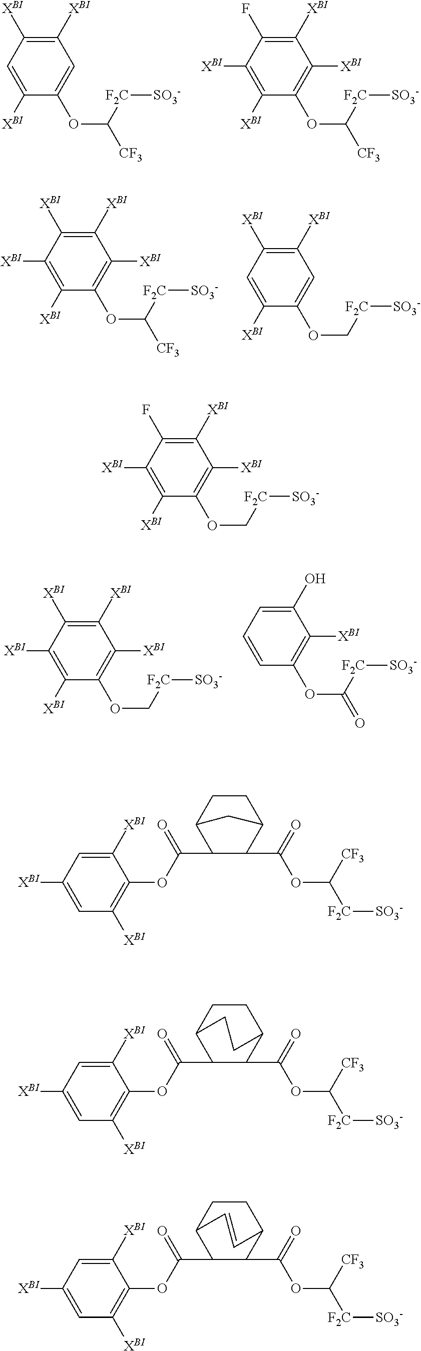

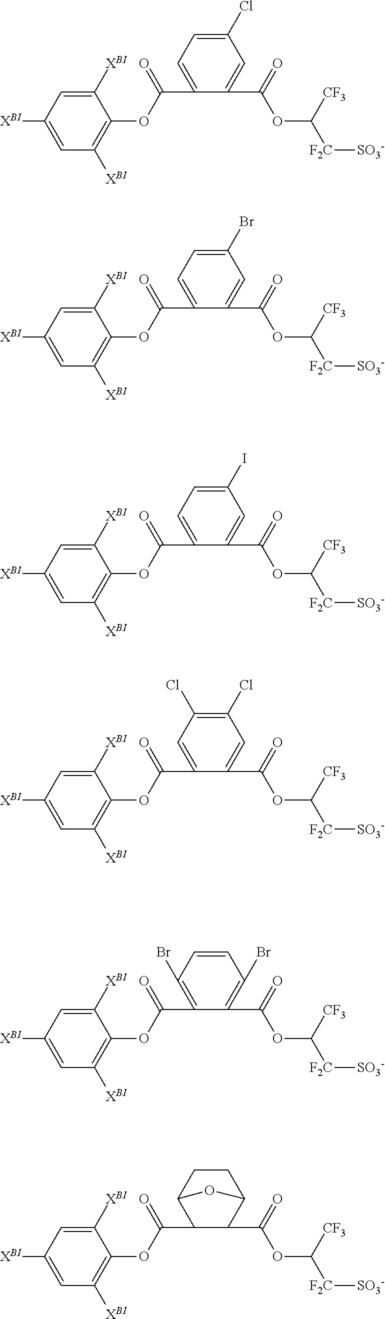

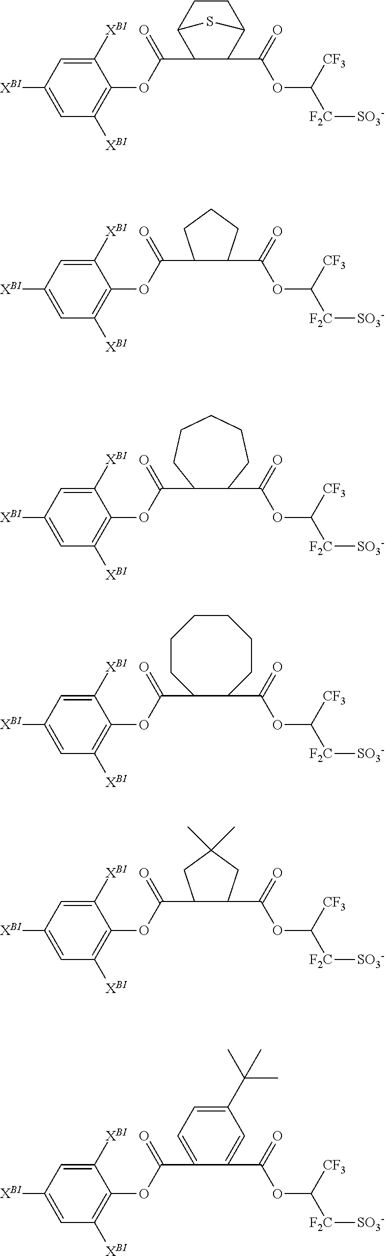

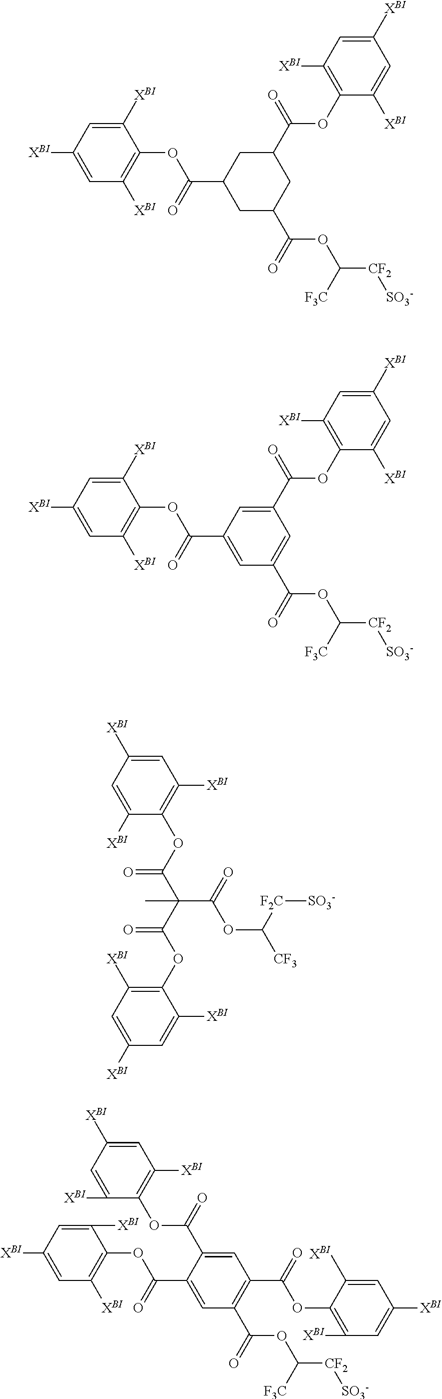

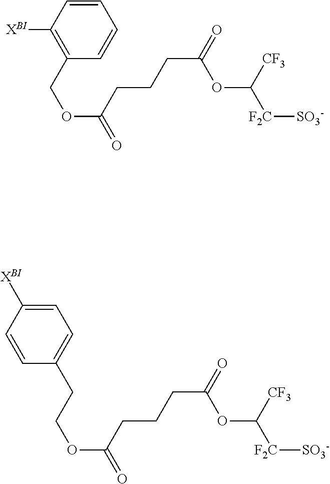

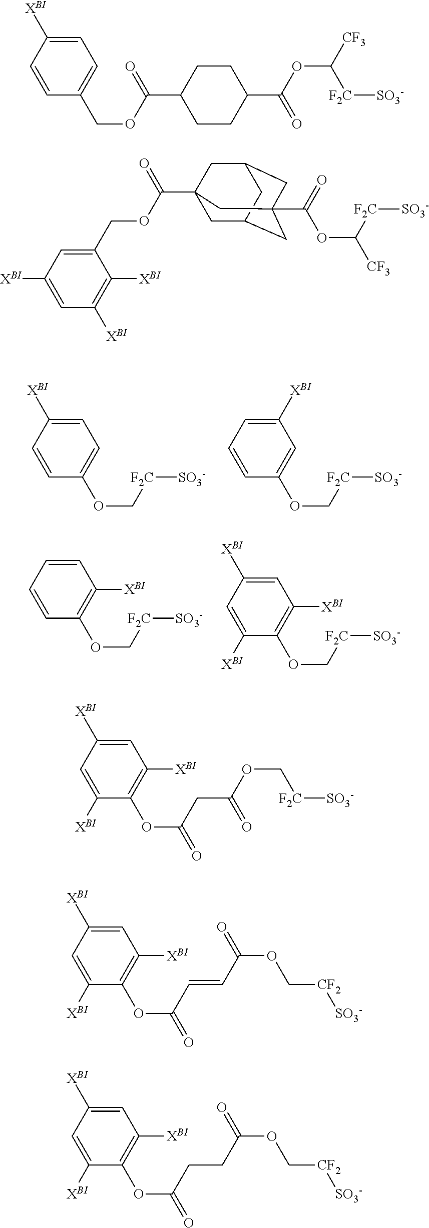

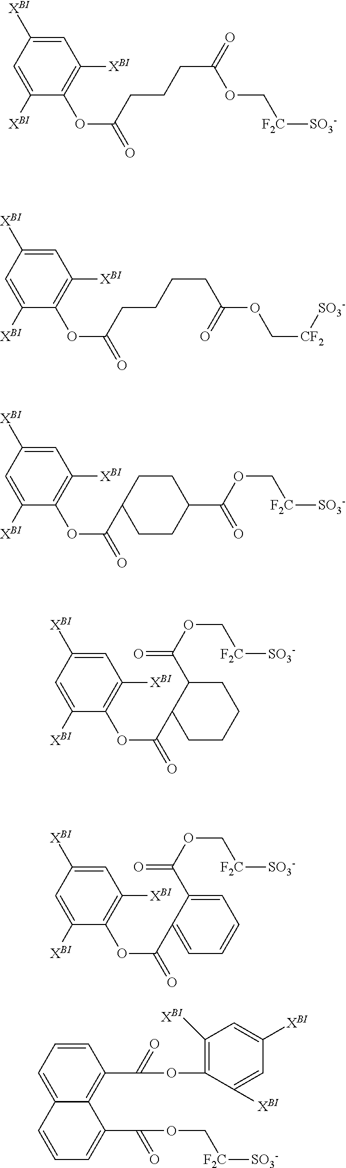

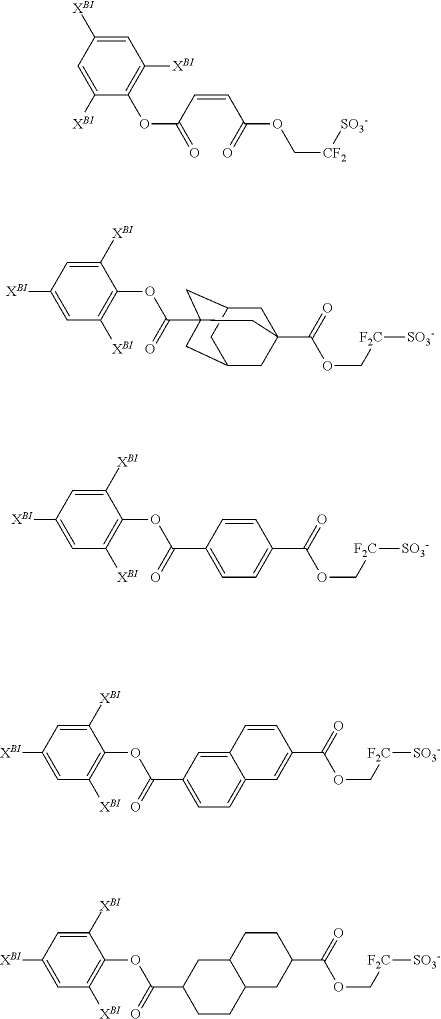

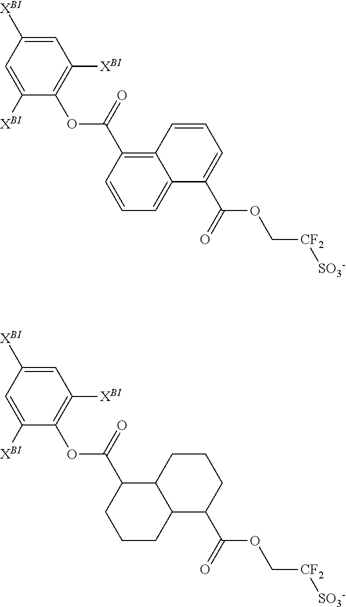

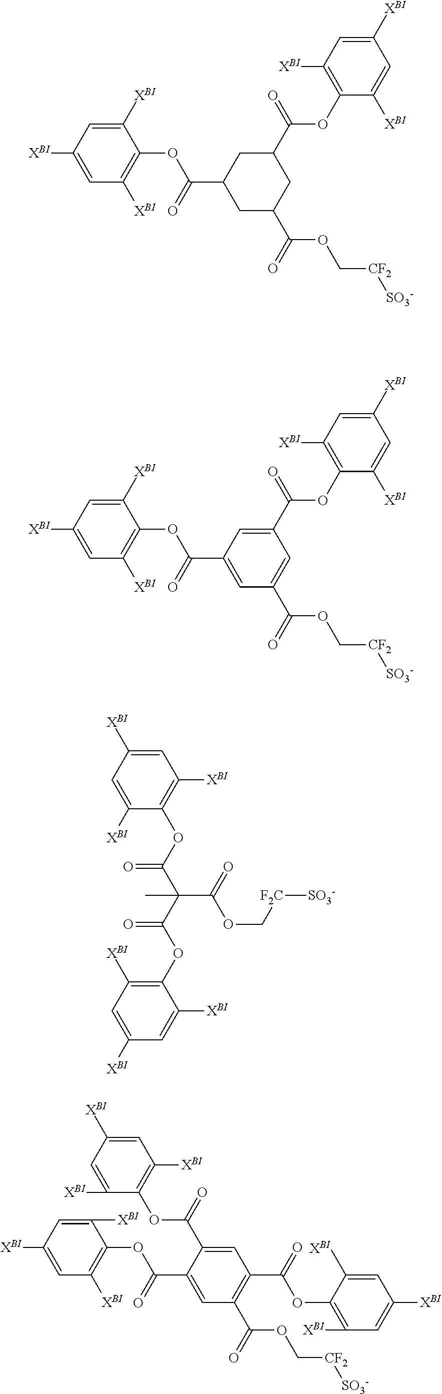

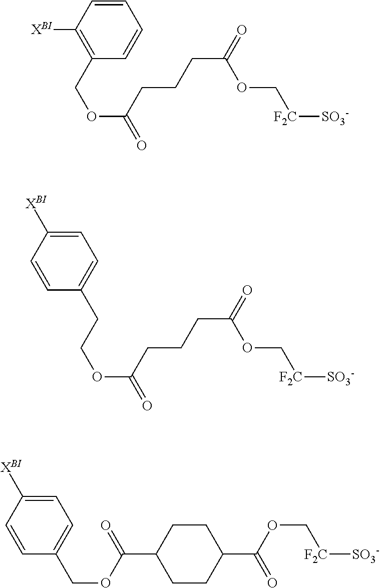

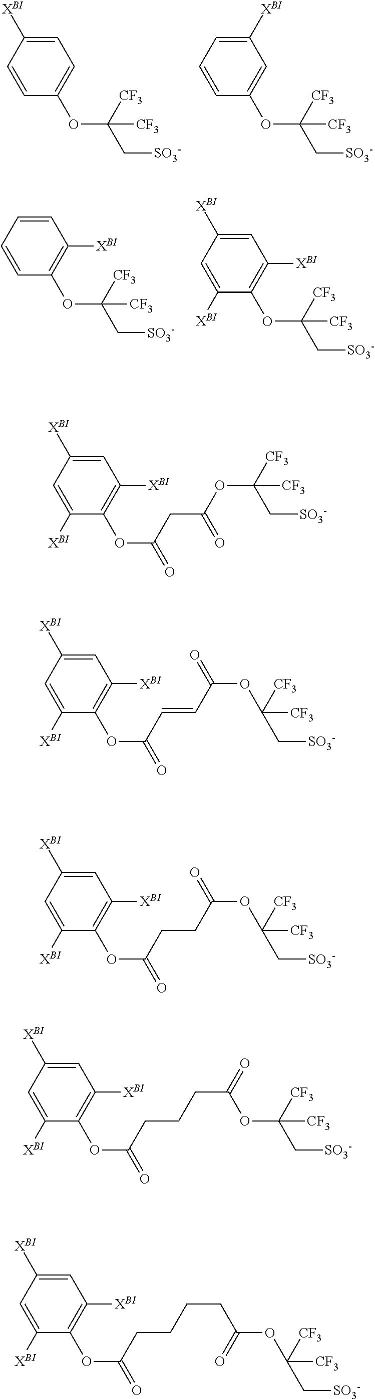

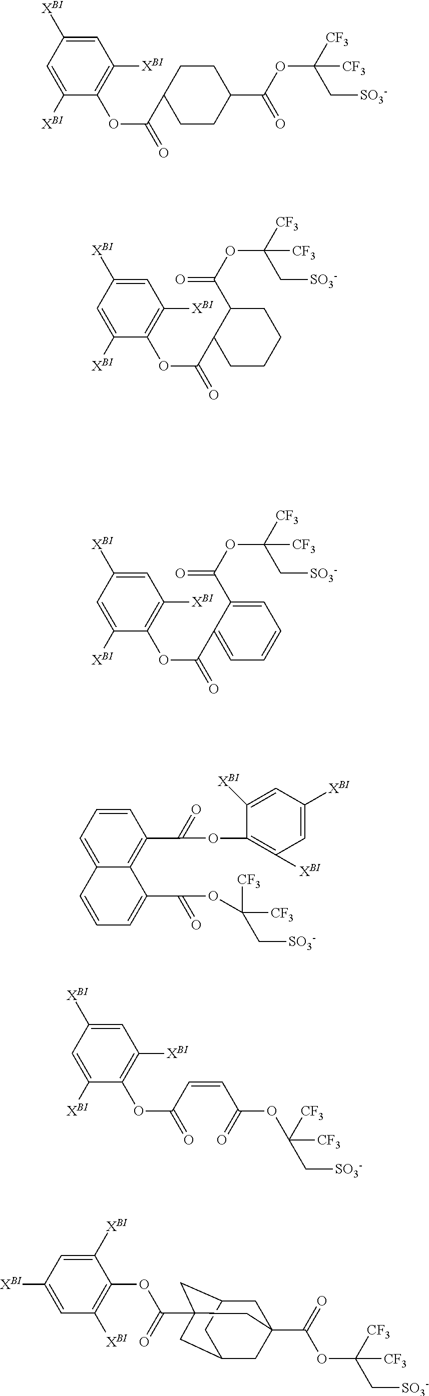

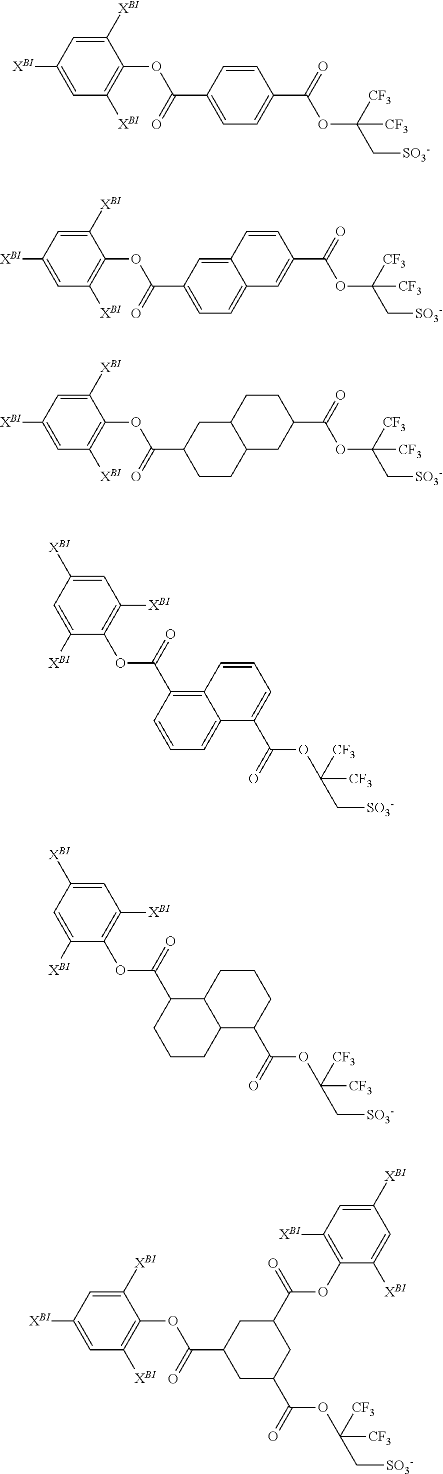

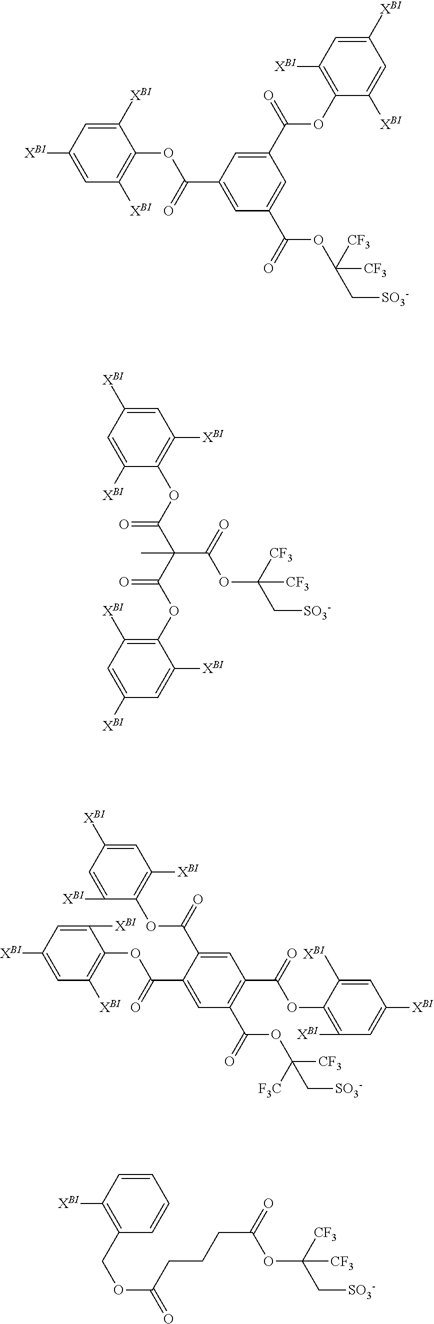

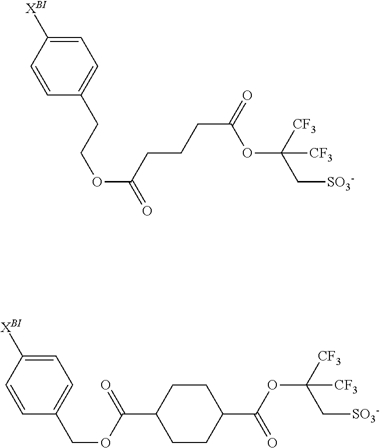

In formula (c2), Z² is a single bond or ester bond. Z³ is a single bond, —Z³¹—C(═O)—O— or —Z³¹—O—, Z³¹ is a C₁-C₁₂ hydrocarbylene group, phenylene group, or C₇-C₁₈ group obtained by combining the foregoing, which may contain carbonyl, nitro, cyano, ester bond, ether bond, urethane bond, fluorine, iodine or bromine. Z⁴ is a single bond, methylene or ethylene.

In formula (c2), Rf¹ to Rf⁴ are each independently hydrogen, fluorine or trifluoromethyl. At least one of Rf¹ to Rf⁴ is fluorine or trifluoromethyl. Rf¹ and Rf², taken together, may form a carbonyl group.

Examples of the anion in the monomer from which repeat units (c2) are derived are shown below, but not limited thereto. Herein R^{A} is as defined above.

[chemical structure]

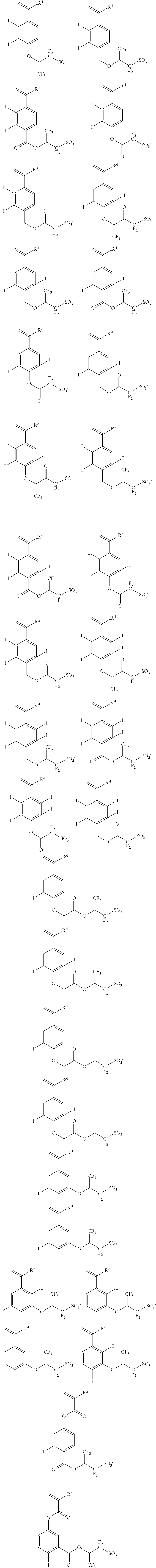

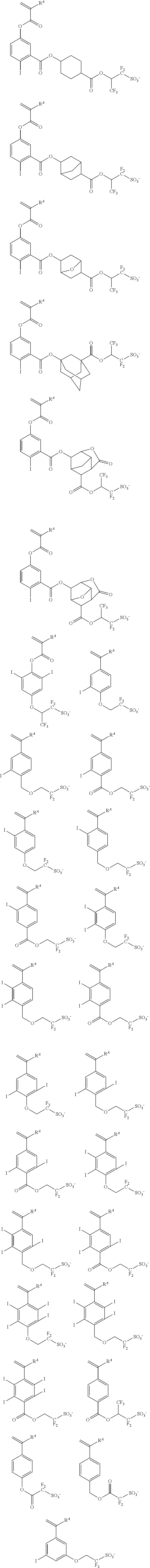

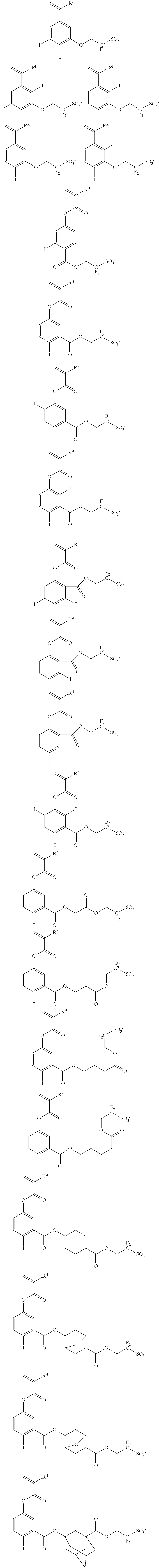

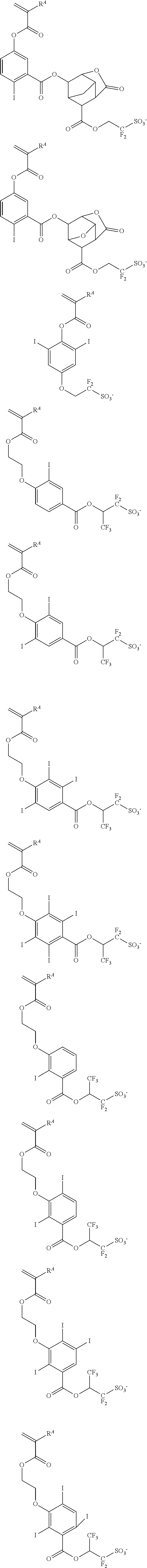

In formula (c3), Z⁵ is a single bond, methylene, ethylene, phenylene, methylphenylene, dimethylphenylene, fluorinated phenylene, trifluoromethyl-substituted phenylene group, —O—Z⁵¹—, —C(═O)—O—Z⁵¹— or —C(═O)—NH—Z⁵¹—. Z⁵¹ is a C₁-C₆ aliphatic hydrocarbylene, phenylene, methylphenylene, dimethylphenylene, fluorinated phenylene, or trifluoromethyl-substituted phenylene group, which may contain carbonyl, ester bond, ether bond, hydroxy or halogen.

Examples of the anion in the monomer from which repeat units (c3) are derived are shown below, but not limited thereto. Herein R^{A} is as defined above.

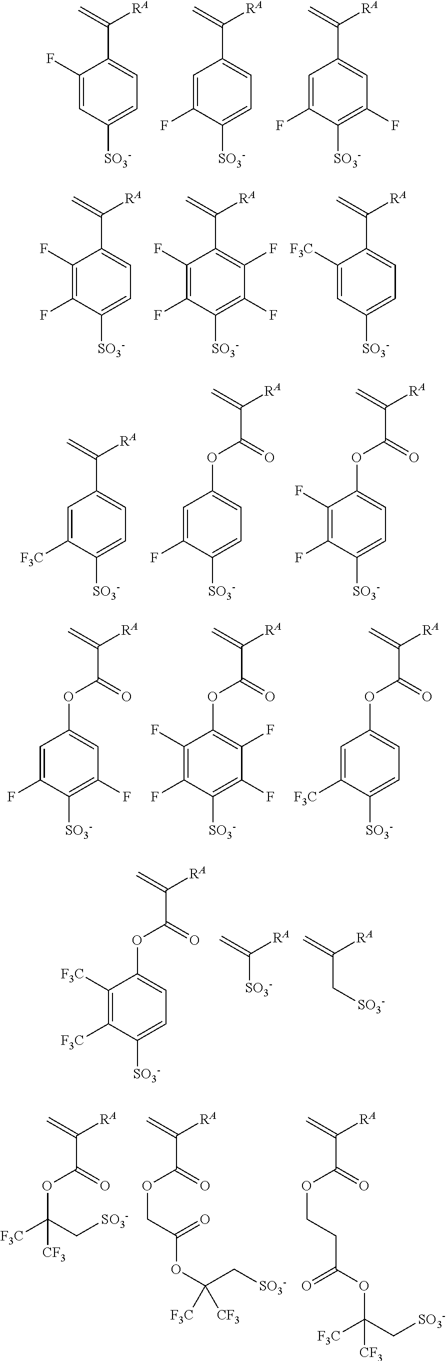

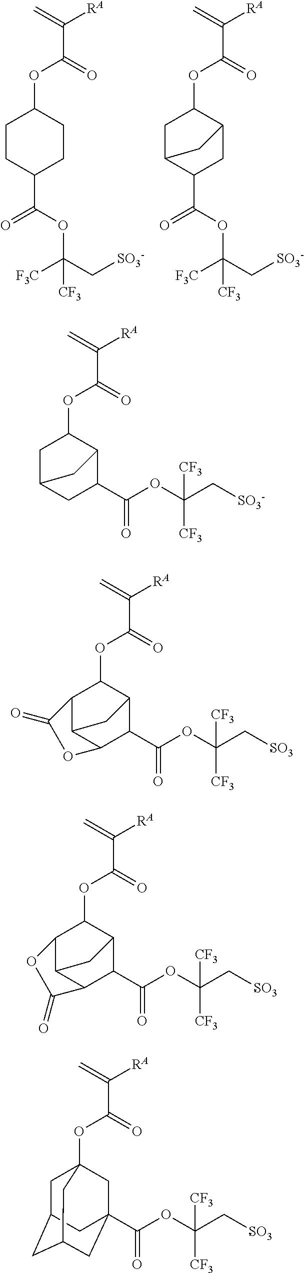

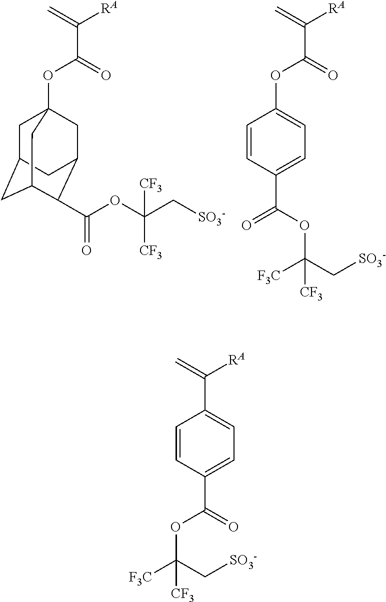

In formulae (c4) and (c5), R^{A} is each independently hydrogen or methyl. R^{B} is each independently hydrogen or may bond with Z⁶ to form a ring.

In formulae (c4) and (c5), Z⁶ is a single bond, phenylene, naphthylene, ester bond or amide bond.

In formula (c4), Z^{7A} is a single bond or a C₁-C₂₄ divalent organic group which may contain at least one element selected from halogen, oxygen, nitrogen, and sulfur.

The divalent organic group Z^{7A} may be saturated or unsaturated and straight, branched or cyclic. Included are C₁-C₂₄ hydrocarbylene groups in which some or all of the hydrogen atoms are substituted by iodine or bromine. Examples of the C₁-C₂₄ hydrocarbylene group include alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, heptadecane-1,17-diyl, octadecane-1,18-diyl, nonadecane-1,19-diyl, and eicosane-1,20-diyl; cyclic saturated hydrocarbylene groups such as cyclopentanediyl, methylcyclopentanediyl, dimethylcyclopentanediyl, trimethylcyclopentanediyl, tetramethylcyclopentanediyl, cyclohexanediyl, methylcyclohexanediyl, dimethylcyclohexanediyl, trimethylcyclohexanediyl, tetramethylcyclohexanediyl, norbornanediyl and adamantanediyl; arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, tert-butylnaphthylene, biphenyldiyl, methylbiphenyldiyl and dimethylbiphenyldiyl; and combinations thereof. In the hydrocarbylene group, some or all of the hydrogen atoms may be substituted by a moiety containing at least one element selected from oxygen, nitrogen and sulfur, or some —CH₂— may be replaced by a moiety containing at least one element selected from oxygen, nitrogen and sulfur, so that the group may contain a hydroxy moiety, ester bond, ether bond, amide bond, carbamate bond or urea bond.

In formula (c5), Z^{7B} is a C₁-C₁₀ monovalent organic group which may contain at least one element selected from halogen, oxygen, nitrogen, and sulfur.

The monovalent organic group Z^{7B} may be saturated or unsaturated and straight, branched or cyclic. Included are C₁-C₁₀ hydrocarbyl groups in which some or all of the hydrogen atoms are substituted by iodine or bromine. Examples of the C₁-C₁₀ hydrocarbyl group include C₁-C₁₀ alkyl groups such as methyl, ethyl, n-propyl, isopropyl, n-butyl, isobutyl, sec-butyl, tert-butyl, n-pentyl, isopentyl, sec-pentyl, 3-pentyl, tert-pentyl, neopentyl, n-hexyl, n-octyl, n-nonyl, and n-decyl; C₃-C₁₀ cyclic saturated hydrocarbyl groups such as cyclopropyl, cyclobutyl, cyclopentyl, cyclohexyl, adamantyl, norbornyl, cyclopropylmethyl, cyclopropylethyl, cyclobutylmethyl, cyclobutylethyl, cyclopentylmethyl, cyclopentylethyl, cyclohexylmethyl, cyclohexylethyl, methylcyclopropyl, methylcyclobutyl, methylcyclopentyl, methylcyclohexyl, ethylcyclopropyl, ethylcyclobutyl, ethylcyclopentyl, and ethylcyclohexyl; C₂-C₁₀ alkenyl groups such as vinyl, 1-propenyl, 2-propenyl, butenyl, pentenyl, hexenyl, heptenyl, nonenyl and decenyl; C₂-C₁₀ alkynyl groups such as ethynyl, propynyl, butynyl, pentynyl, hexynyl, heptynyl, octynyl, nonynyl, and decynyl; C₃-C₁₀ cyclic unsaturated aliphatic hydrocarbyl groups such as cyclopentenyl, cyclohexenyl, methylcyclopentenyl, methylcyclohexenyl, ethylcyclopentenyl, ethylcyclohexenyl, and norbornenyl; C₆-C₁₀ aryl groups such as phenyl, methylphenyl, ethylphenyl, n-propylphenyl, isopropylphenyl, n-butylphenyl, isobutylphenyl, sec-butylphenyl, tert-butylphenyl, and naphthyl; C₇-C₁₀ aralkyl groups such as benzyl, phenethyl, phenylpropyl, and phenylbutyl; and combinations thereof. In the hydrocarbyl group, some or all of the hydrogen atoms may be substituted by a moiety containing at least one element selected from oxygen, nitrogen and sulfur, or some —CH₂— may be replaced by a moiety containing at least one element selected from oxygen, nitrogen and sulfur, so that the group may contain a hydroxy moiety, ester bond, ether bond, amide bond, carbamate bond or urea bond.

In formulae (c4) and (c5), Z⁸ is a single bond, ether bond, ester bond, thioether bond or C₁-C₆ alkanediyl group.

In formula (c5), Z⁹ is a C₁-C₁₂ trivalent organic group which may contain at least one element selected from oxygen, nitrogen, and sulfur. The trivalent organic group Z⁹ may be saturated or unsaturated and straight, branched or cyclic. Examples thereof include groups obtained from C₁-C₁₂ hydrocarbylene groups by further eliminating one hydrogen atom. Examples of the C₁-C₁₂ hydrocarbylene group include those exemplified above for the C₁-C₂₄ hydrocarbylene group, but of 1 to 12 carbon atoms. In the group Z⁹, some or all of the hydrogen atoms may be substituted by a moiety containing at least one element selected from oxygen, nitrogen and sulfur, or some —CH₂— may be replaced by a moiety containing at least one element selected from oxygen, nitrogen and sulfur, so that the group may contain a hydroxy moiety, ester bond, ether bond, amide bond, carbamate bond or urea bond.

In formulae (c4) and (c5), R²³ is a C₁-C₁₀ saturated hydrocarbyl group, C₆-C₁₀ aryl group, fluorine, iodine, trifluoromethoxy, difluoromethoxy, cyano or nitro.

In formulae (c4) and (c5), the circle R is a C₆-C₁₀ (d+2)-valent aromatic hydrocarbon group. Examples of the (d+2)-valent aromatic hydrocarbon group include groups obtained from aromatic hydrocarbons such as benzene and naphthalene by eliminating (d+2) number of hydrogen atoms.

In formulae (c4) and (c5), d is an integer of 0 to 5.

Examples of the anion in repeat units (c4) and (c5) are shown below, but not limited thereto. Herein R^{A} is as defined above and X^{BI} is iodine or bromine.

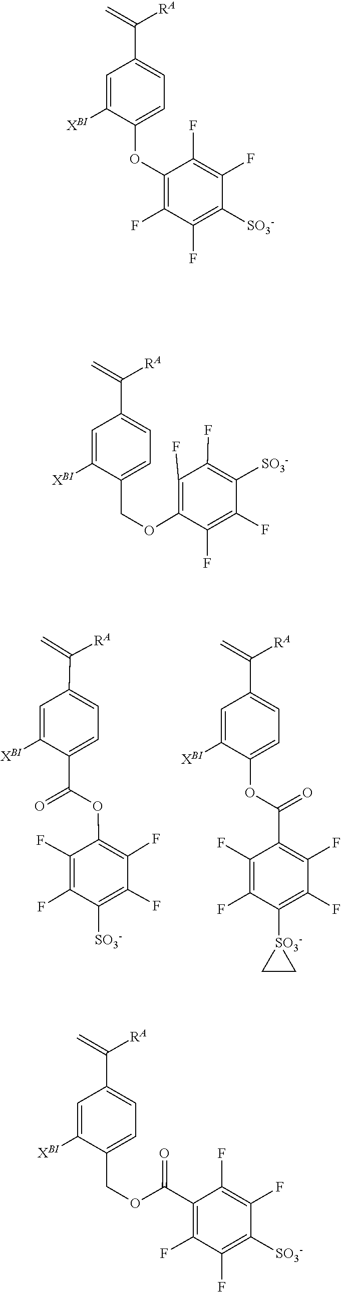

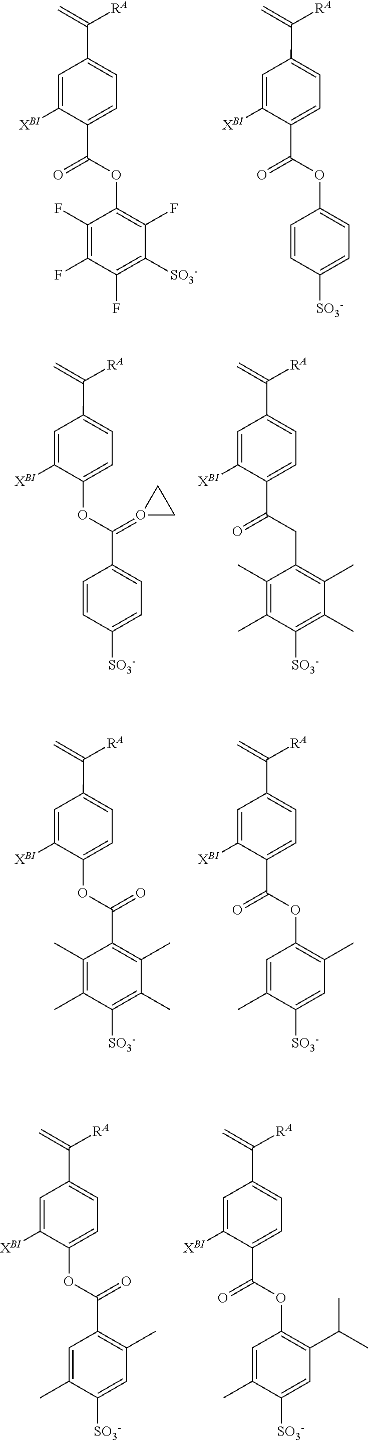

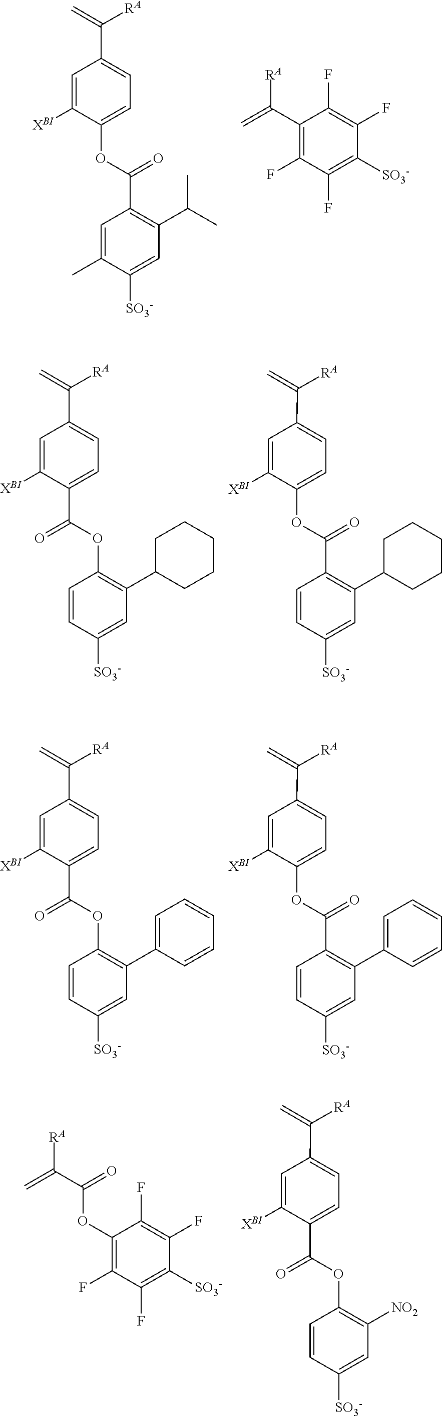

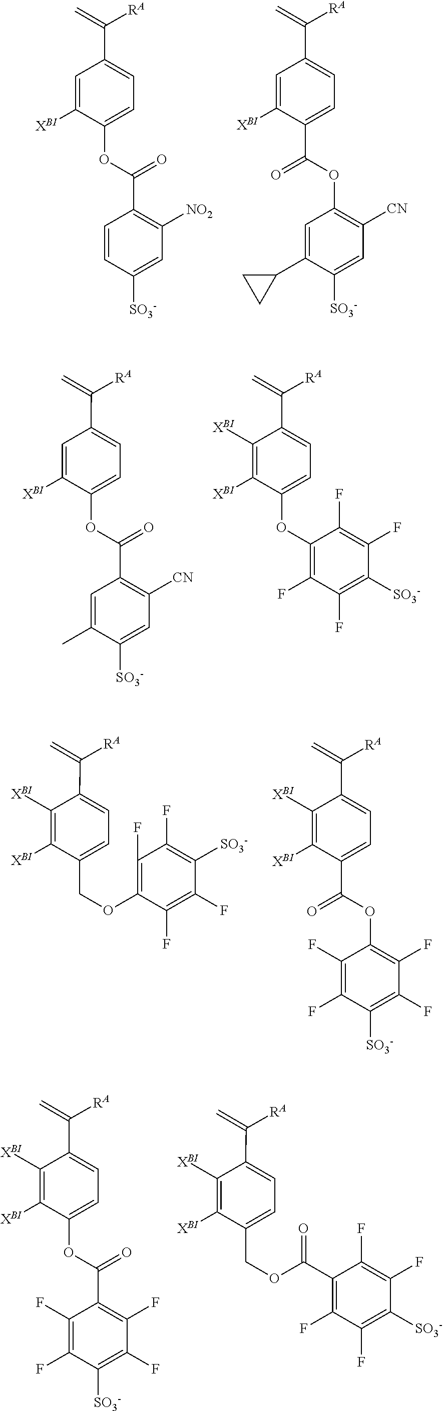

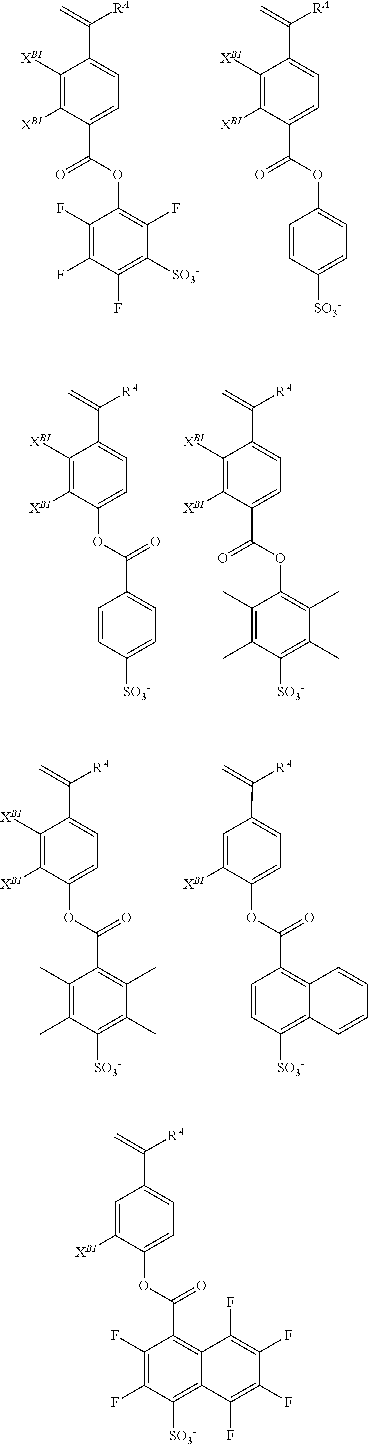

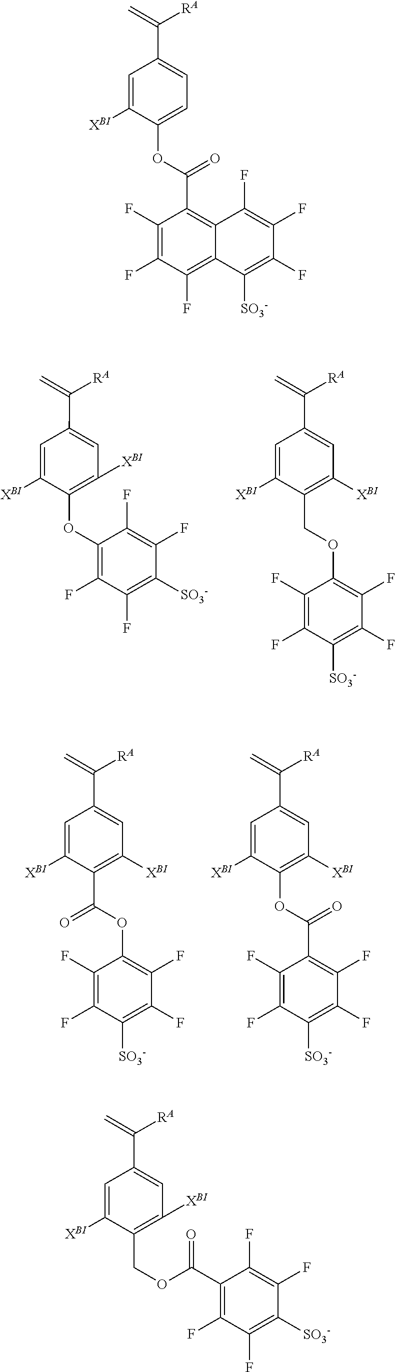

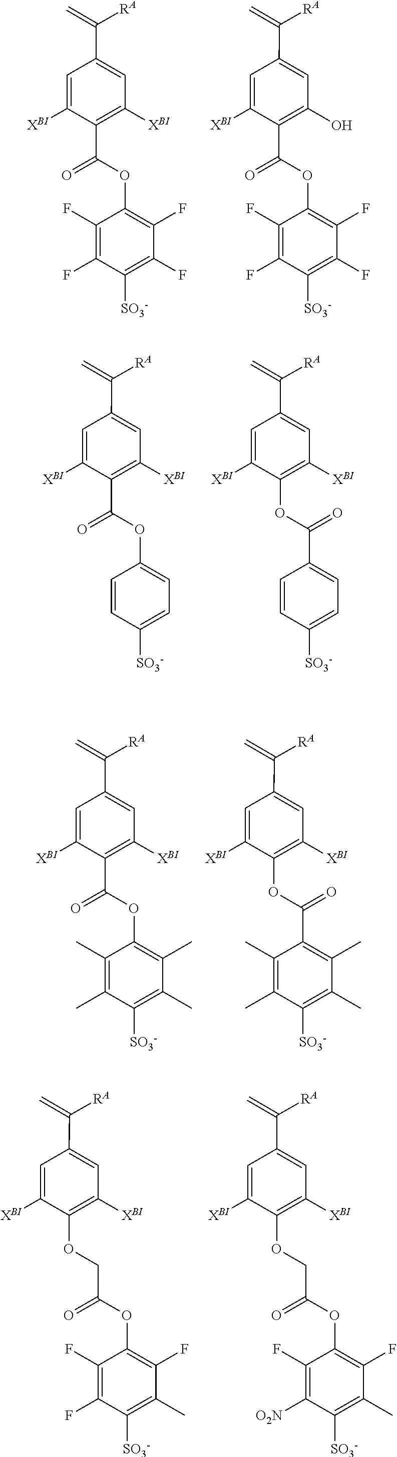

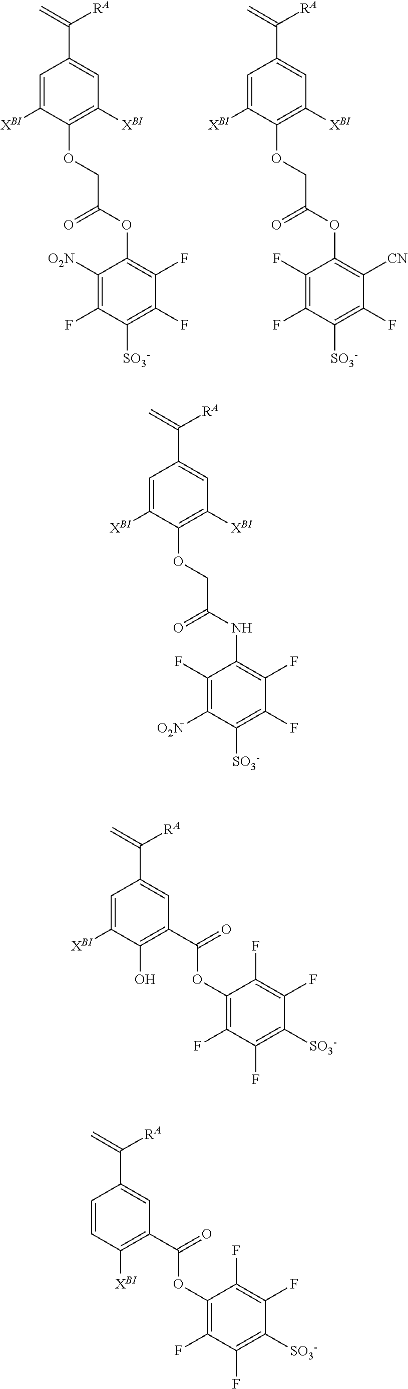

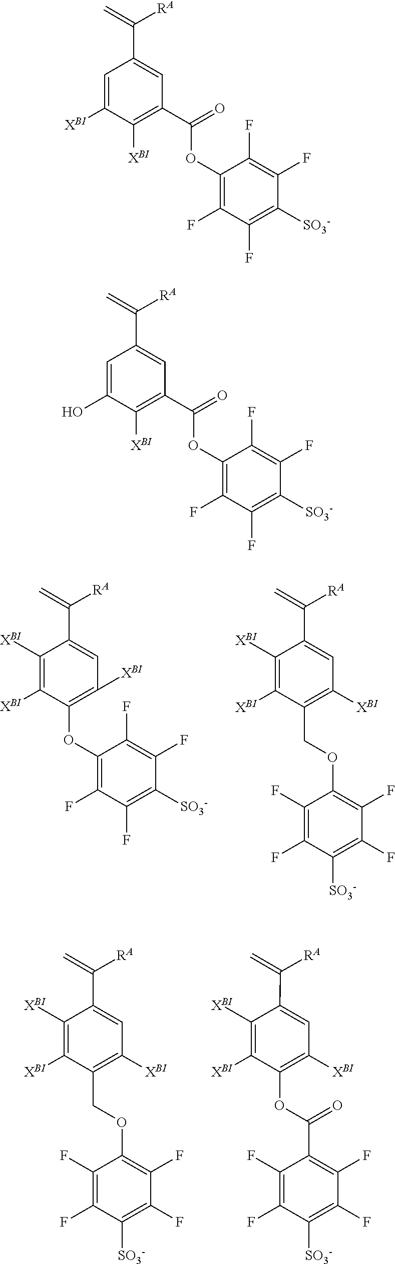

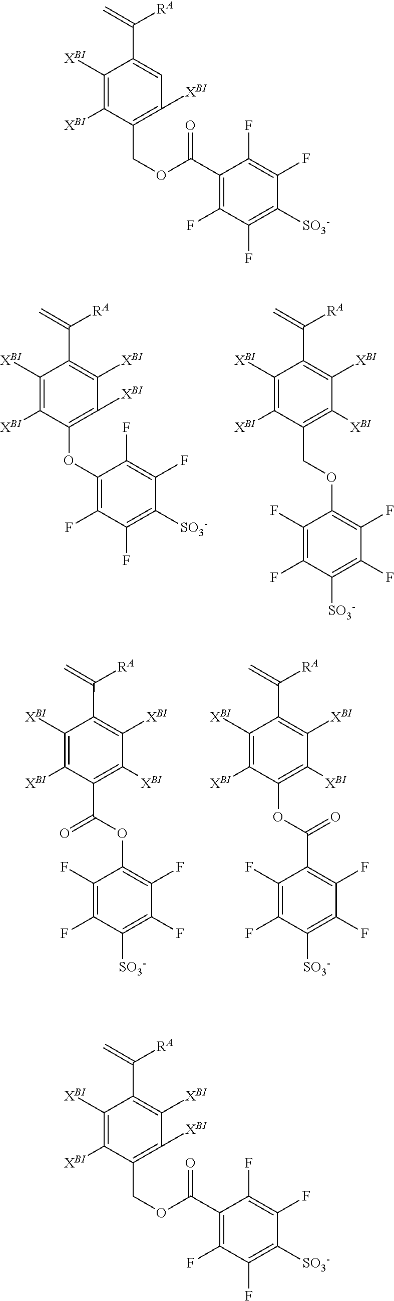

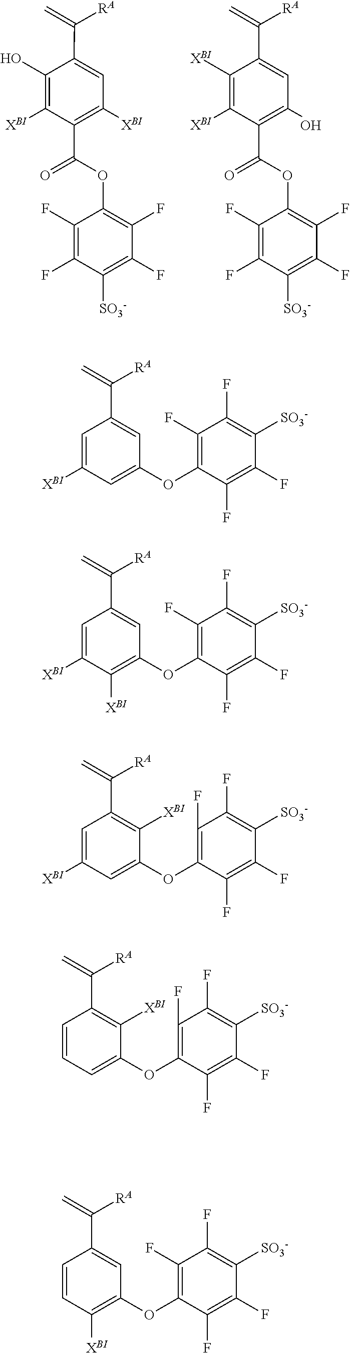

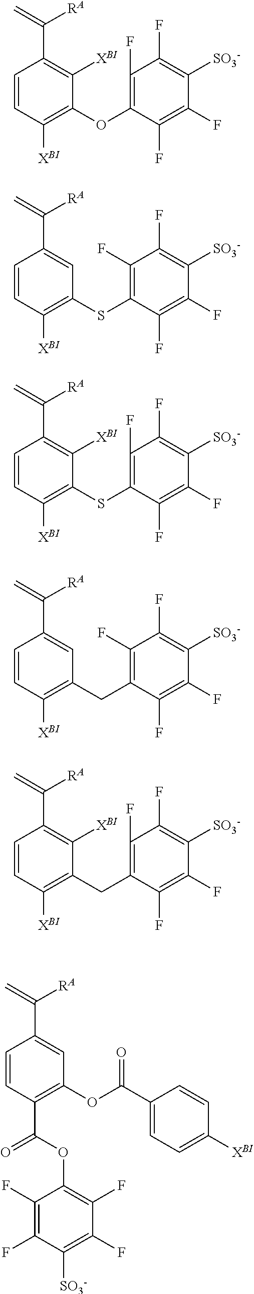

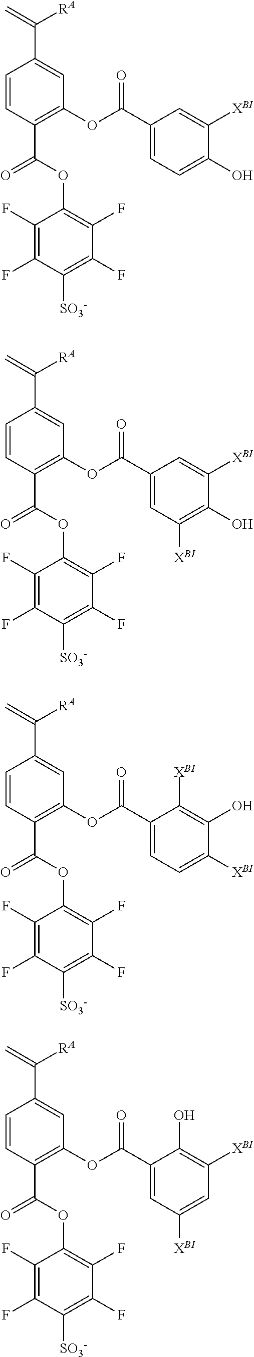

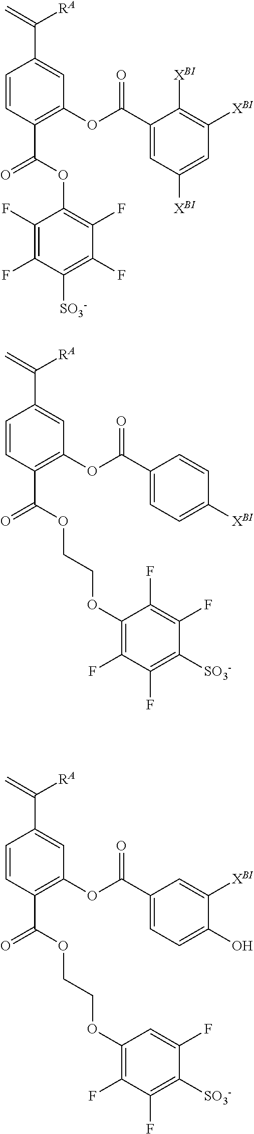

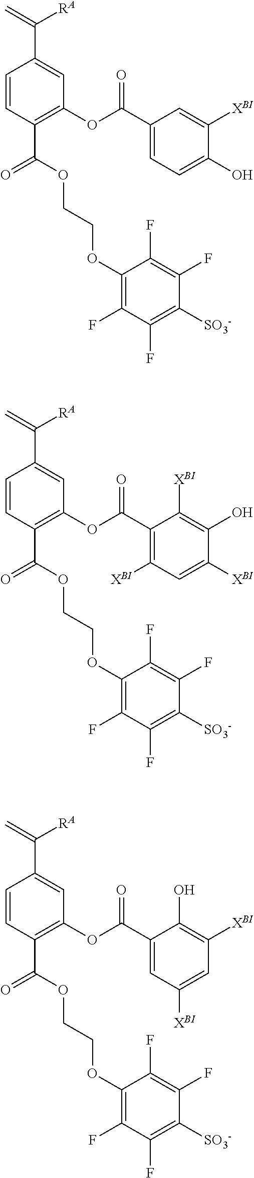

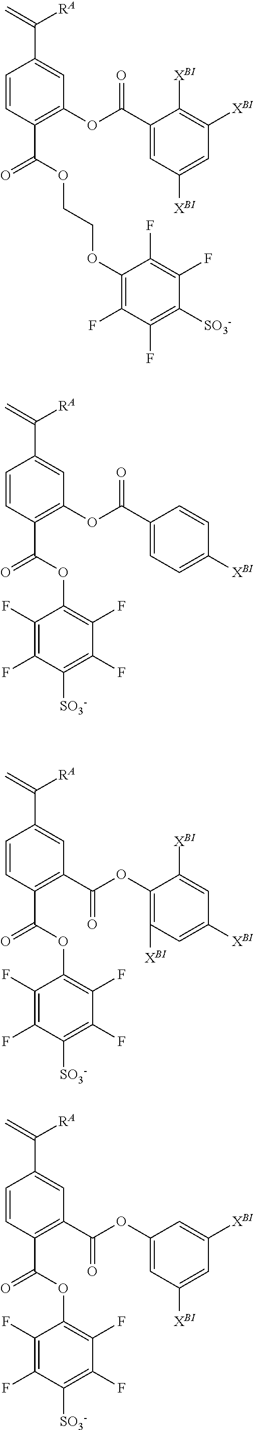

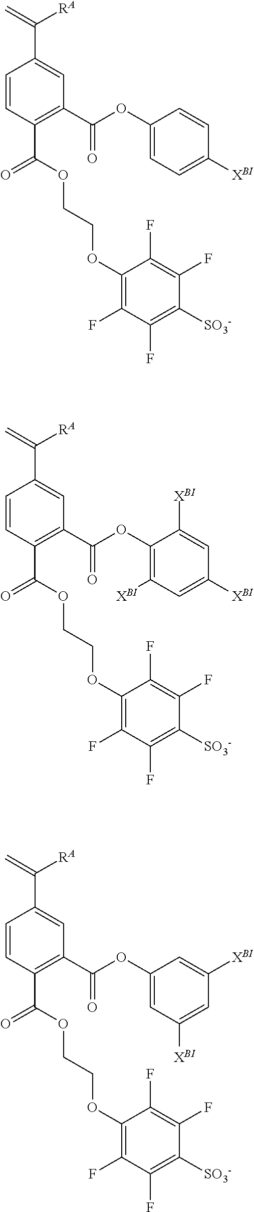

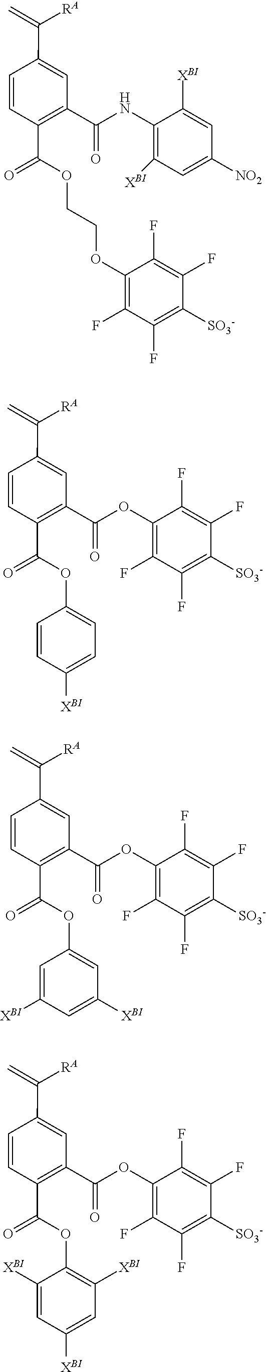

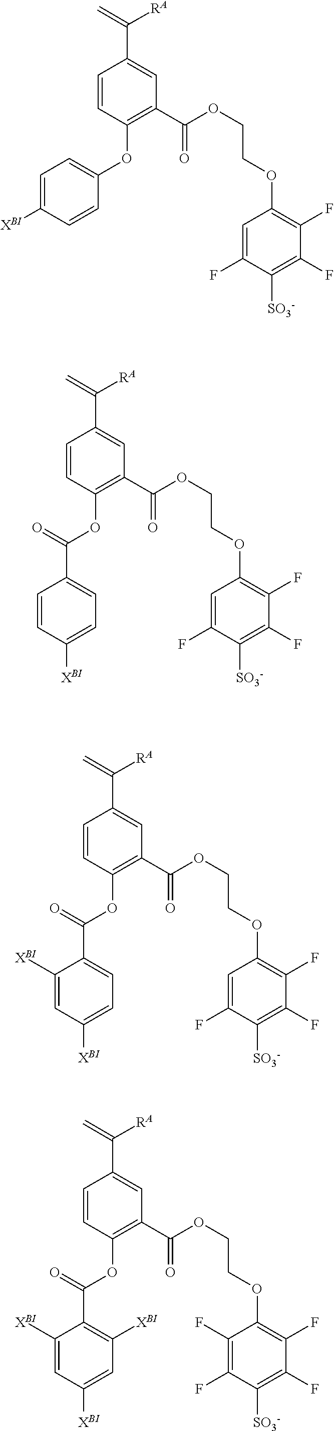

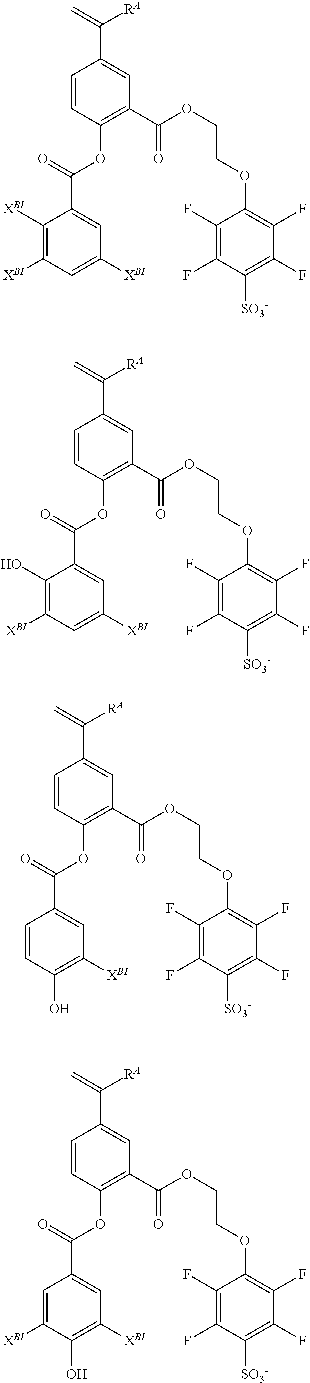

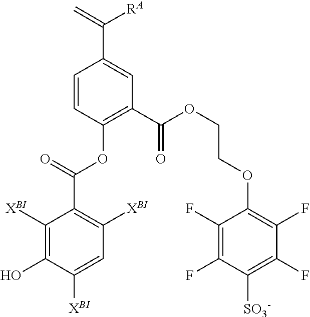

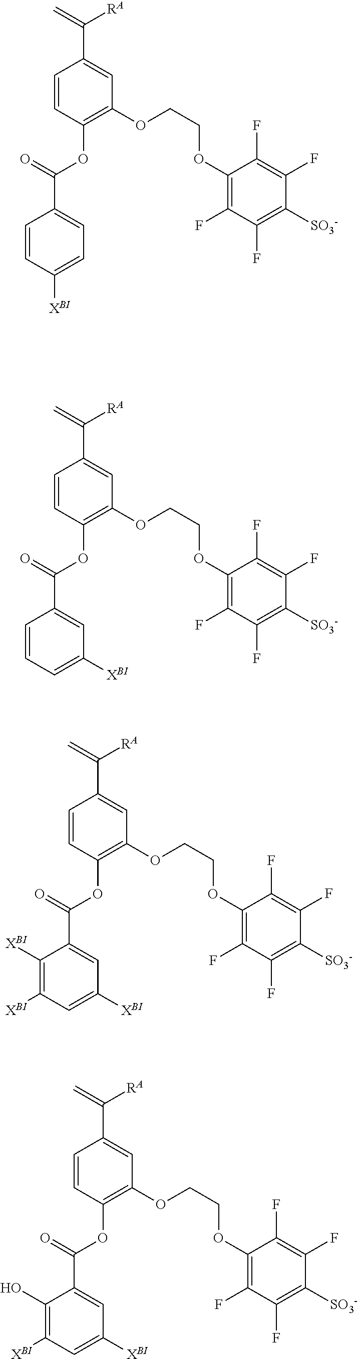

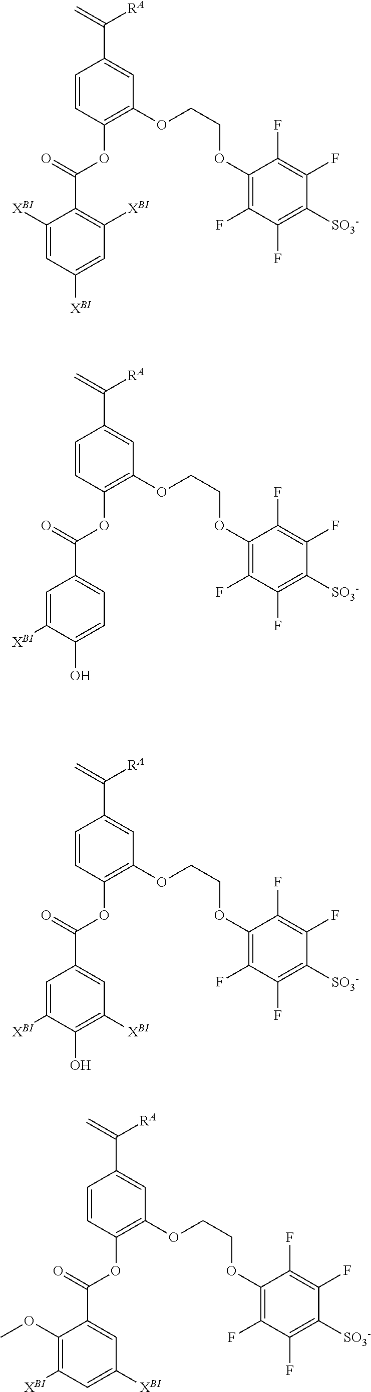

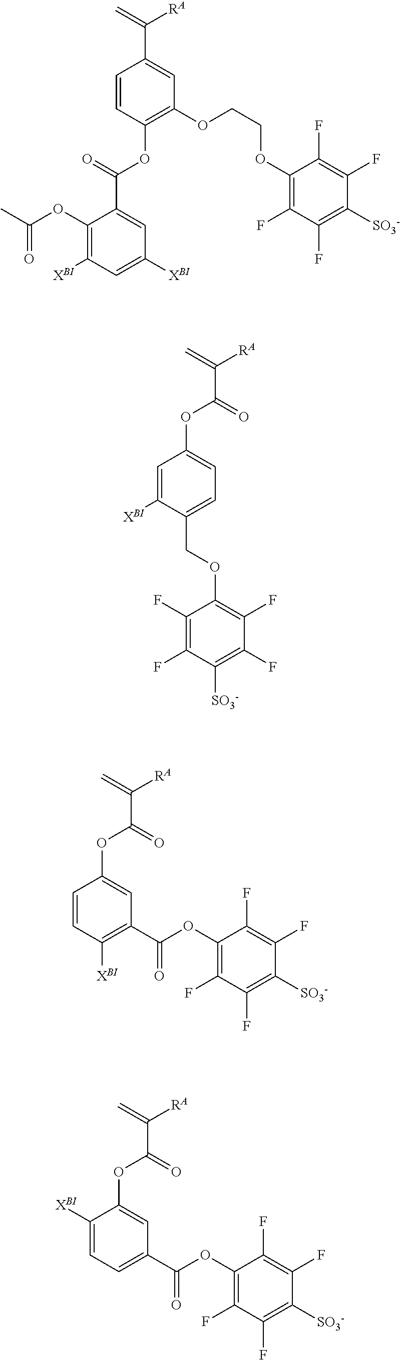

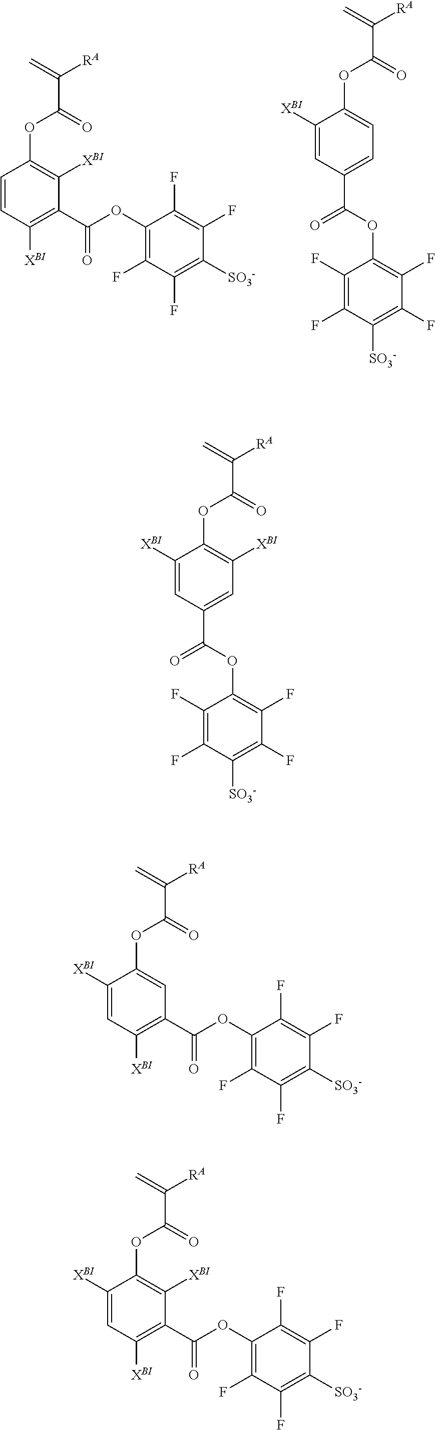

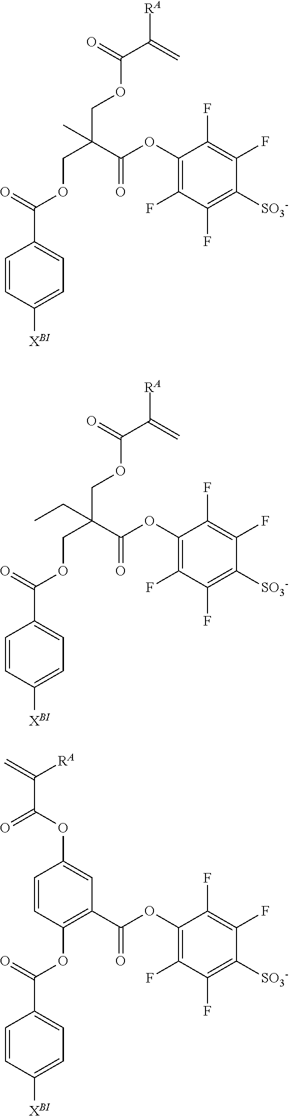

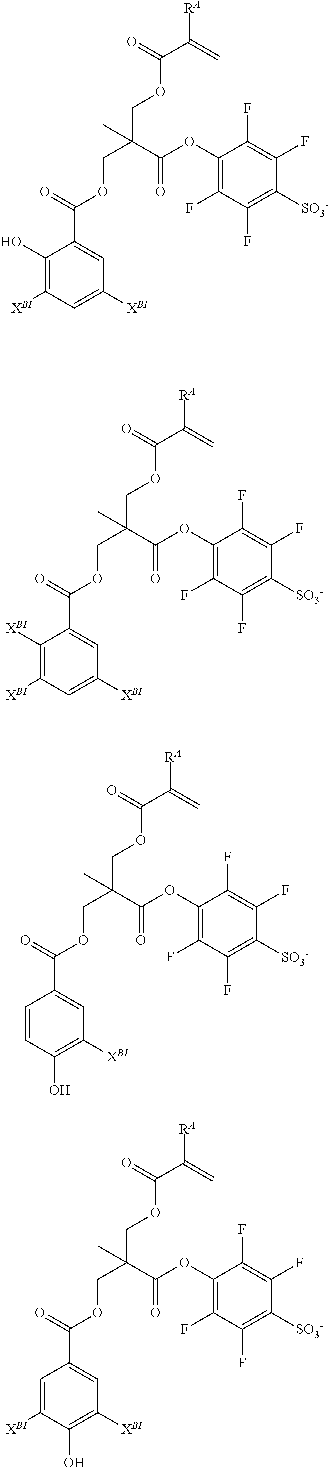

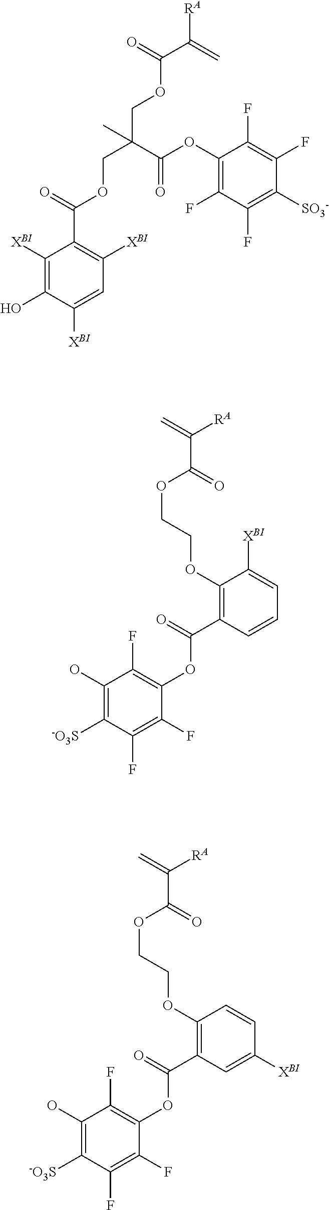

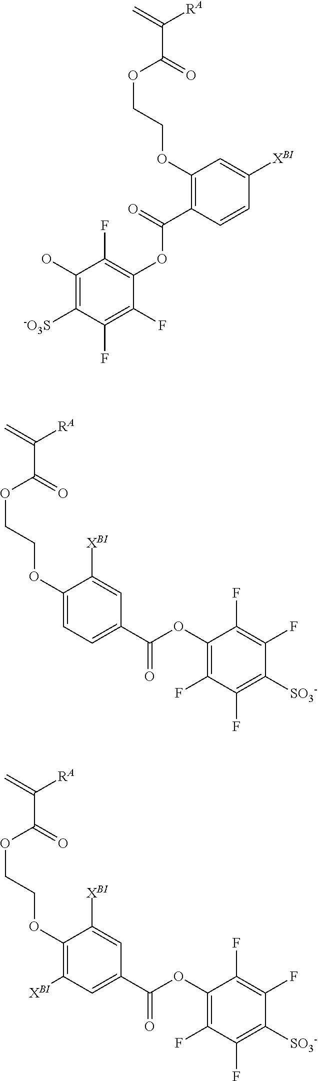

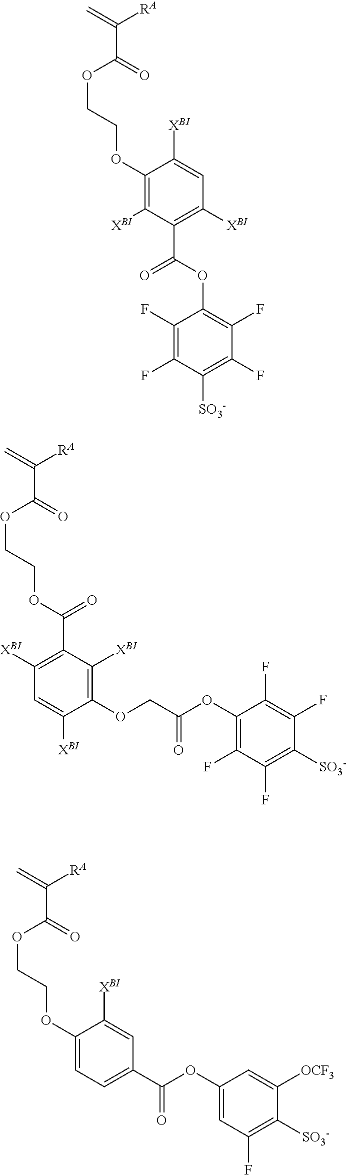

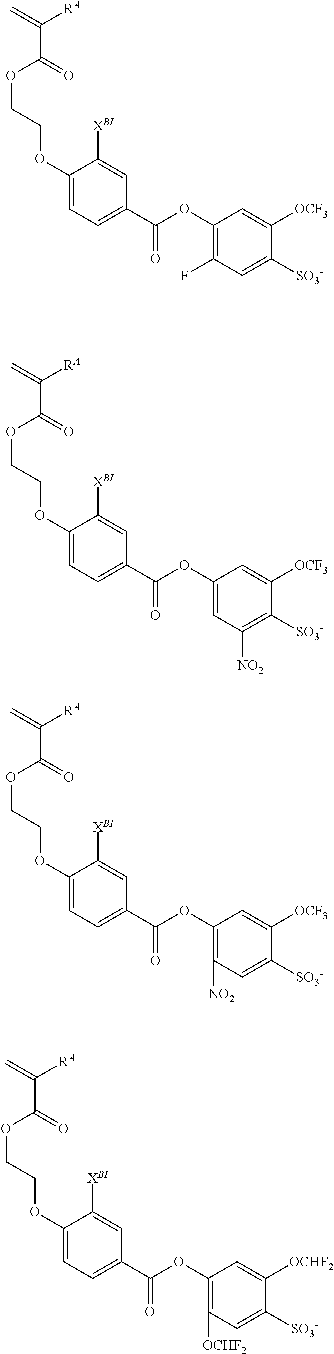

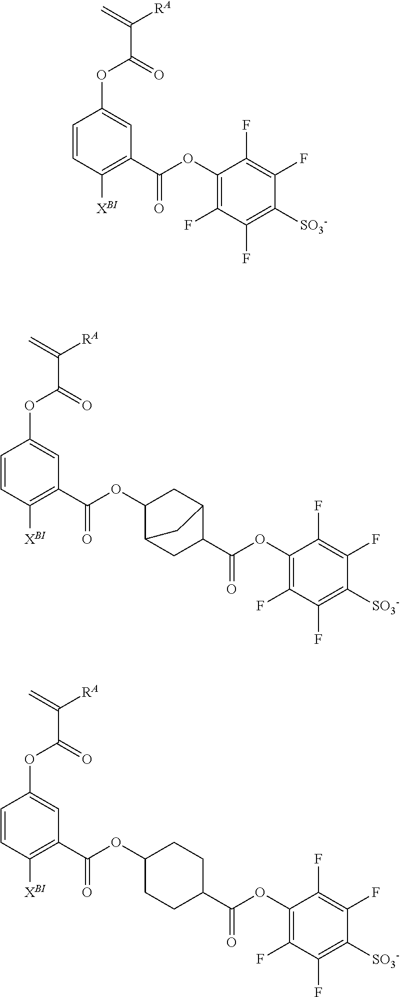

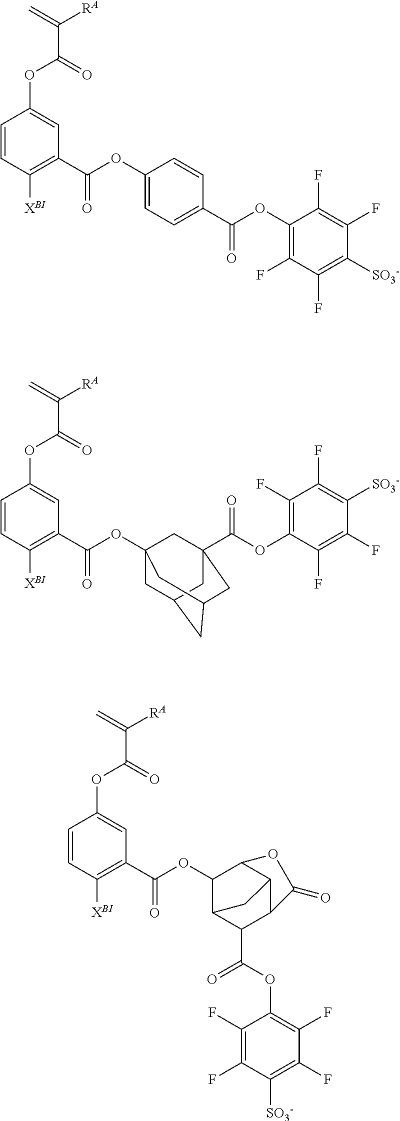

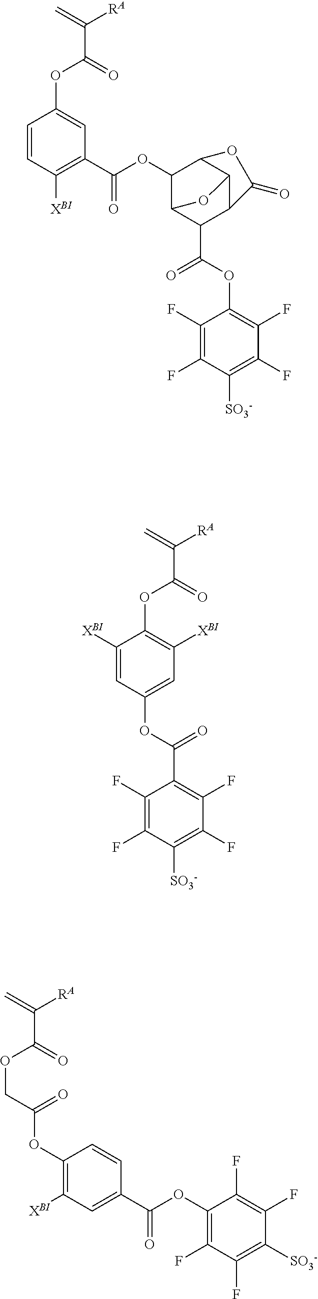

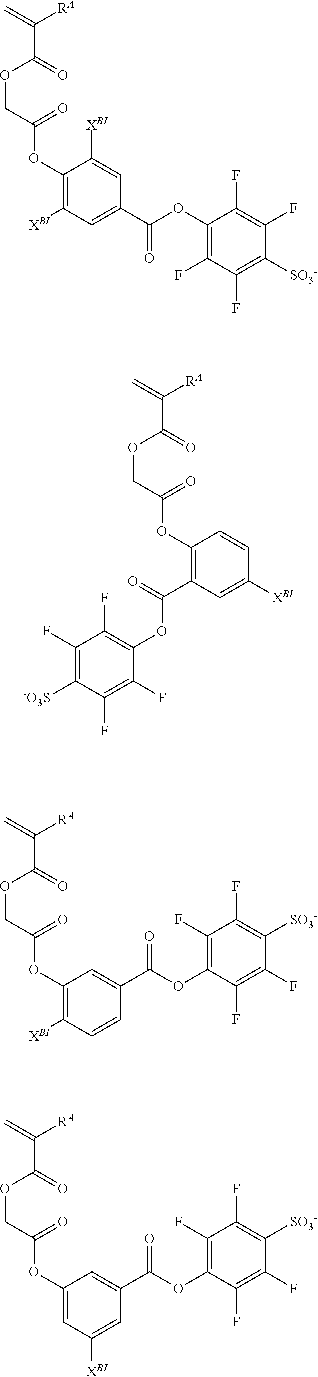

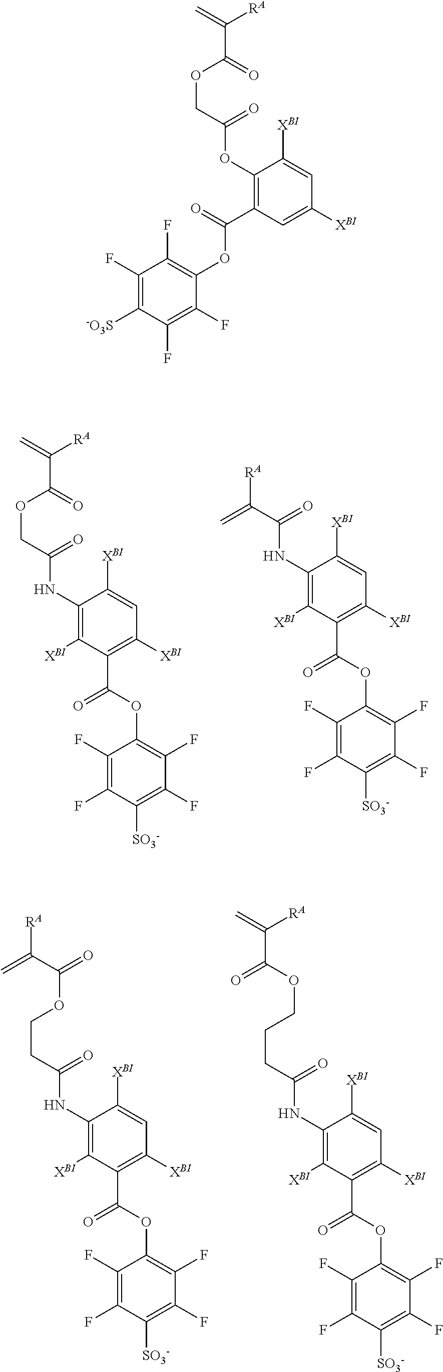

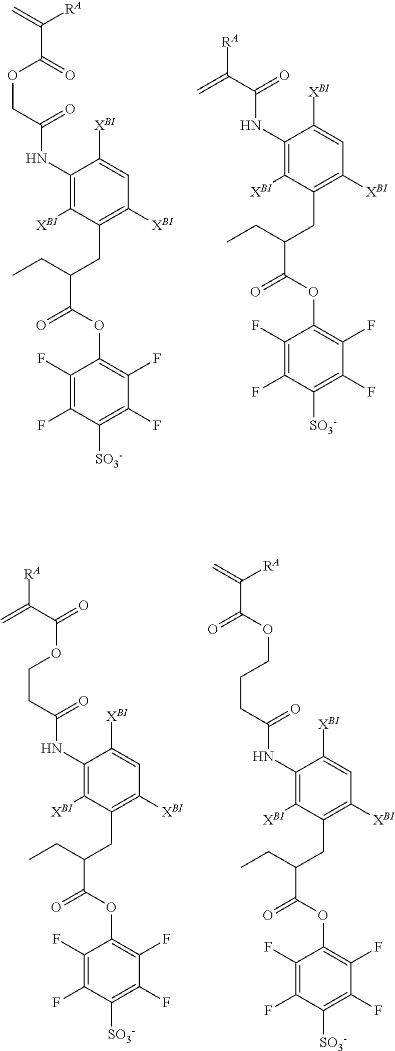

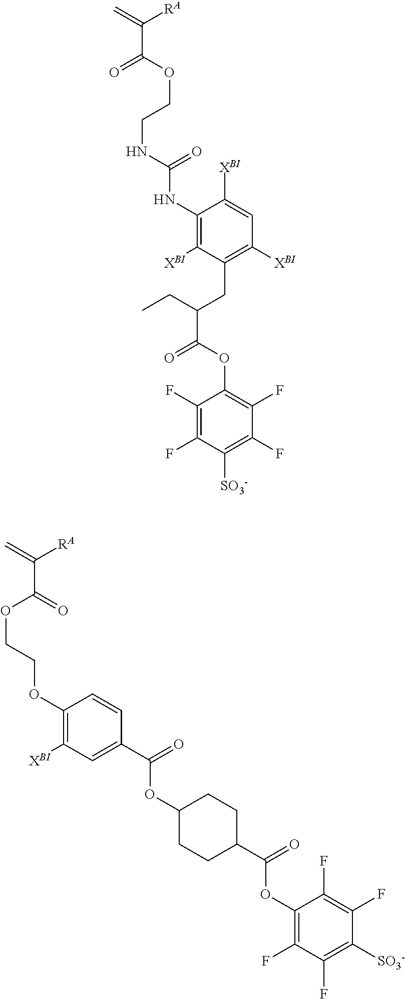

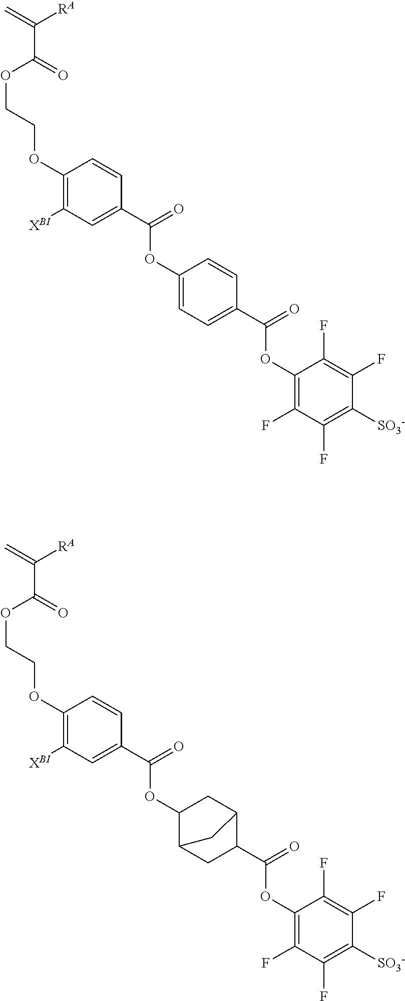

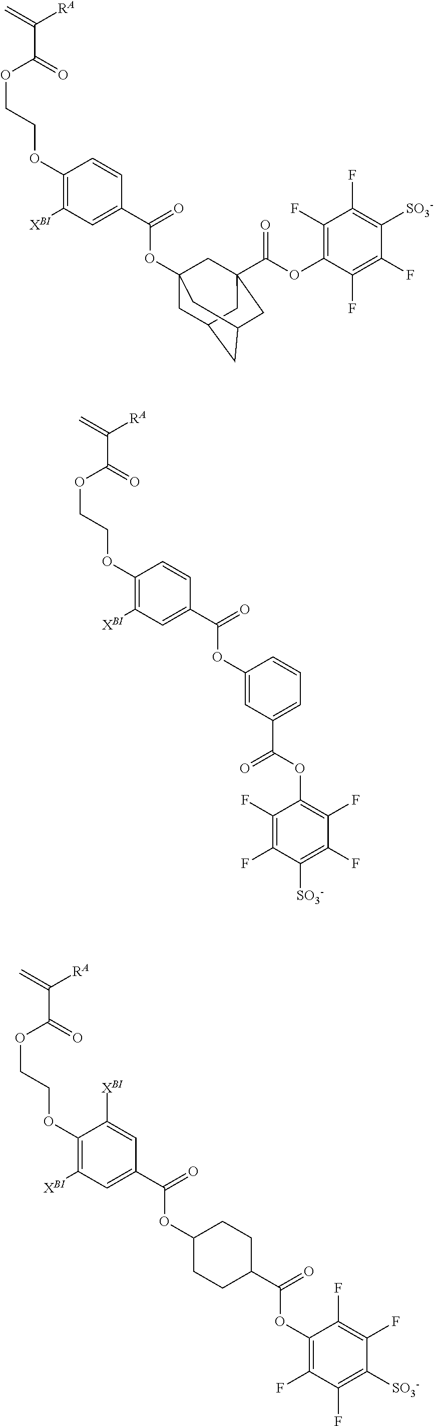

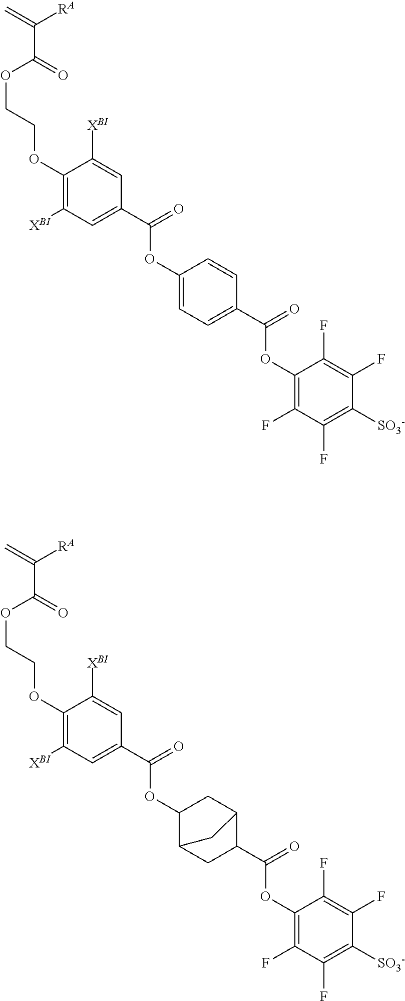

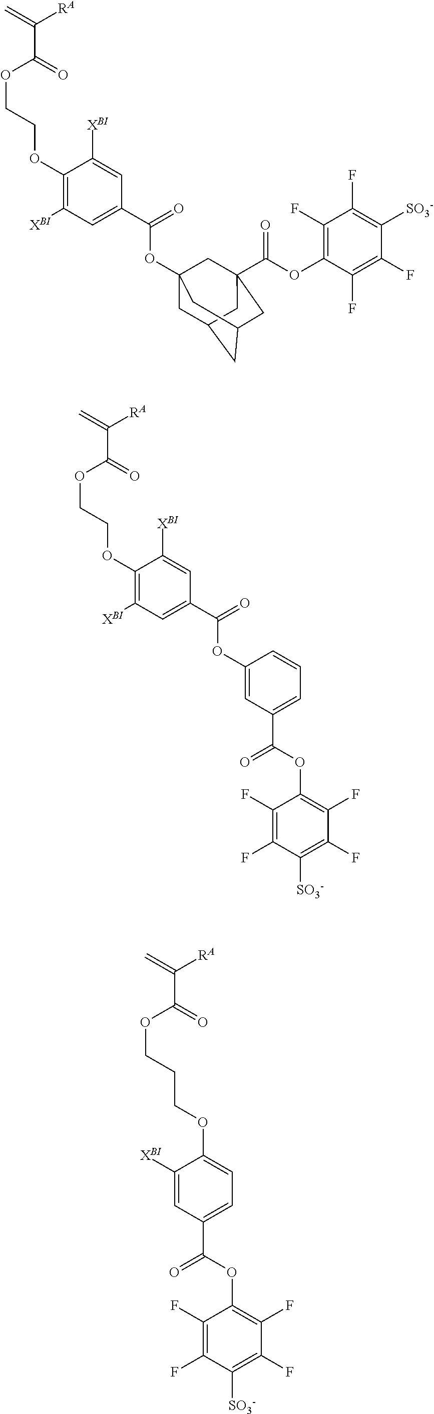

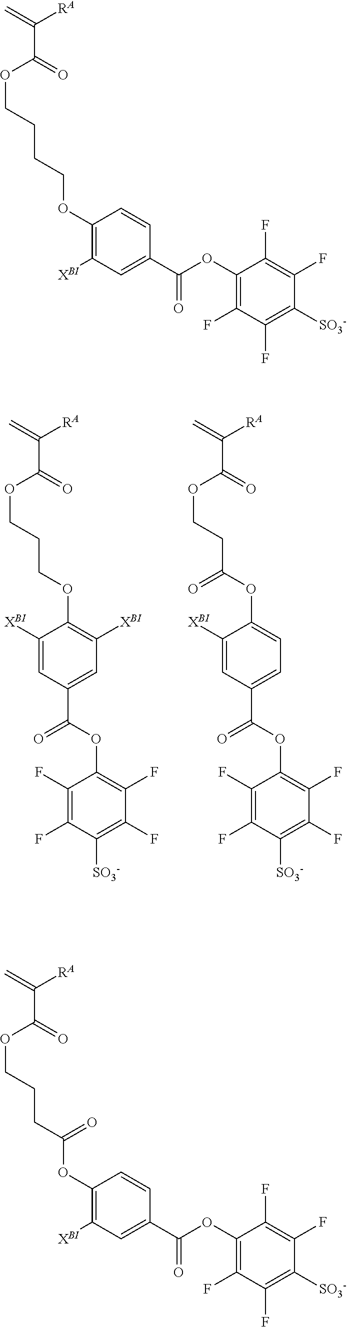

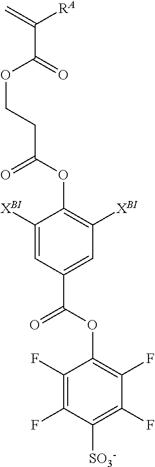

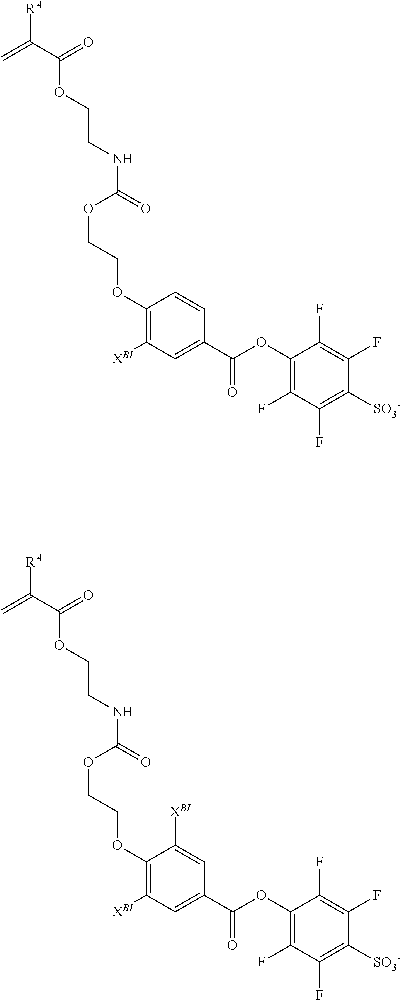

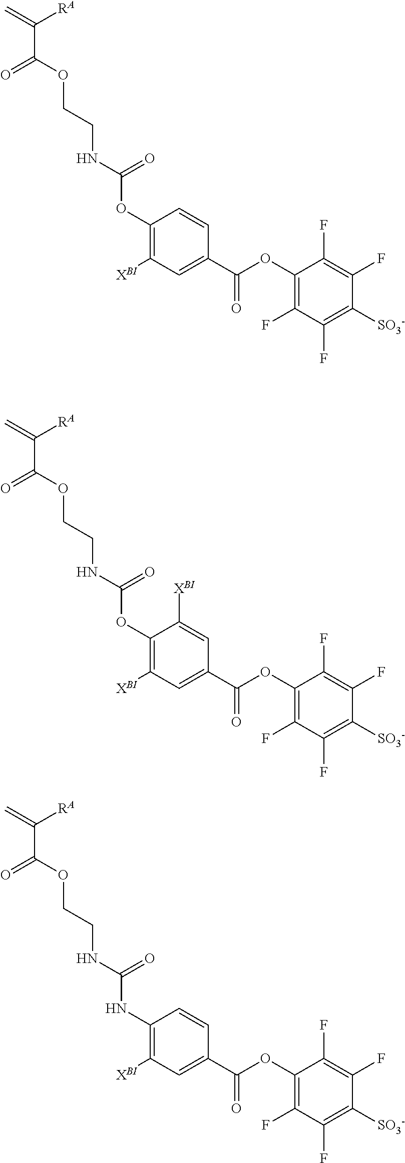

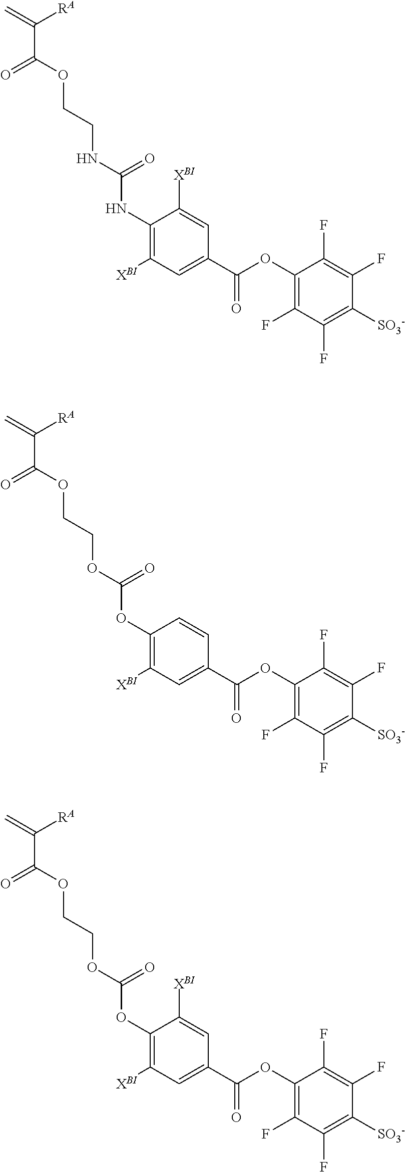

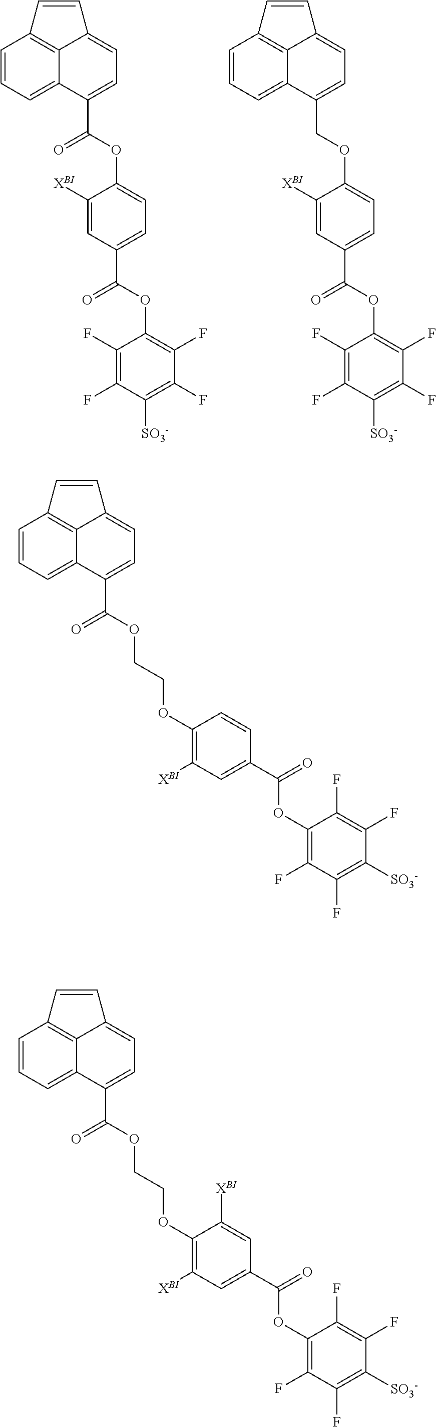

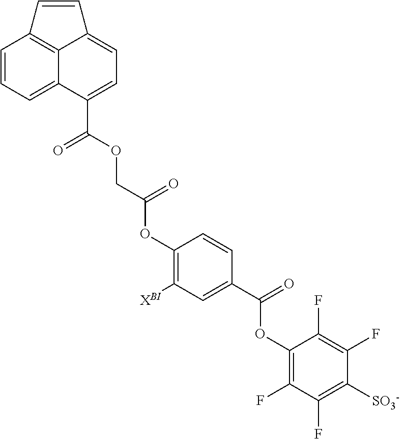

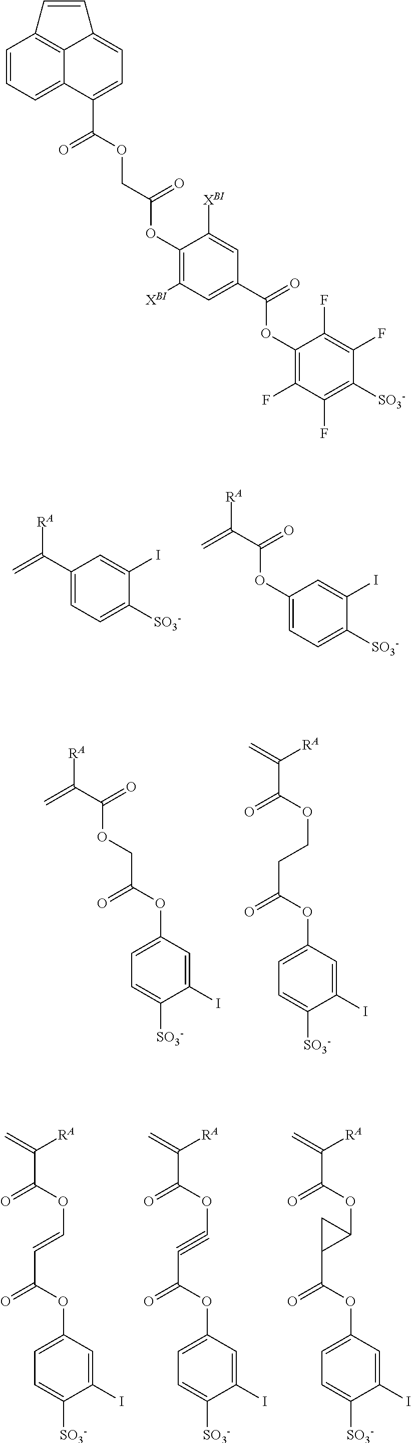

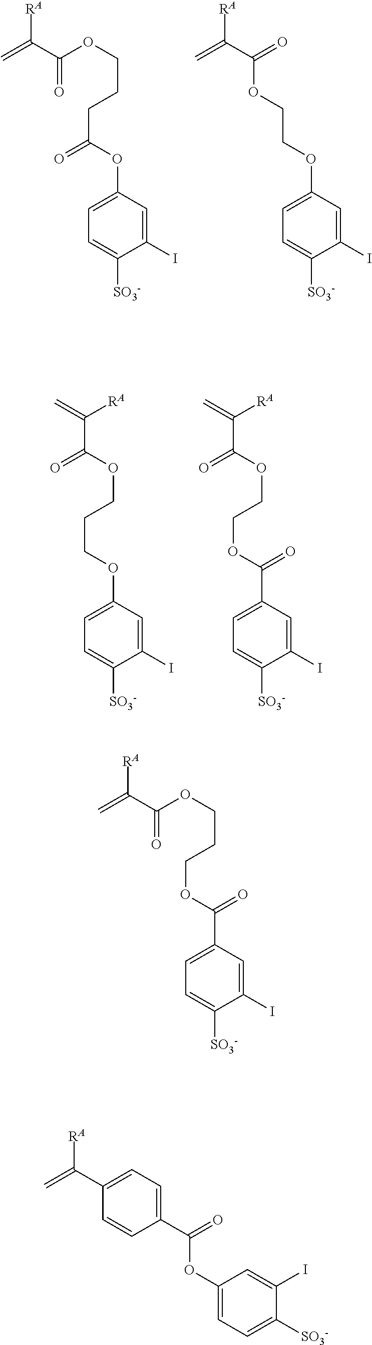

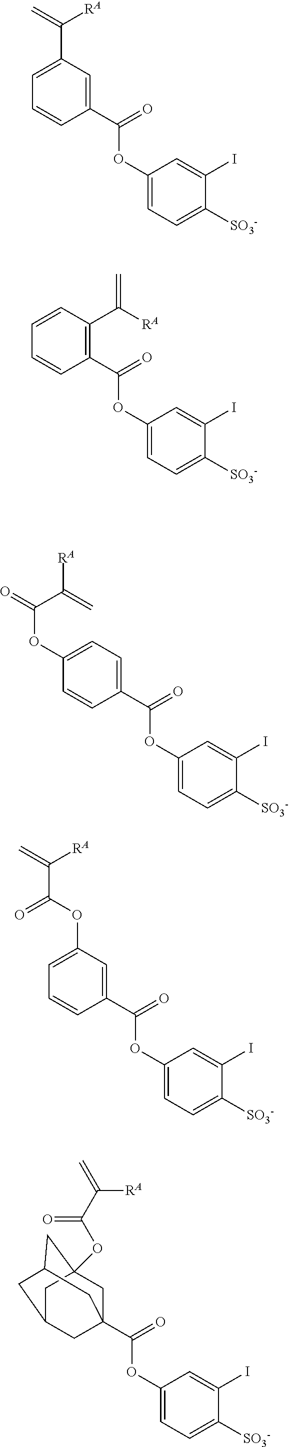

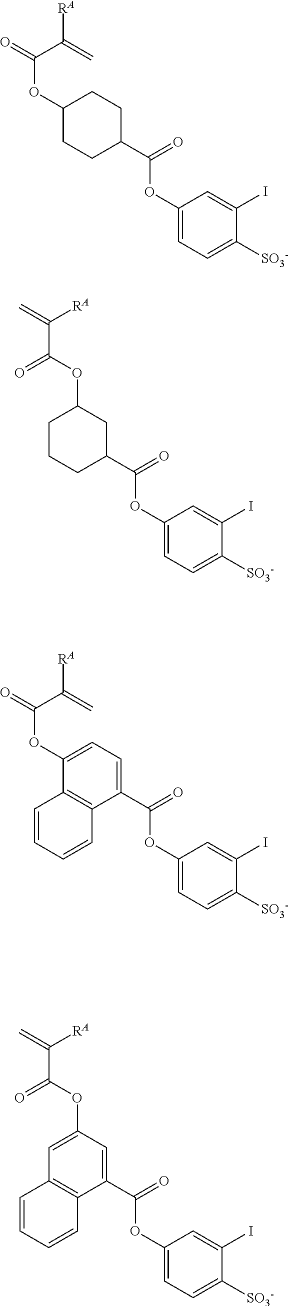

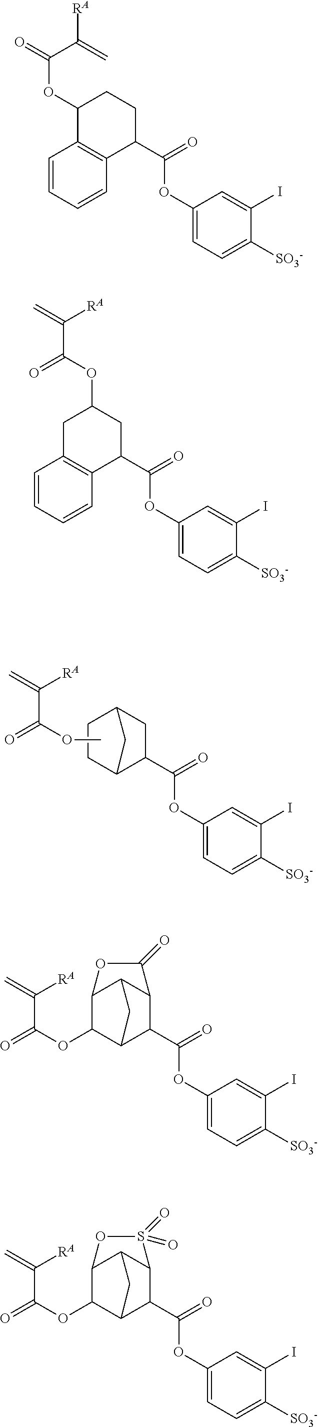

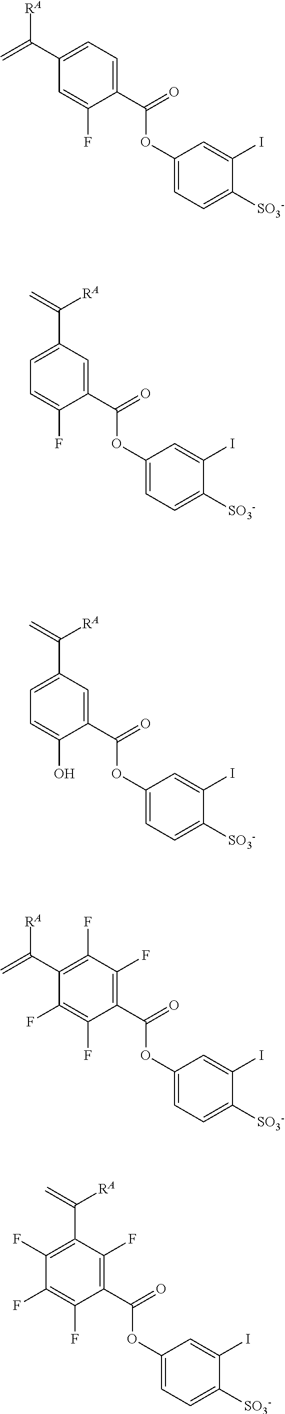

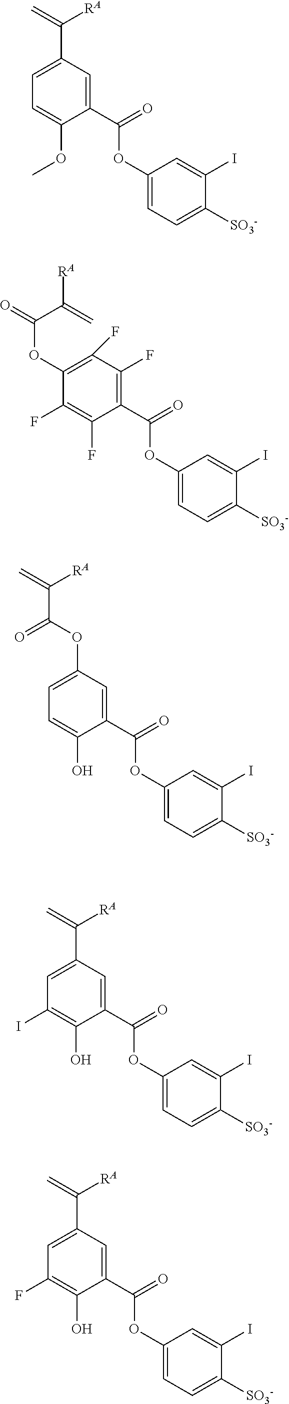

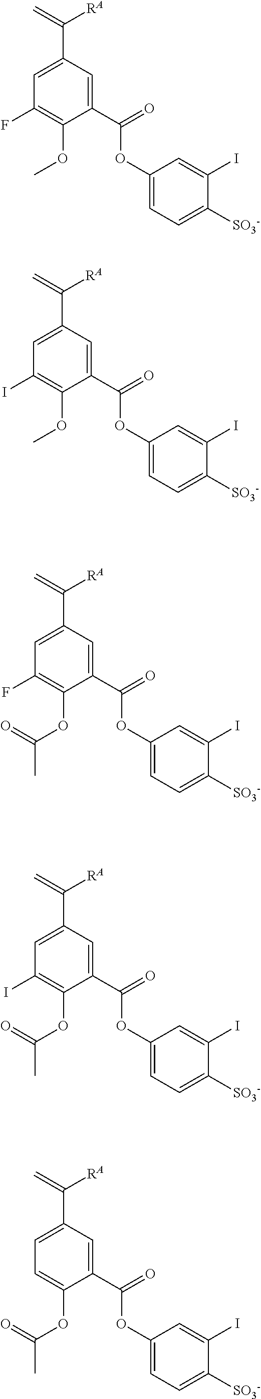

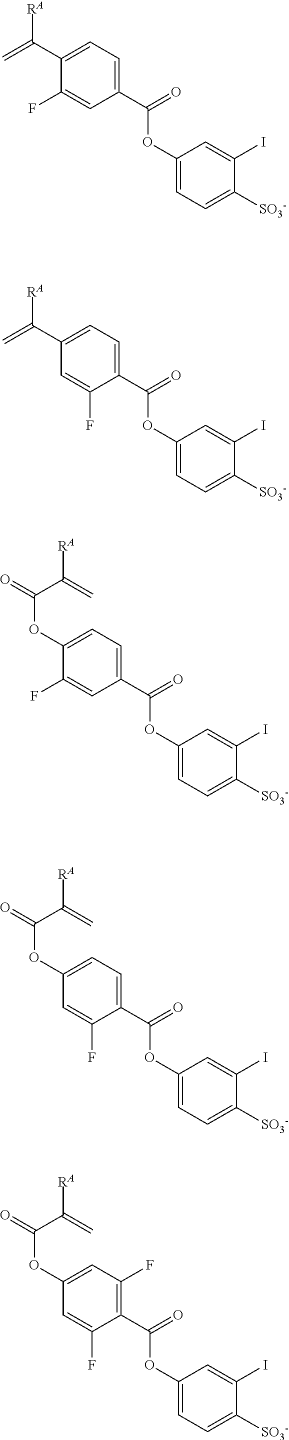

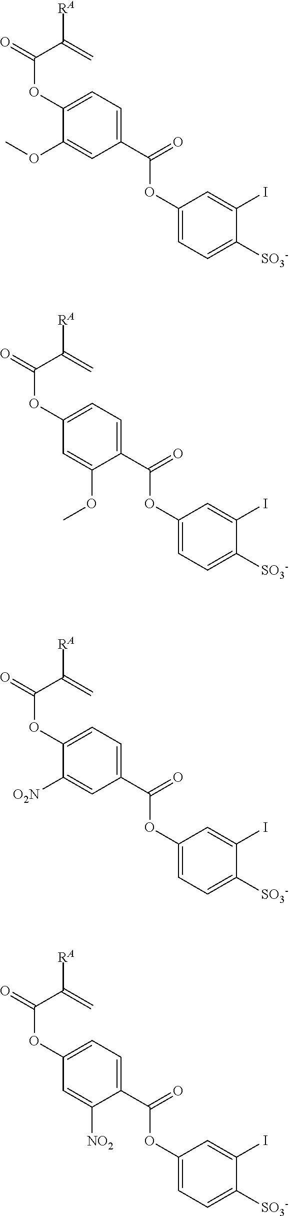

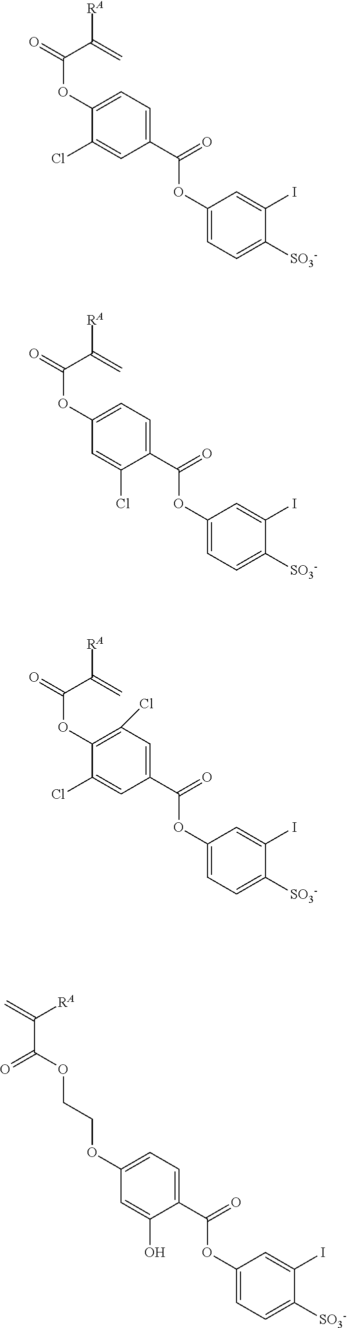

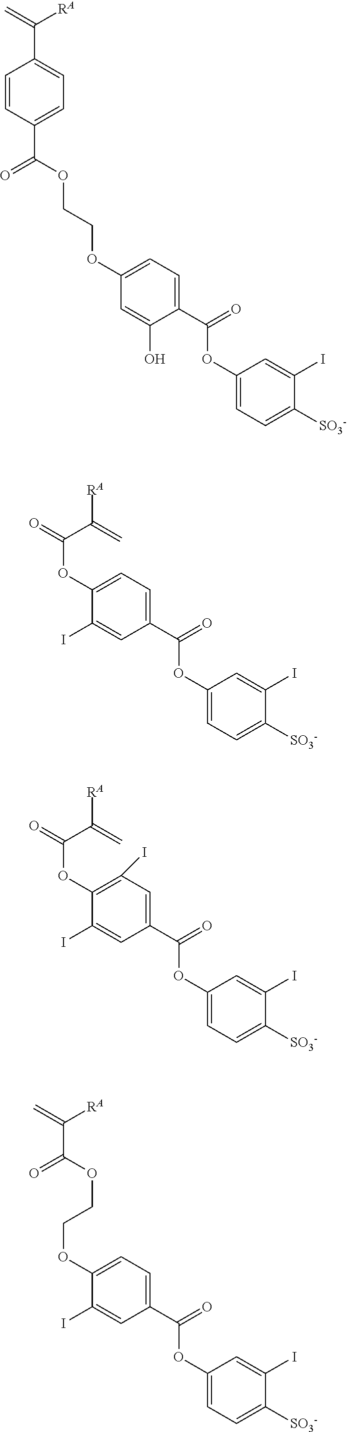

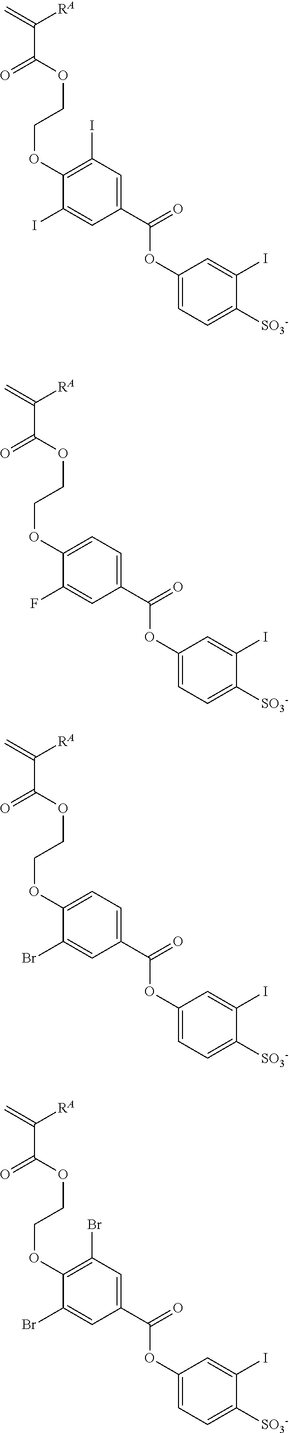

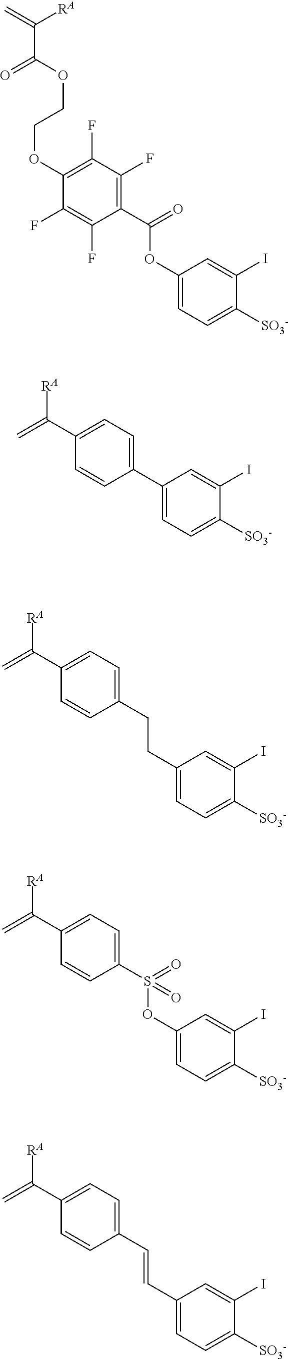

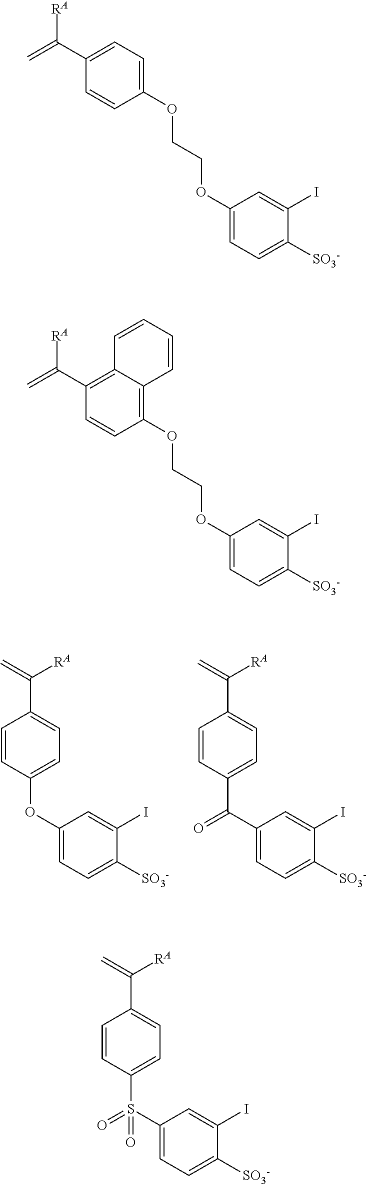

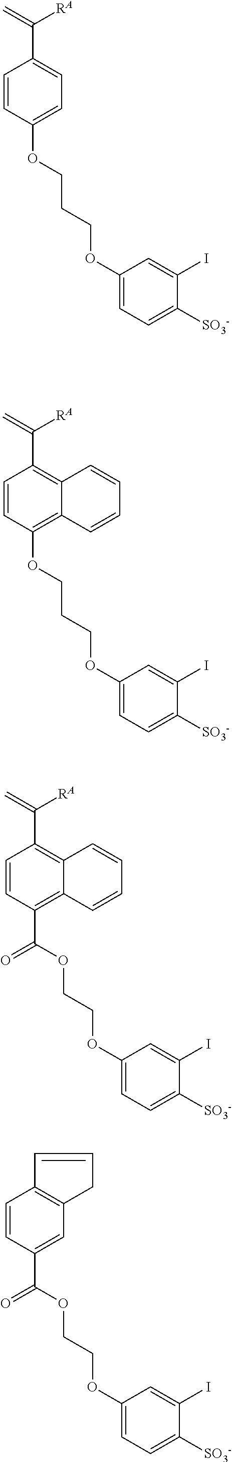

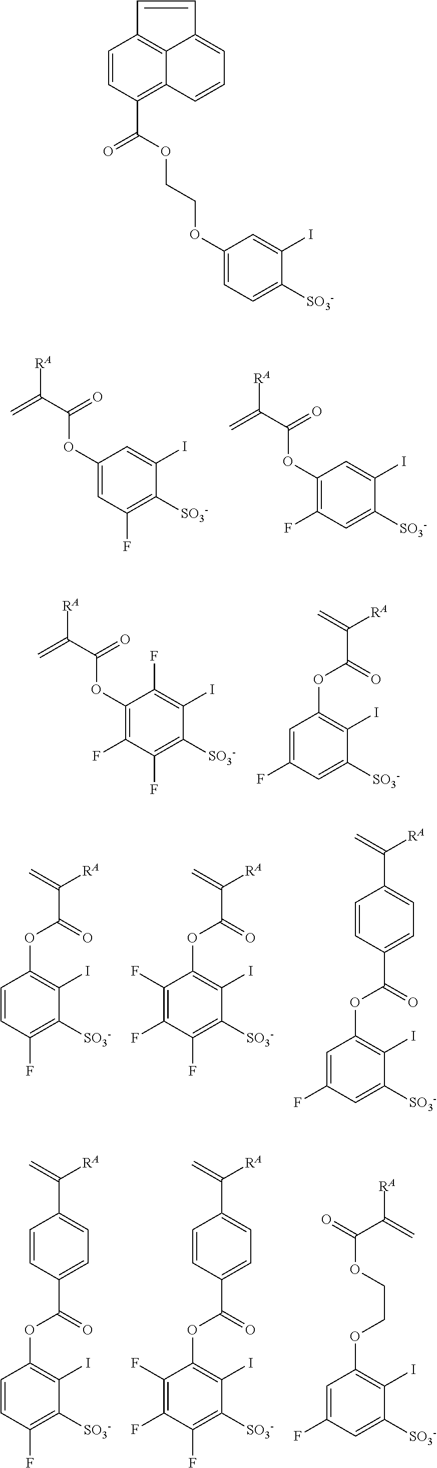

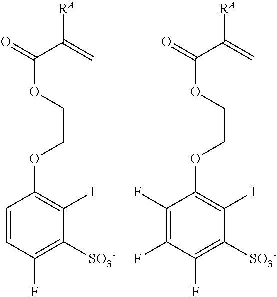

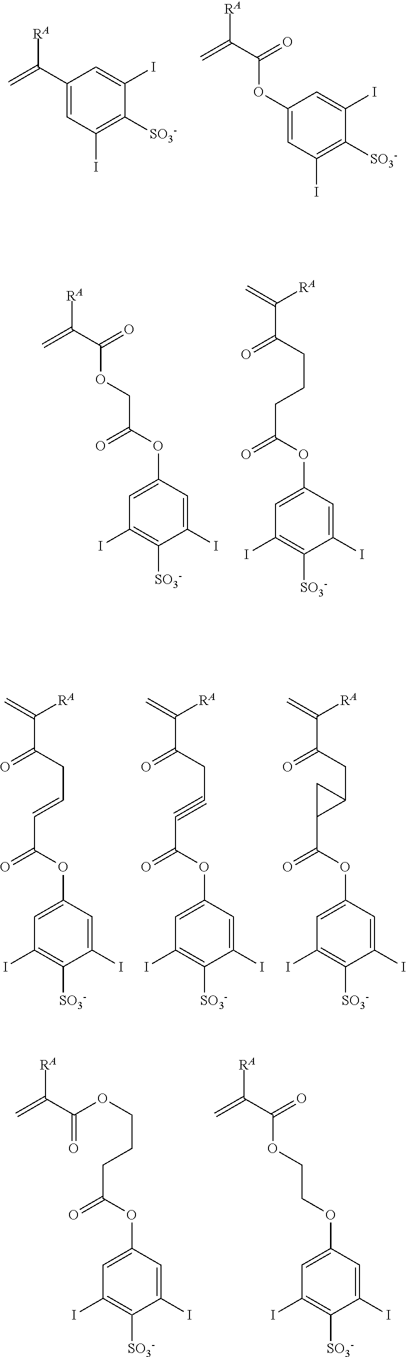

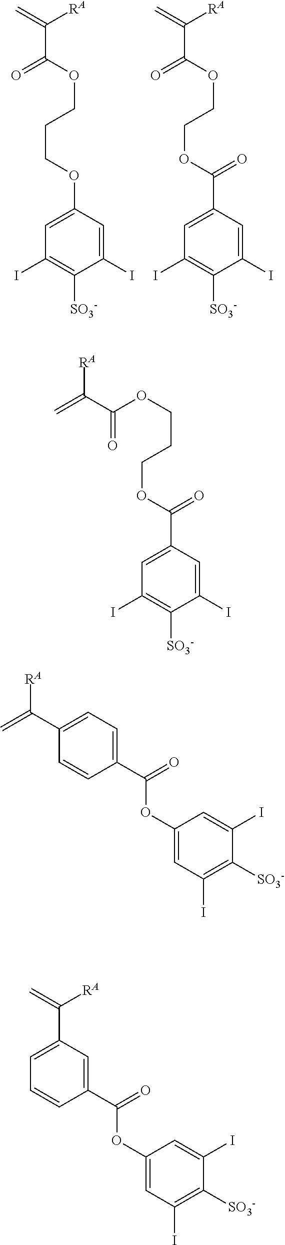

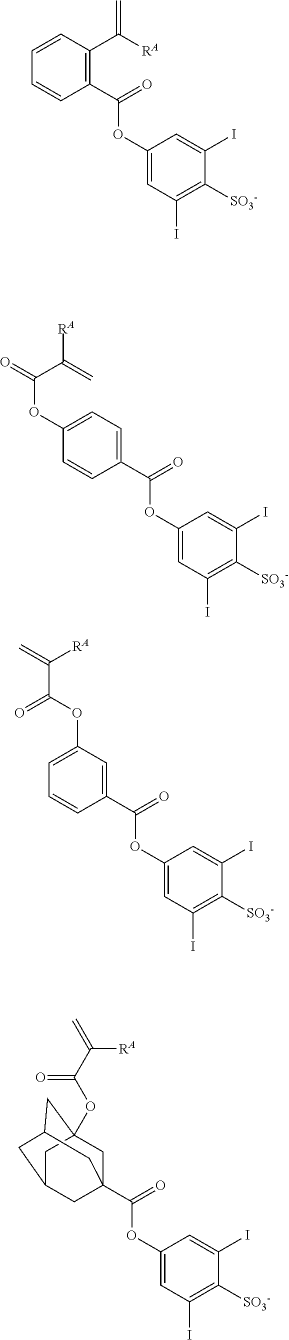

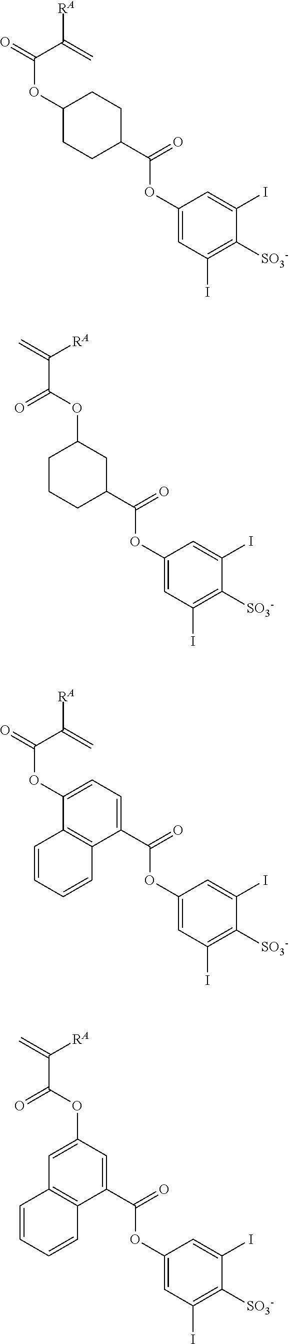

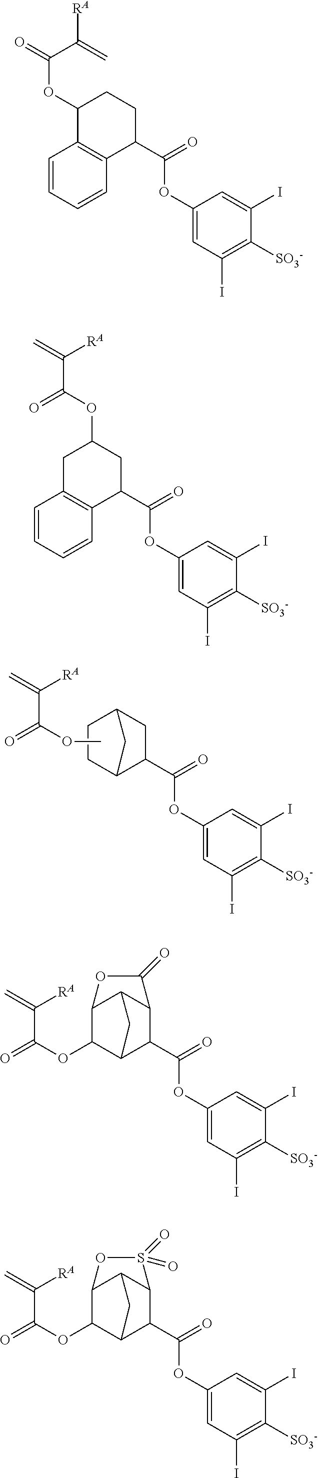

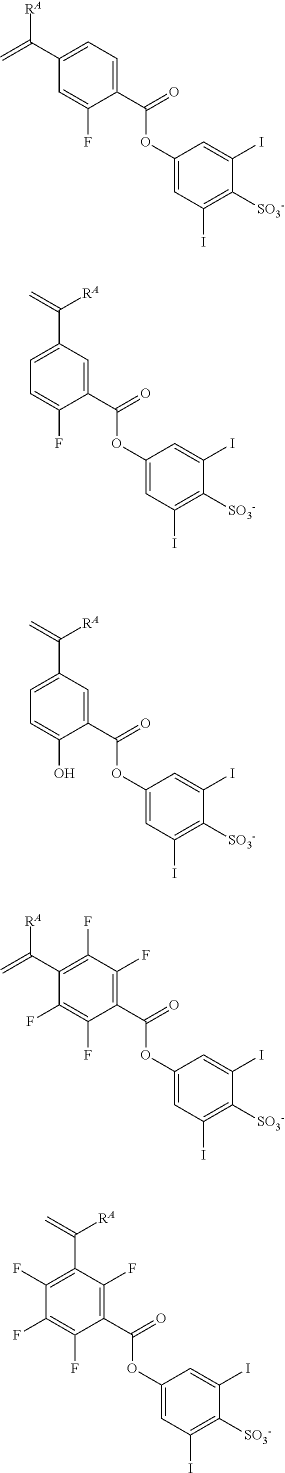

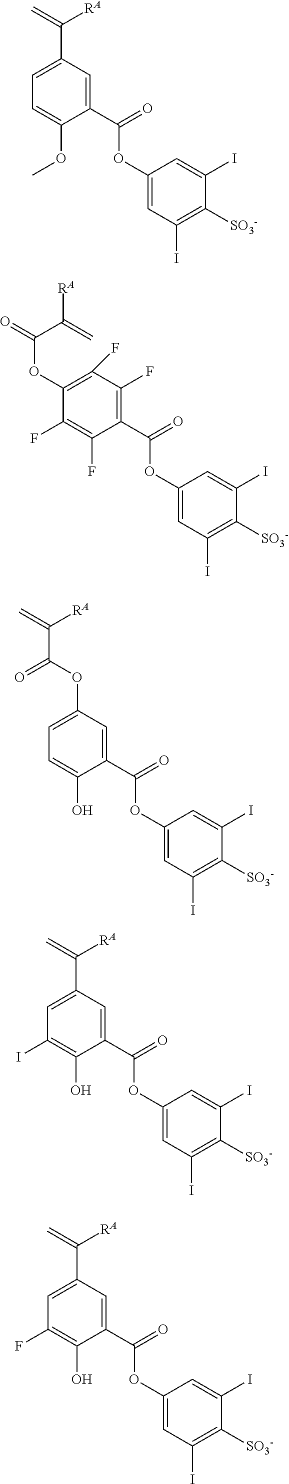

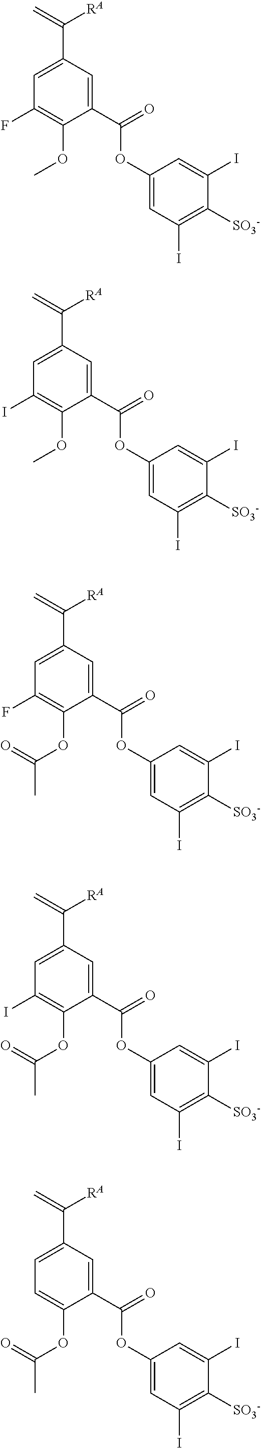

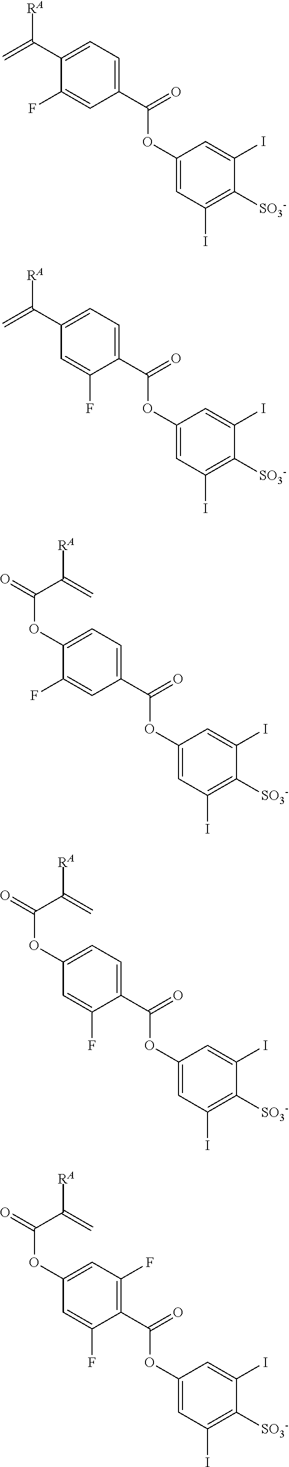

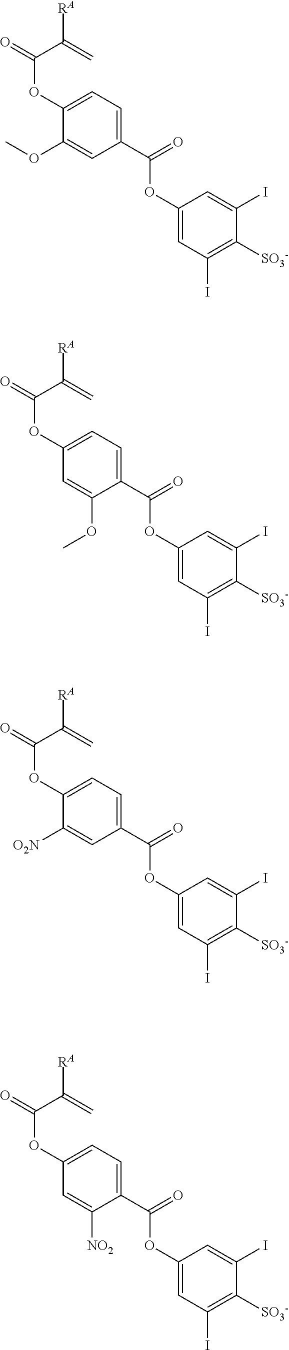

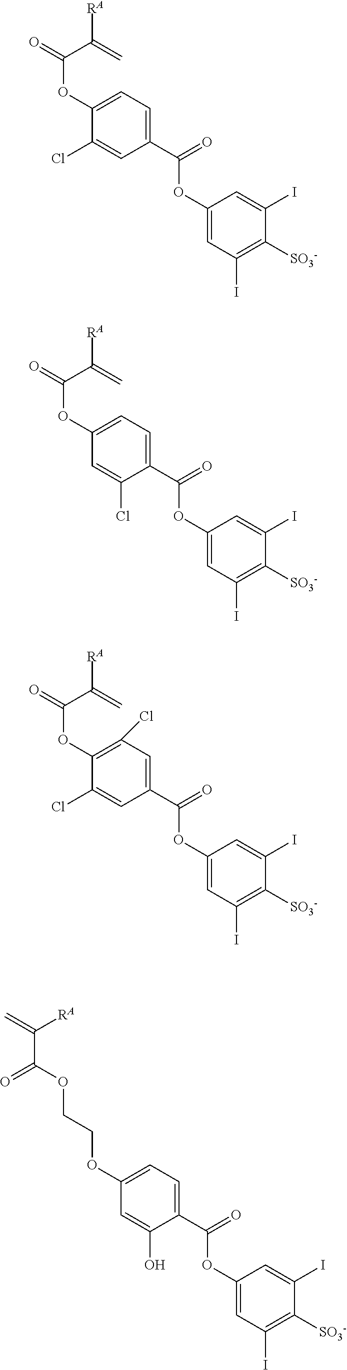

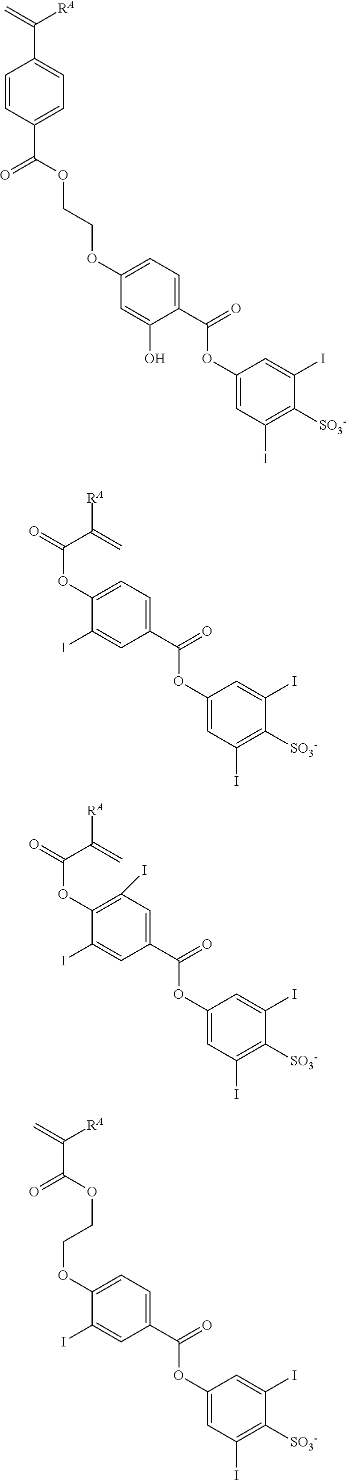

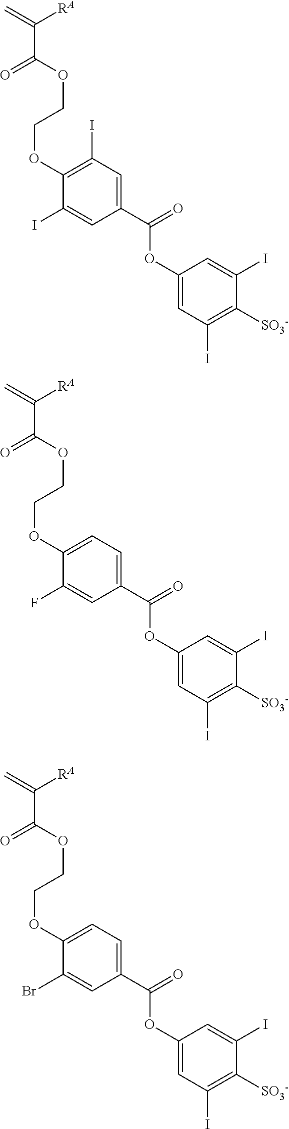

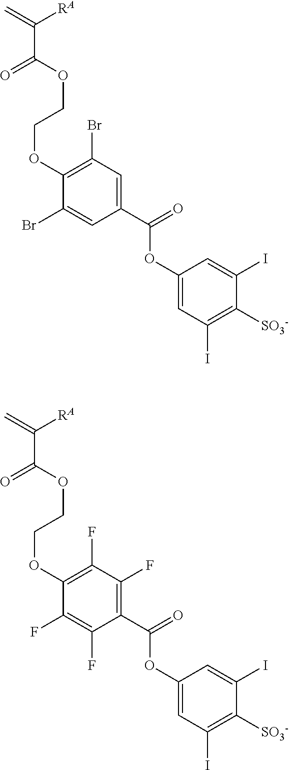

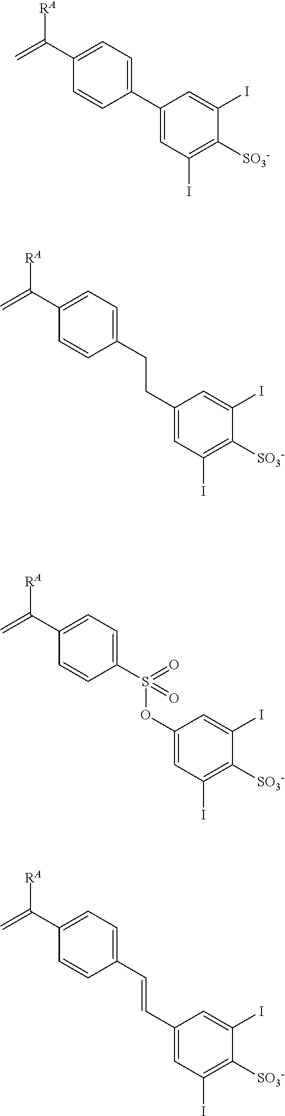

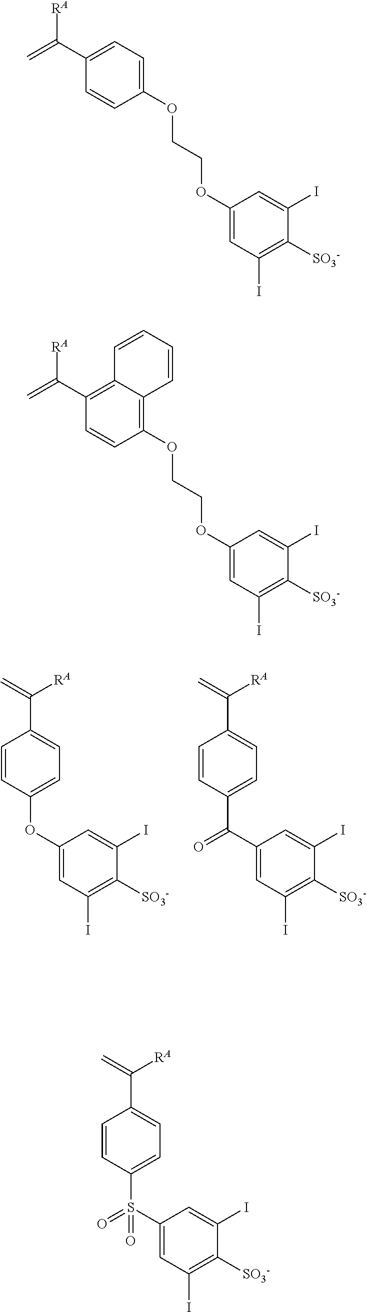

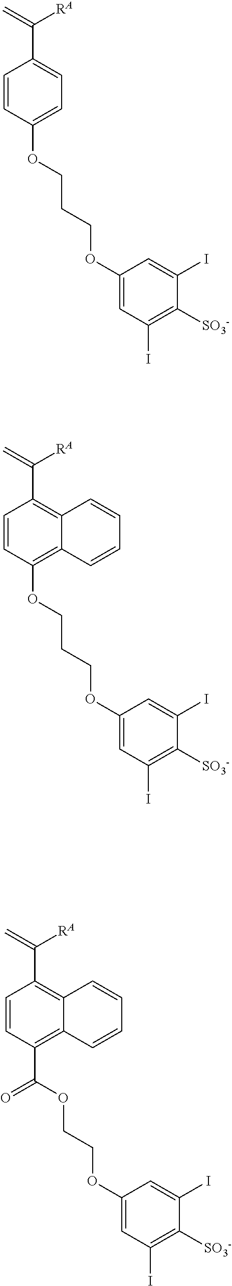

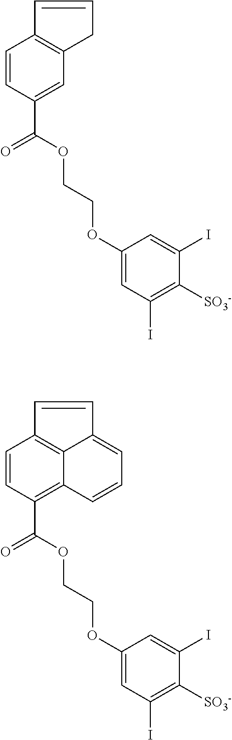

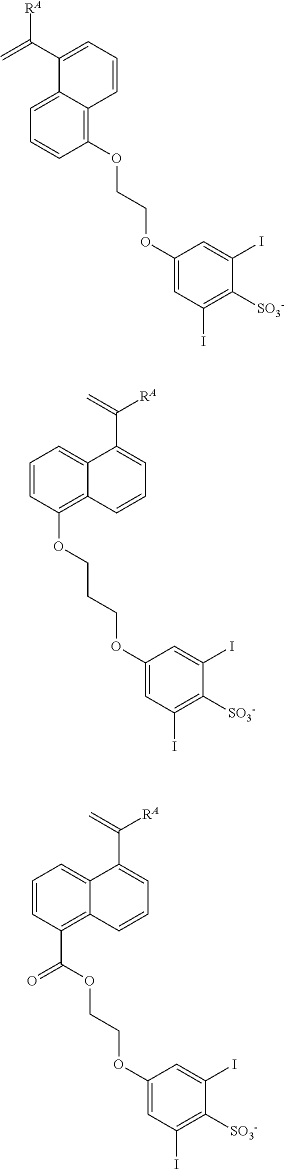

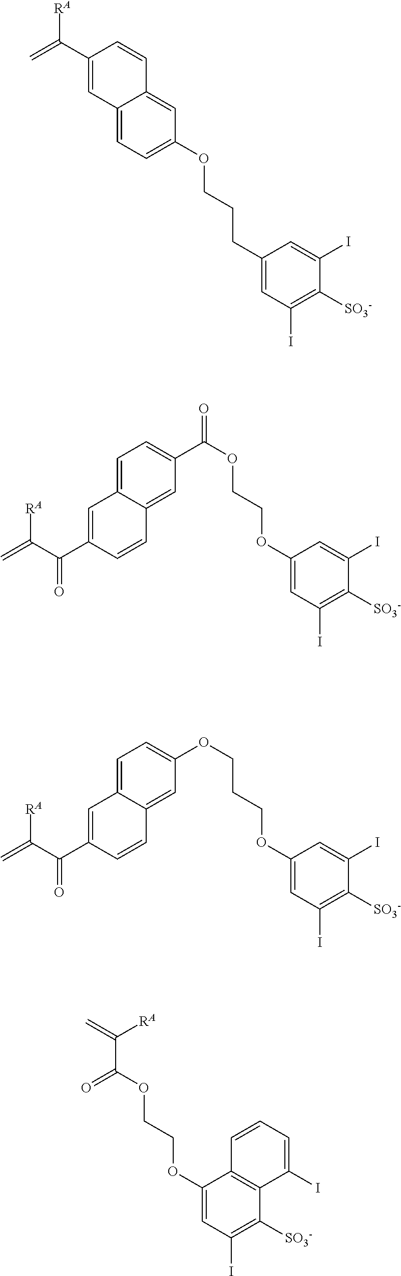

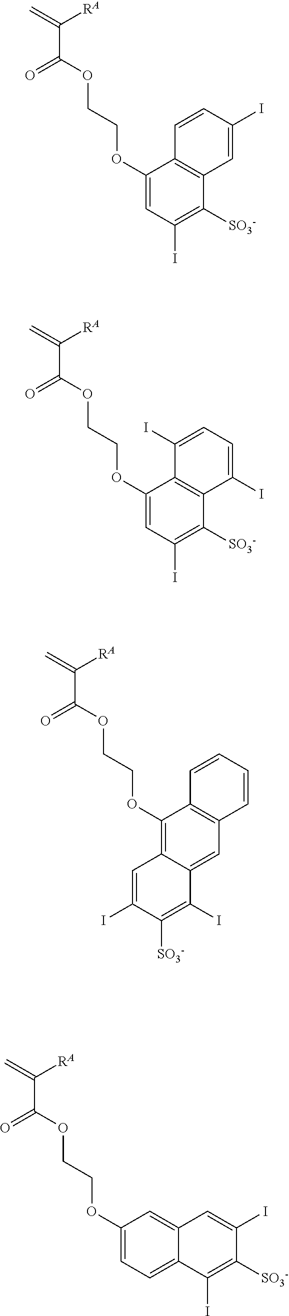

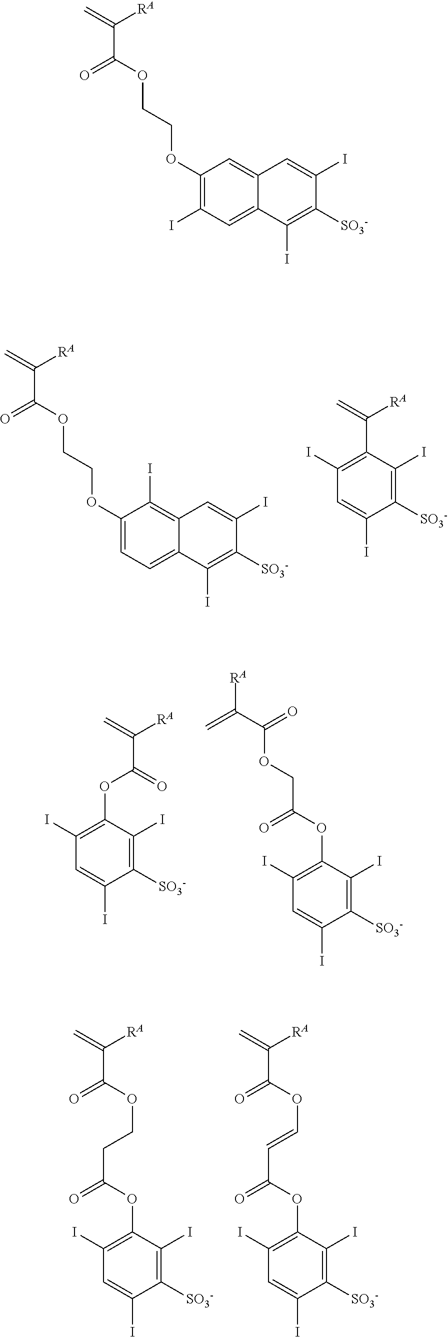

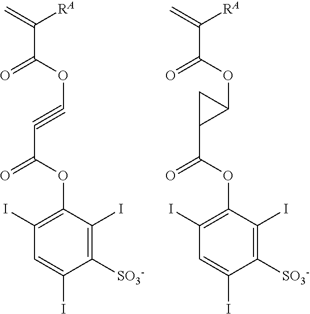

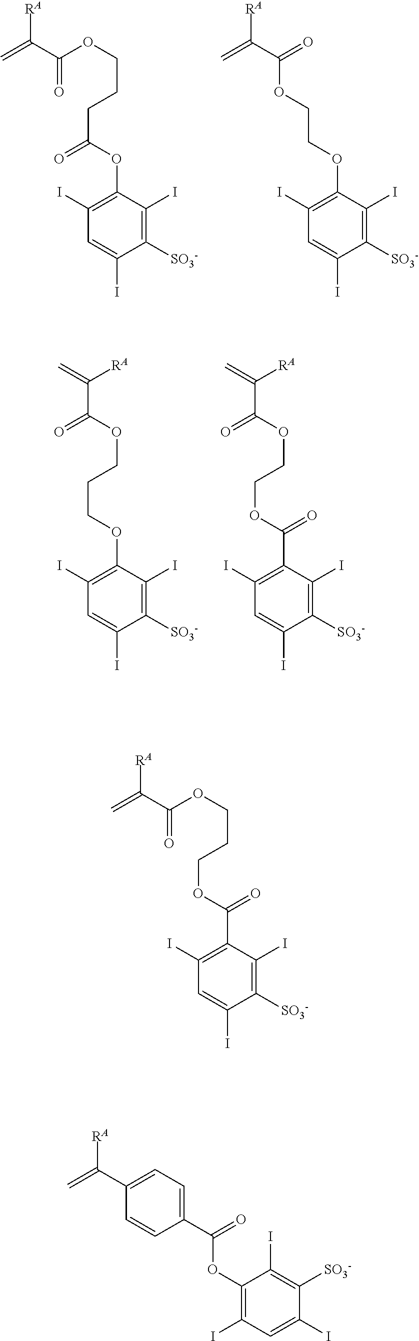

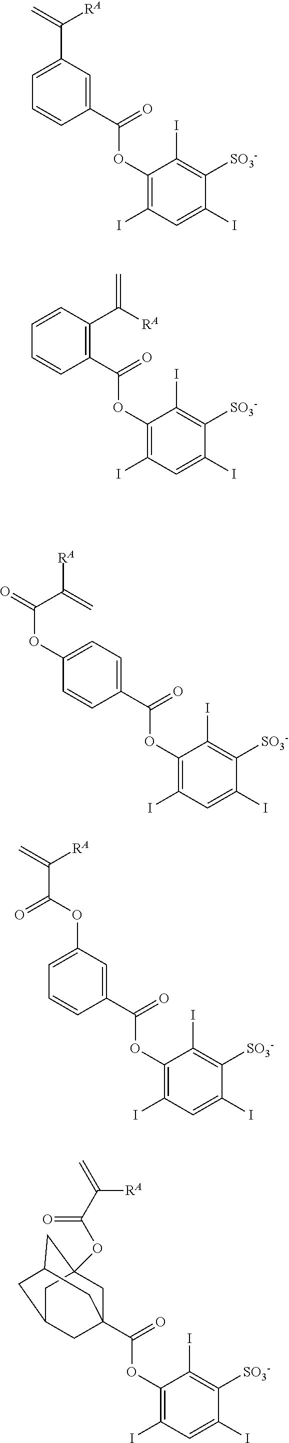

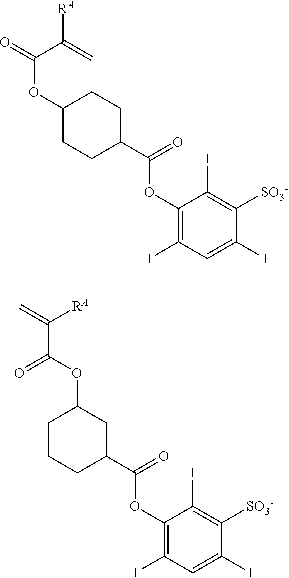

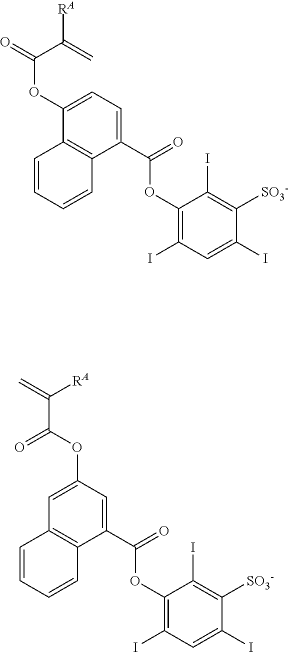

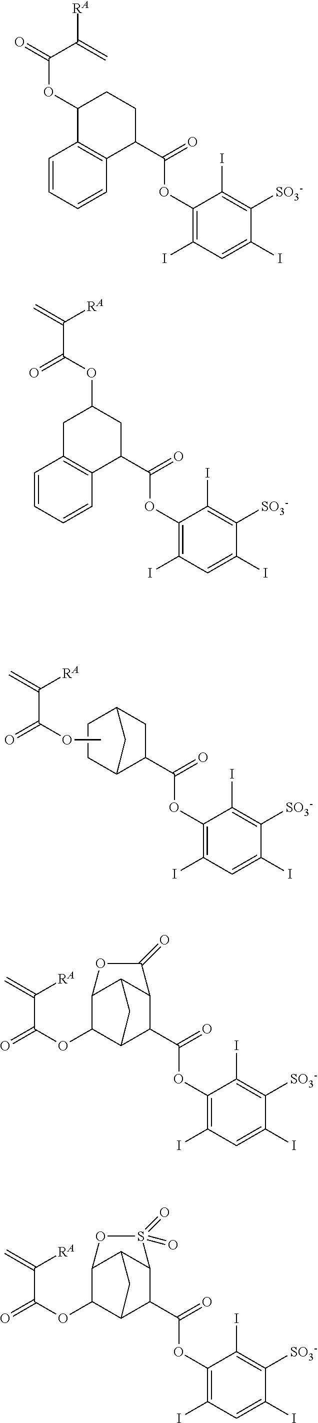

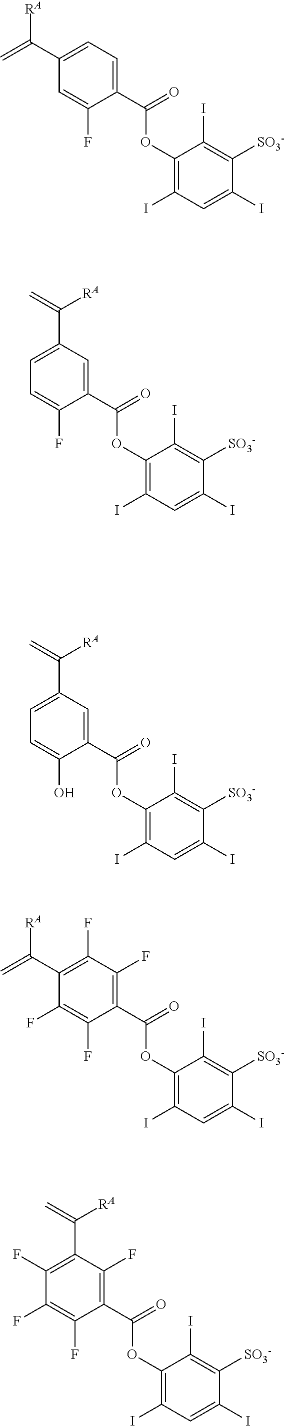

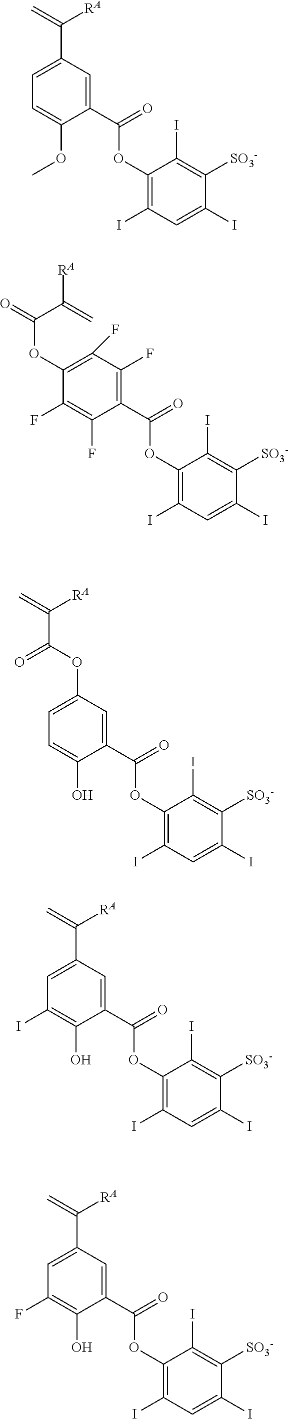

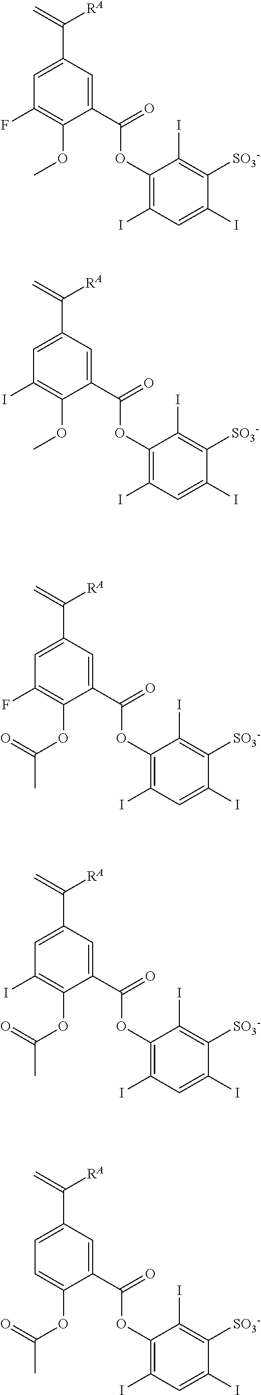

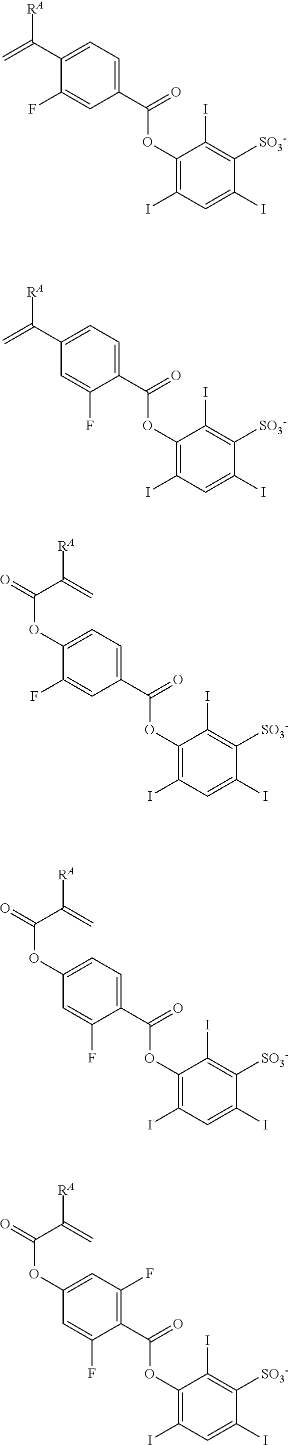

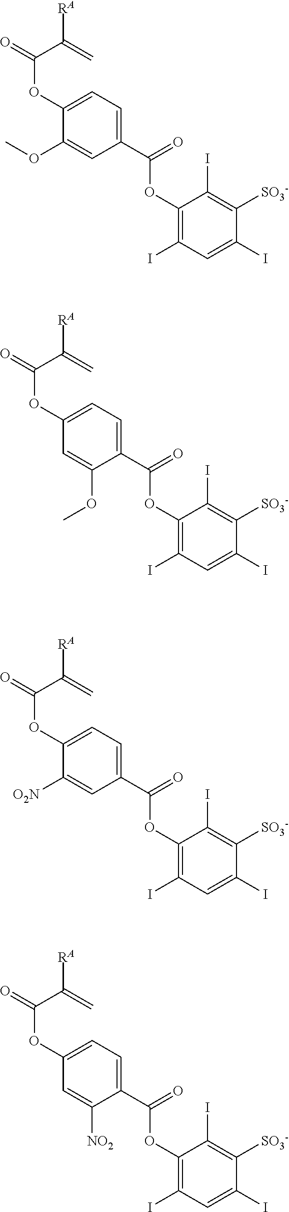

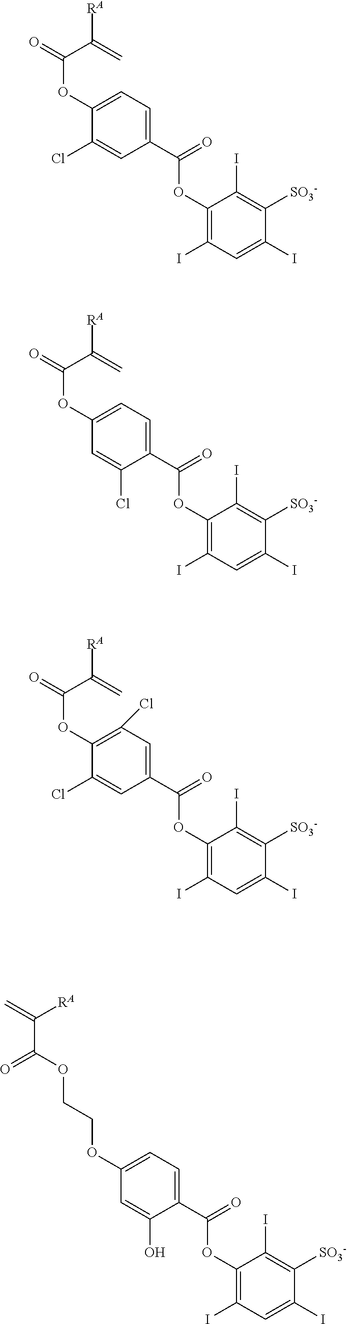

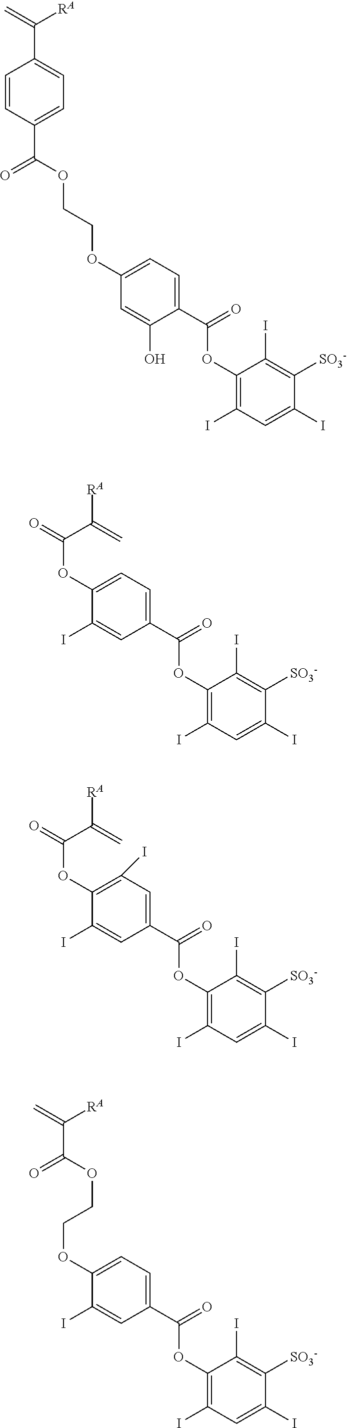

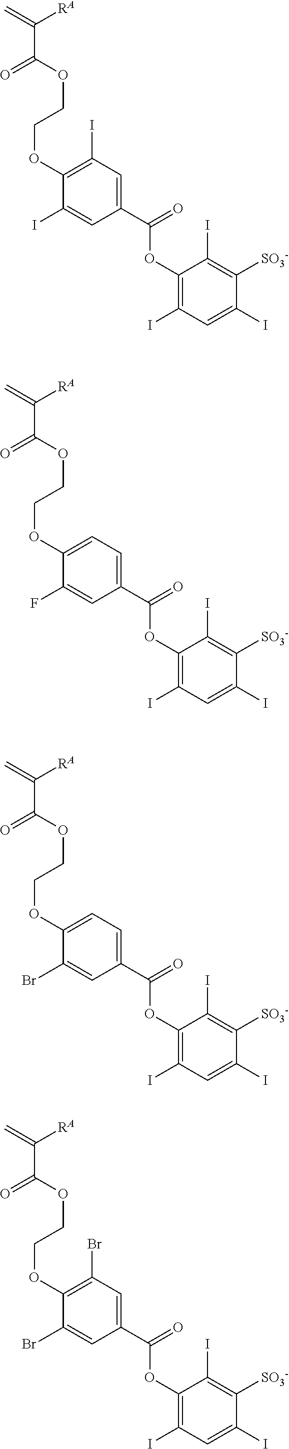

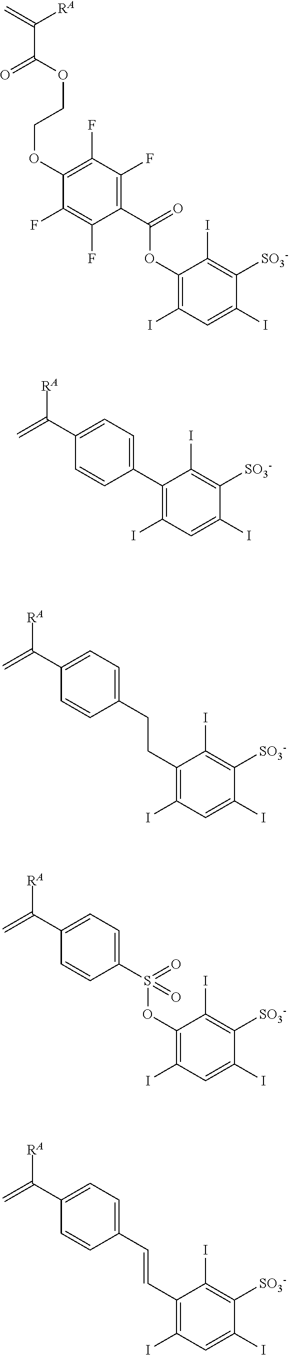

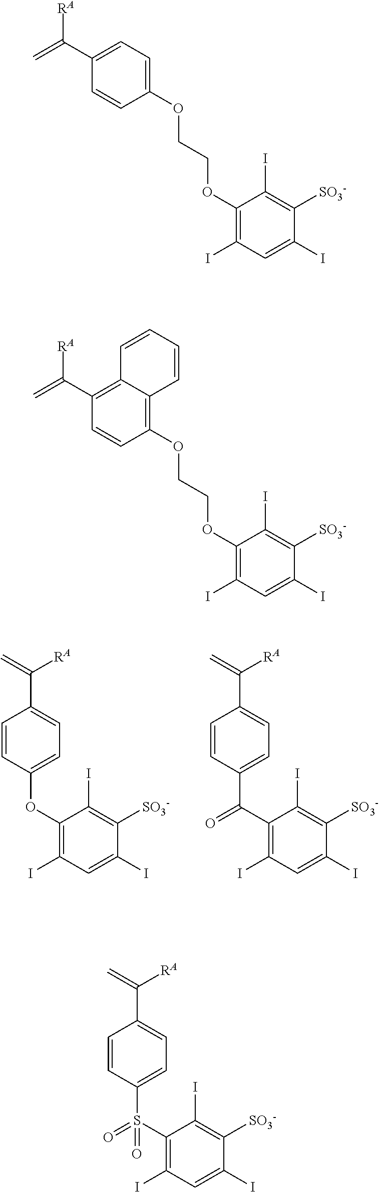

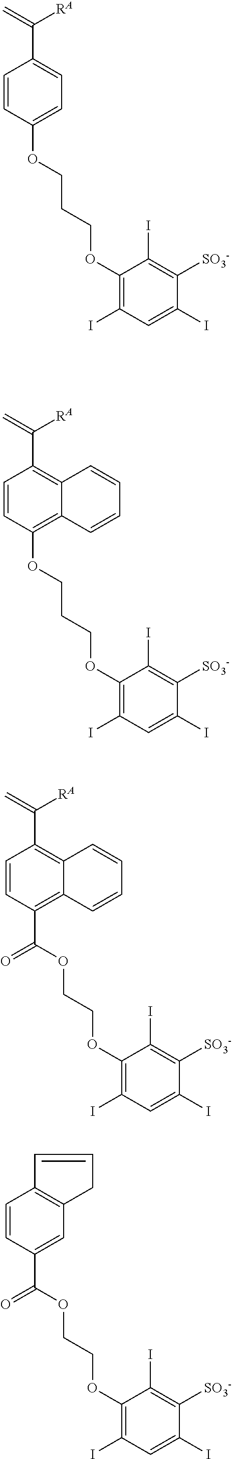

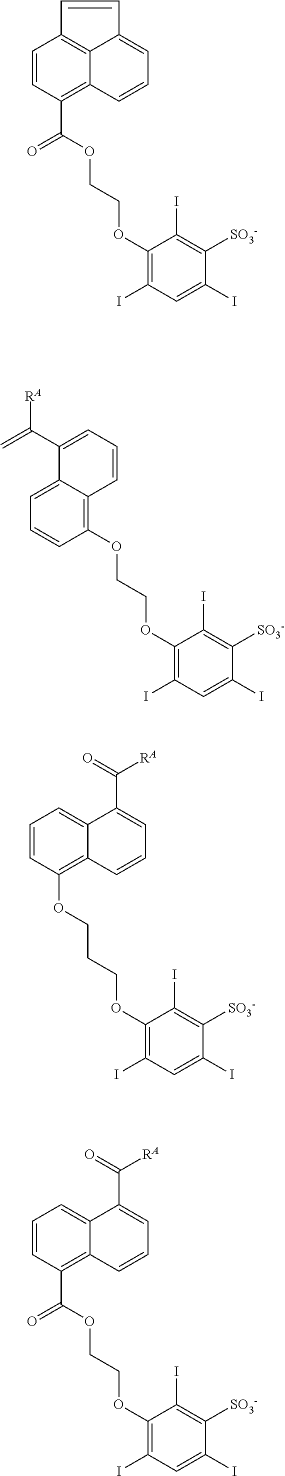

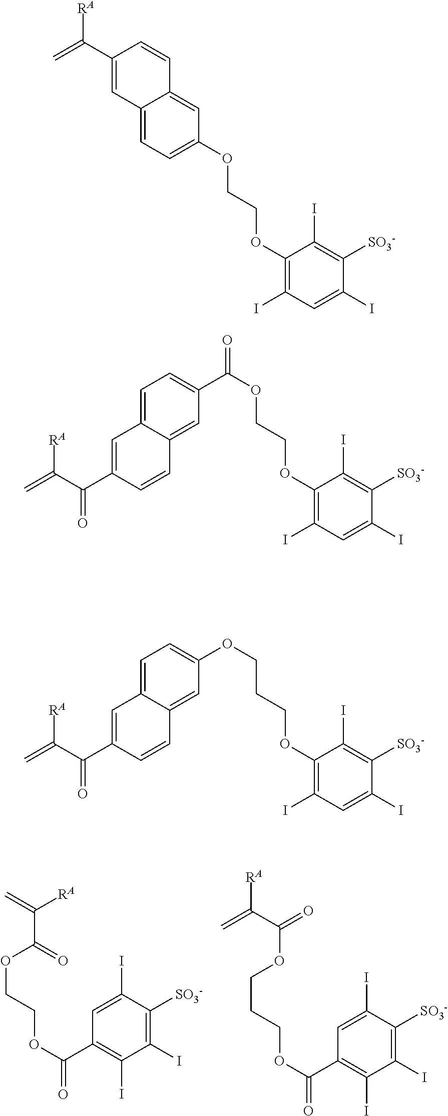

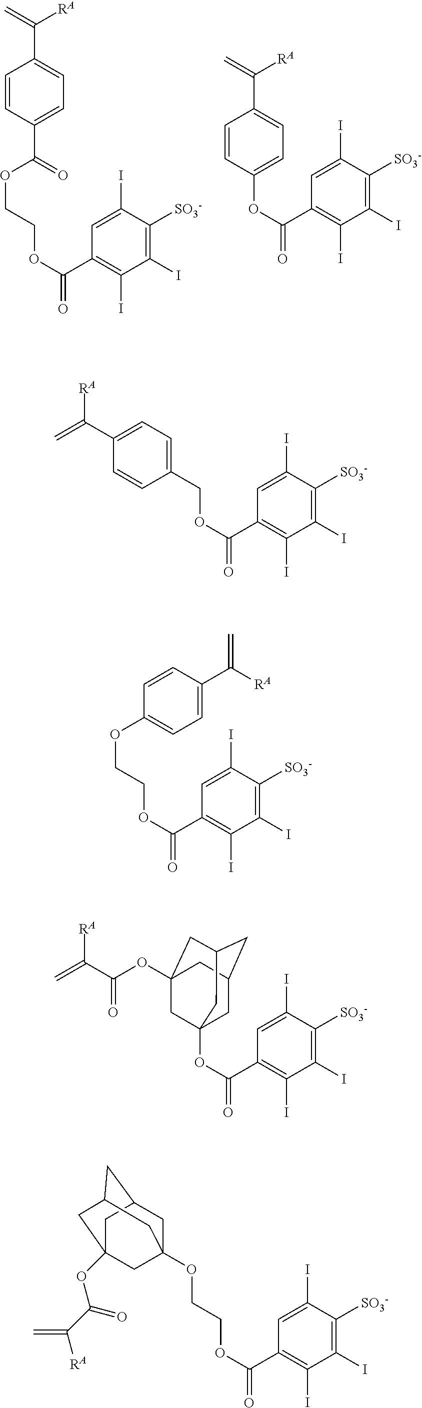

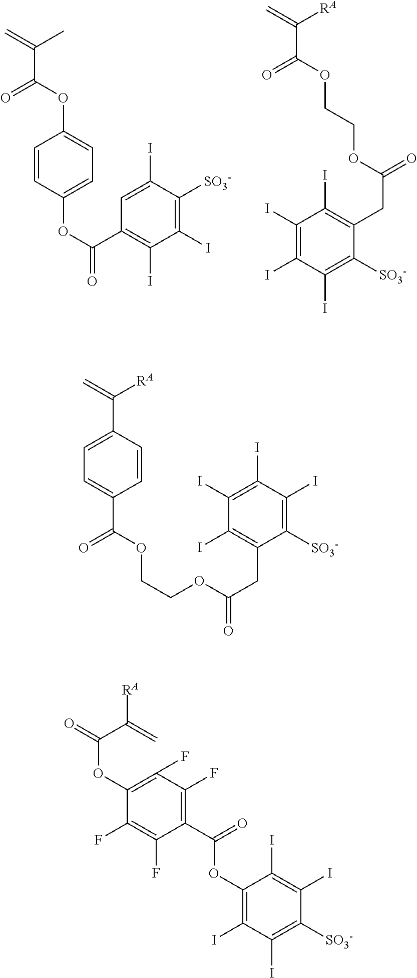

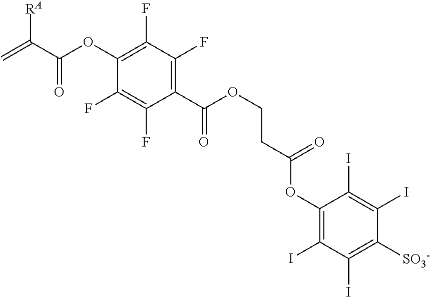

In formulae (c2) to (c5), M⁺ is a sulfonium or iodonium cation, preferably a sulfonium cation having the formula (M1) or iodonium cation having the formula (M2).

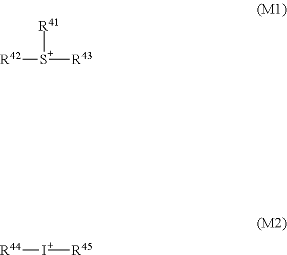

In formulae (M1) and (M2), R⁴¹ to R⁴⁵ are each independently halogen or a C₁-C₂₀ hydrocarbyl group which may contain a heteroatom. Suitable halogen atoms include fluorine, chlorine, bromine and iodine.

The C₁-C₂₀ hydrocarbyl group represented by R⁴¹ to R⁴⁵ may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl, and icosyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, propenyl, butenyl, and hexenyl; C₂-C₂₀ alkynyl groups such as ethynyl, propynyl and butynyl; C₃-C₂₀ cyclic unsaturated aliphatic hydrocarbyl groups such as cyclohexenyl and norbornenyl; C₆-C₂₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, and tert-butylnaphthyl; C₇-C₂₀ aralkyl groups such as benzyl and phenethyl, and combinations thereof.

In the hydrocarbyl group, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, fluorine, chlorine, bromine, iodine, cyano, nitro, mercapto, carbonyl, ether bond, ester bond, sulfonate ester bond, carbonate bond, lactone ring, sultone ring, carboxylic anhydride (—C(═O)—O—C(═O)—) or haloalkyl moiety.

Also, R⁴¹ and R⁴² may bond together to form a ring with the sulfur atom to which they are attached. Exemplary structures of the ring are shown below.

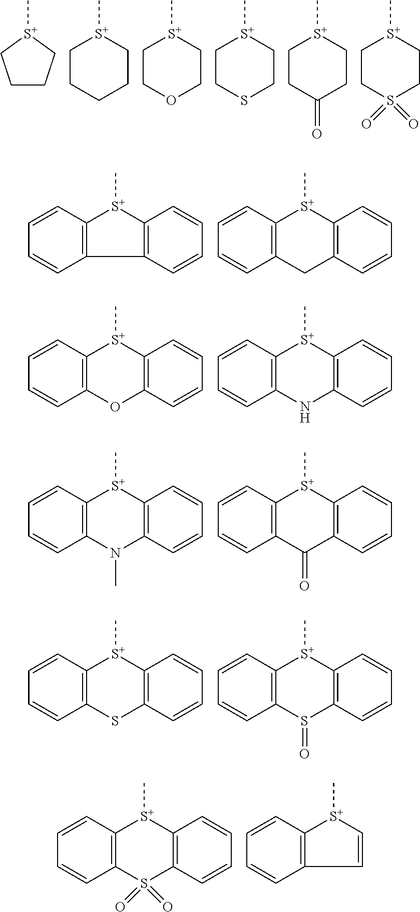

Examples of the sulfonium cation M⁺ are shown below, but not limited thereto.

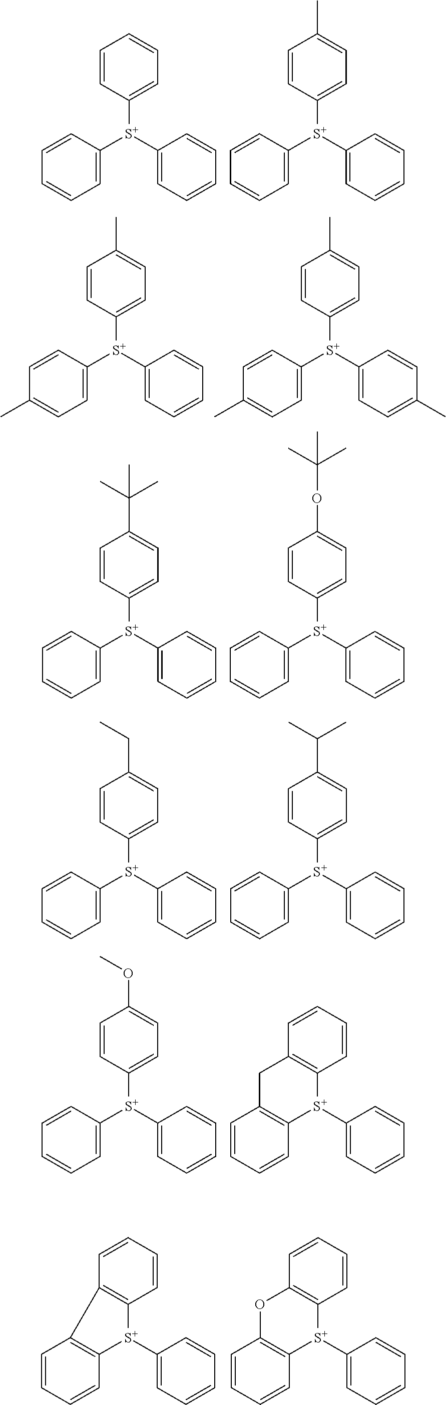

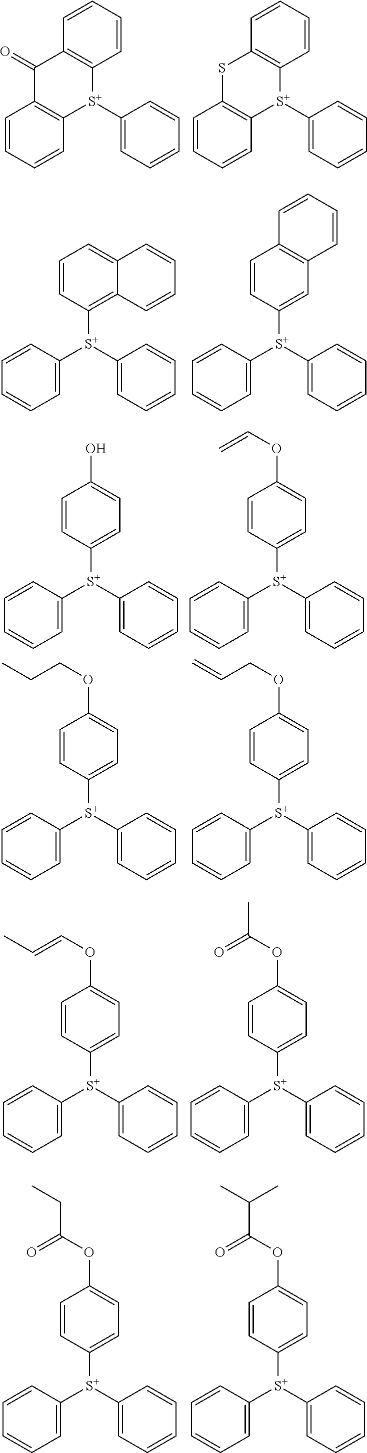

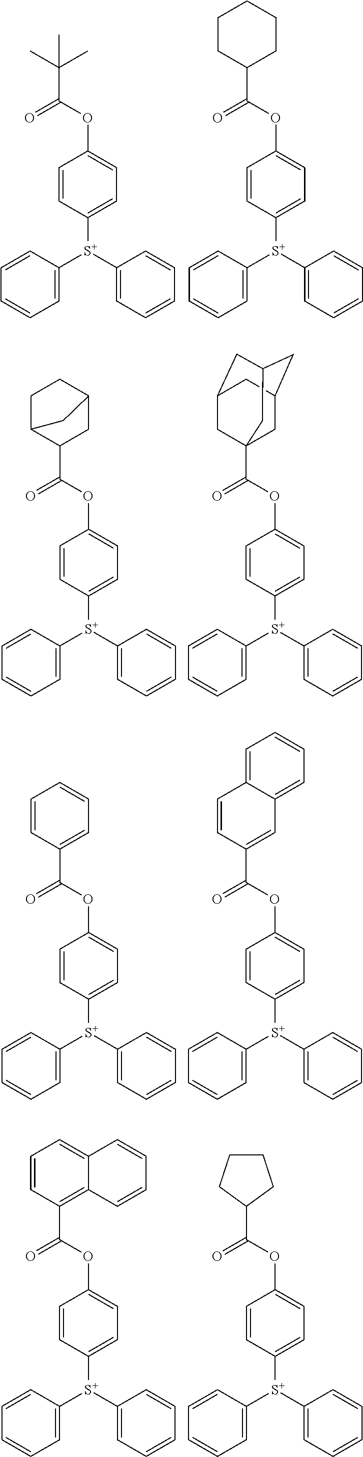

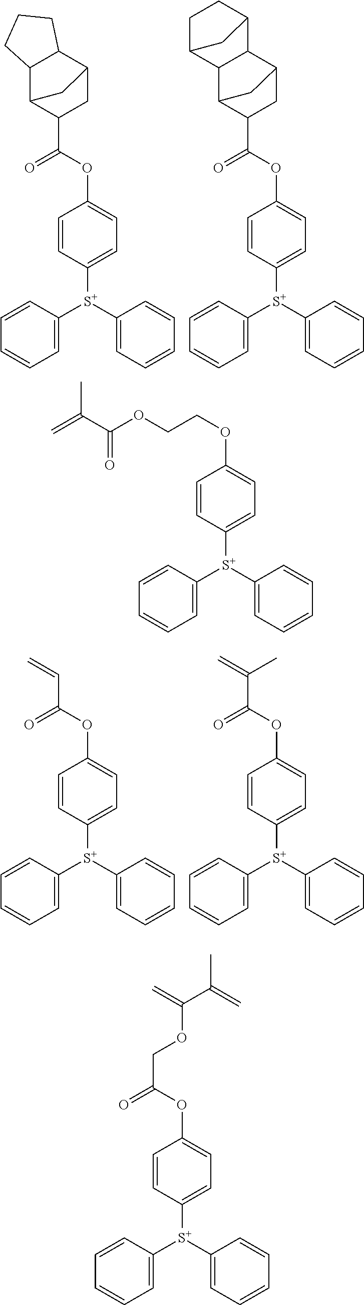 [SMILES: O=C(Oc1ccc([S+](c2ccccc2)c2ccccc2)cc1)C1CC2CC1C1CCCC21 ; O=C(Oc1ccc([S+](c2ccccc2)c2ccccc2)cc1)C1CC2CC1C1C3CCC(C3)C21 ; C=C(C)C(=O)OCCOc1ccc([S+](c2ccccc2)c2ccccc2)cc1 ; C=CC(=O)Oc1ccc([S+](c2ccccc2)c2ccccc2)cc1 ; C=C(C)C(=O)Oc1ccc([S+](c2ccccc2)c2ccccc2)cc1 ; C=C(C)C(=C)OCC(=O)Oc1ccc([S+](c2ccccc2)c2ccccc2)cc1]

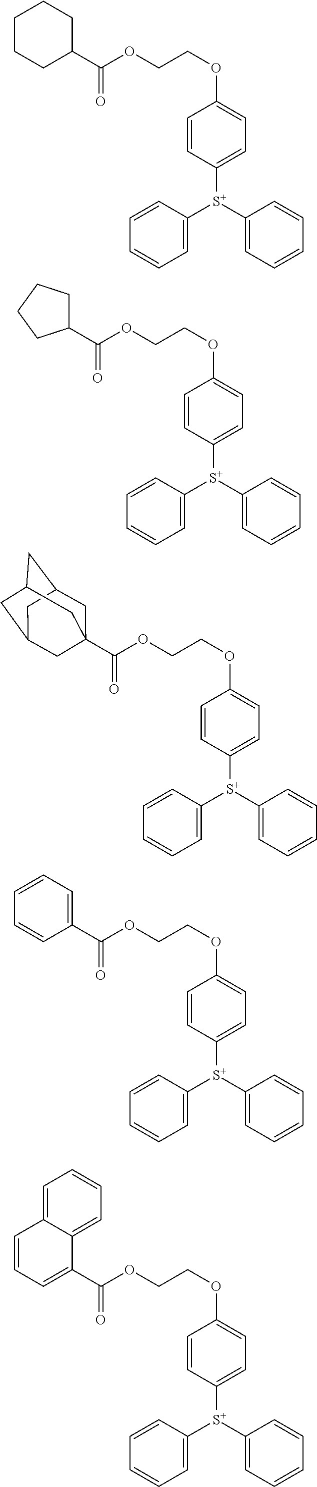 [SMILES: O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2 ; O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12]

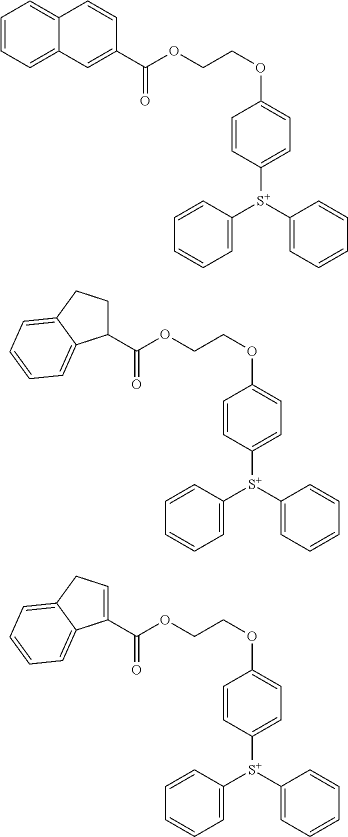 [SMILES: O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21 ; O=C(OCCOc1ccc([S+](c2ccccc2)c2ccccc2)cc1)C1=CCc2ccccc21]

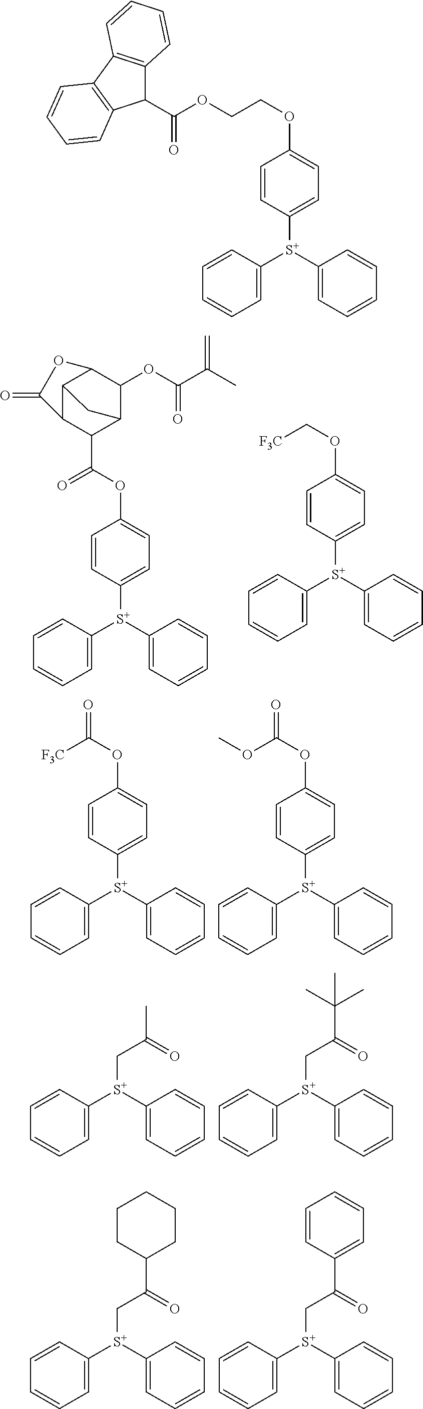

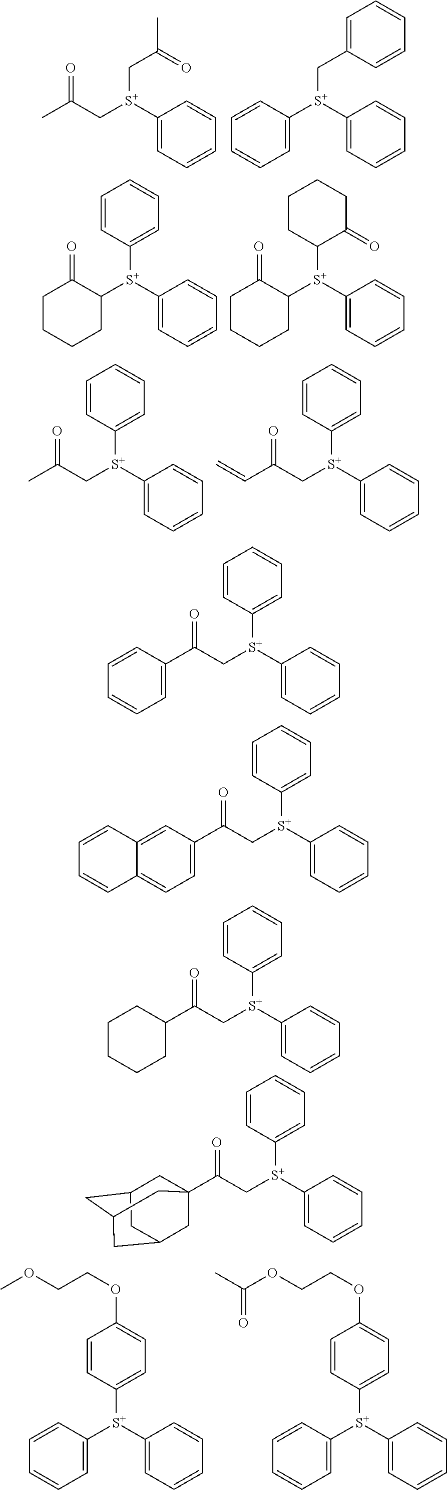

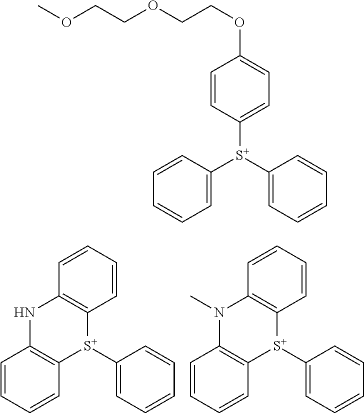 [SMILES: COCCOCCOc1ccc([S+](c2ccccc2)c2ccccc2)cc1 ; c1ccc([S+]2c3ccccc3Nc3ccccc32)cc1 ; CN1c2ccccc2[S+](c2ccccc2)c2ccccc21]

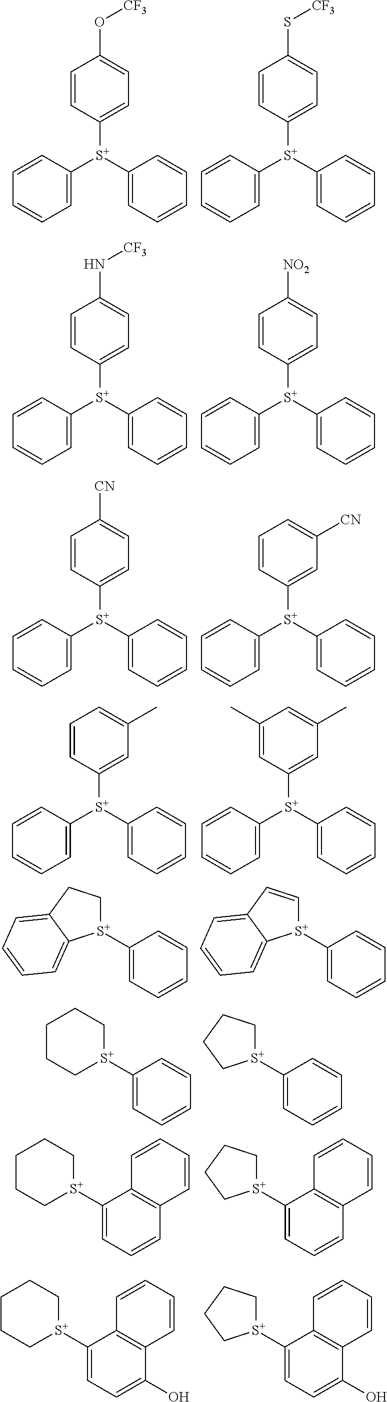

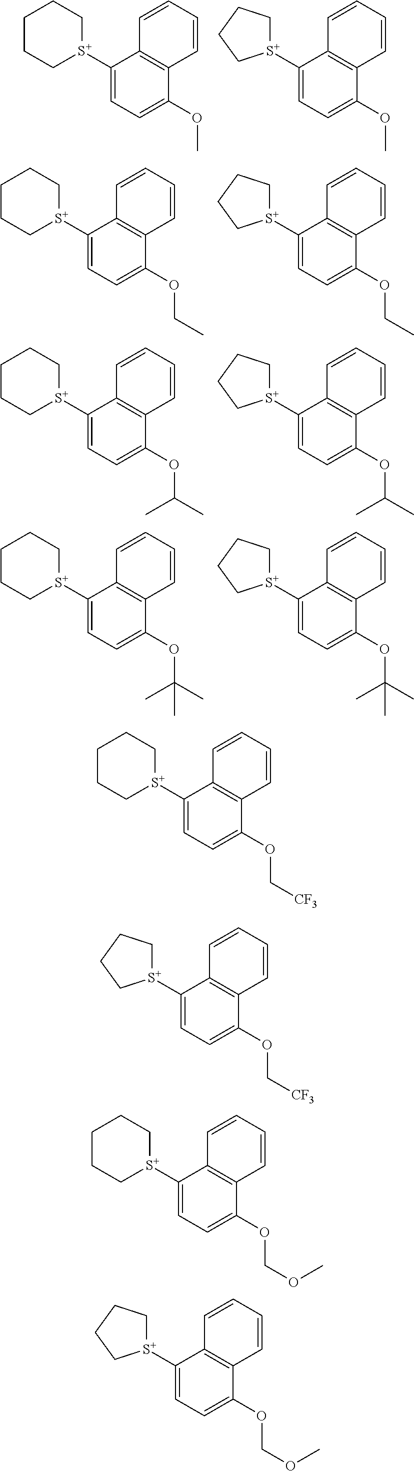

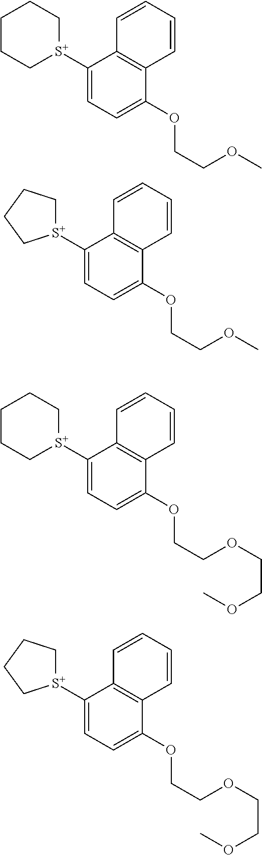 [SMILES: COCCOc1ccc([S+]2CCCCC2)c2ccccc12 ; COCCOc1ccc([S+]2CCCC2)c2ccccc12 ; COCCOCCOc1ccc([S+]2CCCCC2)c2ccccc12 ; COCCOCCOc1ccc([S+]2CCCC2)c2ccccc12]

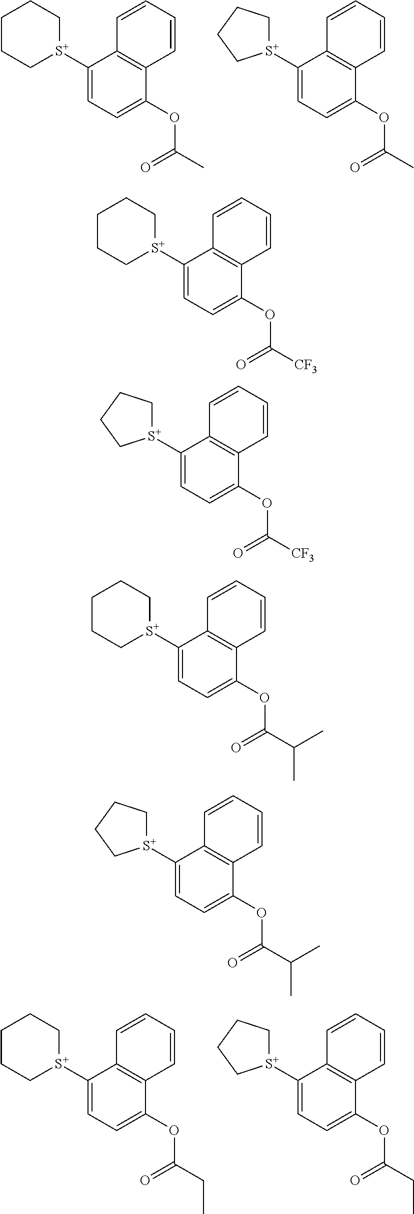

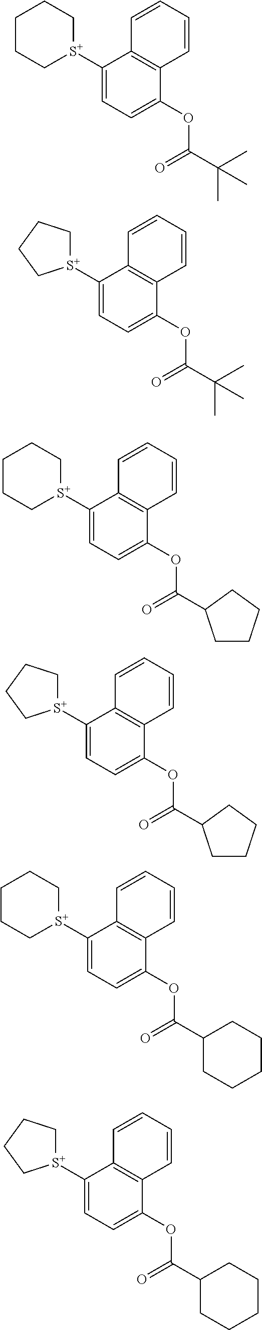 [SMILES: CC(C)(C)C(=O)Oc1ccc([S+]2CCCCC2)c2ccccc12 ; CC(C)(C)C(=O)Oc1ccc([S+]2CCCC2)c2ccccc12 ; O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1]

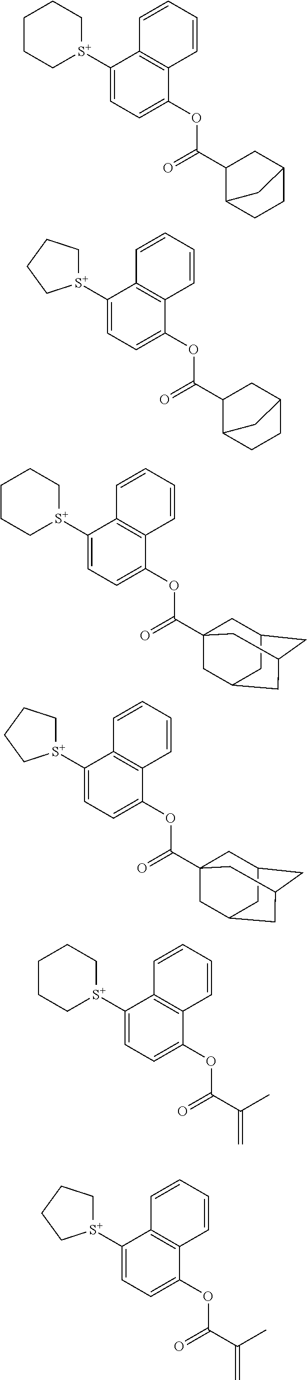 [SMILES: O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2 ; C=C(C)C(=O)Oc1ccc([S+]2CCCCC2)c2ccccc12 ; C=C(C)C(=O)Oc1ccc([S+]2CCCC2)c2ccccc12]

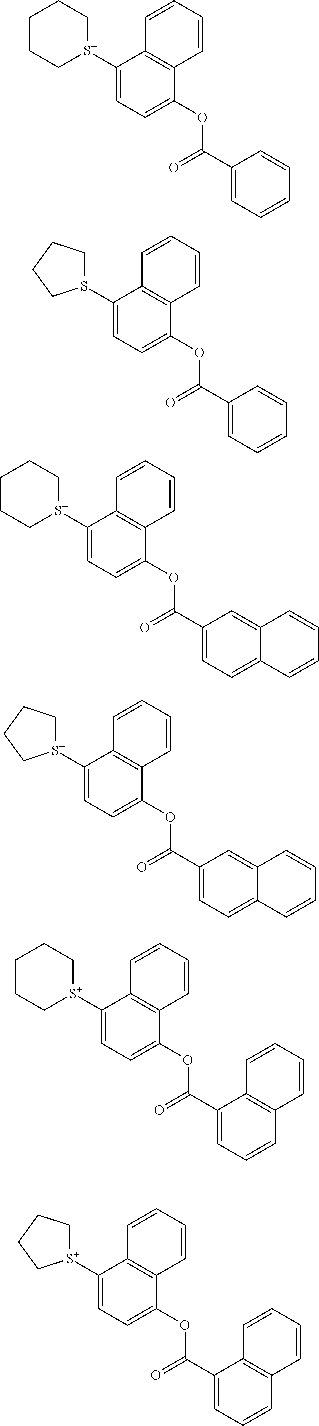 [SMILES: O=C(Oc1ccc([S+]2CCCCC2)c2ccccc12)c1ccccc1 ; O=C(Oc1ccc([S+]2CCCC2)c2ccccc12)c1ccccc1 ; O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12]

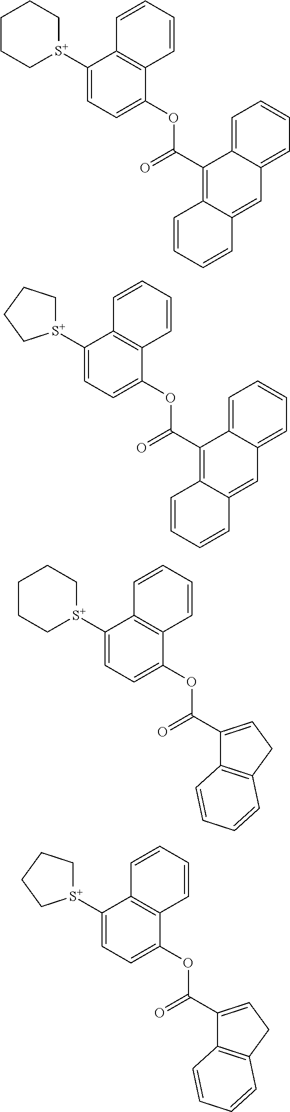 [SMILES: O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21]

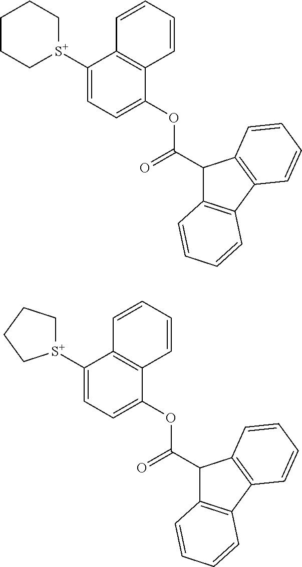 [SMILES: O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21]

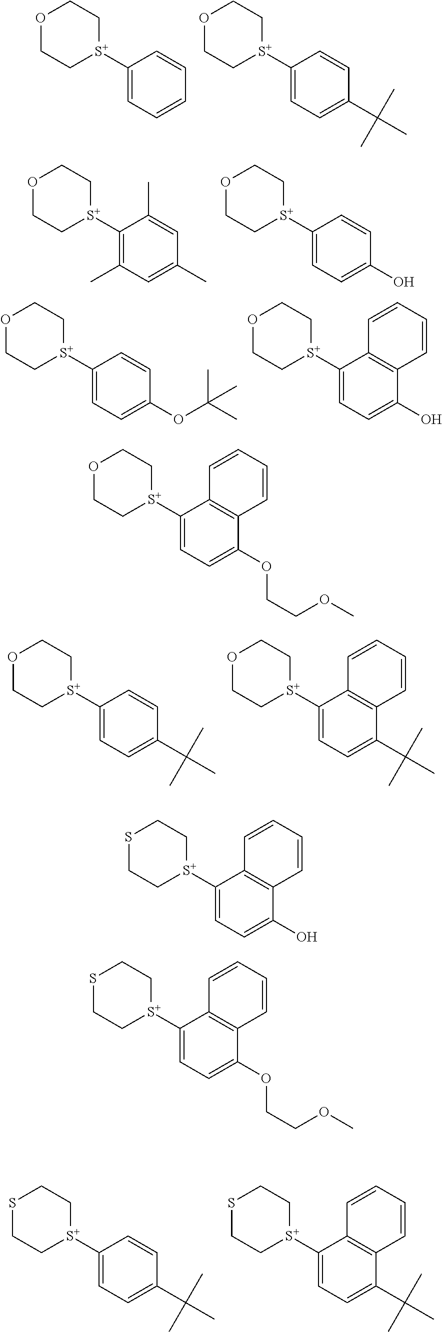

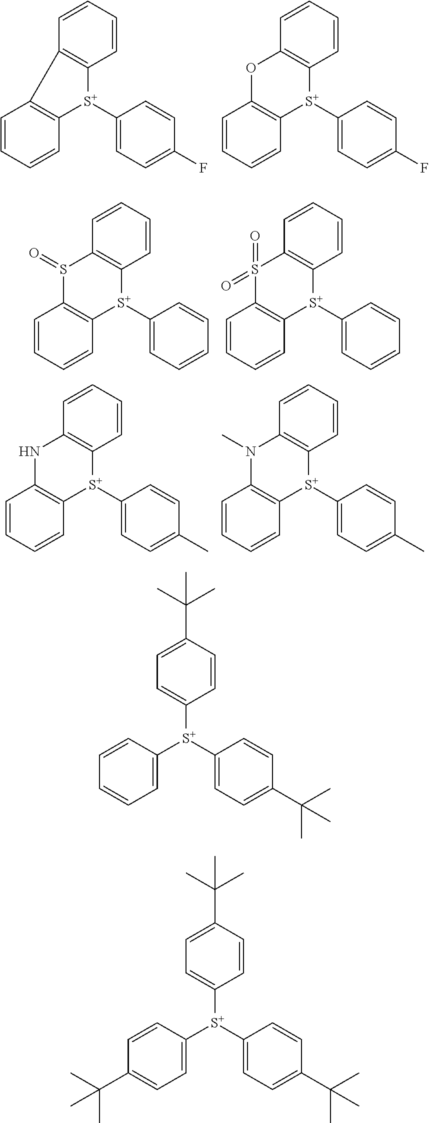

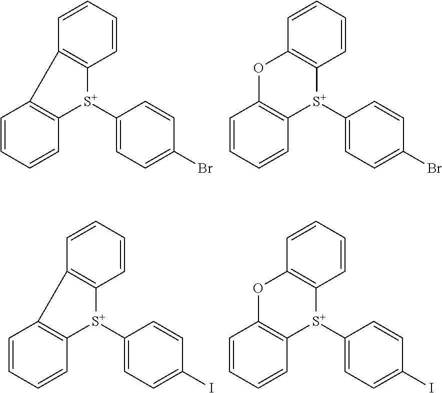 [SMILES: Brc1ccc(-[s+]2c3ccccc3c3ccccc32)cc1 ; Brc1ccc([S+]2c3ccccc3Oc3ccccc32)cc1 ; Ic1ccc(-[s+]2c3ccccc3c3ccccc32)cc1 ; Ic1ccc([S+]2c3ccccc3Oc3ccccc32)cc1]

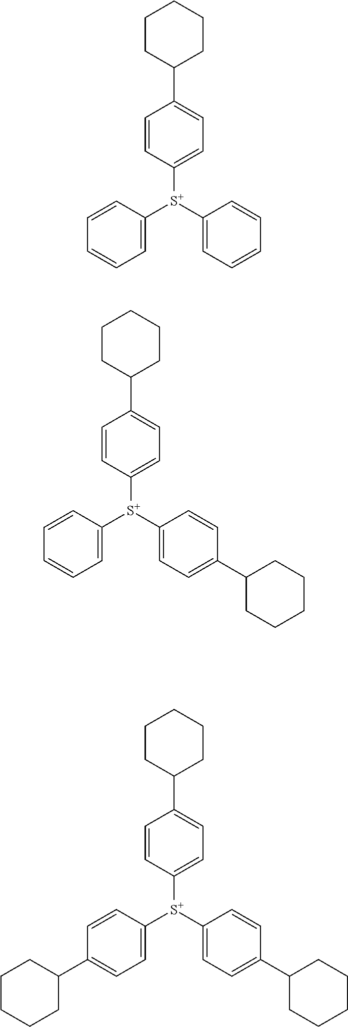 [SMILES: c1ccc([S+](c2ccccc2)c2ccc(C3CCCCC3)cc2)cc1 ; c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1]

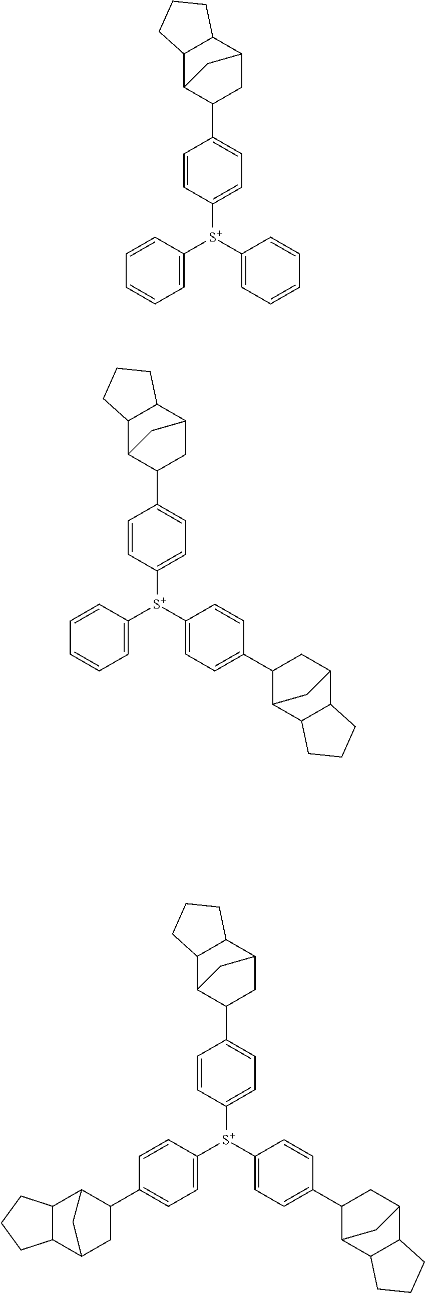 [SMILES: c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1 ; c1cc([S+](c2ccc(C3CC4CC3C3CCCC43)cc2)c2ccc(C3CC4CC3C3CCCC43)cc2)ccc1C1CC2CC1C1CCCC21]

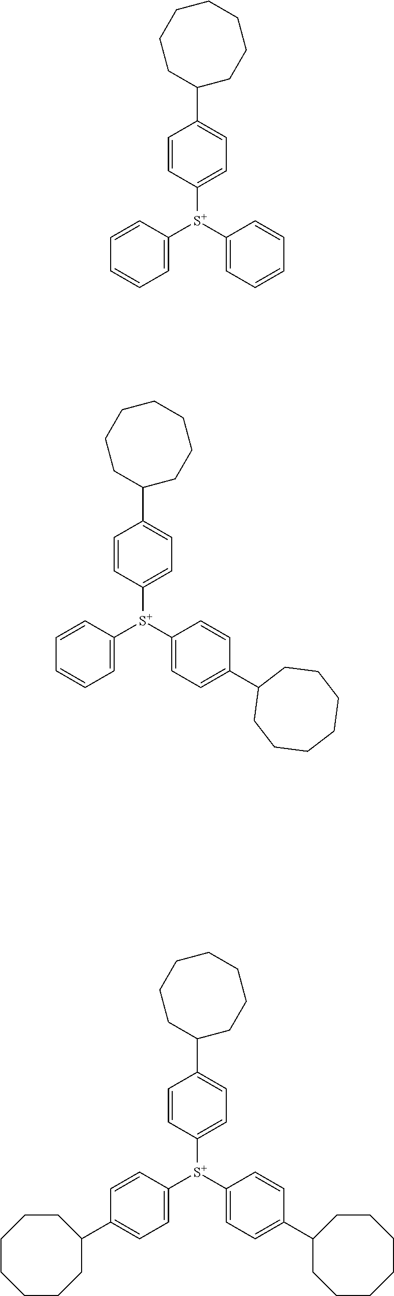 [SMILES: c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1]

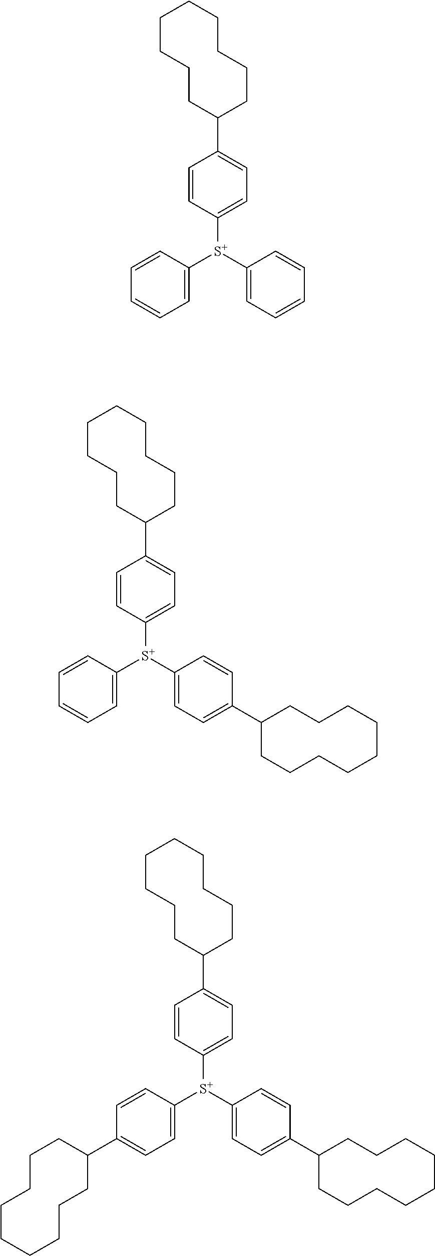 [SMILES: c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1]

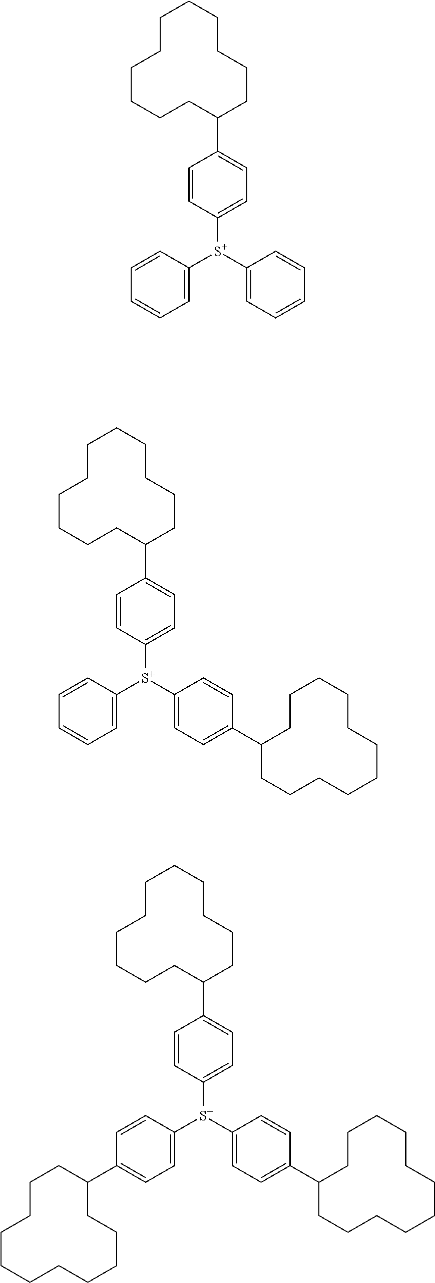 [SMILES: c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1]

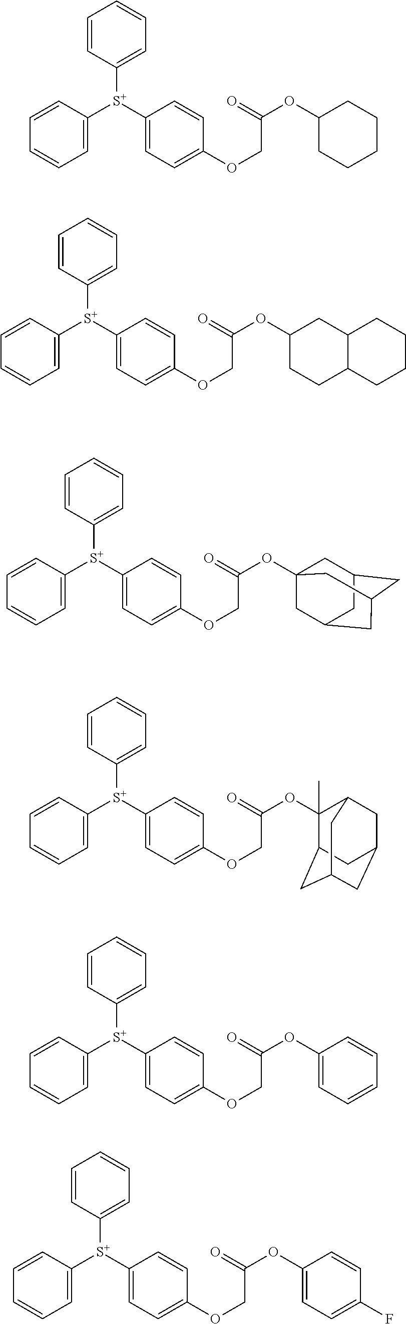 [SMILES: O=C(COc1ccc([S+](c2ccccc2)c2ccccc2)cc1)OC1CCCCC1 ; O=C(COc1ccc([S+](c2ccccc2)c2ccccc2)cc1)OC1CCC2CCCCC2C1 ; O=C(COc1ccc([S+](c2ccccc2)c2ccccc2)cc1)OC12CC3CC(CC(C3)C1)C2 ; CC1(OC(=O)COc2ccc([S+](c3ccccc3)c3ccccc3)cc2)C2CC3CC(C2)CC1C3 ; O=C(COc1ccc([S+](c2ccccc2)c2ccccc2)cc1)Oc1ccccc1 ; O=C(COc1ccc([S+](c2ccccc2)c2ccccc2)cc1)Oc1ccc(F)cc1]

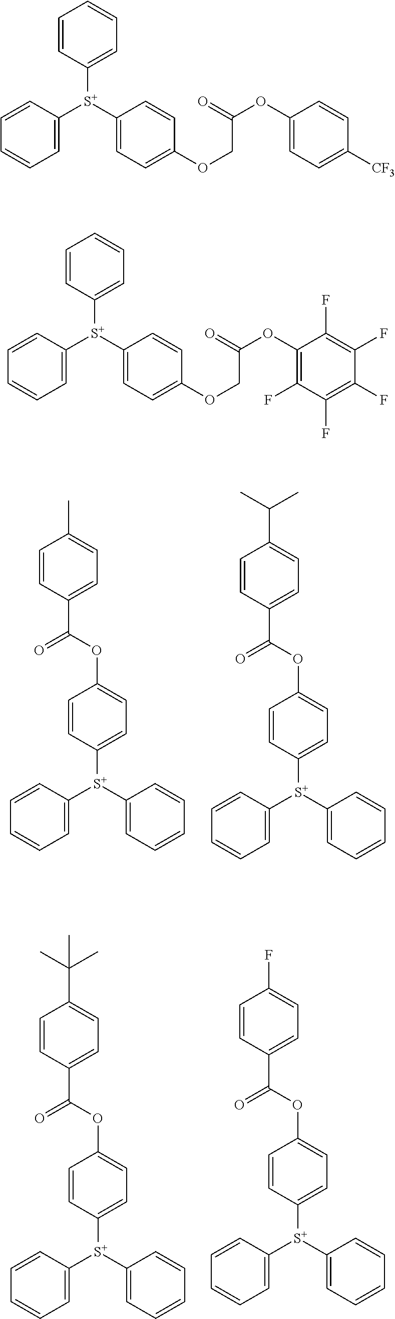 [SMILES: O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1]

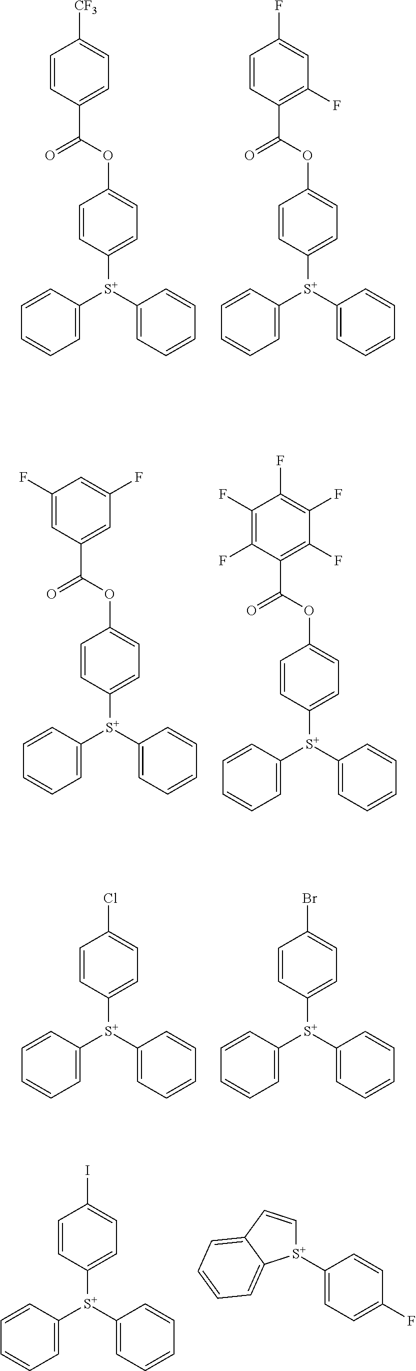

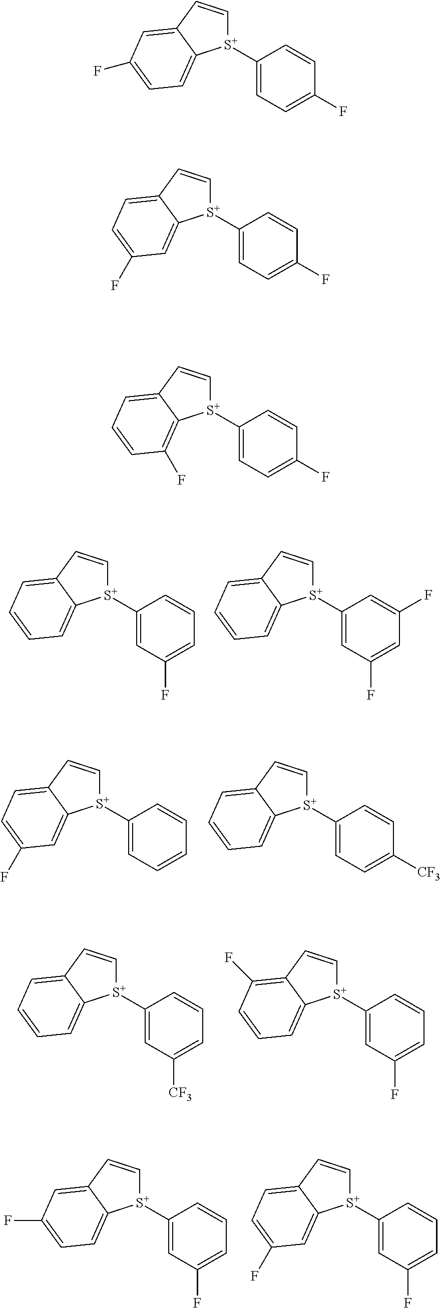

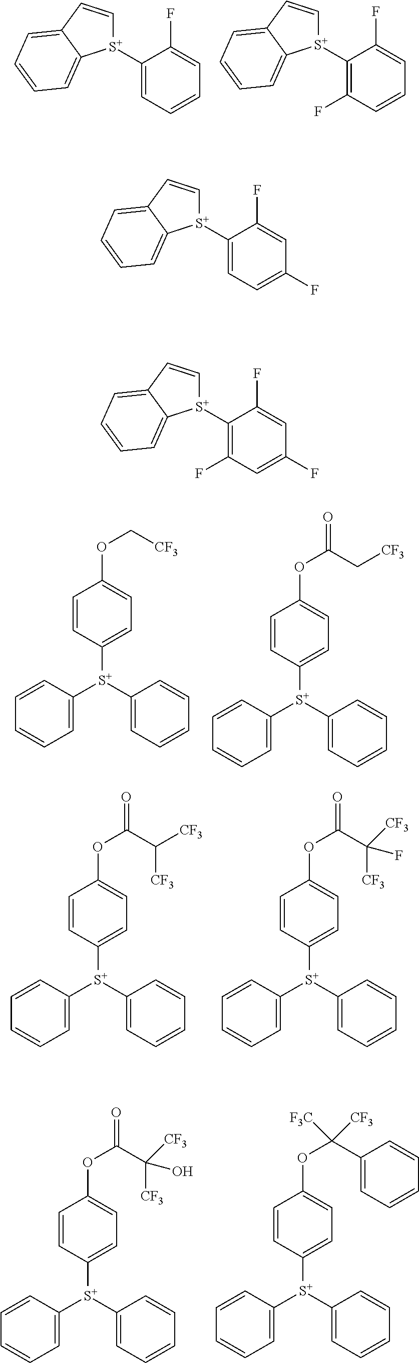

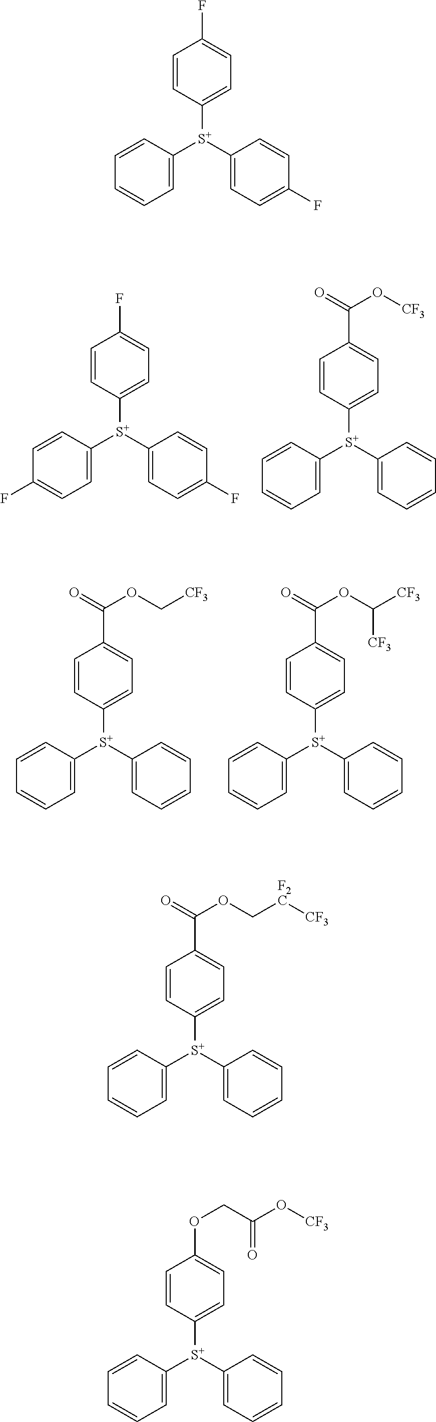

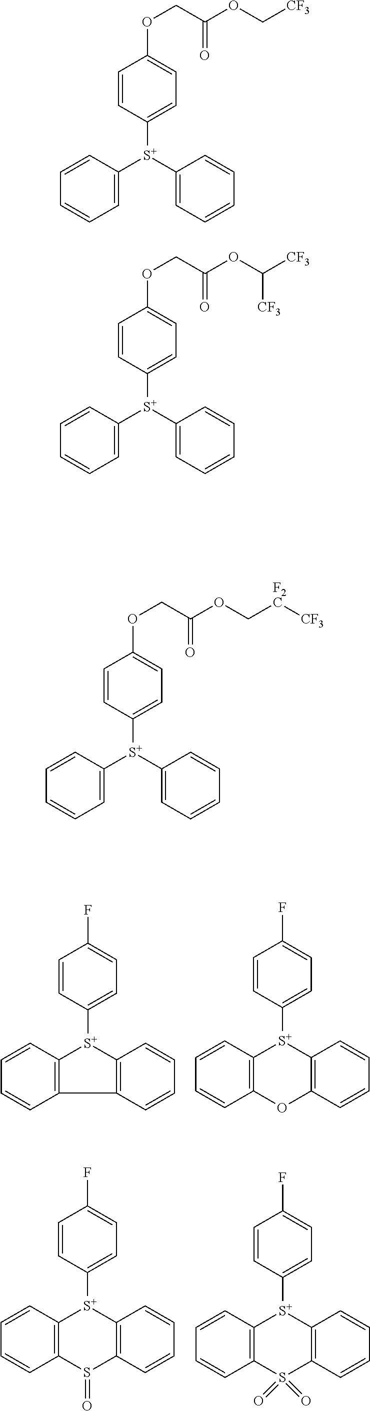

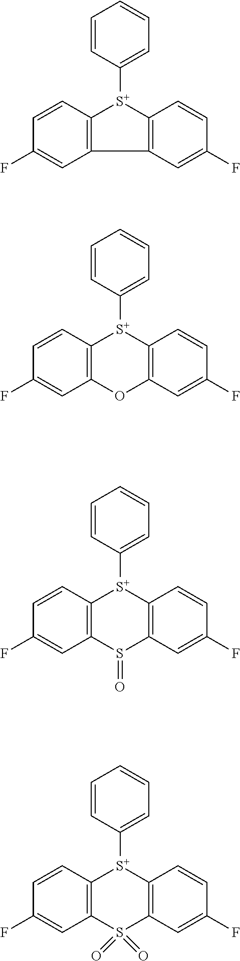 [SMILES: Fc1ccc2c(c1)c1cc(F)ccc1[s+]2-c1ccccc1 ; Fc1ccc2c(c1)Oc1cc(F)ccc1[S+]2c1ccccc1 ; O=S1c2cc(F)ccc2[S+](c2ccccc2)c2ccc(F)cc21 ; O=S1(=O)c2cc(F)ccc2[S+](c2ccccc2)c2ccc(F)cc21]

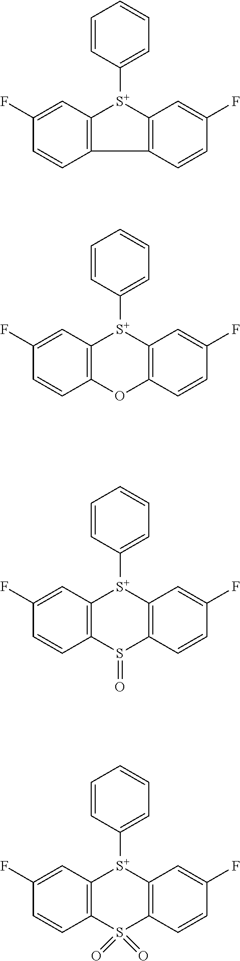 [SMILES: Fc1ccc2c3ccc(F)cc3[s+](-c3ccccc3)c2c1 ; Fc1ccc2c(c1)[S+](c1ccccc1)c1cc(F)ccc1O2 ; O=S1c2ccc(F)cc2[S+](c2ccccc2)c2cc(F)ccc21 ; O=S1(=O)c2ccc(F)cc2[S+](c2ccccc2)c2cc(F)ccc21]

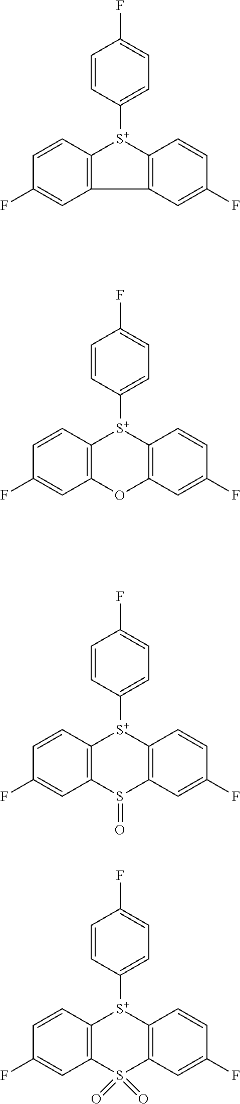 [SMILES: Fc1ccc(-[s+]2c3ccc(F)cc3c3cc(F)ccc32)cc1 ; Fc1ccc([S+]2c3ccc(F)cc3Oc3cc(F)ccc32)cc1 ; O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21]

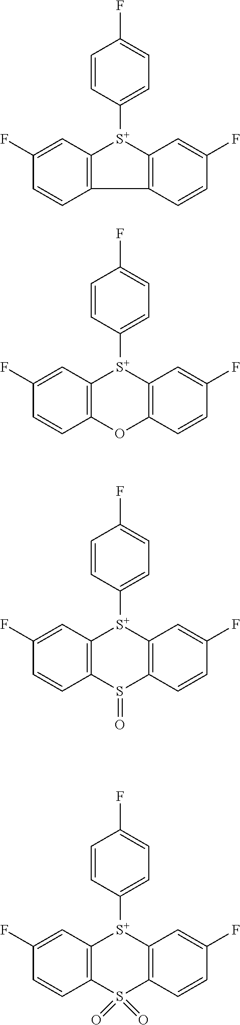 [SMILES: Fc1ccc(-[s+]2c3cc(F)ccc3c3ccc(F)cc32)cc1 ; Fc1ccc([S+]2c3cc(F)ccc3Oc3ccc(F)cc32)cc1 ; O=S1c2ccc(F)cc2[S+](c2ccc(F)cc2)c2cc(F)ccc21 ; O=S1(=O)c2ccc(F)cc2[S+](c2ccc(F)cc2)c2cc(F)ccc21]

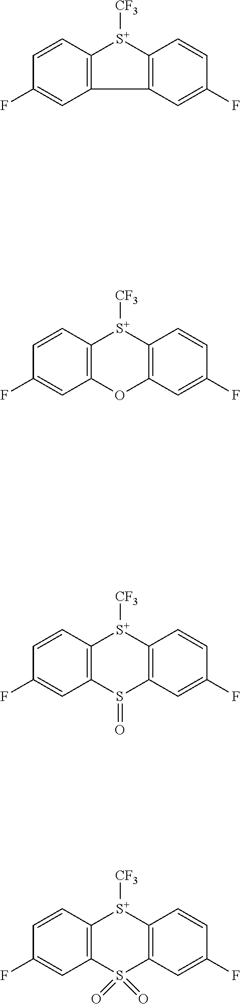 [SMILES: Fc1ccc2c(c1)c1cc(F)ccc1[s+]2C(F)(F)F ; Fc1ccc2c(c1)Oc1cc(F)ccc1[S+]2C(F)(F)F ; O=S1c2cc(F)ccc2[S+](C(F)(F)F)c2ccc(F)cc21 ; O=S1(=O)c2cc(F)ccc2[S+](C(F)(F)F)c2ccc(F)cc21]

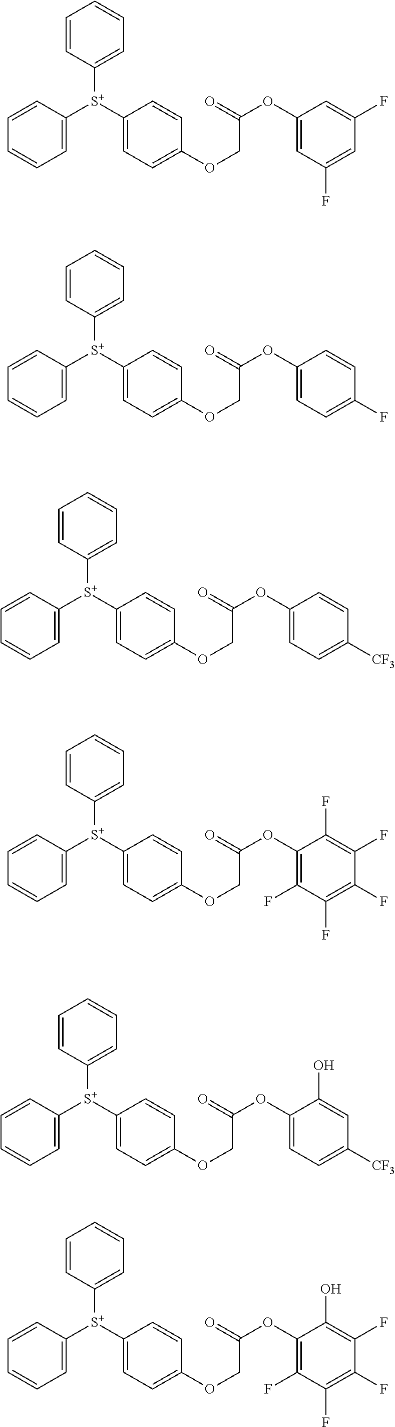 [SMILES: O=C(COc1ccc([S+](c2ccccc2)c2ccccc2)cc1)Oc1cc(F)cc(F)c1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; O=C(COc1ccc([S+](c2ccccc2)c2ccccc2)cc1)Oc1ccc(C(F)(F)F)cc1O ; O=C(COc1ccc([S+](c2ccccc2)c2ccccc2)cc1)Oc1c(O)c(F)c(F)c(F)c1F]

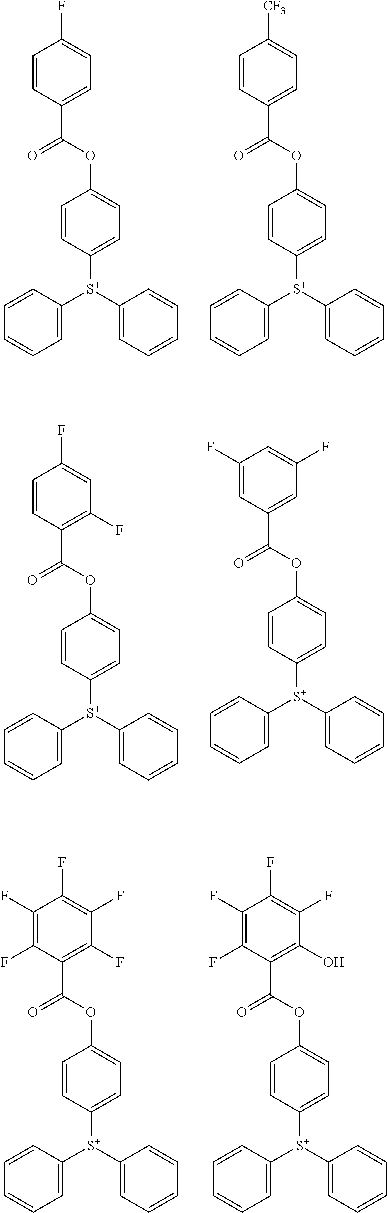 [SMILES: O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F ; O=C(Oc1ccc([S+](c2ccccc2)c2ccccc2)cc1)c1cc(F)cc(F)c1 ; O=C(Oc1ccc([S+](c2ccccc2)c2ccccc2)cc1)c1c(F)c(F)c(F)c(F)c1F ; O=C(Oc1ccc([S+](c2ccccc2)c2ccccc2)cc1)c1c(O)c(F)c(F)c(F)c1F]

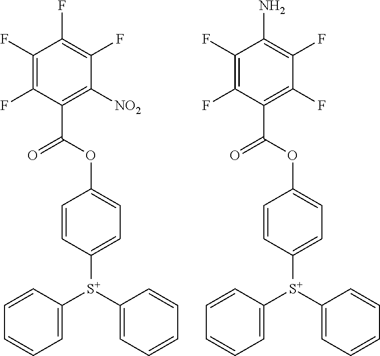 [SMILES: O=C(Oc1ccc([S+](c2ccccc2)c2ccccc2)cc1)c1c(F)c(F)c(F)c(F)c1[N+](=O)[O-] ; Nc1c(F)c(F)c(C(=O)Oc2ccc([S+](c3ccccc3)c3ccccc3)cc2)c(F)c1F]

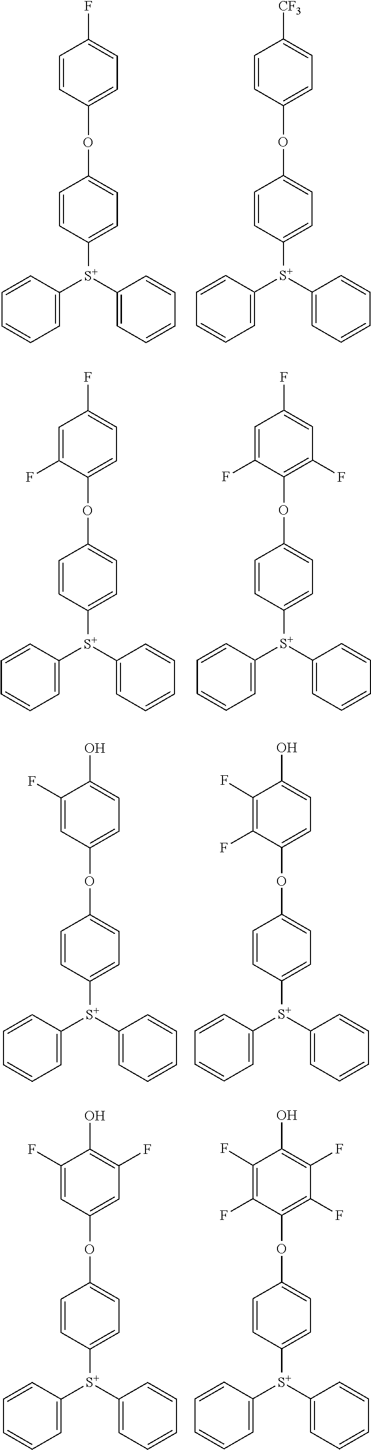

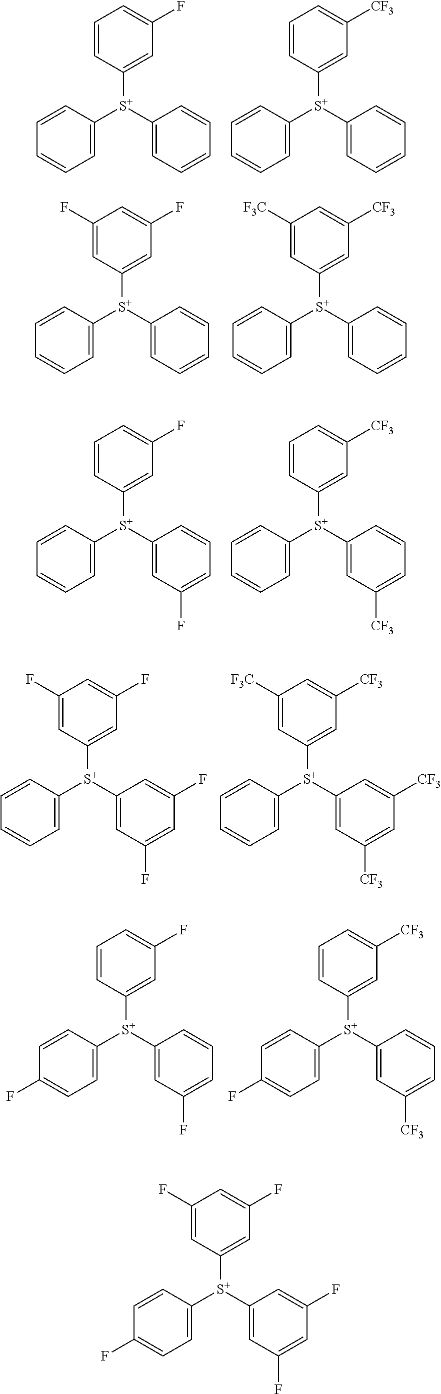

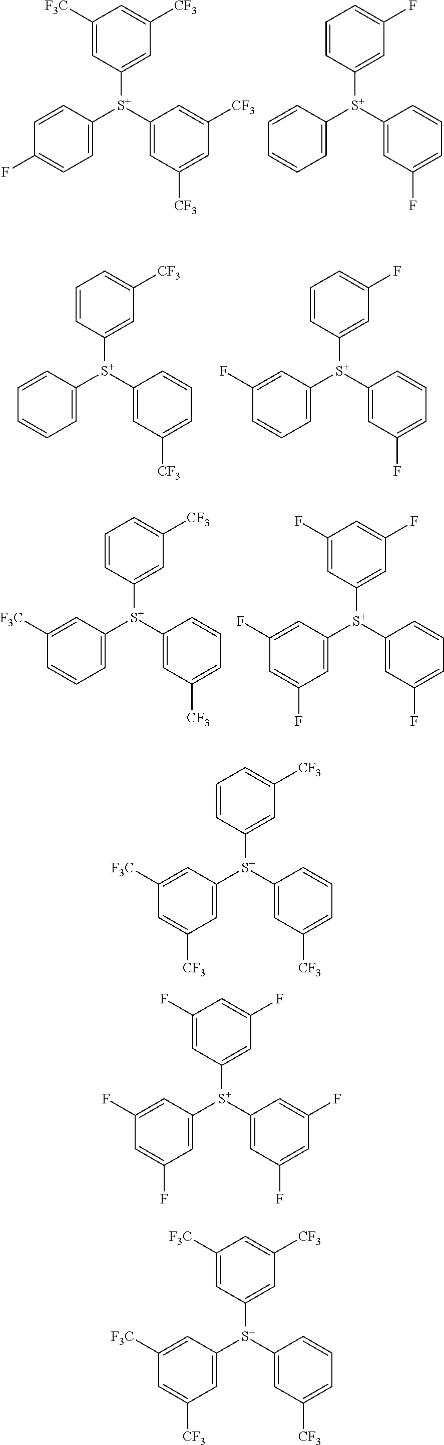

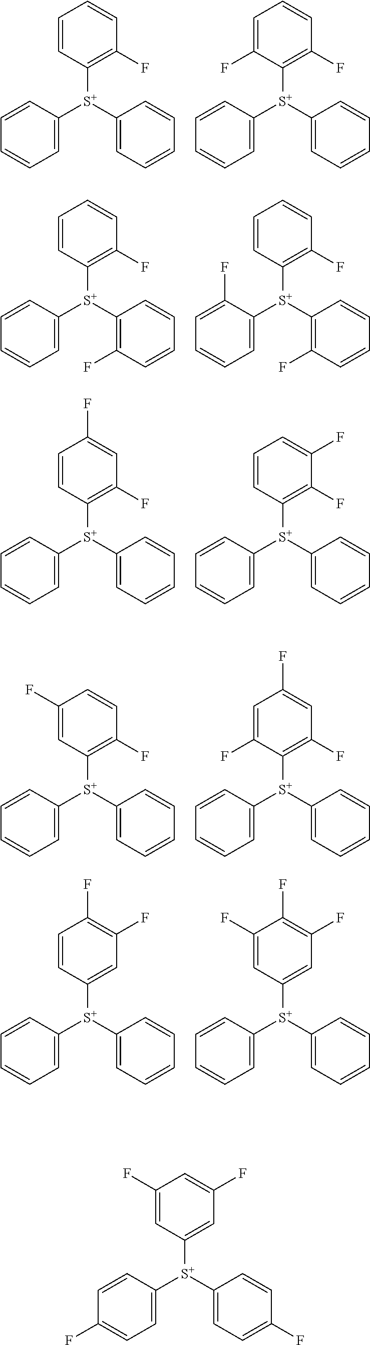

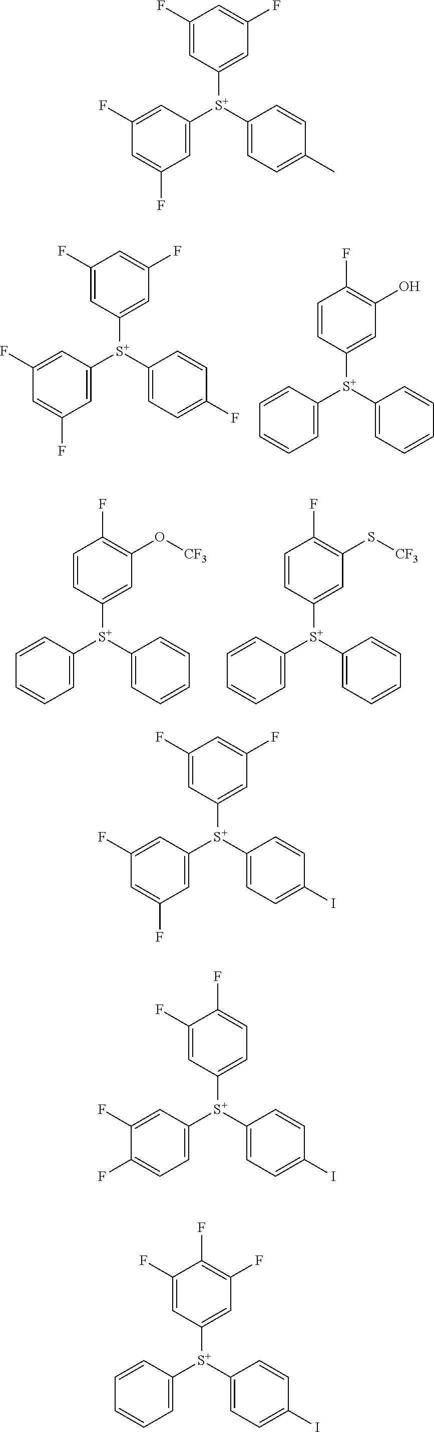

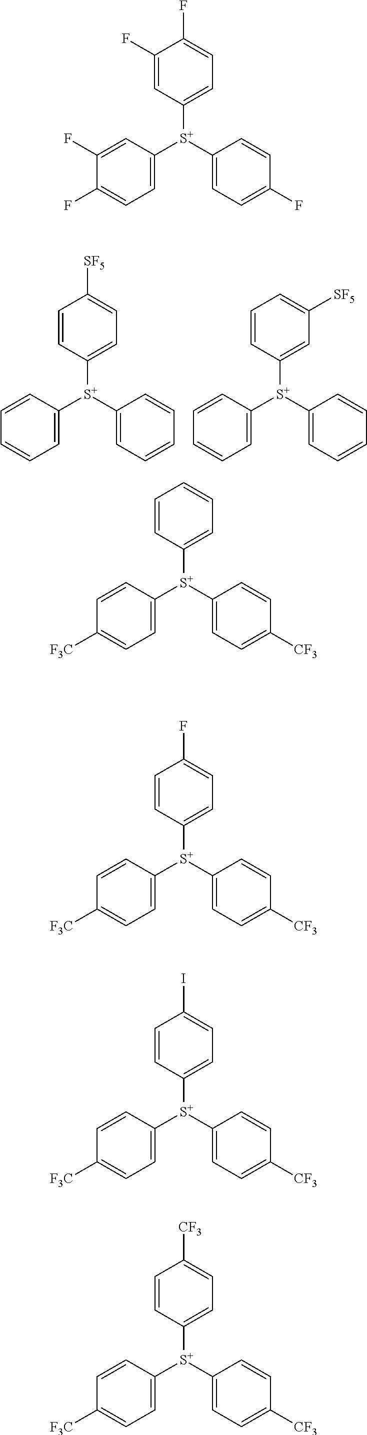

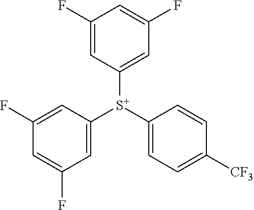 [SMILES: Fc1cc(F)cc([S+](c2ccc(C(F)(F)F)cc2)c2cc(F)cc(F)c2)c1]

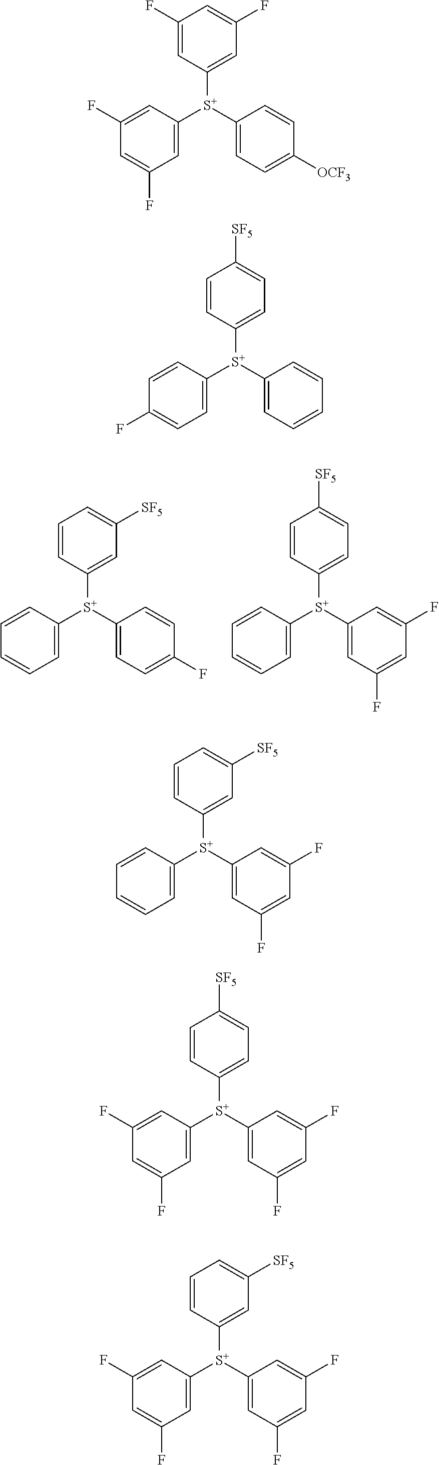

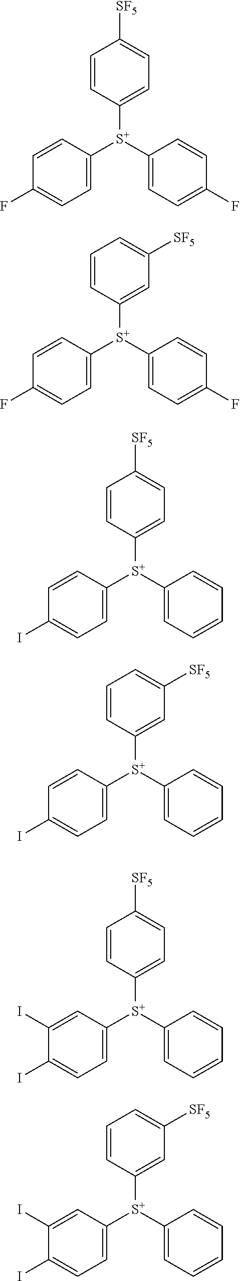

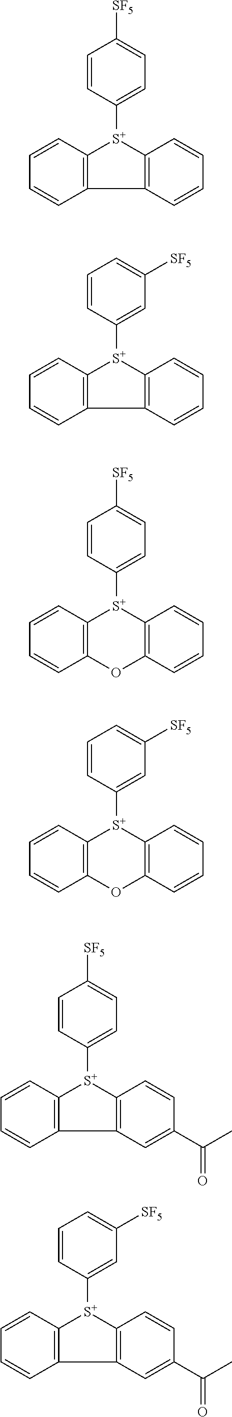

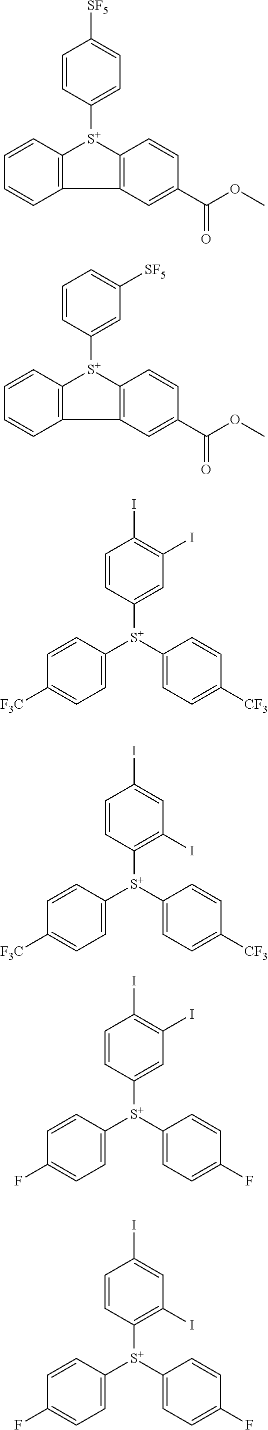

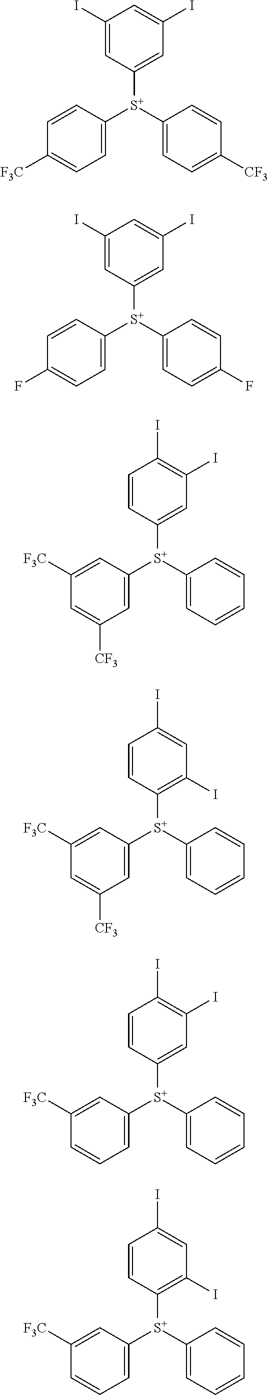 [SMILES: FC(F)(F)c1ccc([S+](c2ccc(C(F)(F)F)cc2)c2cc(I)cc(I)c2)cc1 ; Fc1ccc([S+](c2ccc(F)cc2)c2cc(I)cc(I)c2)cc1 ; FC(F)(F)c1cc([S+](c2ccccc2)c2ccc(I)c(I)c2)cc(C(F)(F)F)c1 ; FC(F)(F)c1cc([S+](c2ccccc2)c2ccc(I)cc2I)cc(C(F)(F)F)c1 ; FC(F)(F)c1cccc([S+](c2ccccc2)c2ccc(I)c(I)c2)c1 ; FC(F)(F)c1cccc([S+](c2ccccc2)c2ccc(I)cc2I)c1]

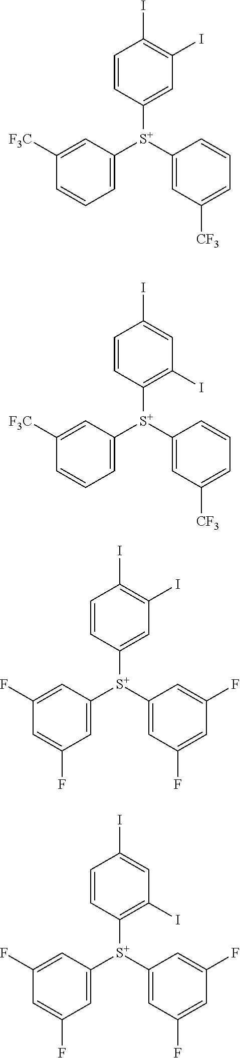 [SMILES: FC(F)(F)c1cccc([S+](c2cccc(C(F)(F)F)c2)c2ccc(I)c(I)c2)c1 ; FC(F)(F)c1cccc([S+](c2cccc(C(F)(F)F)c2)c2ccc(I)cc2I)c1 ; Fc1cc(F)cc([S+](c2cc(F)cc(F)c2)c2ccc(I)c(I)c2)c1 ; Fc1cc(F)cc([S+](c2cc(F)cc(F)c2)c2ccc(I)cc2I)c1]

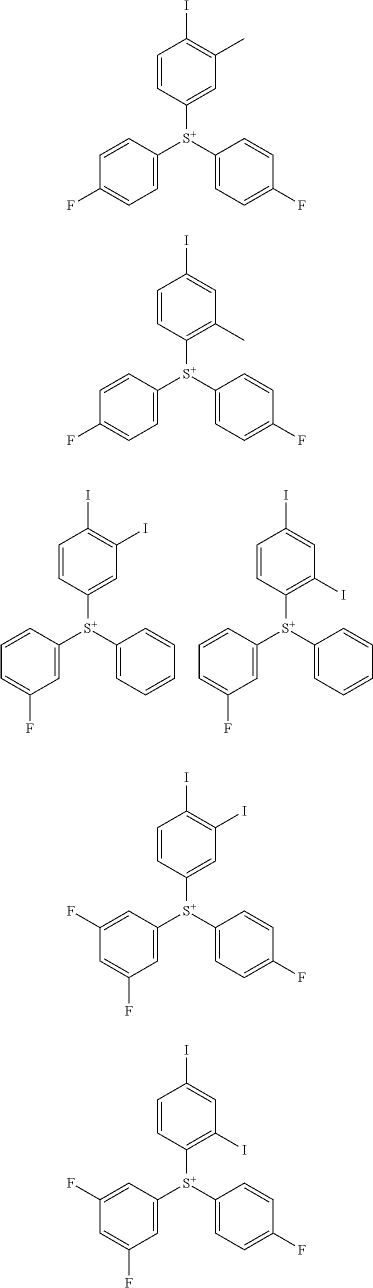 [SMILES: Cc1cc([S+](c2ccc(F)cc2)c2ccc(F)cc2)ccc1I ; Cc1cc(I)ccc1[S+](c1ccc(F)cc1)c1ccc(F)cc1 ; Fc1cccc([S+](c2ccccc2)c2ccc(I)c(I)c2)c1 ; Fc1cccc([S+](c2ccccc2)c2ccc(I)cc2I)c1 ; Fc1ccc([S+](c2cc(F)cc(F)c2)c2ccc(I)c(I)c2)cc1 ; Fc1ccc([S+](c2cc(F)cc(F)c2)c2ccc(I)cc2I)cc1]

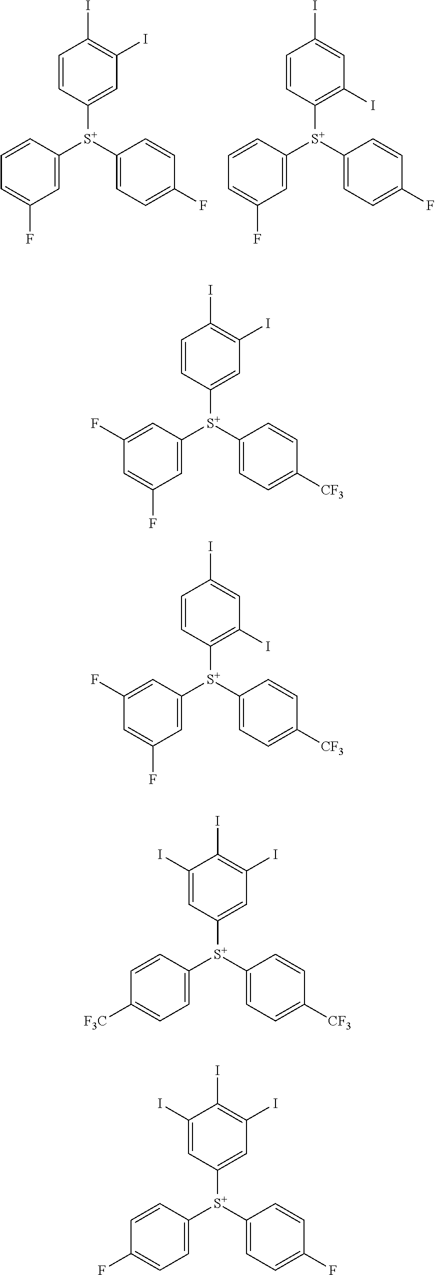 [SMILES: Fc1ccc([S+](c2cccc(F)c2)c2ccc(I)c(I)c2)cc1 ; Fc1ccc([S+](c2cccc(F)c2)c2ccc(I)cc2I)cc1 ; Fc1cc(F)cc([S+](c2ccc(C(F)(F)F)cc2)c2ccc(I)c(I)c2)c1 ; Fc1cc(F)cc([S+](c2ccc(C(F)(F)F)cc2)c2ccc(I)cc2I)c1 ; FC(F)(F)c1ccc([S+](c2ccc(C(F)(F)F)cc2)c2cc(I)c(I)c(I)c2)cc1 ; Fc1ccc([S+](c2ccc(F)cc2)c2cc(I)c(I)c(I)c2)cc1]

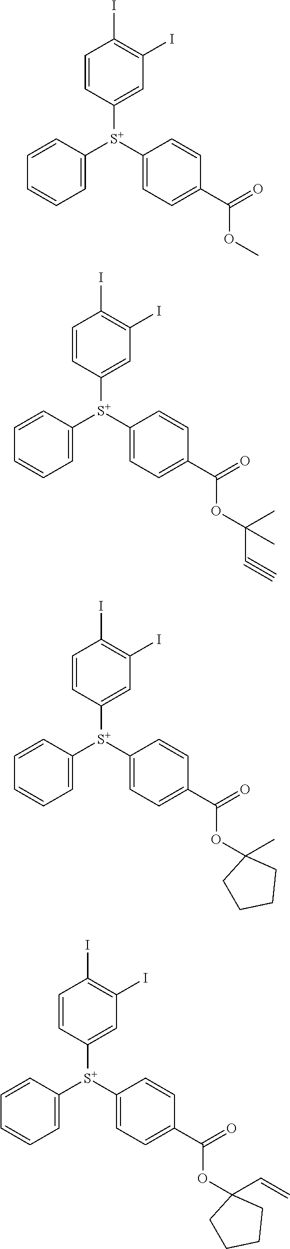 [SMILES: COC(=O)c1ccc([S+](c2ccccc2)c2ccc(I)c(I)c2)cc1 ; C#CC(C)(C)OC(=O)c1ccc([S+](c2ccccc2)c2ccc(I)c(I)c2)cc1 ; CC1(OC(=O)c2ccc([S+](c3ccccc3)c3ccc(I)c(I)c3)cc2)CCCC1 ; C=CC1(OC(=O)c2ccc([S+](c3ccccc3)c3ccc(I)c(I)c3)cc2)CCCC1]

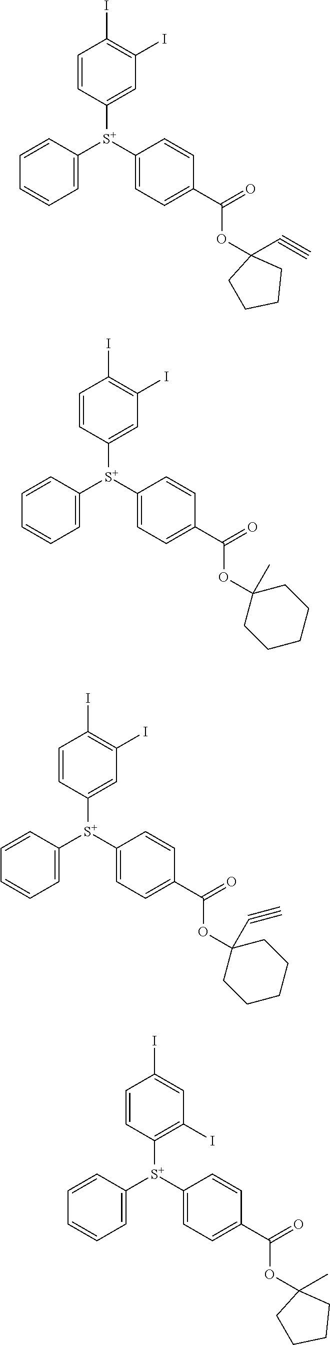 [SMILES: C#CC1(OC(=O)c2ccc([S+](c3ccccc3)c3ccc(I)c(I)c3)cc2)CCCC1 ; CC1(OC(=O)c2ccc([S+](c3ccccc3)c3ccc(I)c(I)c3)cc2)CCCCC1 ; C#CC1(OC(=O)c2ccc([S+](c3ccccc3)c3ccc(I)c(I)c3)cc2)CCCCC1 ; CC1(OC(=O)c2ccc([S+](c3ccccc3)c3ccc(I)cc3I)cc2)CCCC1]

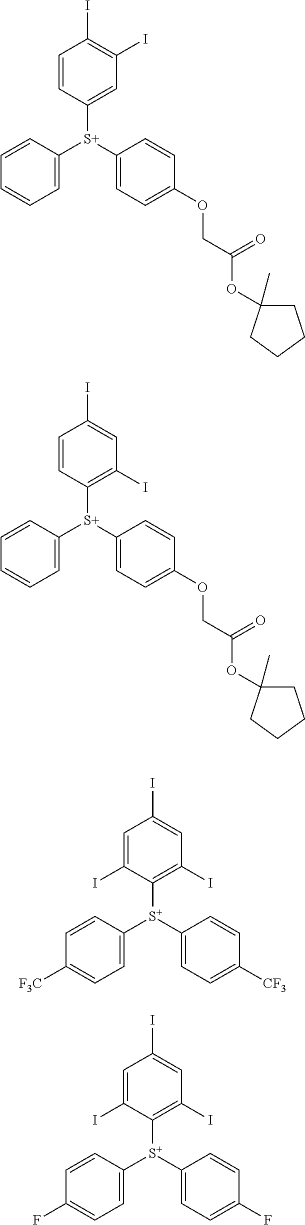 [SMILES: CC1(OC(=O)COc2ccc([S+](c3ccccc3)c3ccc(I)c(I)c3)cc2)CCCC1 ; CC1(OC(=O)COc2ccc([S+](c3ccccc3)c3ccc(I)cc3I)cc2)CCCC1 ; FC(F)(F)c1ccc([S+](c2ccc(C(F)(F)F)cc2)c2c(I)cc(I)cc2I)cc1 ; Fc1ccc([S+](c2ccc(F)cc2)c2c(I)cc(I)cc2I)cc1]

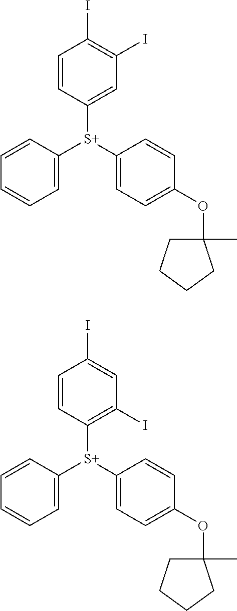 [SMILES: CC1(Oc2ccc([S+](c3ccccc3)c3ccc(I)c(I)c3)cc2)CCCC1 ; CC1(Oc2ccc([S+](c3ccccc3)c3ccc(I)cc3I)cc2)CCCC1]

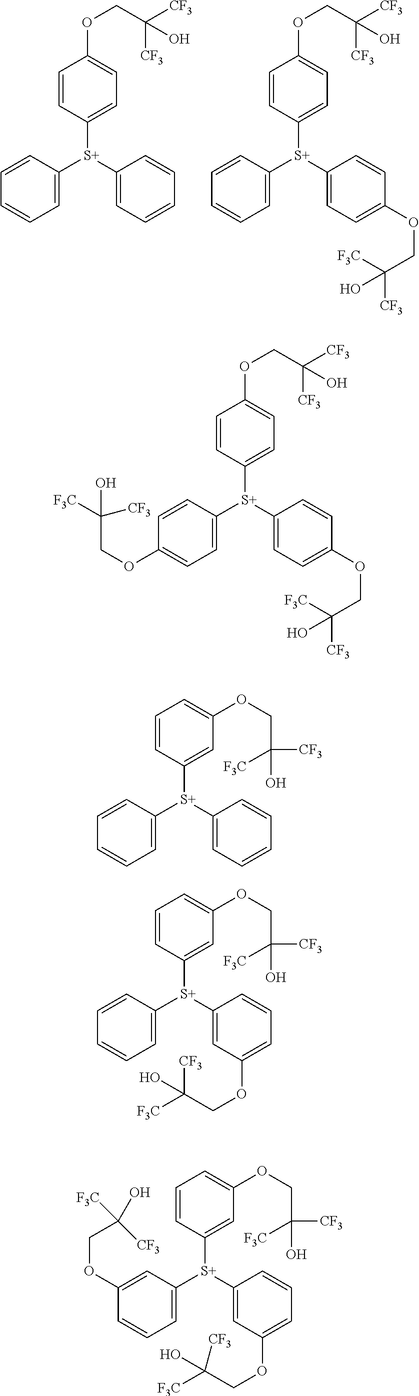

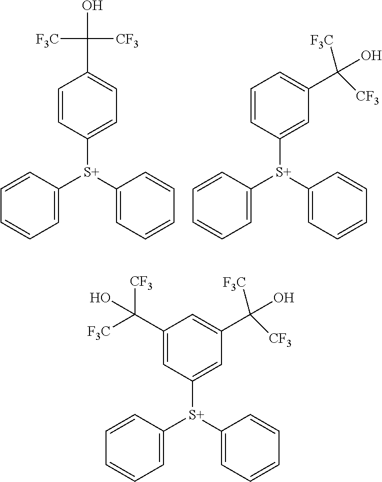 [SMILES: OC(c1ccc([S+](c2ccccc2)c2ccccc2)cc1)(C(F)(F)F)C(F)(F)F ; OC(c1cccc([S+](c2ccccc2)c2ccccc2)c1)(C(F)(F)F)C(F)(F)F ; OC(c1cc([S+](c2ccccc2)c2ccccc2)cc(C(O)(C(F)(F)F)C(F)(F)F)c1)(C(F)(F)F)C(F)(F)F]

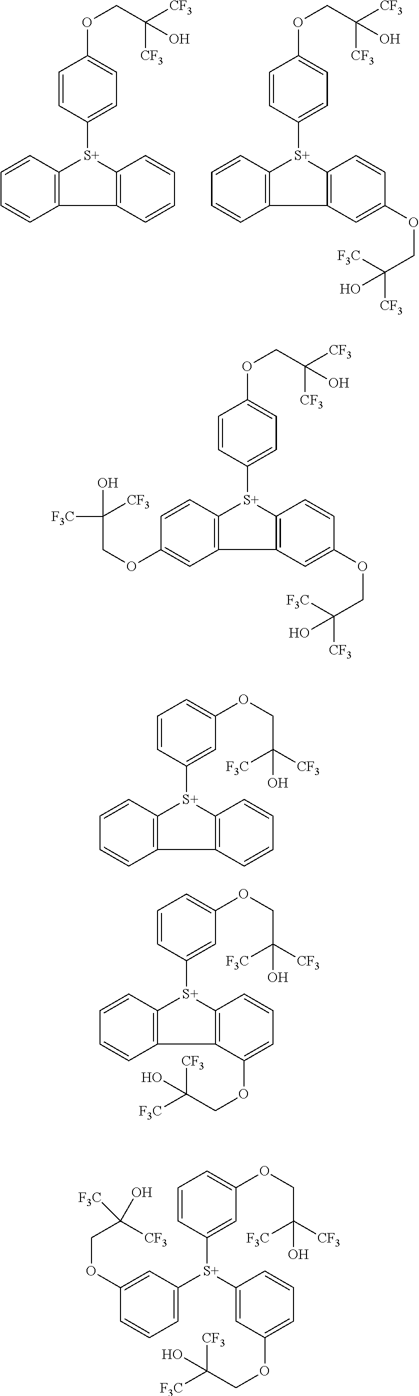

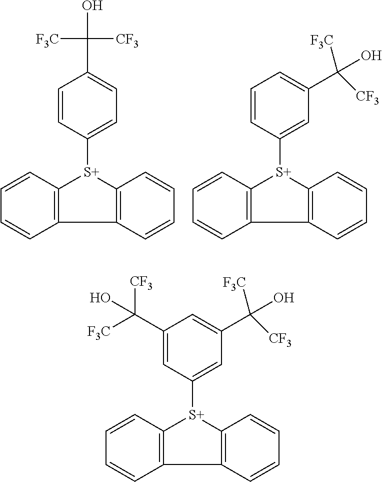 [SMILES: OC(c1ccc(-[s+]2c3ccccc3c3ccccc32)cc1)(C(F)(F)F)C(F)(F)F ; OC(c1cccc(-[s+]2c3ccccc3c3ccccc32)c1)(C(F)(F)F)C(F)(F)F ; OC(c1cc(-[s+]2c3ccccc3c3ccccc32)cc(C(O)(C(F)(F)F)C(F)(F)F)c1)(C(F)(F)F)C(F)(F)F]

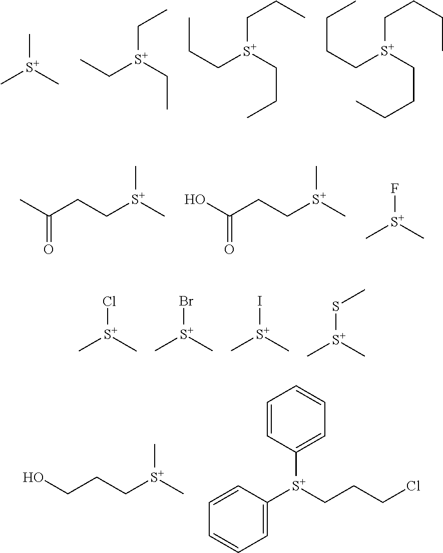

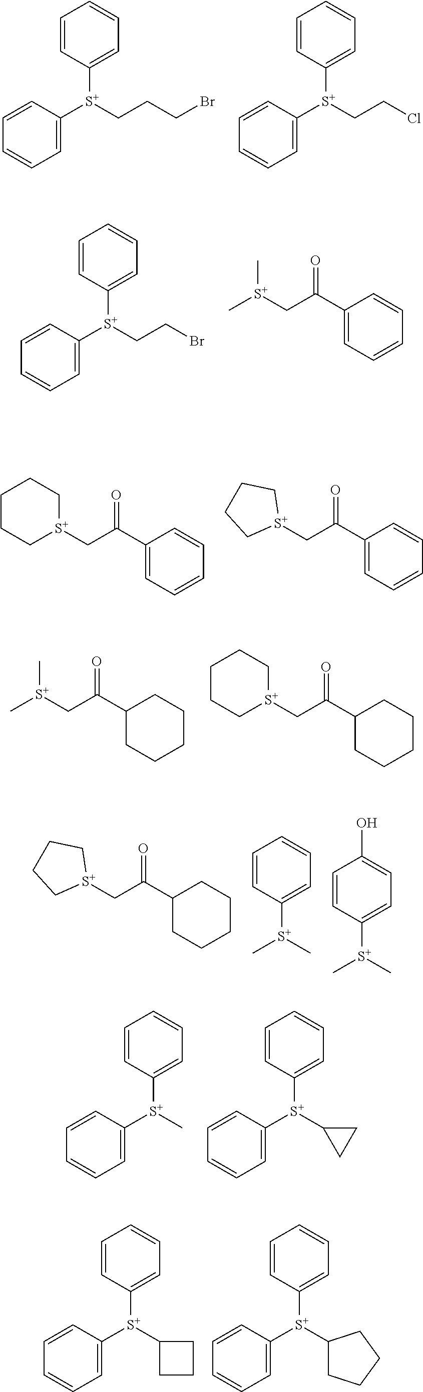

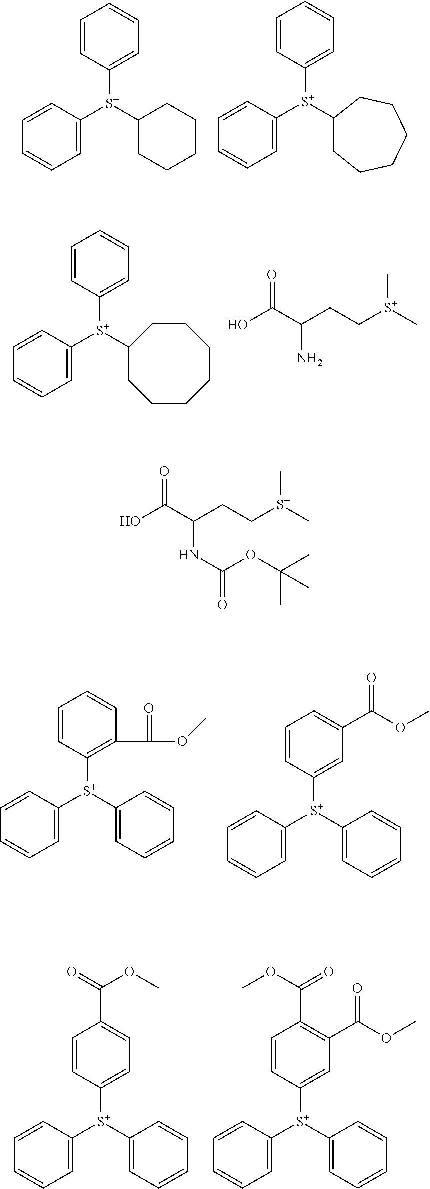

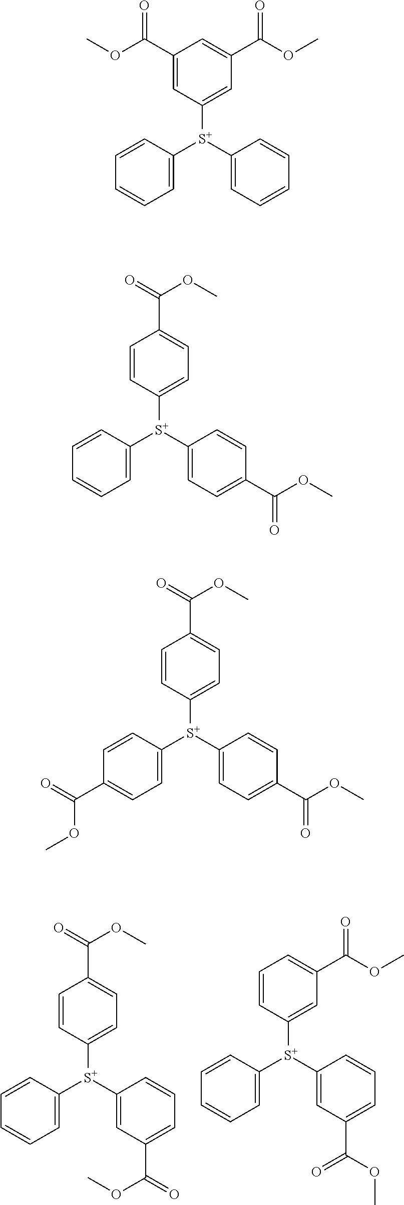

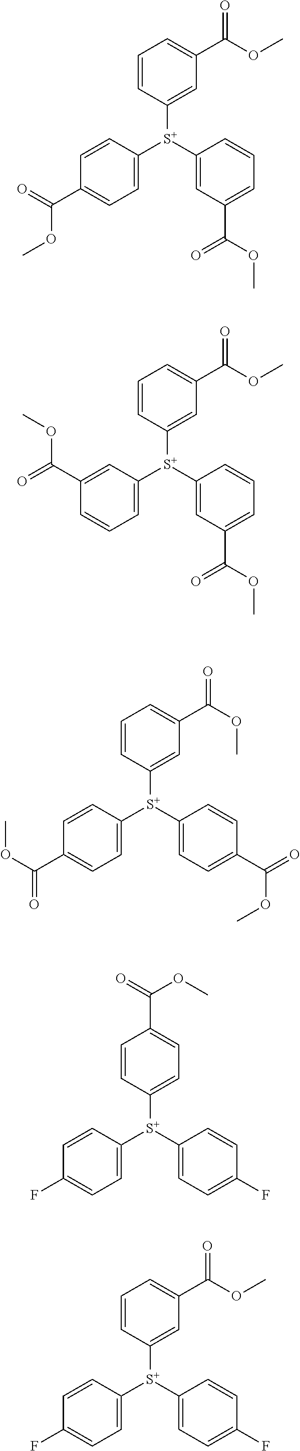 [SMILES: COC(=O)c1ccc([S+](c2cccc(C(=O)OC)c2)c2cccc(C(=O)OC)c2)cc1 ; COC(=O)c1cccc([S+](c2cccc(C(=O)OC)c2)c2cccc(C(=O)OC)c2)c1 ; COC(=O)c1ccc([S+](c2ccc(C(=O)OC)cc2)c2cccc(C(=O)OC)c2)cc1 ; COC(=O)c1ccc([S+](c2ccc(F)cc2)c2ccc(F)cc2)cc1 ; COC(=O)c1cccc([S+](c2ccc(F)cc2)c2ccc(F)cc2)c1]

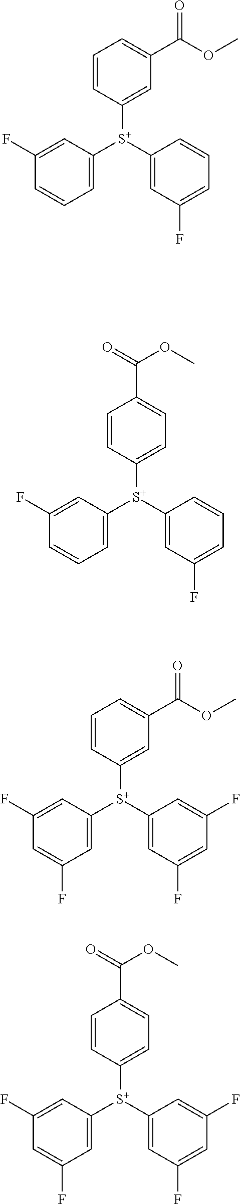 [SMILES: COC(=O)c1cccc([S+](c2cccc(F)c2)c2cccc(F)c2)c1 ; COC(=O)c1ccc([S+](c2cccc(F)c2)c2cccc(F)c2)cc1 ; COC(=O)c1cccc([S+](c2cc(F)cc(F)c2)c2cc(F)cc(F)c2)c1 ; COC(=O)c1ccc([S+](c2cc(F)cc(F)c2)c2cc(F)cc(F)c2)cc1]

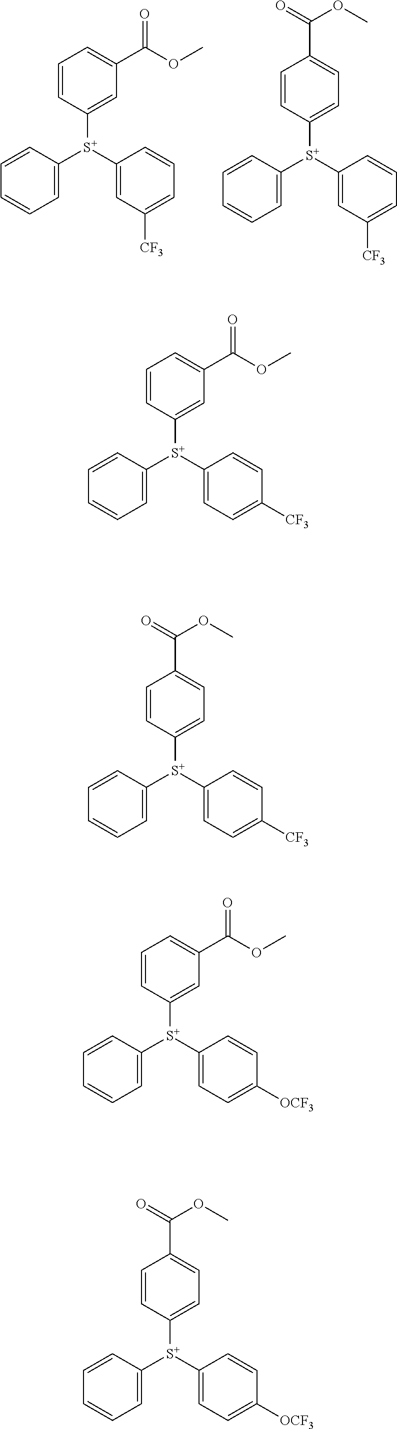 [SMILES: COC(=O)c1cccc([S+](c2ccccc2)c2cccc(C(F)(F)F)c2)c1 ; COC(=O)c1ccc([S+](c2ccccc2)c2cccc(C(F)(F)F)c2)cc1 ; COC(=O)c1cccc([S+](c2ccccc2)c2ccc(C(F)(F)F)cc2)c1 ; COC(=O)c1ccc([S+](c2ccccc2)c2ccc(C(F)(F)F)cc2)cc1 ; COC(=O)c1cccc([S+](c2ccccc2)c2ccc(OC(F)(F)F)cc2)c1 ; COC(=O)c1ccc([S+](c2ccccc2)c2ccc(OC(F)(F)F)cc2)cc1]

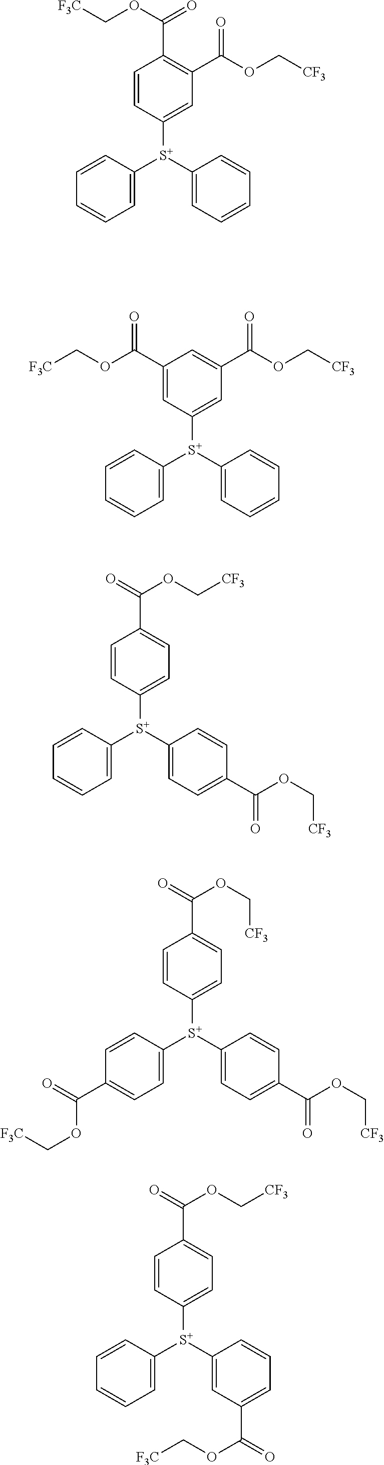 [SMILES: O=C(OCC(F)(F)F)c1ccc([S+](c2ccccc2)c2ccccc2)cc1C(=O)OCC(F)(F)F ; O=C(OCC(F)(F)F)c1cc(C(=O)OCC(F)(F)F)cc([S+](c2ccccc2)c2ccccc2)c1 ; O=C(OCC(F)(F)F)c1ccc([S+](c2ccccc2)c2ccc(C(=O)OCC(F)(F)F)cc2)cc1 ; O=C(OCC(F)(F)F)c1ccc([S+](c2ccc(C(=O)OCC(F)(F)F)cc2)c2ccc(C(=O)OCC(F)(F)F)cc2)cc1 ; O=C(OCC(F)(F)F)c1ccc([S+](c2ccccc2)c2cccc(C(=O)OCC(F)(F)F)c2)cc1]

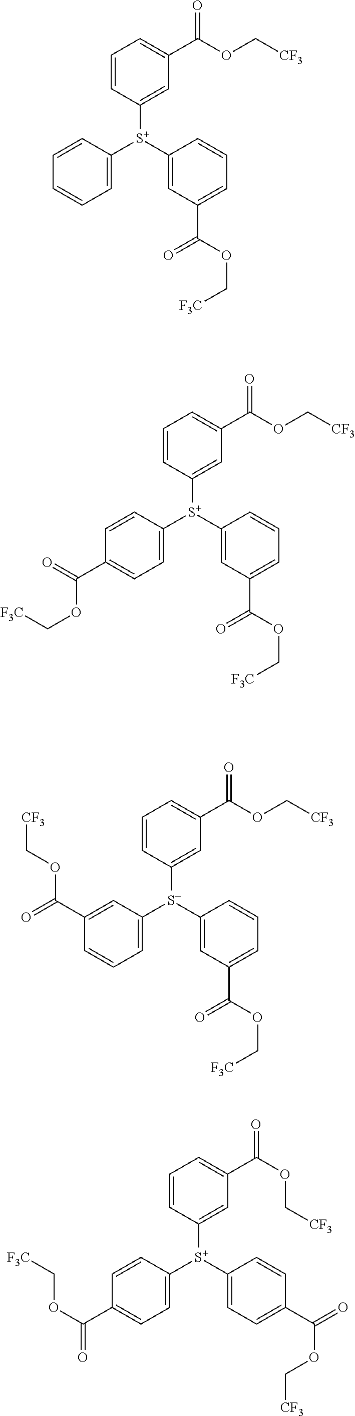 [SMILES: O=C(OCC(F)(F)F)c1cccc([S+](c2ccccc2)c2cccc(C(=O)OCC(F)(F)F)c2)c1 ; O=C(OCC(F)(F)F)c1ccc([S+](c2cccc(C(=O)OCC(F)(F)F)c2)c2cccc(C(=O)OCC(F)(F)F)c2)cc1 ; O=C(OCC(F)(F)F)c1cccc([S+](c2cccc(C(=O)OCC(F)(F)F)c2)c2cccc(C(=O)OCC(F)(F)F)c2)c1 ; O=C(OCC(F)(F)F)c1ccc([S+](c2ccc(C(=O)OCC(F)(F)F)cc2)c2cccc(C(=O)OCC(F)(F)F)c2)cc1]

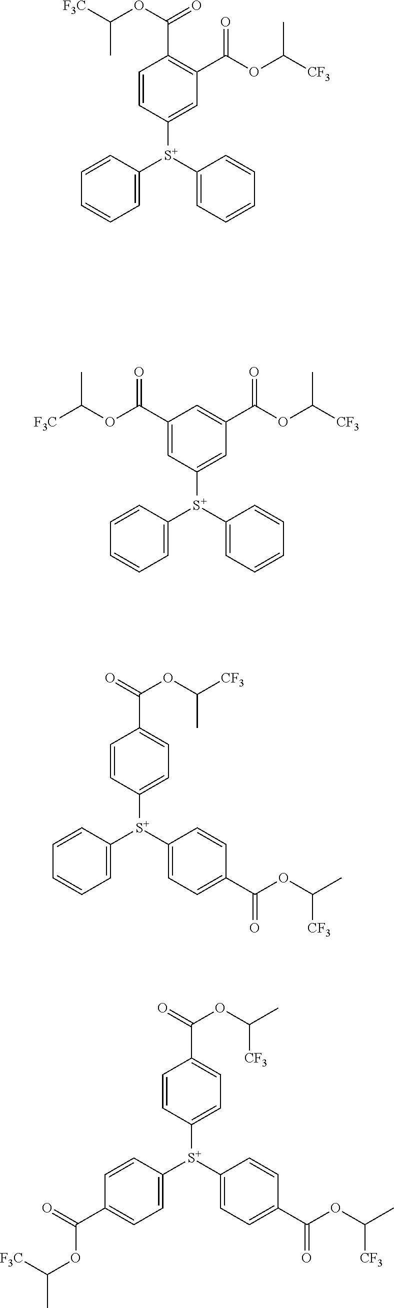 [SMILES: CC(OC(=O)c1ccc([S+](c2ccccc2)c2ccccc2)cc1C(=O)OC(C)C(F)(F)F)C(F)(F)F ; CC(OC(=O)c1cc(C(=O)OC(C)C(F)(F)F)cc([S+](c2ccccc2)c2ccccc2)c1)C(F)(F)F ; CC(OC(=O)c1ccc([S+](c2ccccc2)c2ccc(C(=O)OC(C)C(F)(F)F)cc2)cc1)C(F)(F)F ; CC(OC(=O)c1ccc([S+](c2ccc(C(=O)OC(C)C(F)(F)F)cc2)c2ccc(C(=O)OC(C)C(F)(F)F)cc2)cc1)C(F)(F)F]

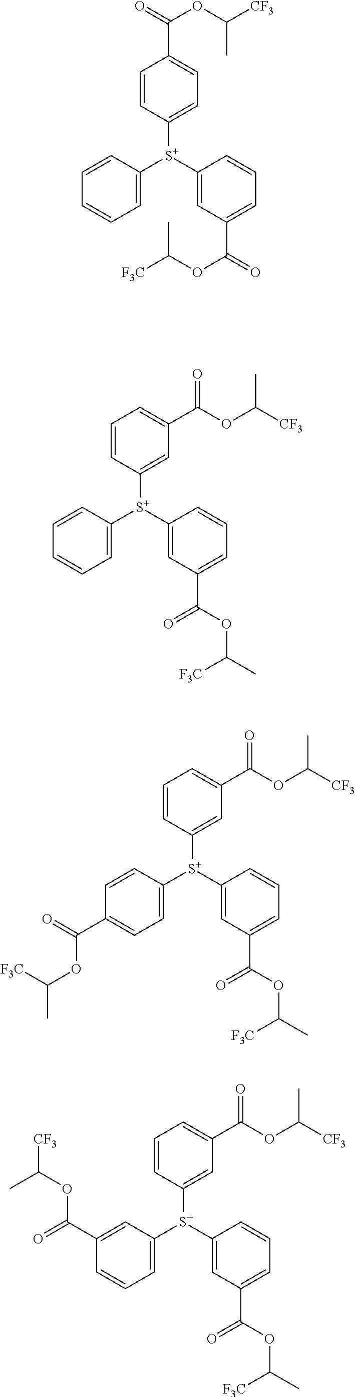 [SMILES: CC(OC(=O)c1ccc([S+](c2ccccc2)c2cccc(C(=O)OC(C)C(F)(F)F)c2)cc1)C(F)(F)F ; CC(OC(=O)c1cccc([S+](c2ccccc2)c2cccc(C(=O)OC(C)C(F)(F)F)c2)c1)C(F)(F)F ; CC(OC(=O)c1ccc([S+](c2cccc(C(=O)OC(C)C(F)(F)F)c2)c2cccc(C(=O)OC(C)C(F)(F)F)c2)cc1)C(F)(F)F ; CC(OC(=O)c1cccc([S+](c2cccc(C(=O)OC(C)C(F)(F)F)c2)c2cccc(C(=O)OC(C)C(F)(F)F)c2)c1)C(F)(F)F]

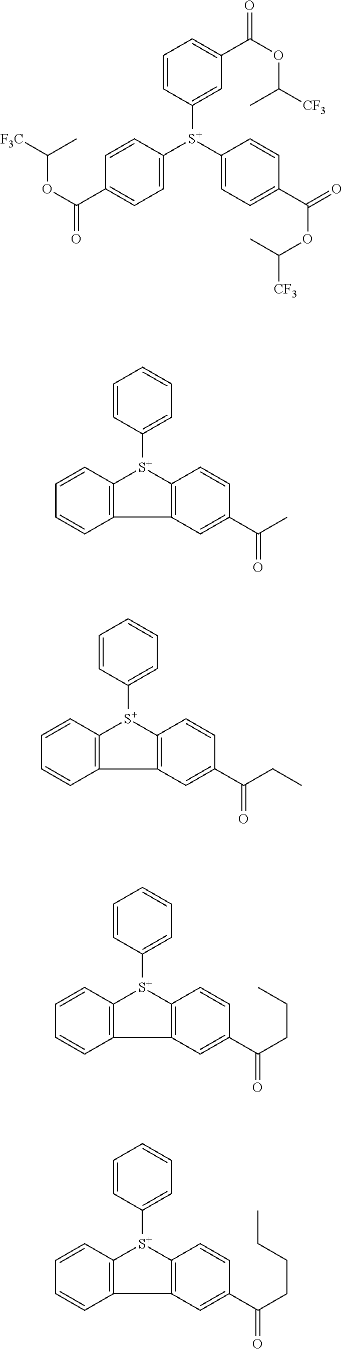 [SMILES: CC(OC(=O)c1ccc([S+](c2ccc(C(=O)OC(C)C(F)(F)F)cc2)c2cccc(C(=O)OC(C)C(F)(F)F)c2)cc1)C(F)(F)F ; CC(=O)c1ccc2c(c1)c1ccccc1[s+]2-c1ccccc1 ; CCC(=O)c1ccc2c(c1)c1ccccc1[s+]2-c1ccccc1 ; CCCC(=O)c1ccc2c(c1)c1ccccc1[s+]2-c1ccccc1 ; CCCCC(=O)c1ccc2c(c1)c1ccccc1[s+]2-c1ccccc1]

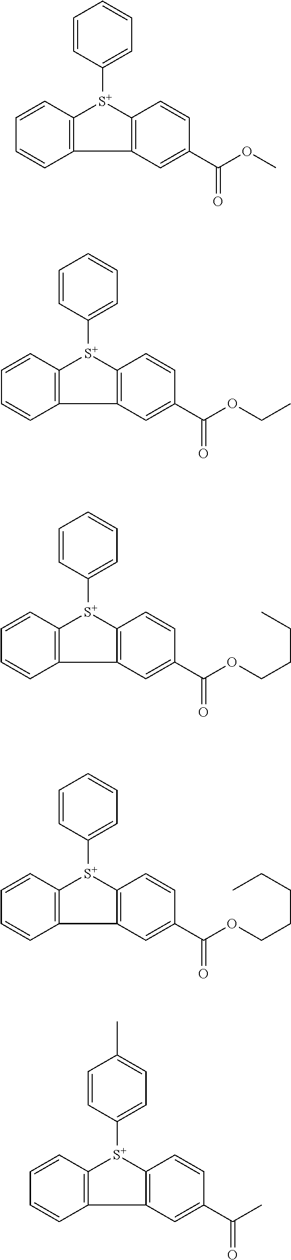 [SMILES: COC(=O)c1ccc2c(c1)c1ccccc1[s+]2-c1ccccc1 ; CCOC(=O)c1ccc2c(c1)c1ccccc1[s+]2-c1ccccc1 ; CCCCOC(=O)c1ccc2c(c1)c1ccccc1[s+]2-c1ccccc1 ; CCCCCOC(=O)c1ccc2c(c1)c1ccccc1[s+]2-c1ccccc1 ; CC(=O)c1ccc2c(c1)c1ccccc1[s+]2-c1ccc(C)cc1]

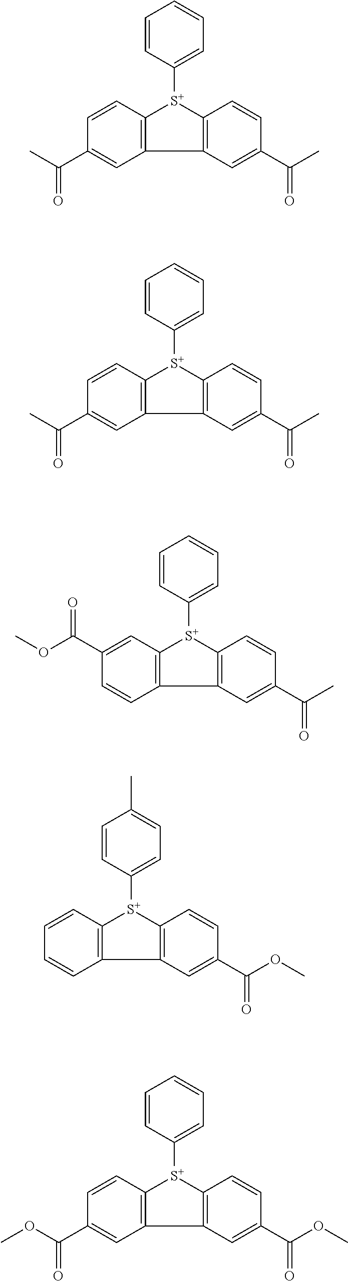

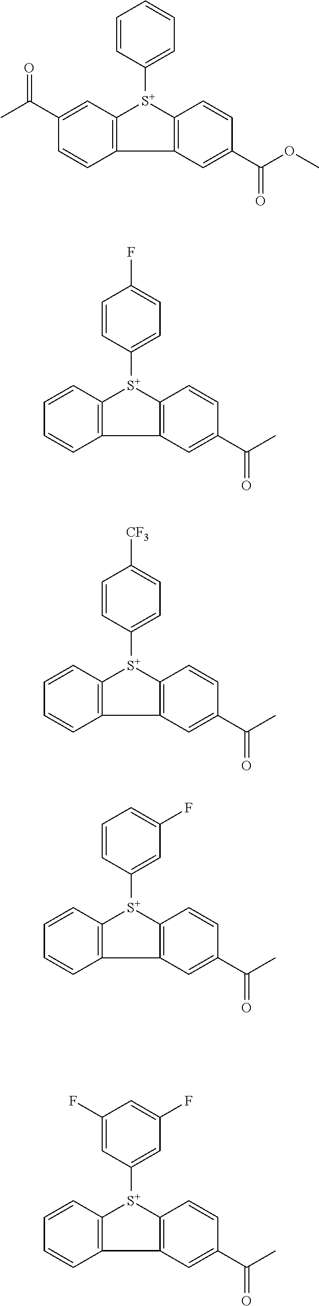 [SMILES: COC(=O)c1ccc2c(c1)c1ccc(C(C)=O)cc1[s+]2-c1ccccc1 ; CC(=O)c1ccc2c(c1)c1ccccc1[s+]2-c1ccc(F)cc1 ; CC(=O)c1ccc2c(c1)c1ccccc1[s+]2-c1ccc(C(F)(F)F)cc1 ; CC(=O)c1ccc2c(c1)c1ccccc1[s+]2-c1cccc(F)c1 ; CC(=O)c1ccc2c(c1)c1ccccc1[s+]2-c1cc(F)cc(F)c1]

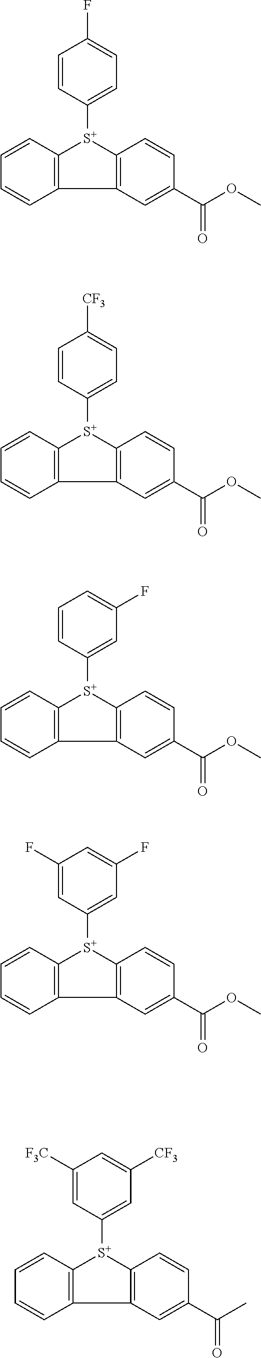 [SMILES: COC(=O)c1ccc2c(c1)c1ccccc1[s+]2-c1ccc(F)cc1 ; COC(=O)c1ccc2c(c1)c1ccccc1[s+]2-c1ccc(C(F)(F)F)cc1 ; COC(=O)c1ccc2c(c1)c1ccccc1[s+]2-c1cccc(F)c1 ; COC(=O)c1ccc2c(c1)c1ccccc1[s+]2-c1cc(F)cc(F)c1 ; CC(=O)c1ccc2c(c1)c1ccccc1[s+]2-c1cc(C(F)(F)F)cc(C(F)(F)F)c1]

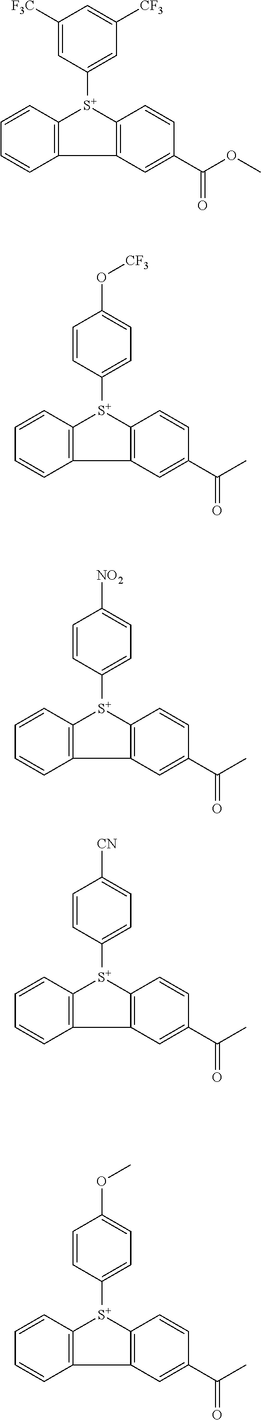 [SMILES: COC(=O)c1ccc2c(c1)c1ccccc1[s+]2-c1cc(C(F)(F)F)cc(C(F)(F)F)c1 ; CC(=O)c1ccc2c(c1)c1ccccc1[s+]2-c1ccc(OC(F)(F)F)cc1 ; CC(=O)c1ccc2c(c1)c1ccccc1[s+]2-c1ccc([N+](=O)[O-])cc1 ; CC(=O)c1ccc2c(c1)c1ccccc1[s+]2-c1ccc(C#N)cc1 ; COc1ccc(-[s+]2c3ccccc3c3cc(C(C)=O)ccc32)cc1]

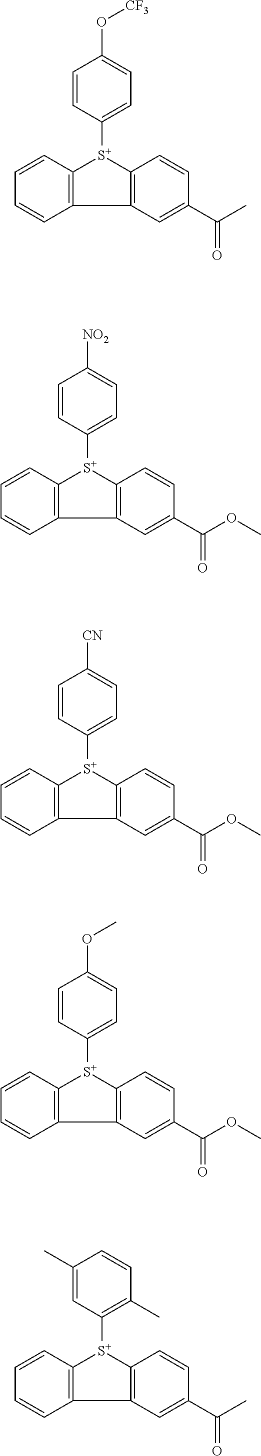 [SMILES: CC(=O)c1ccc2c(c1)c1ccccc1[s+]2-c1ccc(OC(F)(F)F)cc1 ; COC(=O)c1ccc2c(c1)c1ccccc1[s+]2-c1ccc([N+](=O)[O-])cc1 ; COC(=O)c1ccc2c(c1)c1ccccc1[s+]2-c1ccc(C#N)cc1 ; COC(=O)c1ccc2c(c1)c1ccccc1[s+]2-c1ccc(OC)cc1 ; CC(=O)c1ccc2c(c1)c1ccccc1[s+]2-c1cc(C)ccc1C]

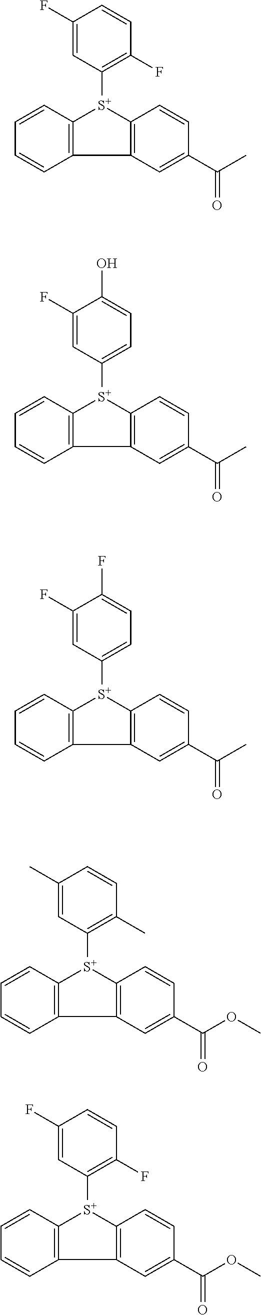 [SMILES: CC(=O)c1ccc2c(c1)c1ccccc1[s+]2-c1cc(F)ccc1F ; CC(=O)c1ccc2c(c1)c1ccccc1[s+]2-c1ccc(O)c(F)c1 ; CC(=O)c1ccc2c(c1)c1ccccc1[s+]2-c1ccc(F)c(F)c1 ; COC(=O)c1ccc2c(c1)c1ccccc1[s+]2-c1cc(C)ccc1C ; COC(=O)c1ccc2c(c1)c1ccccc1[s+]2-c1cc(F)ccc1F]

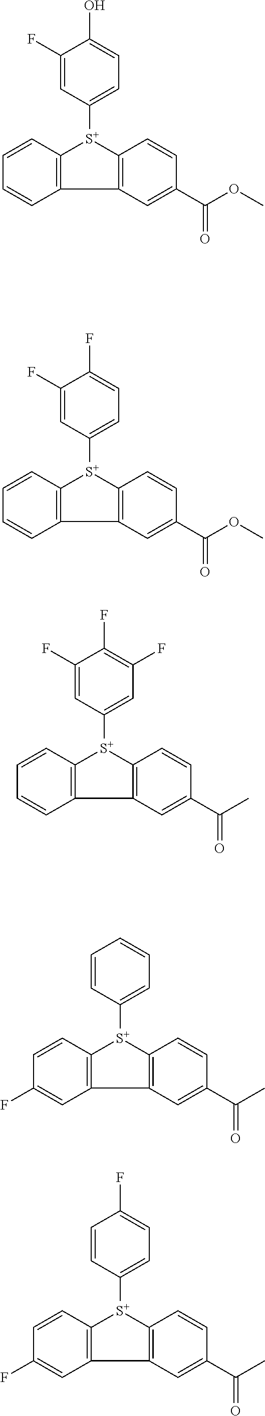 [SMILES: COC(=O)c1ccc2c(c1)c1ccccc1[s+]2-c1ccc(O)c(F)c1 ; COC(=O)c1ccc2c(c1)c1ccccc1[s+]2-c1ccc(F)c(F)c1 ; CC(=O)c1ccc2c(c1)c1ccccc1[s+]2-c1cc(F)c(F)c(F)c1 ; CC(=O)c1ccc2c(c1)c1cc(F)ccc1[s+]2-c1ccccc1 ; CC(=O)c1ccc2c(c1)c1cc(F)ccc1[s+]2-c1ccc(F)cc1]

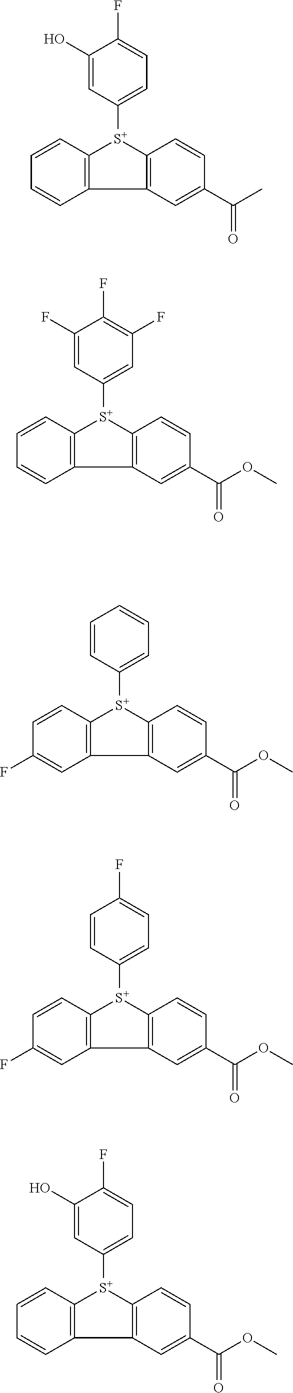 [SMILES: CC(=O)c1ccc2c(c1)c1ccccc1[s+]2-c1ccc(F)c(O)c1 ; COC(=O)c1ccc2c(c1)c1ccccc1[s+]2-c1cc(F)c(F)c(F)c1 ; COC(=O)c1ccc2c(c1)c1cc(F)ccc1[s+]2-c1ccccc1 ; COC(=O)c1ccc2c(c1)c1cc(F)ccc1[s+]2-c1ccc(F)cc1 ; COC(=O)c1ccc2c(c1)c1ccccc1[s+]2-c1ccc(F)c(O)c1]

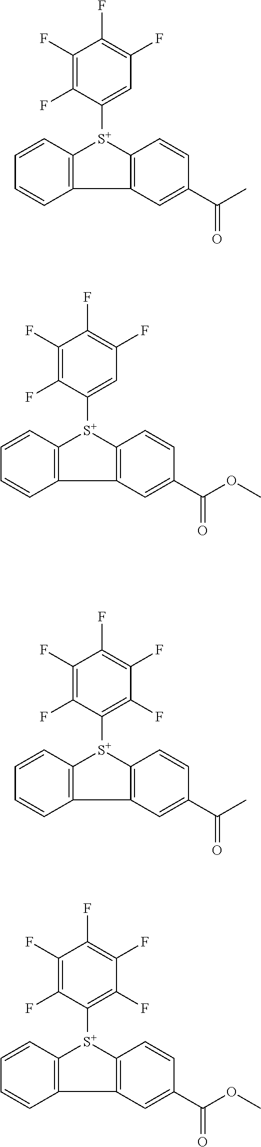 [SMILES: CC(=O)c1ccc2c(c1)c1ccccc1[s+]2-c1cc(F)c(F)c(F)c1F ; COC(=O)c1ccc2c(c1)c1ccccc1[s+]2-c1cc(F)c(F)c(F)c1F ; CC(=O)c1ccc2c(c1)c1ccccc1[s+]2-c1c(F)c(F)c(F)c(F)c1F ; COC(=O)c1ccc2c(c1)c1ccccc1[s+]2-c1c(F)c(F)c(F)c(F)c1F]

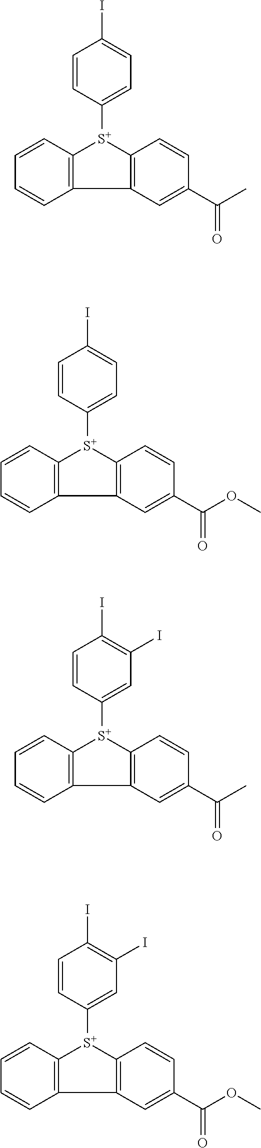 [SMILES: CC(=O)c1ccc2c(c1)c1ccccc1[s+]2-c1ccc(I)cc1 ; COC(=O)c1ccc2c(c1)c1ccccc1[s+]2-c1ccc(I)cc1 ; CC(=O)c1ccc2c(c1)c1ccccc1[s+]2-c1ccc(I)c(I)c1 ; COC(=O)c1ccc2c(c1)c1ccccc1[s+]2-c1ccc(I)c(I)c1]

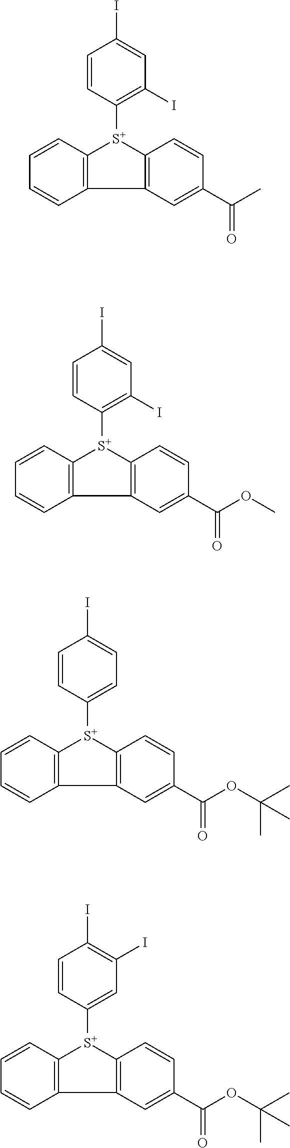 [SMILES: CC(=O)c1ccc2c(c1)c1ccccc1[s+]2-c1ccc(I)cc1I ; COC(=O)c1ccc2c(c1)c1ccccc1[s+]2-c1ccc(I)cc1I ; CC(C)(C)OC(=O)c1ccc2c(c1)c1ccccc1[s+]2-c1ccc(I)cc1 ; CC(C)(C)OC(=O)c1ccc2c(c1)c1ccccc1[s+]2-c1ccc(I)c(I)c1]

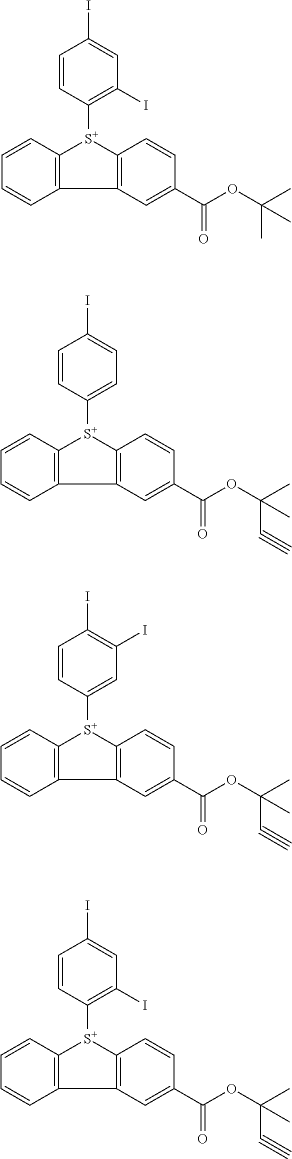 [SMILES: CC(C)(C)OC(=O)c1ccc2c(c1)c1ccccc1[s+]2-c1ccc(I)cc1I ; C#CC(C)(C)OC(=O)c1ccc2c(c1)c1ccccc1[s+]2-c1ccc(I)cc1 ; C#CC(C)(C)OC(=O)c1ccc2c(c1)c1ccccc1[s+]2-c1ccc(I)c(I)c1 ; C#CC(C)(C)OC(=O)c1ccc2c(c1)c1ccccc1[s+]2-c1ccc(I)cc1I]

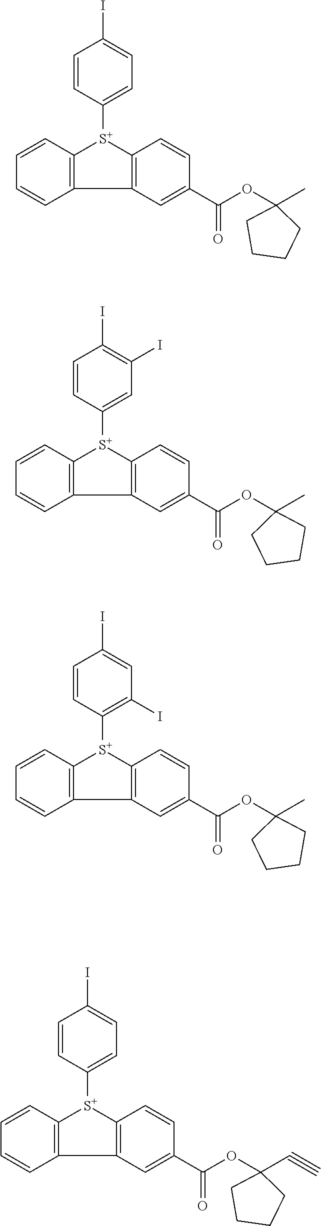 [SMILES: CC1(OC(=O)c2ccc3c(c2)c2ccccc2[s+]3-c2ccc(I)cc2)CCCC1 ; CC1(OC(=O)c2ccc3c(c2)c2ccccc2[s+]3-c2ccc(I)c(I)c2)CCCC1 ; CC1(OC(=O)c2ccc3c(c2)c2ccccc2[s+]3-c2ccc(I)cc2I)CCCC1 ; C#CC1(OC(=O)c2ccc3c(c2)c2ccccc2[s+]3-c2ccc(I)cc2)CCCC1]

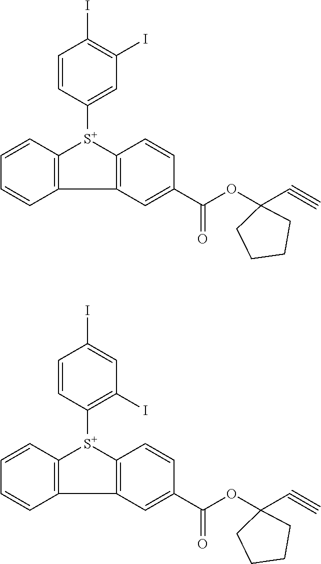 [SMILES: C#CC1(OC(=O)c2ccc3c(c2)c2ccccc2[s+]3-c2ccc(I)c(I)c2)CCCC1 ; C#CC1(OC(=O)c2ccc3c(c2)c2ccccc2[s+]3-c2ccc(I)cc2I)CCCC1]

Examples of the iodonium cation M⁺ are shown below, but not limited thereto.

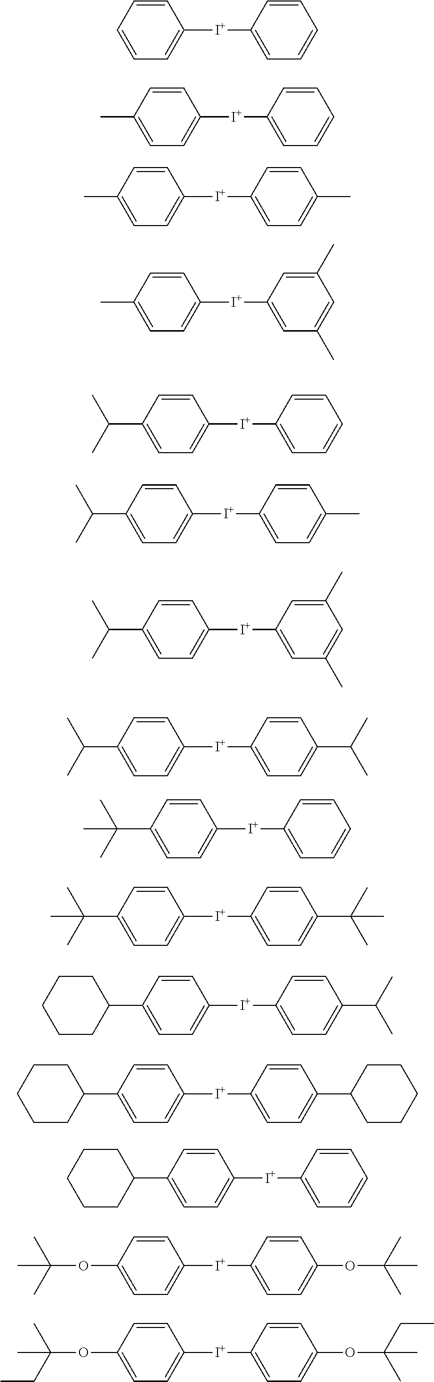

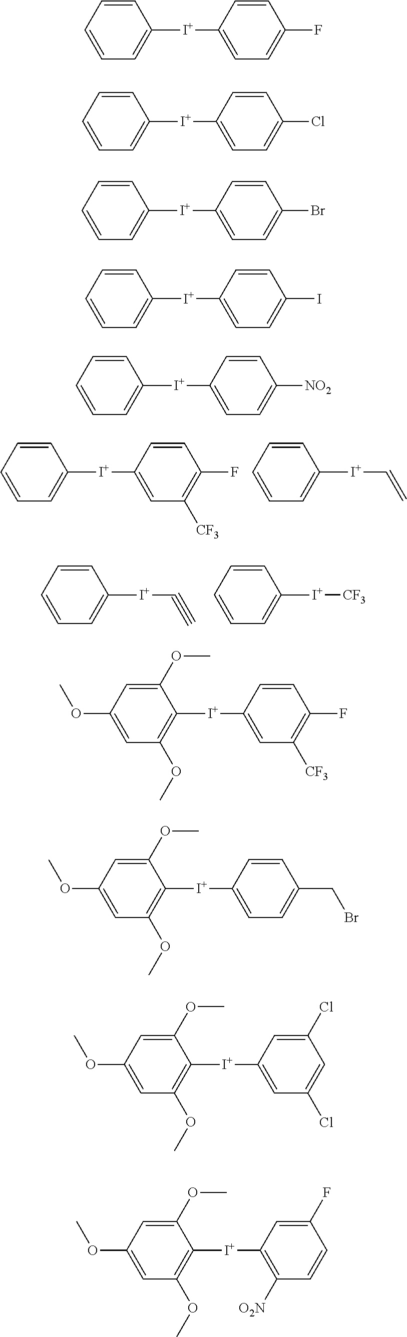

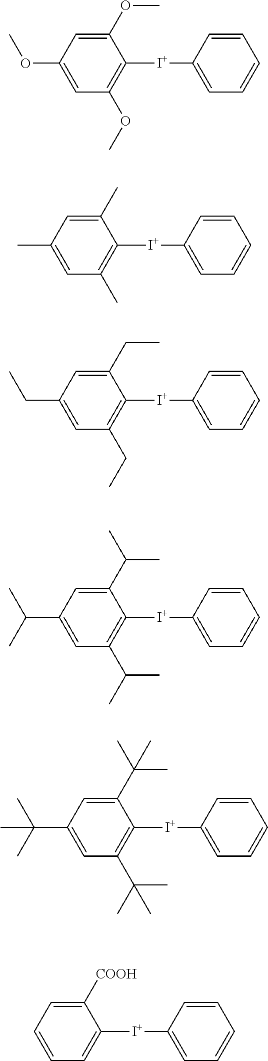 [SMILES: COc1cc(OC)c([I+]c2ccccc2)c(OC)c1 ; Cc1cc(C)c([I+]c2ccccc2)c(C)c1 ; CCc1cc(CC)c([I+]c2ccccc2)c(CC)c1 ; CC(C)c1cc(C(C)C)c([I+]c2ccccc2)c(C(C)C)c1 ; CC(C)(C)c1cc(C(C)(C)C)c([I+]c2ccccc2)c(C(C)(C)C)c1 ; O=C(O)c1ccccc1[I+]c1ccccc1]

The preferred repeat units (c) are units (c2), (c4) and (c5) wherein Z³, Z^{7A}, Z^{7B} or M⁺ contains at least one iodine.

The base polymer may further comprise repeat units (d) having an adhesive group selected from hydroxy, carboxy, lactone ring, carbonate, thiocarbonate, carbonyl, cyclic acetal, ether bond, ester bond, sulfonate ester bond, cyano, amide, —O—C(═O)—S—, and —O—C(═O)—NH—.

Examples of the monomer from which repeat units (d) are derived are given below, but not limited thereto. Herein R^{A} is as defined above.

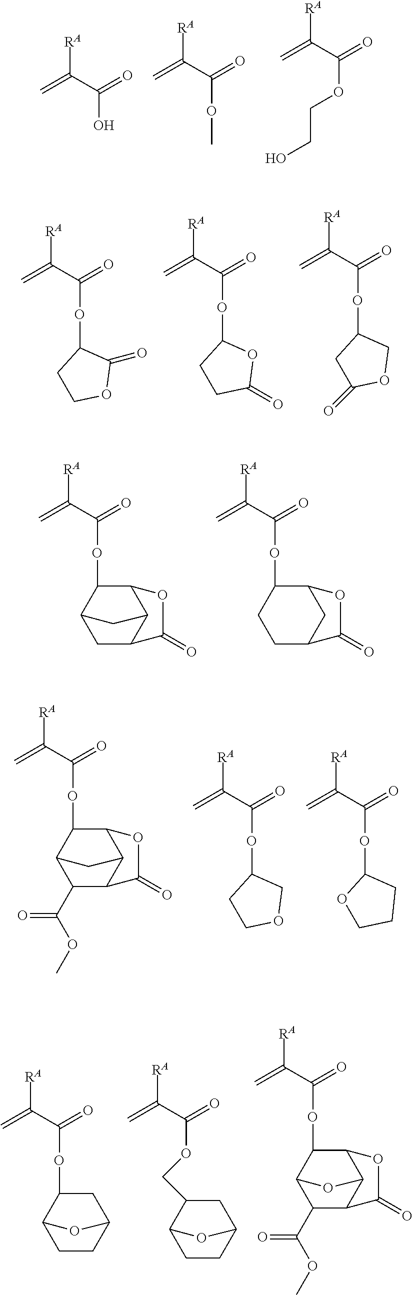

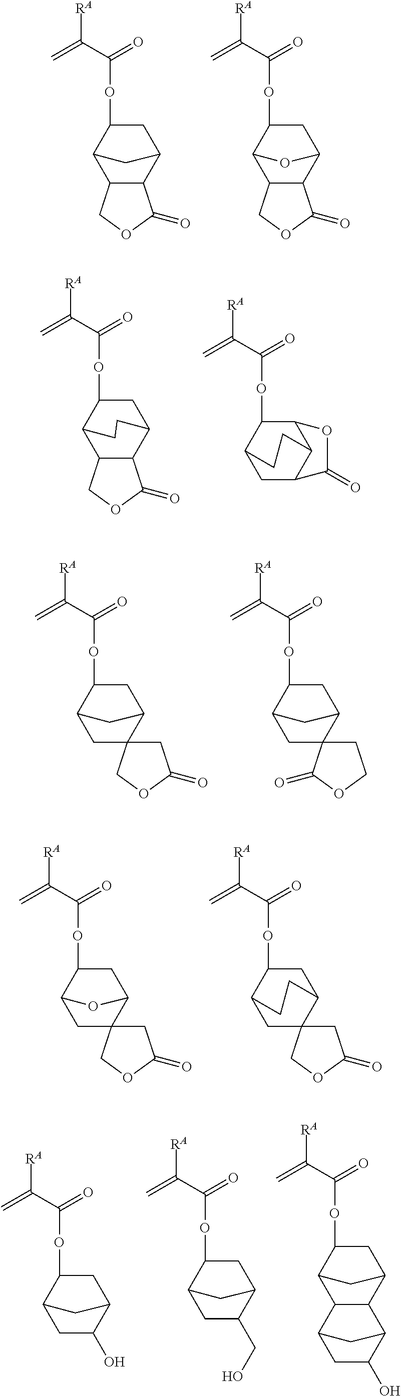

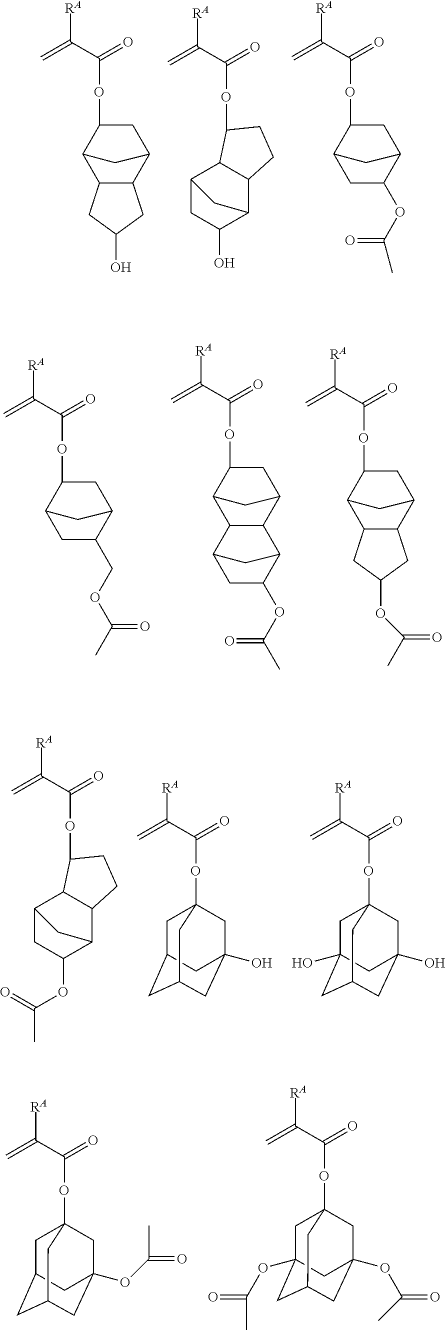

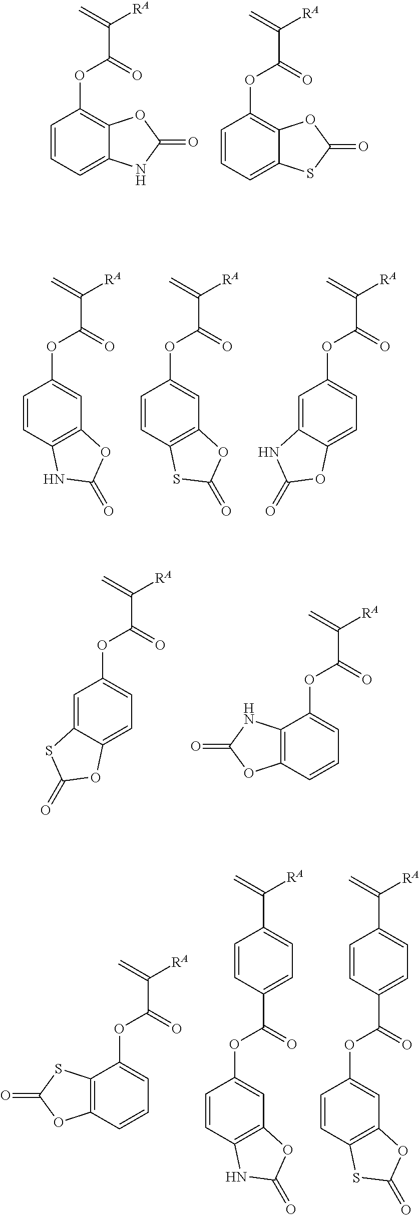

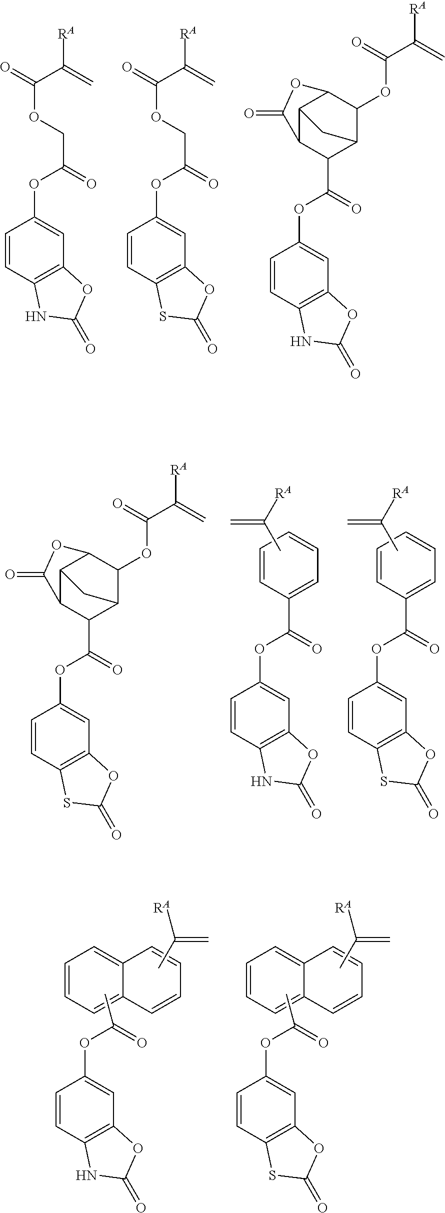

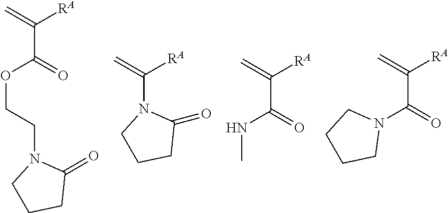

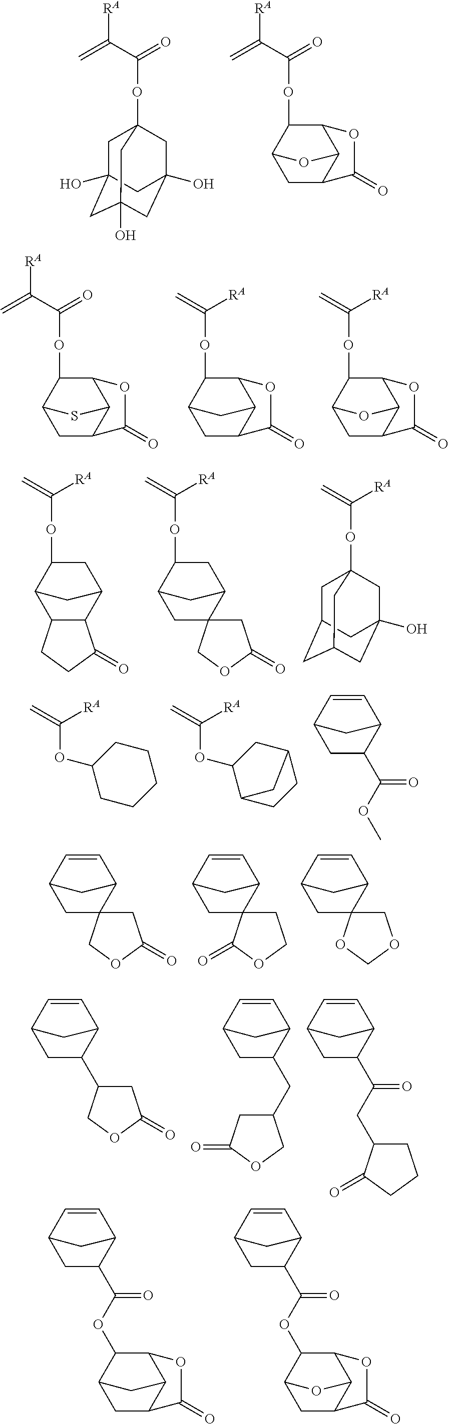

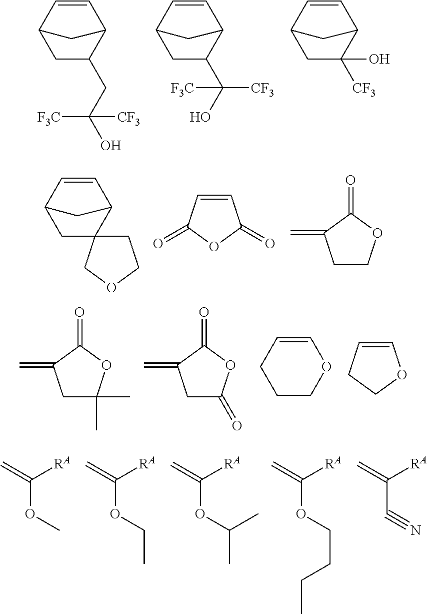

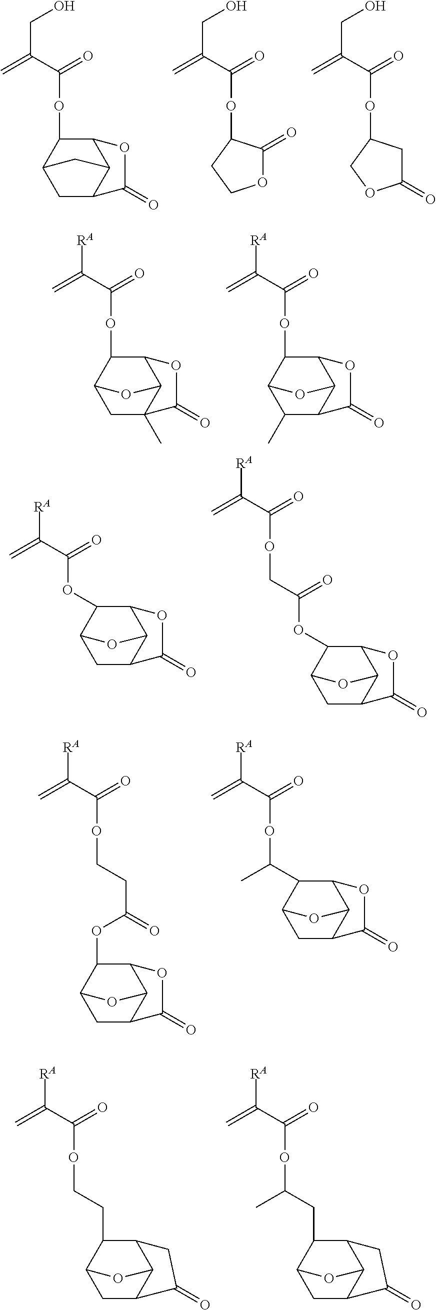

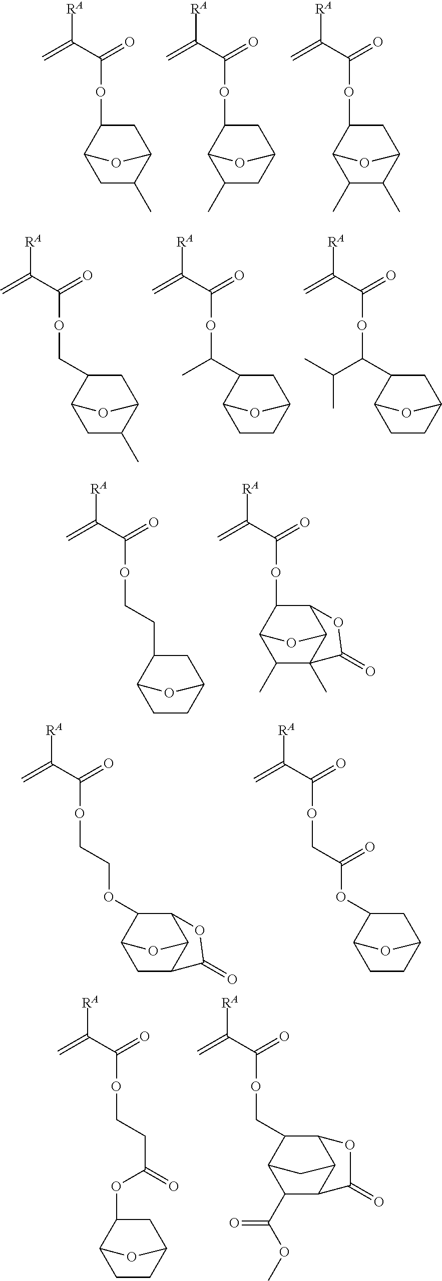

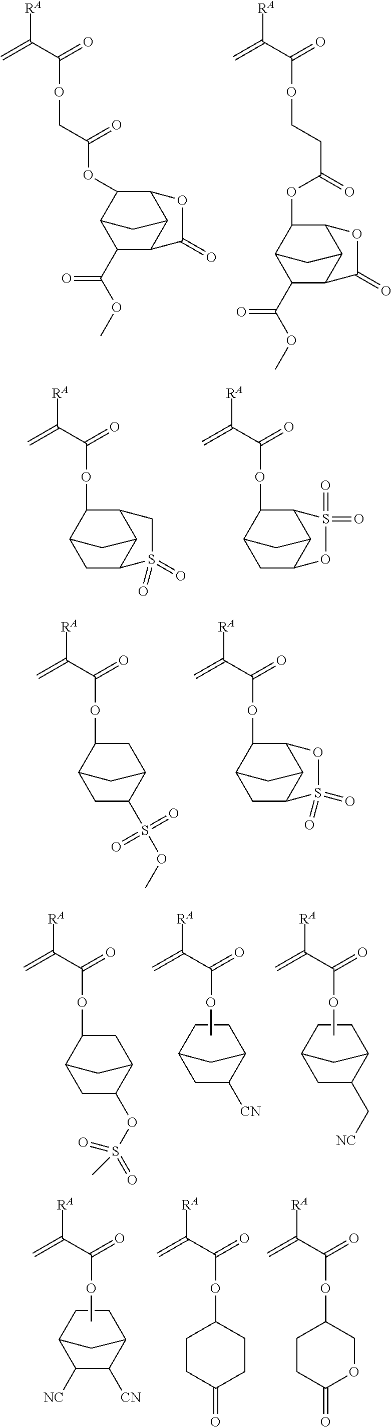

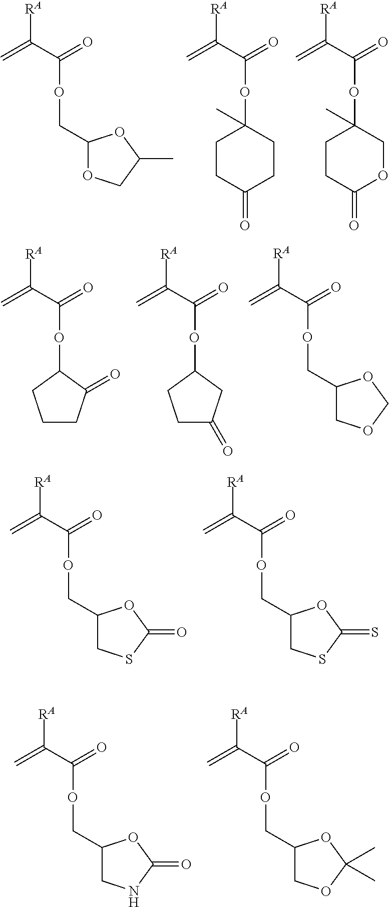

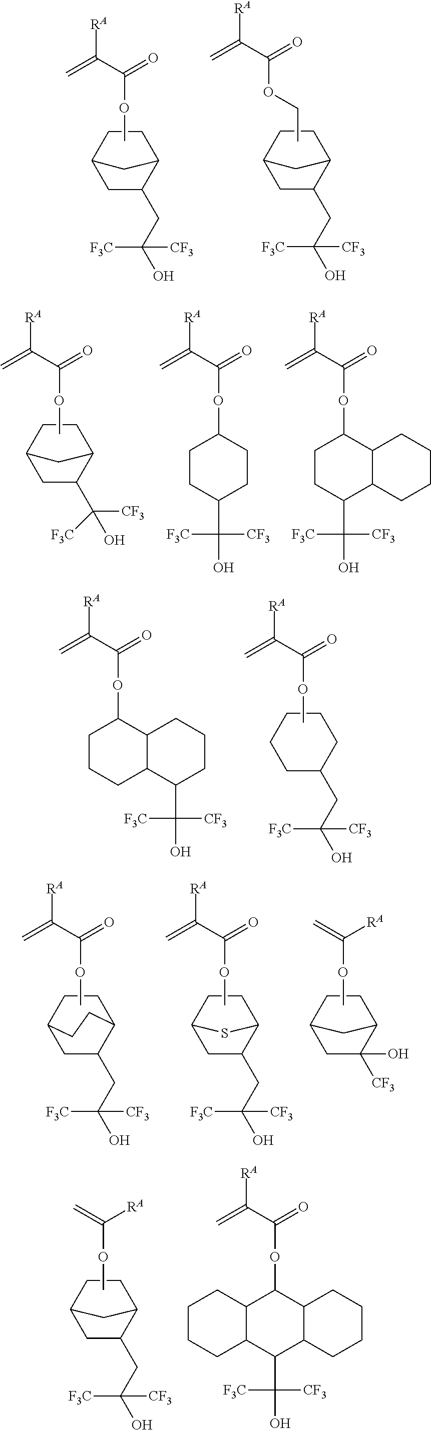

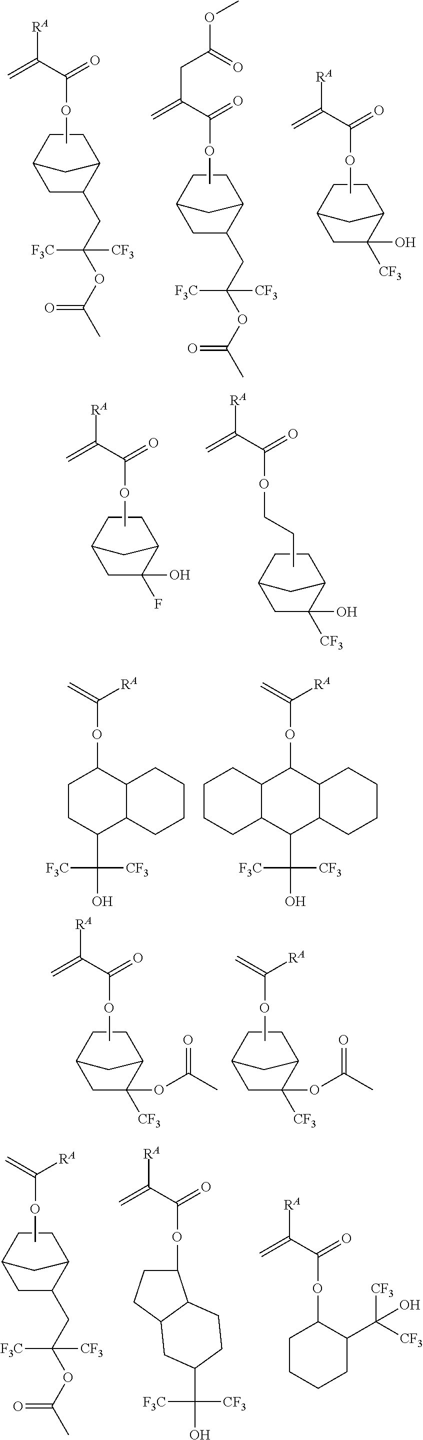

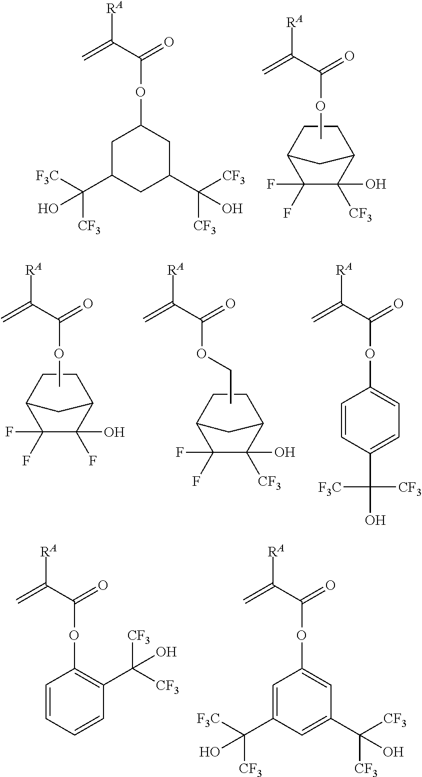

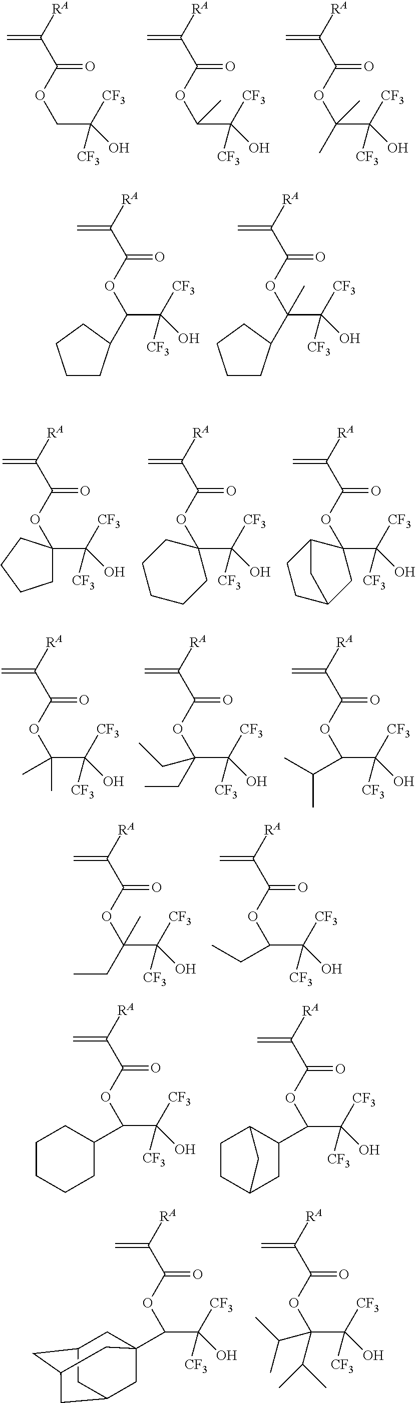

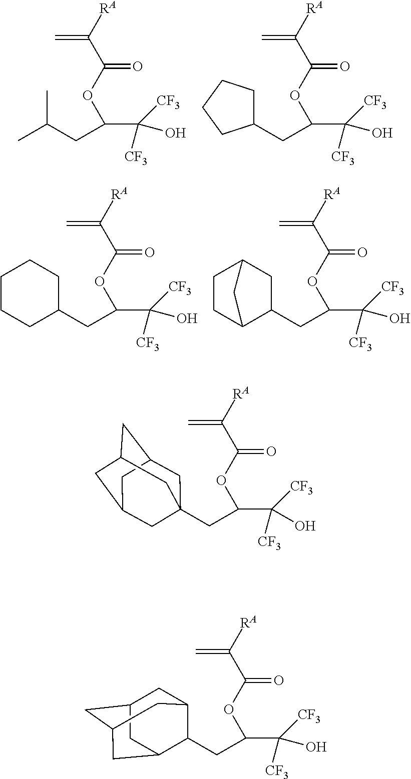

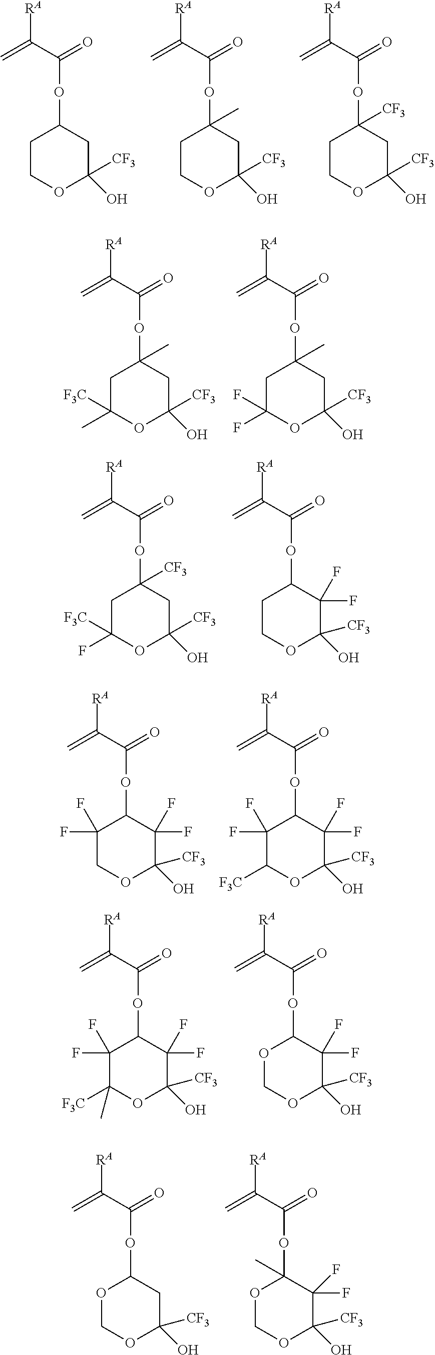

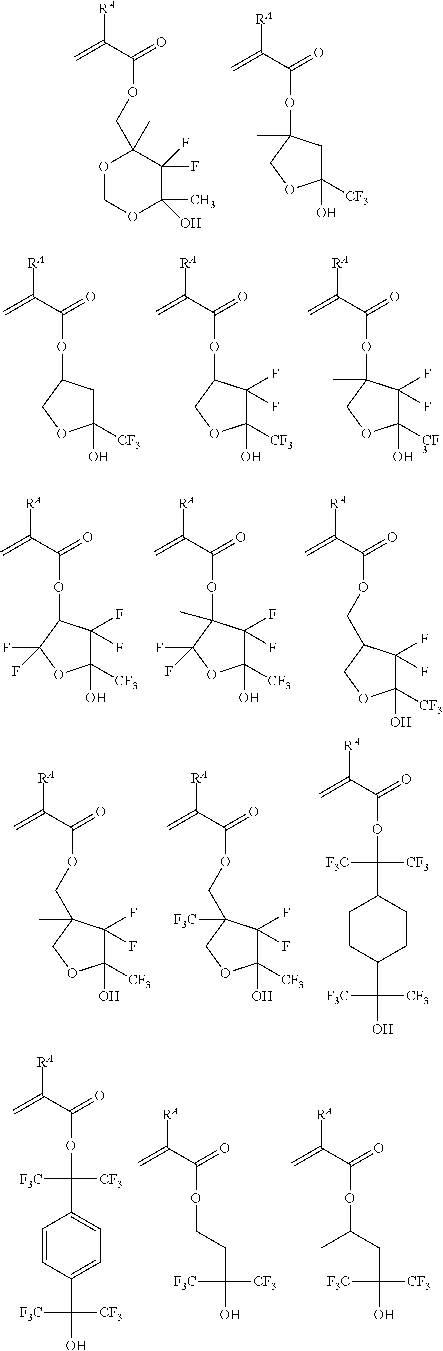

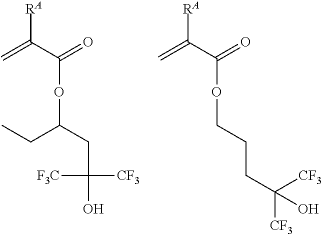

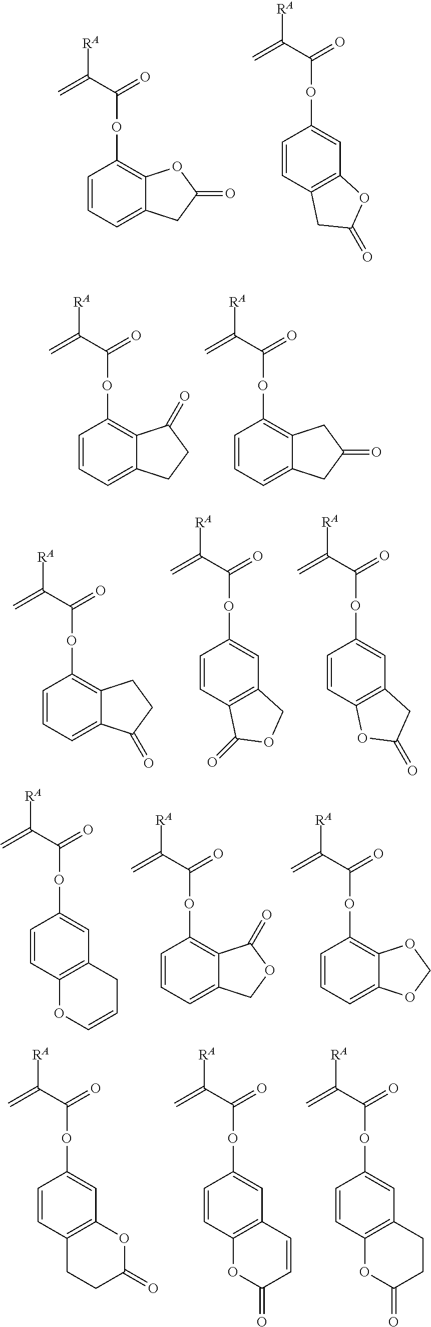

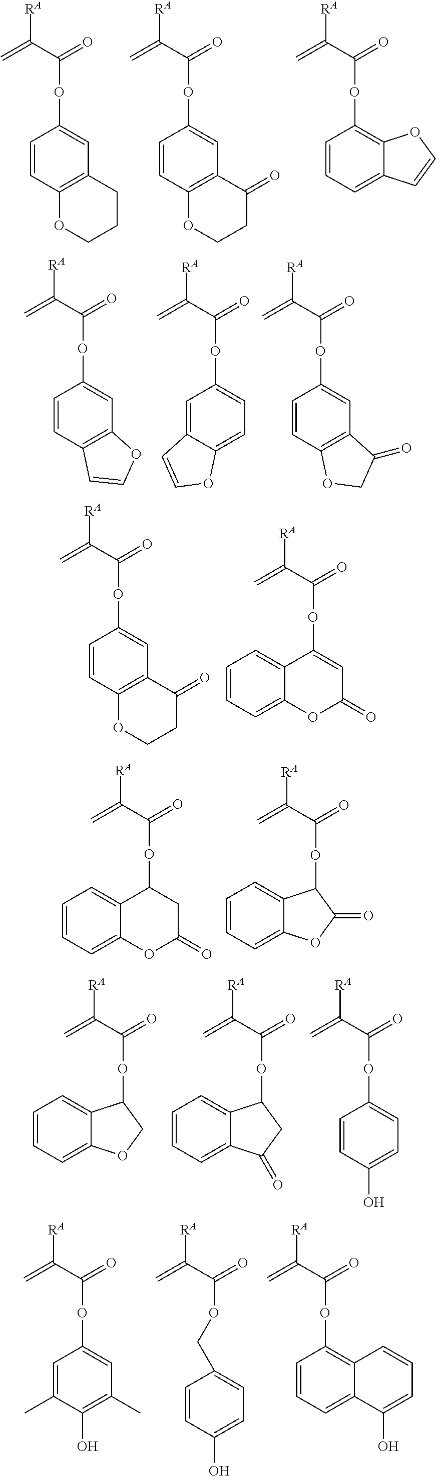

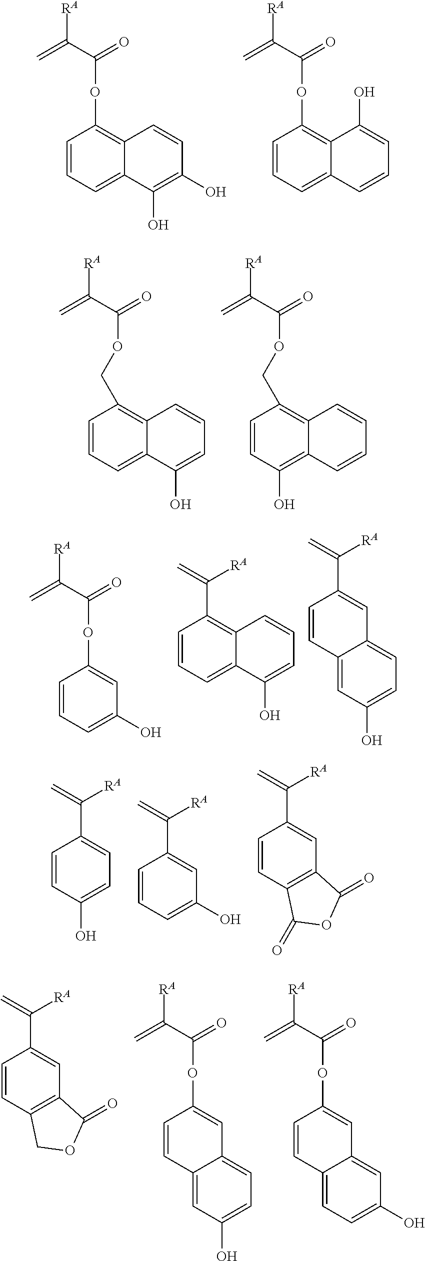

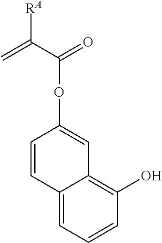

The base polymer may further comprise repeat units (c) containing iodine, but not amino group. Examples of the monomer from which repeat units (c) are derived are given below, but not limited thereto. Herein R^{A} is as defined above.

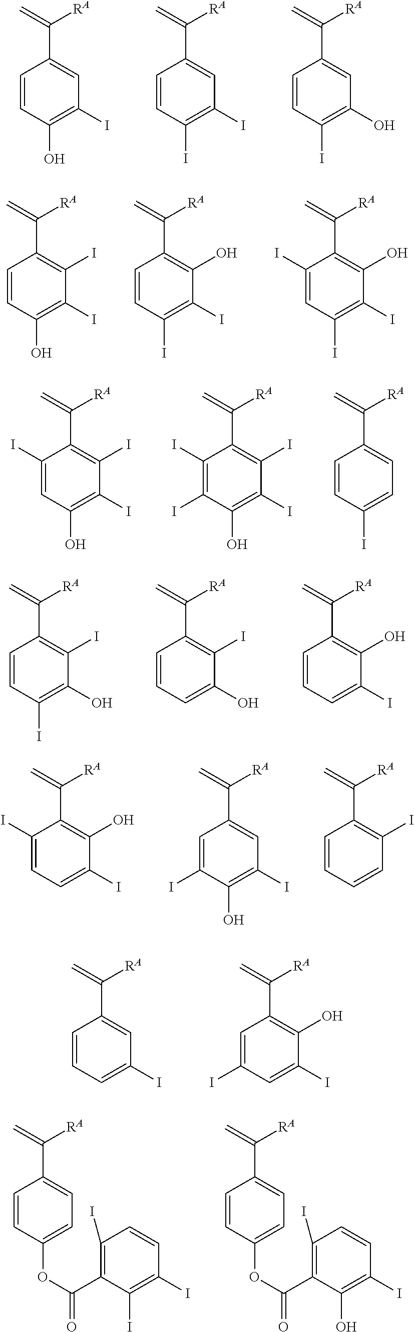

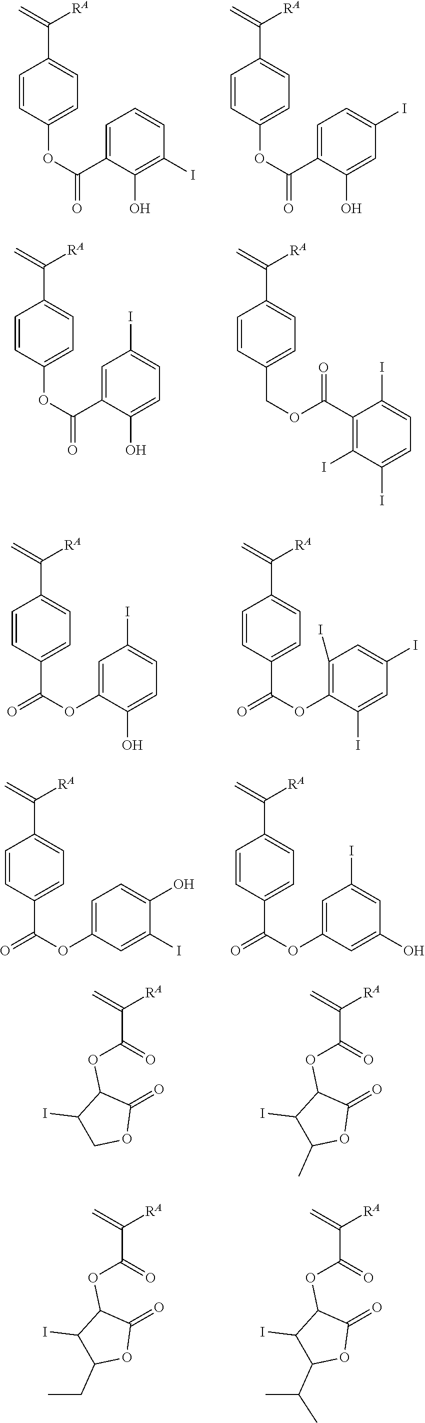

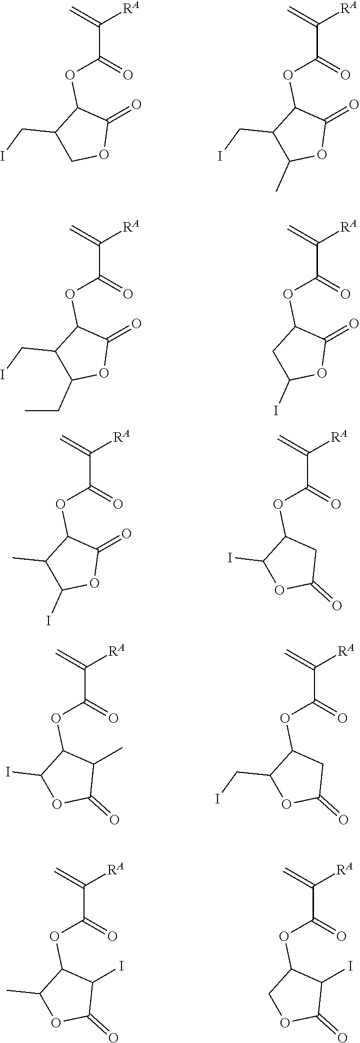

Besides the foregoing repeat units, the base polymer may further comprise repeat units (f) which are derived from styrene, vinylnaphthalene, indene, acenaphthylene, coumarin, and coumarone.

The base polymer contains units (a), (b1), (b2), (c1), (c2), (c3), (c4), (c5), (d), (e), and (f) in the following fraction:
preferably 0<a≤0.5, 0≤b1≤0.8, 0≤b2≤0.8, 0<b1+b2≤0.8, 0≤c1≤0.5, 0≤c2≤0.5, 0≤c3≤0.5, 0≤c4≤0.5, 0≤c5≤0.5, 0<c1+c2+c3+c4+c5≤0.5, 0≤d≤0.9, 0≤e≤0.5, and 0≤f≤0.5;
more preferably 0.001≤a≤0.4, 0≤b1≤0.75, 0≤b2≤0.75, 0.1≤b1+b2≤0.8, 0≤c1≤0.4, 0≤c2≤0.4, 0≤c3≤0.4, 0≤c4≤0.4, 0≤c5≤0.4, 0.01≤c1+c2+c3+c4+c5≤0.4, 0≤d≤0.8, 0≤e≤0.4, and 0≤f≤0.4;

even more preferably 0.002≤a≤0.3, 0≤b1≤0.7, 0≤b2≤0.7, 0.2≤b1+b2≤0.7, 0≤c1≤0.3, 0≤c2≤0.3, 0≤c3≤0.3, 0≤c4≤0.3, 0≤c5≤0.3, 0.02≤c1+c2+c3+c4+c5≤0.3, 0≤d≤0.7, 0≤e≤0.3, and 0≤f≤0.3. Notably, a+b1+b2+c1+c2+c3+c4+c5+d+e+f=1.0.

The base polymer may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, propylene glycol monomethyl ether, γ-butyrolactone, and mixtures thereof. Examples of the polymerization initiator used herein include 2,2′-azobisisobutyronitrile (AIBN), 2,2′-azobis(2,4-dimethylvaleronitrile), dimethyl 2,2-azobis (2-methylpropionate), benzoyl peroxide, and lauroyl peroxide. Preferably, the reaction temperature is 50 to 80° C. and the reaction time is 2 to 100 hours, more preferably 5 to 20 hours.

Where a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaphthalene. For alkaline hydrolysis, a base such as aqueous ammonia or triethylamine may be used. Preferably the reaction temperature is −20° C. to 100° C., more preferably 0° C. to 60° C., and the reaction time is 0.2 to 100 hours, more preferably 0.5 to 20 hours.

The base polymer should preferably have a weight average molecular weight (Mw) in the range of 1,000 to 500,000, and more preferably 2,000 to 30,000, as measured by GPC versus polystyrene standards using tetrahydrofuran (THF) solvent. A Mw in the range ensures that the resist film has heat resistance and high solubility in alkaline developer.

If a base polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

For forming a narrow dispersity polymer, not only ordinary radical polymerization, but living radical polymerization may also be employed. Suitable living radical polymerization processes include radical polymerization using nitroxide radicals, i.e., nitroxide-mediated radical polymerization (NMP), atom transfer radical polymerization (ATRP), and reversible addition-fragmentation chain transfer (RAFT) polymerization.

The base polymer may be a blend of two or more polymers which differ in compositional ratio, Mw or Mw/Mn. A blend of a polymer comprising repeat units (a) and a polymer free of repeat units (a) is also acceptable.

### [Organic Solvent]

An organic solvent may be added to the positive resist composition. The organic solvent used herein is not particularly limited as long as the foregoing and other components are soluble therein. Examples of the organic solvent are described in JP-A 2008-111103, paragraphs [0144]-[0145] (U.S. Pat. No. 7,537,880). Exemplary solvents include ketones such as cyclohexanone, cyclopentanone, methyl-2-n-pentyl ketone and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone, which may be used alone or in admixture.

The organic solvent is preferably added in an amount of 100 to 10,000 parts, and more preferably 200 to 8,000 parts by weight per 100 parts by weight of the base polymer.

### [Quencher]

The resist composition may comprise a quencher. As used herein, the “quencher” refers to a compound capable of trapping the acid generated from the acid generator for thereby preventing the acid from diffusing to the unexposed region.

The quencher is typically selected from conventional basic compounds. Conventional basic compounds include primary, secondary, and tertiary aliphatic amines, mixed amines, aromatic amines, heterocyclic amines, nitrogen-containing compounds with carboxy group, nitrogen-containing compounds with sulfonyl group, nitrogen-containing compounds with hydroxy group, nitrogen-containing compounds with hydroxyphenyl group, alcoholic nitrogen-containing compounds, amide derivatives, imide derivatives, and carbamate derivatives. Also included are primary, secondary, and tertiary amine compounds, specifically amine compounds having a hydroxy group, ether bond, ester bond, lactone ring, cyano group, or sulfonic ester bond as described in U.S. Pat. No. 7,537,880 (JP-A 2008-111103, paragraphs [0146]-[0164]), and compounds having a carbamate bond as described in JP 3790649. Addition of a basic compound is effective for further suppressing the diffusion rate of acid in the resist film or correcting the pattern profile.

Suitable quenchers also include onium salts such as sulfonium salts, iodonium salts and ammonium salts of sulfonic acids which are not fluorinated at α-position, carboxylic acids or fluorinated alkoxides, as described in U.S. Pat. No. 8,795,942 (JP-A 2008-158339). While an a-fluorinated sulfonic acid, imide acid, and methide acid are necessary to deprotect the acid labile group of carboxylic acid ester, an α-non-fluorinated sulfonic acid, carboxylic acid or fluorinated alcohol is released by salt exchange with an α-non-fluorinated onium salt. The α-non-fluorinated sulfonic acid, carboxylic acid and fluorinated alcohol function as a quencher because they do not induce deprotection reaction.

Exemplary such quenchers include a compound (onium salt of α-non-fluorinated sulfonic acid) having the formula (1), a compound (onium salt of carboxylic acid) having the formula (2), and a compound (onium salt of alkoxide) having the formula (3).

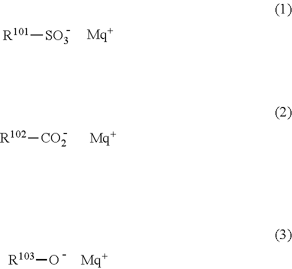

In formula (1), R¹⁰¹ is hydrogen or a C₁-C₄₀ hydrocarbyl group which may contain a heteroatom, exclusive of the hydrocarbyl group in which the hydrogen bonded to the carbon atom at α-position of the sulfo group is substituted by fluorine or fluoroalkyl moiety.

The C₁-C₄₀ hydrocarbyl group may be saturated or unsaturated and straight, branched or cyclic. Examples thereof include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, n-decyl; C₃-C₄₀ Cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl, and adamantylmethyl; C₂-C₄₀ alkenyl groups such as vinyl, allyl, butenyl and hexenyl; C₃-C₄₀ cyclic unsaturated aliphatic hydrocarbyl groups such as cyclohexenyl; C₆-C₄₀ aryl groups such as phenyl, naphthyl, alkylphenyl groups (e.g., 2-methylphenyl, 3-methylphenyl, 4-methylphenyl, 4-ethylphenyl, 4-tert-butylphenyl, 4-n-butylphenyl), di- or trialkylphenyl groups (e.g., 2,4-dimethylphenyl and 2,4,6-triisopropylphenyl), alkylnaphthyl groups (e.g., methylnaphthyl and ethylnaphthyl), dialkylnaphthyl groups (e.g., dimethylnaphthyl and diethylnaphthyl); and C₇-C₄₀ aralkyl groups such as benzyl, 1-phenylethyl and 2-phenylethyl.

In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, carbonyl moiety, ether bond, ester bond, sulfonic ester bond, carbonate bond, lactone ring, sultone ring, carboxylic anhydride (—C(═O)—O—C(═O)—), or haloalkyl moiety. Suitable heteroatom-containing hydrocarbyl groups include heteroaryl groups such as thienyl, 4-hydroxyphenyl, alkoxyphenyl groups such as 4-methoxyphenyl, 3-methoxyphenyl, 2-methoxyphenyl, 4-ethoxyphenyl, 4-tert-butoxyphenyl, 3-tert-butoxyphenyl; alkoxynaphthyl groups such as methoxynaphthyl, ethoxynaphthyl, n-propoxynaphthyl and n-butoxynaphthyl; dialkoxynaphthyl groups such as dimethoxynaphthyl and diethoxynaphthyl; and aryloxoalkyl groups, typically 2-aryl-2-oxoethyl groups such as 2-phenyl-2-oxoethyl, 2-(1-naphthyl)-2-oxoethyl and 2-(2-naphthyl)-2-oxoethyl.

In formula (2), R¹⁰² is a C₁-C₄₀ hydrocarbyl group which may contain a heteroatom. Examples of the hydrocarbyl group R¹⁰² are as exemplified above for the hydrocarbyl group R¹⁰¹. Also included are fluorinated alkyl groups such as trifluoromethyl, trifluoroethyl, 2,2,2-trifluoro-1-methyl-1-hydroxyethyl, 2,2,2-trifluoro-1-(trifluoromethyl)-1-hydroxyethyl, and fluorinated aryl groups such as pentafluorophenyl and 4-trifluoromethylphenyl.

In formula (3), R¹⁰³ is a C₁-C₈ saturated hydrocarbyl group containing at least 3 fluorine atoms or a C₆-C₁₀ aryl group containing at least 3 fluorine atoms, the hydrocarbyl and aryl groups optionally containing a nitro moiety.

In formulae (1), (2) and (3), Mq⁺ is an onium cation. The onium cation is preferably a sulfonium, iodonium or ammonium cation, with the sulfonium cation being more preferred. Suitable sulfonium cations are as exemplified for the sulfonium cation M⁺ in formula (a).

A sulfonium salt of iodized benzene ring-containing carboxylic acid having the formula (4) is also useful as the quencher.

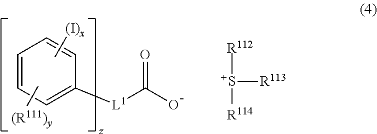

In formula (4), x is an integer of 1 to 5, y is an integer of 0 to 3, and z is an integer of 1 to 3.

In formula (4), R¹¹¹ is hydroxy, fluorine, chlorine, bromine, amino, nitro, cyano, or a C₁-C₆ saturated hydrocarbyl, C₁-C₆ saturated hydrocarbyloxy, C₂-C₆ saturated hydrocarbylcarbonyloxy, or C₁-C₄ saturated hydrocarbylsulfonyloxy group, in which some or all hydrogen may be substituted by halogen, or —N(R^{111A})—C(═O)—R^{111B}, or —N(R^{111A})—C(═O)—O—R^{111B}. R^{111A} is hydrogen or a C₁-C₆ saturated hydrocarbyl group. R^{111B} is a C₁-C₆ saturated hydrocarbyl or C₂-C₈ unsaturated aliphatic hydrocarbyl group. A plurality of R¹¹¹ may be identical or different when y and/or z is 2 or 3.

In formula (4), L¹ is a single bond, or a C₁-C₂₀ (z+1)-valent linking group which may contain an ether bond, carbonyl, ester bond, amide bond, sultone ring, lactam ring, carbonate bond, halogen, hydroxy or carboxy moiety or a mixture thereof. The saturated hydrocarbyl, saturated hydrocarbyloxy, saturated hydrocarbylcarbonyloxy and saturated hydrocarbylsulfonyloxy groups may be straight, branched or cyclic.

In formula (4), R¹¹², R¹¹³ and R¹¹⁴ are each independently halogen or a C₁-C₂₀ hydrocarbyl group which may contain a heteroatom. The hydrocarbyl group may be saturated or unsaturated and straight, branched or cyclic. Examples thereof are as exemplified for the hydrocarbyl groups R⁴¹ to R⁴⁵ in formulae (M1) and (M2).

Examples of the compound having formula (4) include those described in U.S. Pat. No. 10,295,904 (JP-A 2017-219836) and US20210188770 (JP-A 2021-091666).

Also useful are quenchers of polymer type as described in U.S. Pat. No. 7,598,016 (JP-A 2008-239918). The polymeric quencher segregates at the resist film surface and thus enhances the rectangularity of resist pattern. When a protective film is applied as is often the case in the immersion lithography, the polymeric quencher is also effective for preventing a film thickness loss of resist pattern or rounding of pattern top.

Other useful quenchers include sulfonium salts of betaine structure as described in JP 6848776 and JP-A 2020-037544, fluorine-free methide acids as described in JP-A 2020-055797, sulfonium salts of sulfonamide as described in JP 5807552, and sulfonium salts of iodized sulfonamide, phenols, halogens or acid generators capable of generating carbonic acid as described in JP-A 2019-211751.

The quencher is preferably added in an amount of 0 to 5 parts, more preferably 0 to 4 parts by weight per 100 parts by weight of the base polymer. The quencher may be used alone or in admixture.

### [Other Components]

In addition to the foregoing components, the resist composition may contain other components such as an acid generator, surfactant, dissolution inhibitor, water repellency improver and acetylene alcohol. Each of the other components may be used alone or in admixture.

The acid generator is typically a compound (PAG) capable of generating an acid upon exposure to actinic ray or radiation. Although the PAG used herein may be any compound capable of generating an acid upon exposure to high-energy radiation, those compounds capable of generating sulfonic acid, imide acid (imidic acid) or methide acid are preferred. Suitable PAGs include sulfonium salts, iodonium salts, sulfonyldiazomethane, N-sulfonyloxyimide, and oxime-O-sulfonate acid generators. Exemplary PAGs are described in JP-A 2008-111103, paragraphs [0122]-[0142] (U.S. Pat. No. 7,537,880), JP-A 2018-005224, JP-A 2018-025789, JP-A 2018-155908, and JP-A 2018-159744. The acid generator is preferably used in an amount of 0 to 200 parts, more preferably 0.1 to 100 parts by weight per 100 parts by weight of the base polymer.

Exemplary surfactants are described in JP-A 2008-111103, paragraphs [0165]-[0166]. Inclusion of a surfactant may improve or control the coating characteristics of the resist composition. The surfactant is preferably added in an amount of 0.0001 to 10 parts by weight per 100 parts by weight of the base polymer.

In the positive resist composition, a dissolution inhibitor may be added to increase the difference in dissolution rate between exposed and unexposed areas to achieve a further improvement in resolution. The dissolution inhibitor is typically a compound having at least two phenolic hydroxy groups on the molecule, in which an average of from 0 to 100 mol % of all the hydrogen atoms on the phenolic hydroxy groups are replaced by acid labile groups or a compound having at least one carboxy group on the molecule, in which an average of 50 to 100 mol % of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid, and cholic acid derivatives in which the hydrogen atom on the hydroxy or carboxy group is replaced by an acid labile group, as described in U.S. Pat. No. 7,771,914 (JP-A 2008-122932, paragraphs [0155]-[0178]).

The dissolution inhibitor is preferably added in an amount of 0 to 50 parts, more preferably 5 to 40 parts by weight per 100 parts by weight of the base polymer.

To the resist composition, a water repellency improver may also be added for improving the water repellency on surface of a resist film. The water repellency improver may be used in the topcoatless immersion lithography. Suitable water repellency improvers include polymers having a fluoroalkyl group and polymers having a specific structure with a 1,1,1,3,3,3-hexafluoro-2-propanol residue and are described in JP-A 2007-297590 and JP-A 2008-111103, for example. The water repellency improver to be added to the resist composition should be soluble in alkaline developers and organic solvent developers. The water repellency improver of specific structure with a 1,1,1,3,3,3-hexafluoro-2-propanol residue is well soluble in the developer. A polymer having an amino group or amine salt copolymerized as repeat units may serve as the water repellent additive and is effective for preventing evaporation of acid during PEB, thus preventing any hole pattern opening failure after development. An appropriate amount of the water repellency improver is 0 to 20 parts, preferably 0.5 to 10 parts by weight per 100 parts by weight of the base polymer.

Also, an acetylene alcohol may be blended in the resist composition. Suitable acetylene alcohols are described in JP-A 2008-122932, paragraphs [0179]-[0182]. An appropriate amount of the acetylene alcohol blended is 0 to 5 parts by weight per 100 parts by weight of the base polymer.

### [Process]

The positive resist composition is used in the fabrication of various integrated circuits. Pattern formation using the resist composition may be performed by well-known lithography processes. The process generally involves the steps of applying the positive resist composition onto a substrate to form a resist film thereon, exposing the resist film to high-energy radiation, and developing the exposed resist film in a developer. If necessary, any additional steps may be added.

Specifically, the resist composition is first applied onto a substrate on which an integrated circuit is to be formed (e.g., Si, SiO₂, SIN, SION, TIN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying or doctor coating. The coating is prebaked on a hotplate preferably at a temperature of 60 to 150° C. for 10 seconds to 30 minutes, more preferably at 80 to 120° C. for 30 seconds to 20 minutes. The resulting resist film is generally 0.01 to 2 μm thick.

The resist film is then exposed to a desired pattern of high-energy radiation such as UV, deep-UV, EB, EUV of wavelength 3 to 15 nm, x-ray, soft x-ray, excimer laser light, Y-ray or synchrotron radiation. When UV, deep-UV, EUV, x-ray, soft x-ray, excimer laser light, y-ray or synchrotron radiation is used as the high-energy radiation, the resist film is exposed thereto directly or through a mask having a desired pattern in a dose of preferably about 1 to 200 mJ/cm², more preferably about 10 to 100 mJ/cm². When EB is used as the high-energy radiation, the resist film is exposed thereto directly or through a mask having a desired pattern in a dose of preferably about 0.1 to 300 μC/cm², more preferably about 0.5 to 200 μC/cm². It is appreciated that the inventive resist composition is suited in micropatterning using KrF excimer laser, ArF excimer laser, EB, EUV, x-ray, soft x-ray, γ-ray or synchrotron radiation, especially in micropatterning using EB or EUV.

After the exposure, the resist film may be baked (PEB) on a hotplate or in an oven preferably at 30 to 150° C. for 10 seconds to 30 minutes, more preferably at 50 to 120° C. for 30 seconds to 20 minutes.

After the exposure or PEB, the resist film is developed in a developer in the form of an aqueous base solution for 3 seconds to 3 minutes, preferably 5 seconds to 2 minutes by conventional techniques such as dip, puddle and spray techniques. A typical developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). The resist film in the exposed area is dissolved in the developer whereas the resist film in the unexposed area is not dissolved. In this way, the desired positive pattern is formed on the substrate.

In an alternative embodiment, a negative pattern can be obtained from the positive resist composition comprising a base polymer containing acid labile groups by effecting organic solvent development. The developer used herein is preferably selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate, and mixtures thereof.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable aromatic solvents include toluene, xylene, ethylbenzene, isopropylbenzene, t-butylbenzene and mesitylene.

Rinsing is effective for minimizing the risks of resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by coating a shrink agent thereto, and baking such that the shrink agent may undergo crosslinking at the resist surface as a result of the acid catalyst diffusing from the resist layer during bake, and the shrink agent may attach to the sidewall of the hole pattern. The bake is preferably at a temperature of 70 to 180° C., more preferably 80 to 170° C., for a time of 10 to 300 seconds. The extra shrink agent is stripped and the hole pattern is shrunk.

### EXAMPLES

Examples of the invention are given below by way of illustration and not by way of limitation. All parts are by weight (pbw). THF stands for tetrahydrofuran, AIBN for azobisisobutyronitrile, and IPA for isopropyl alcohol.

Polymers were synthesized using vinylsalicylic acid monomers a-1 to a-11, acid labile group-bearing monomer ALG-1, and acid generating group-bearing monomers PM-1 to PM-12 as shown below. It is noted that Mw of a polymer is measured versus polystyrene standard by GPC using THF.

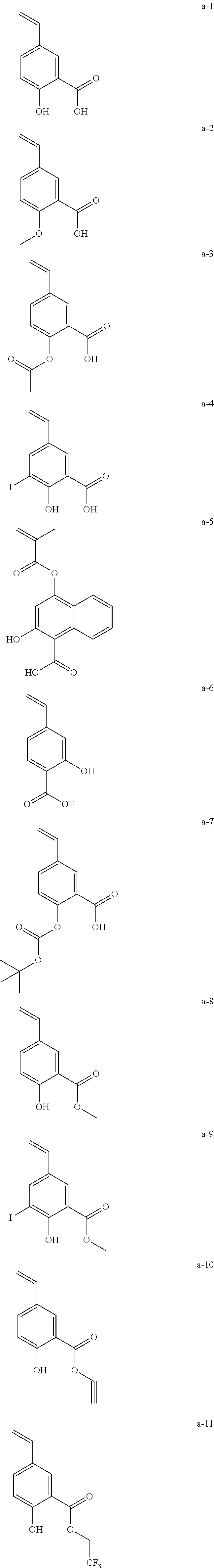

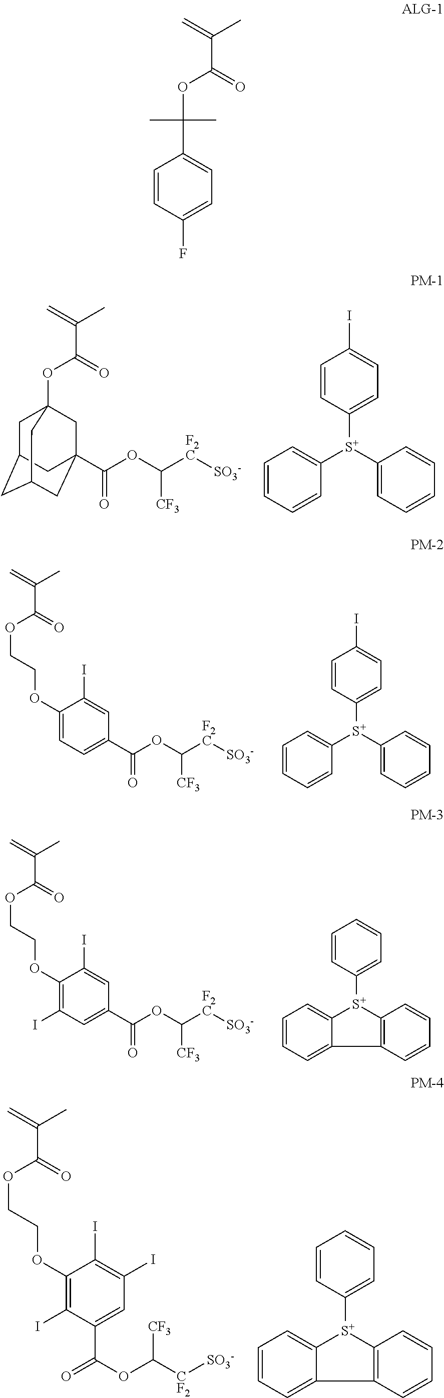

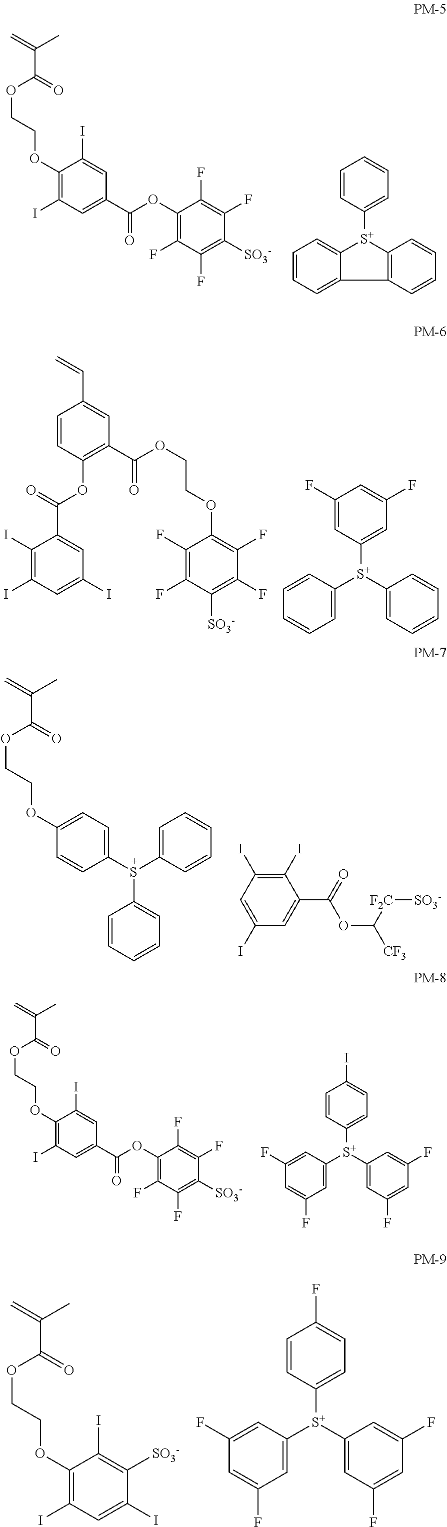

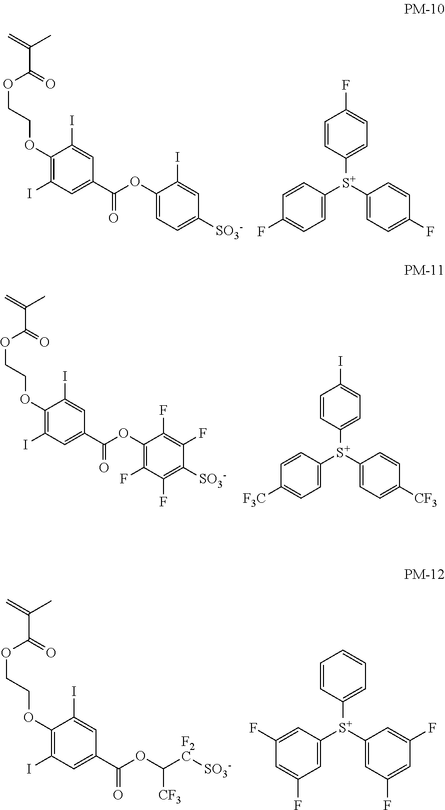

### [Synthesis Example 1] Synthesis of Polymer P-1

A 2-L flask was charged with 0.8 g of Monomer a-1, 8.4 g of 1-methyl-1-cyclopentyl methacrylate, 4.2 g of 3-hydroxystyrene, 8.6 g of Monomer PM-1, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-1. The polymer was analyzed for composition by ¹³C- and ¹H-NMR spectroscopy and for Mw and Mw/Mn by GPC.

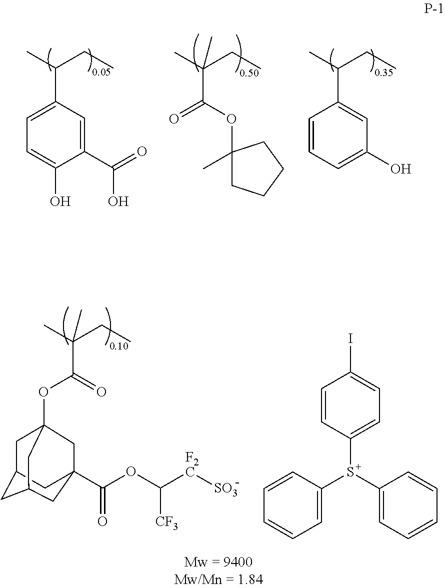

### [Synthesis Example 2] Synthesis of Polymer P-2

A 2-L flask was charged with 0.9 g of Monomer a-2, 8.4 g of 1-methyl-1-cyclopentyl methacrylate, 4.2 g of 3-hydroxystyrene, 9.8 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-2. The polymer was analyzed for composition by ¹³C- and ¹H-NMR spectroscopy and for Mw and Mw/Mn by GPC.

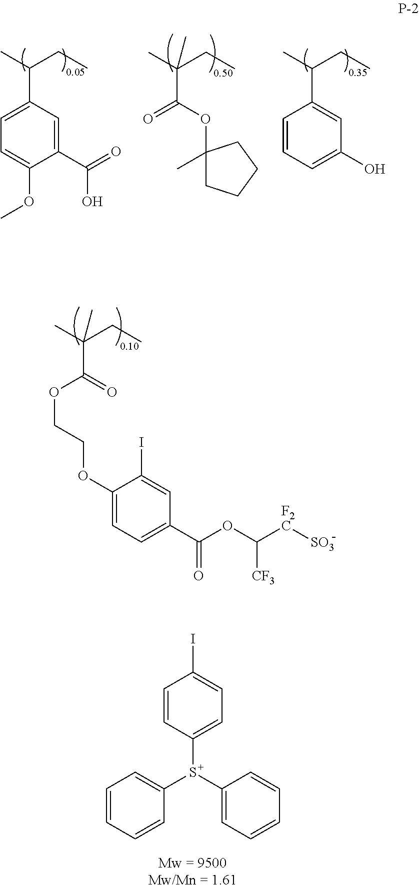

### [Synthesis Example 3] Synthesis of Polymer P-3

A 2-L flask was charged with 1.0 g of Monomer a-3, 8.9 g of 1-methyl-1-cyclopentyl methacrylate, 3.6 g of 3-hydroxystyrene, 9.7 g of Monomer PM-3, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-3. The polymer was analyzed for composition by ¹³C- and ¹H-NMR spectroscopy and for Mw and Mw/Mn by GPC.

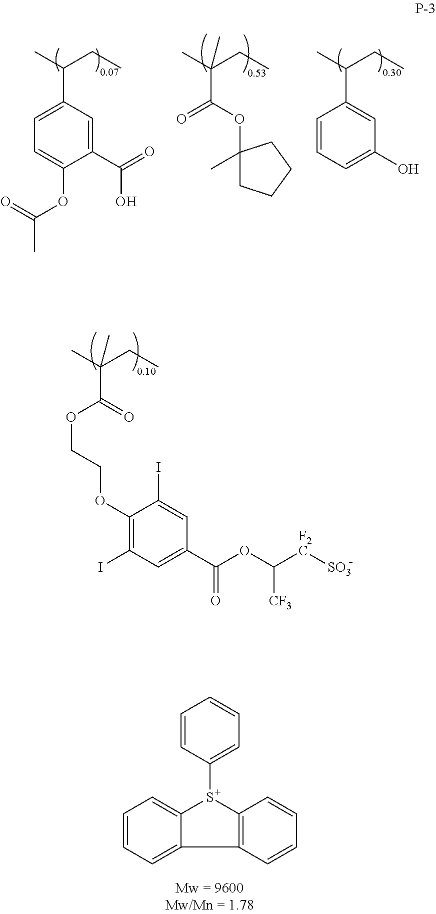

### [Synthesis Example 4] Synthesis of Polymer P-4

A 2-L flask was charged with 1.2 g of Monomer a-4, 8.6 g of 1-methyl-1-cyclopentyl methacrylate, 4.2 g of 4-hydroxystyrene, 11.0 g of Monomer PM-4, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-4. The polymer was analyzed for composition by ¹³C- and ¹H-NMR spectroscopy and for Mw and Mw/Mn by GPC.

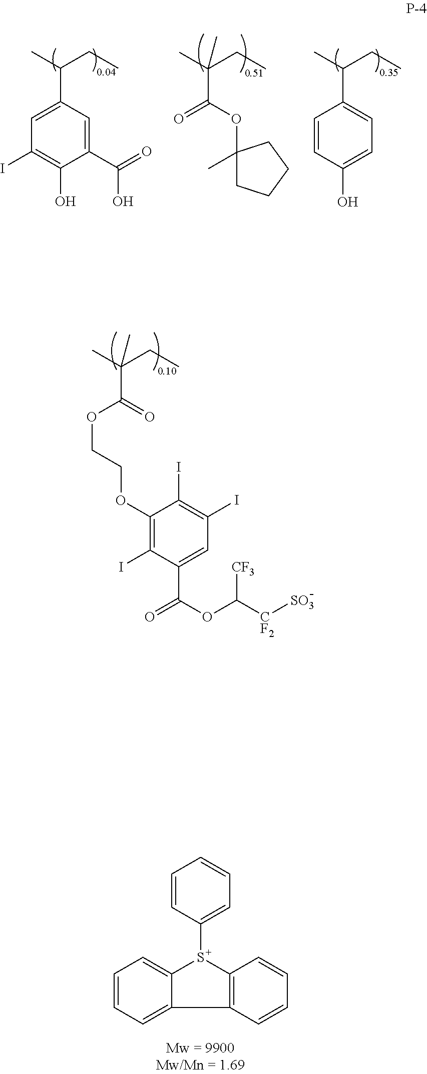

### [Synthesis Example 5] Synthesis of Polymer P-5

A 2-L flask was charged with 1.4 g of Monomer a-5, 11.1 g of Monomer ALG-1, 4.2 g of 4-hydroxystyrene, 9.9 g of Monomer PM-5, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-5. The polymer was analyzed for composition by ¹³C- and ¹H-NMR spectroscopy and for Mw and Mw/Mn by GPC.

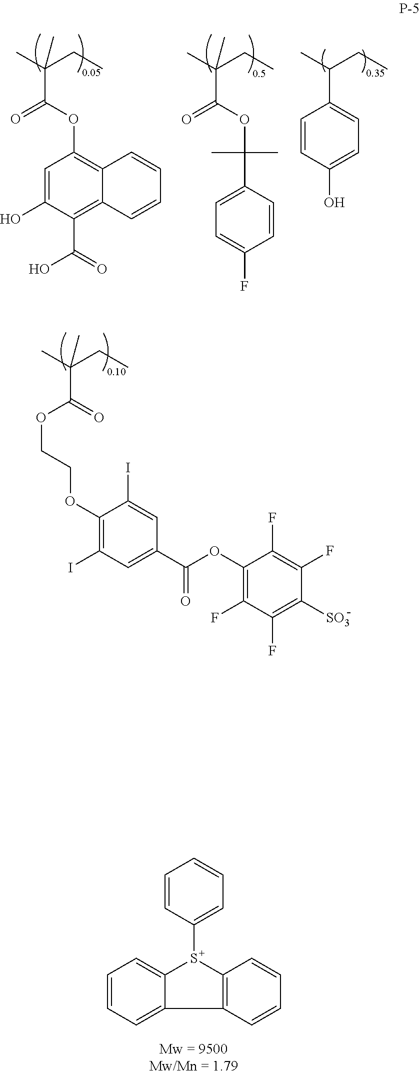

### [Synthesis Example 6] Synthesis of Polymer P-6

A 2-L flask was charged with 0.8 g of Monomer a-1, 8.4 g of 1-methyl-1-cyclopentyl methacrylate, 4.2 g of 4-hydroxystyrene, 12.2 g of Monomer PM-6, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-6. The polymer was analyzed for composition by ¹³C- and ¹H-NMR spectroscopy and for Mw and Mw/Mn by GPC.

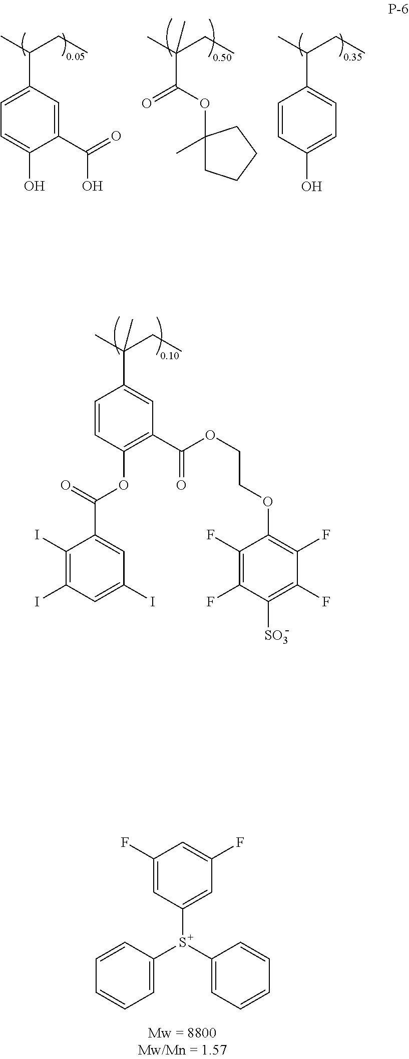

### [Synthesis Example 7] Synthesis of Polymer P-7

A 2-L flask was charged with 0.8 g of Monomer a-1, 11.1 g of Monomer ALG-1, 5.4 g of 4-hydroxystyrene, 11.0 g of Monomer PM-7, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-7. The polymer was analyzed for composition by ¹³C- and ¹H-NMR spectroscopy and for Mw and Mw/Mn by GPC.

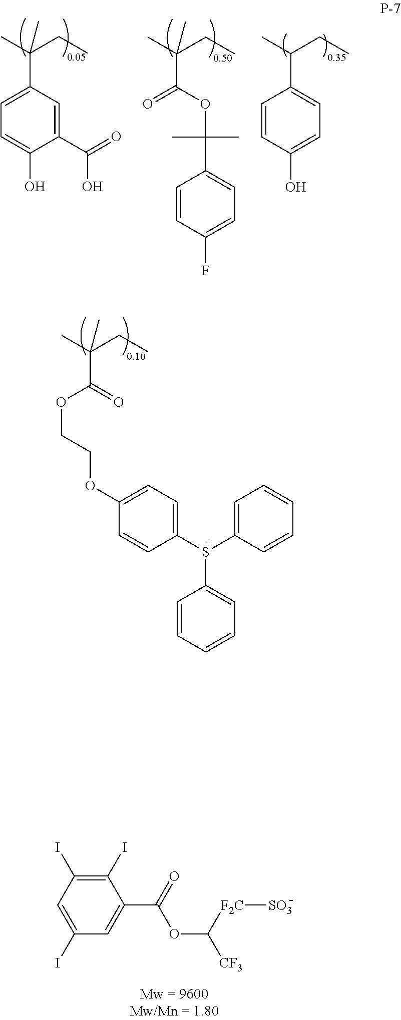

### [Synthesis Example 8] Synthesis of Polymer P-8

A 2-L flask was charged with 0.8 g of Monomer a-1, 9.0 g of 1-vinyl-1-cyclopentyl methacrylate, 4.2 g of 3-hydroxystyrene, 11.9 g of Monomer PM-8, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-8. The polymer was analyzed for composition by ¹³C- and ¹H-NMR spectroscopy and for Mw and Mw/Mn by GPC.

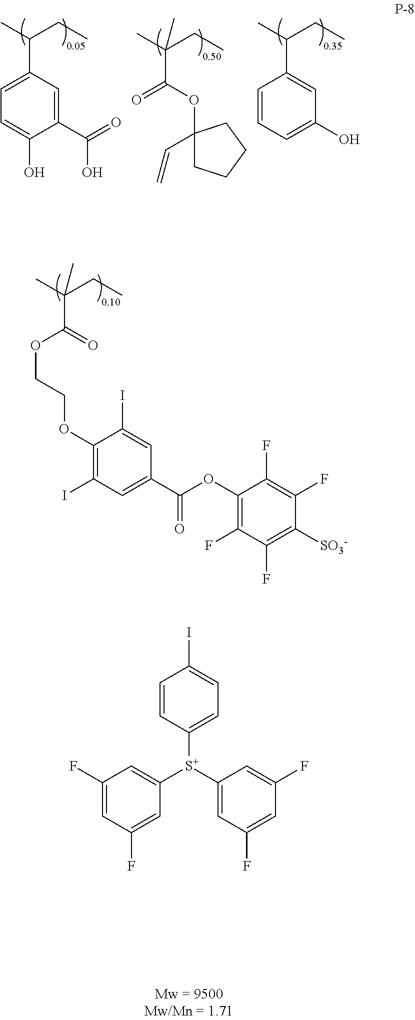

### [Synthesis Example 9] Synthesis of Polymer P-9

A 2-L flask was charged with 0.8 g of Monomer a-6, 8.9 g of 1-ethynyl-1-cyclopentyl methacrylate, 4.2 g of 3-hydroxystyrene, 10.2 g of Monomer PM-9, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-9. The polymer was analyzed for composition by ¹³C- and ¹H-NMR spectroscopy and for Mw and Mw/Mn by GPC.

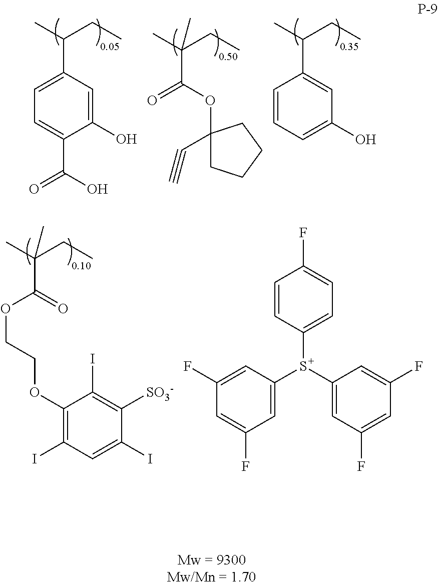

### [Synthesis Example 10] Synthesis of Polymer P-10

A 2-L flask was charged with 1.3 g of Monomer a-7, 11.1 g of Monomer ALG-1, 4.2 g of 3-hydroxystyrene, 11.0 g of Monomer PM-10, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-10. The polymer was analyzed for composition by ¹³C- and ¹H-NMR spectroscopy and for Mw and Mw/Mn by GPC.

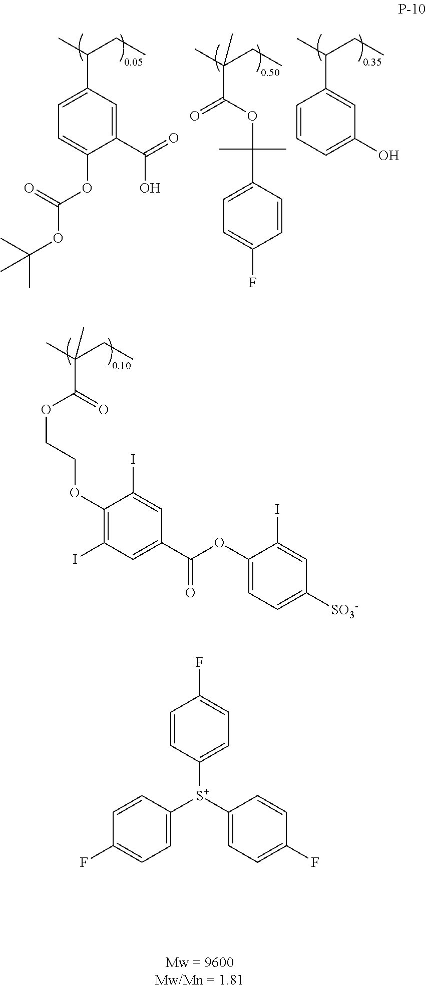

### [Synthesis Example 11] Synthesis of Polymer P-11

A 2-L flask was charged with 0.8 g of Monomer a-1, 11.1 g of Monomer ALG-1, 5.4 g of 3-hydroxystyrene, 12.5 g of Monomer PM-11, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-11. The polymer was analyzed for composition by ¹³C- and ¹H-NMR spectroscopy and for Mw and Mw/Mn by GPC.

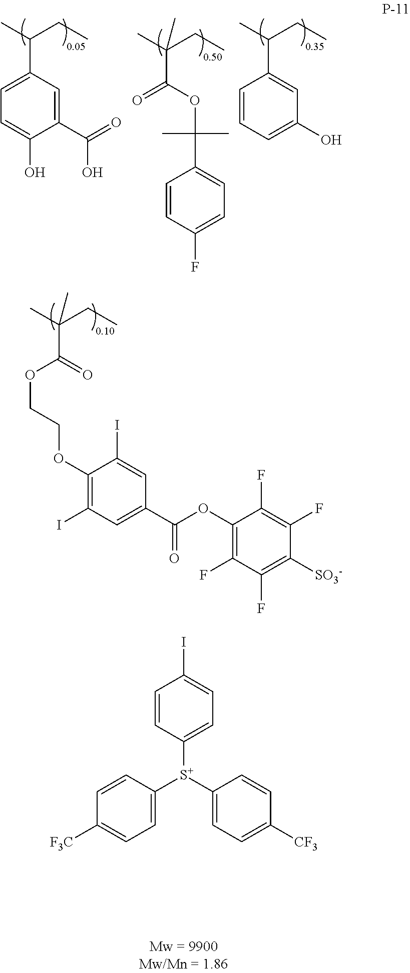

### [Synthesis Example 12] Synthesis of Polymer P-12

A 2-L flask was charged with 0.8 g of Monomer a-1, 11.1 g of Monomer ALG-1, 5.4 g of 3-hydroxystyrene, 10.5 g of Monomer PM-12, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-12. The polymer was analyzed for composition by ¹³C- and ¹H-NMR spectroscopy and for Mw and Mw/Mn by GPC.

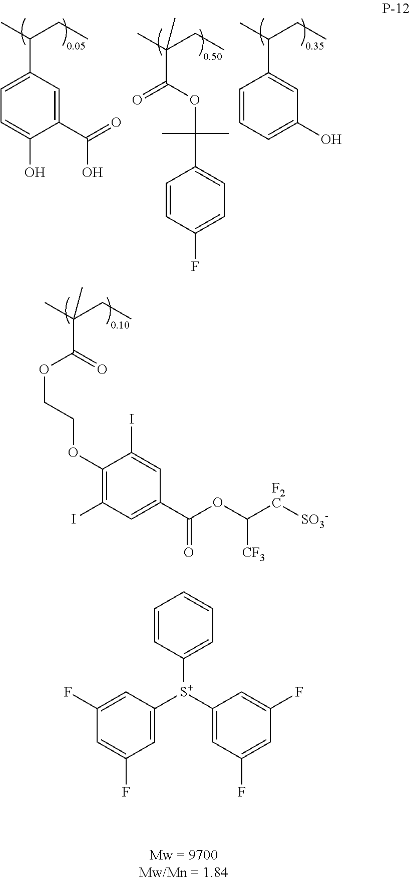

### [Synthesis Example 13] Synthesis of Polymer P-13

A 2-L flask was charged with 1.8 g of Monomer a-8, 11.1 g of Monomer ALG-1, 4.6 g of 3-hydroxystyrene, 10.5 g of Monomer PM-12, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-13. The polymer was analyzed for composition by ¹³C- and ¹H-NMR spectroscopy and for Mw and Mw/Mn by GPC.

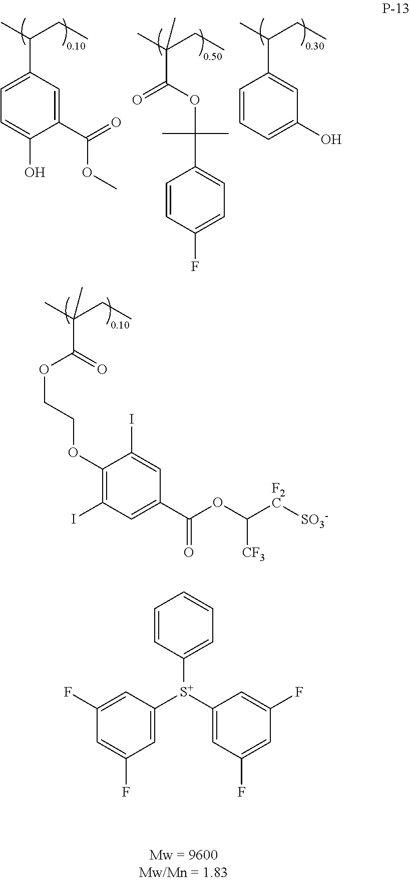

### [Synthesis Example 14] Synthesis of Polymer P-14

A 2-L flask was charged with 3.0 g of Monomer a-9, 11.1 g of Monomer ALG-1, 4.6 g of 3-hydroxystyrene, 10.5 g of Monomer PM-12, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-14. The polymer was analyzed for composition by ¹³C- and ¹H-NMR spectroscopy and for Mw and Mw/Mn by GPC.

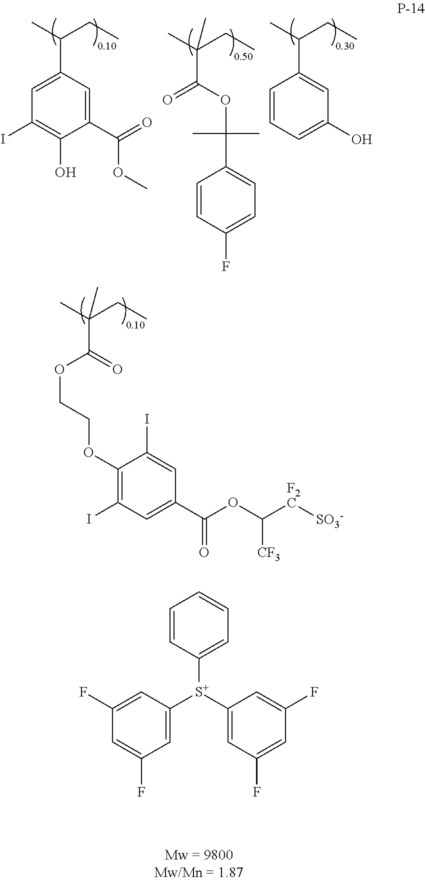

### [Synthesis Example 15] Synthesis of Polymer P-15

A 2-L flask was charged with 1.9 g of Monomer a-10, 11.1 g of Monomer ALG-1, 4.6 g of 3-hydroxystyrene, 10.5 g of Monomer PM-12, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-15. The polymer was analyzed for composition by ¹³C- and ¹H-NMR spectroscopy and for Mw and Mw/Mn by GPC.

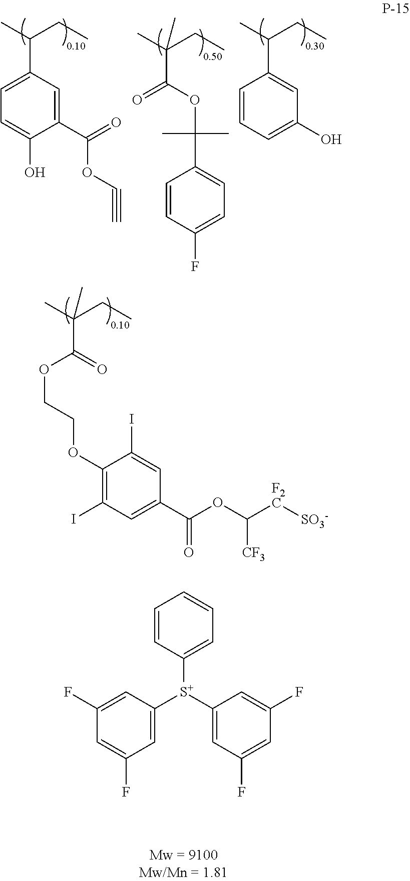

### [Synthesis Example 16] Synthesis of Polymer P-16

A 2-L flask was charged with 2.5 g of Monomer a-11, 11.1 g of Monomer ALG-1, 4.6 g of 3-hydroxystyrene, 10.5 g of Monomer PM-12, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-16. The polymer was analyzed for composition by ¹³C- and ¹H-NMR spectroscopy and for Mw and Mw/Mn by GPC.

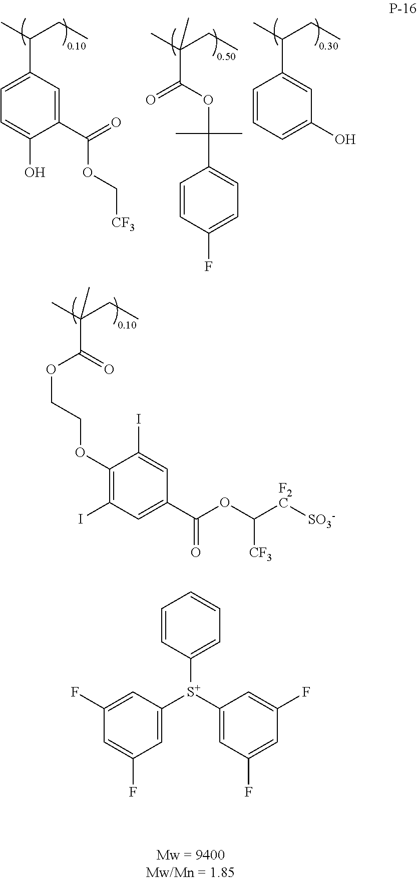

### [Comparative Synthesis Example 1] Synthesis of Comparative Polymer cP-1

Comparative Polymer cP-1 was synthesized by the same procedure as in Synthesis Example 1 aside from omitting Monomer a-1. The polymer was analyzed for composition by ¹³C- and ¹H-NMR spectroscopy and for Mw and Mw/Mn by GPC.

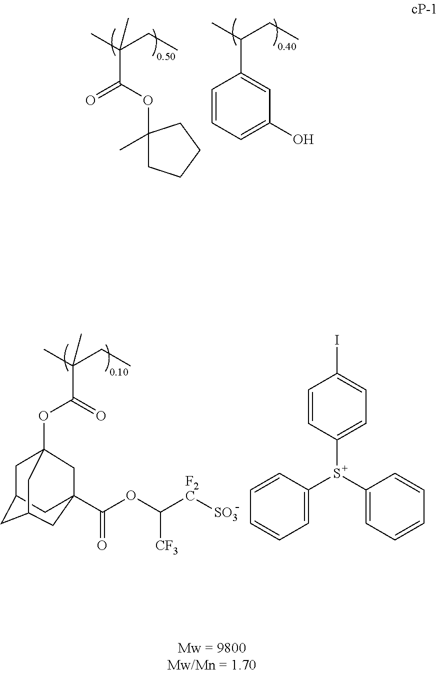

### [Examples 1 to 18 and Comparative Example 1] Preparation and Evaluation of Resist Compositions

### (1) Preparation of Resist Compositions

Resist compositions were prepared by dissolving the selected components in a solvent in accordance with the recipe shown in Table 1, and filtering through a filter having a pore size of 0.2 μm. The solvent contained 50 ppm of surfactant Polyfox 636 (Omnova Solutions, Inc.)

The components in Table 1 are as identified below.

### Organic Solvents:

PGMEA (propylene glycol monomethyl ether acetate)
DAA (diacetone alcohol)
EL (ethyl lactate)

### Acid Generators: PAG-1 and PAG-2

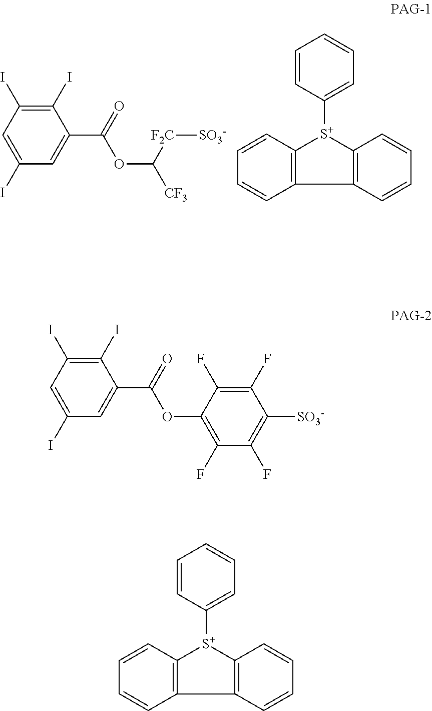

### Quencher: Q-1

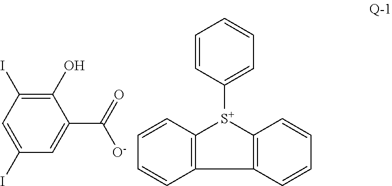 [SMILES: O=C([O-])c1cc(I)cc(I)c1O ; c1ccc(-[s+]2c3ccccc3c3ccccc32)cc1]

### (2) EUV Lithography Test

Each of the positive resist compositions in Table 1 was spin coated on a silicon substrate having a 20-nm coating of silicon-containing spin-on hard mask SHB-A940 (Shin-Etsu Chemical Co., Ltd., silicon content 43 wt %) and prebaked on a hotplate at 105° C. for 60 seconds to form a resist film of 40 nm thick. Using an EUV scanner NXE3400 (ASML, NA 0.33, σ 0.9/0.7, dipole illumination), the resist film was exposed to EUV. The resist film was baked (PEB) on a hotplate at the temperature shown in Table 1 for 60 seconds and developed in a 2.38 wt % TMAH aqueous solution for 30 seconds to form a line-and-space pattern having a pitch of 32 nm and a line width of 16 nm.

The resist pattern was observed under CD-SEM (CG-6300, Hitachi High-Technologies Corp.). The exposure dose that provides a L/S pattern having a size of 16±1.6 nm is reported as sensitivity. The LWR at this dose was measured. The wafer was sectioned, after which the cross section of the 16-nm L/S pattern was observed under SEM (S-4800, Hitachi High-Technologies Corp.) to see whether or not a footing occurred in the space region.

The resist composition is shown in Table 1 together with the sensitivity, LWR, and footing in spaces during the EUV lithography test.

TABLE 1

| | | Polymer | Additive | Organic solvent | PEB temp. | Sensitivity | LWR | Footing |
|---|---|---|---|---|---|---|---|---|
| | | (pbw) | (pbw) | (pbw) | (° C.) | (mJ/cm²) | (nm) | in spaces |
| Example | 1 | P-1 (100) | Q-1 (11.50) | PGMEA (500) | 85 | 43 | 2.4 | nil |
| | | | | EL (3500) | | | | |
| | 2 | P-2 (100) | Q-1 (11.50) | PGMEA (500) | 85 | 42 | 2.6 | nil |
| | | | | EL (3500) | | | | |
| | 3 | P-3 (100) | Q-1 (11.50) | PGMEA (500) | 85 | 43 | 2.5 | nil |
| | | | | EL (3500) | | | | |
| | 4 | P-4 (100) | Q-1 (11.50) | PGMEA (3500) | 85 | 43 | 2.6 | nil |
| | | | | DAA (500) | | | | |
| | 5 | P-5 (100) | Q-1 (11.50) | PGMEA (3500) | 85 | 44 | 2.5 | nil |
| | | | | DAA (500) | | | | |
| | 6 | P-6 (100) | Q-1 (11.50) | PGMEA (3500) | 85 | 42 | 2.4 | nil |
| | | | | DAA (500) | | | | |
| | 7 | P-7 (100) | Q-1 (11.50) | PGMEA (3500) | 85 | 39 | 2.5 | nil |
| | | | | DAA (500) | | | | |
| | 8 | P-8 (100) | Q-1 (11.50) | PGMEA (3500) | 85 | 44 | 2.3 | nil |
| | | | | DAA (500) | | | | |
| | 9 | P-9 (100) | Q-1 (11.50) | PGMEA (3500) | 85 | 43 | 2.3 | nil |
| | | | | DAA (500) | | | | |
| | 10 | P-10 (100) | Q-1 (11.50) | PGMEA (3500) | 85 | 42 | 2.4 | nil |
| | | | | DAA (500) | | | | |
| | 11 | P-11 (100) | Q-1 (11.50) | PGMEA (3500) | 85 | 44 | 2.3 | nil |
| | | | | DAA (500) | | | | |
| | 12 | P-12 (100) | Q-1 (11.50) | PGMEA (3500) | 85 | 45 | 2.4 | nil |
| | | | | DAA (500) | | | | |
| | 13 | P-13 (100) | Q-1 (11.50) | PGMEA (3500) | 85 | 43 | 2.4 | nil |
| | | | | DAA (500) | | | | |
| | 14 | P-14 (100) | Q-1 (11.50) | PGMEA (3500) | 85 | 42 | 2.4 | nil |
| | | | | DAA (500) | | | | |
| | 15 | P-15 (100) | Q-1 (11.50) | PGMEA (3500) | 85 | 41 | 2.5 | nil |
| | | | | DAA (500) | | | | |
| | 16 | P-16 (100) | Q-1 (11.50) | PGMEA (3500) | 80 | 43 | 2.5 | nil |
| | | | | DAA (500) | | | | |
| | 17 | P-10 (100) | PAG-1 (4.86) | PGMEA (3500) | 85 | 36 | 2.6 | nil |
| | | | Q-1 (11.50) | DAA (500) | | | | |
| | 18 | P-10 (100) | PAG-2 (4.94) | PGMEA (3500) | 85 | 37 | 2.6 | nil |
| | | | Q-1 (11.50) | DAA (500) | | | | |
| Comparative | 1 | cP-1 (100) | Q-1 (11.50) | PGMEA (3500) | 85 | 45 | 2.8 | found |
| Example | | | | DAA (500) | | | | |

It is demonstrated in Table 1 that positive resist compositions comprising a base polymer comprising repeat units (a) having a substituted or unsubstituted carboxy group and a substituted or unsubstituted phenolic hydroxy group, with the proviso that repeat unit (a) has at least one group selected from an unsubstituted carboxy group and an unsubstituted phenolic hydroxy group, repeat units (b) having an acid labile group, and repeat units (c) consisting of a sulfonic acid anion bonded to the polymer backbone and a sulfonium or iodonium cation exhibit a high sensitivity and form patterns with reduced LWR and little or no footing in spaces.

Japanese Patent Application Nos. 2023-186658 and 2024-065075 are incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A positive resist composition comprising a base polymer comprising repeat units (a) having a substituted or unsubstituted carboxy group and a substituted or unsubstituted phenolic hydroxy group, with the proviso that repeat unit (a) has at least one group selected from an unsubstituted carboxy group and an unsubstituted phenolic hydroxy group, repeat units (b) having an acid labile group, and repeat units (c) having a sulfonium or iodonium salt structure of a sulfonic acid bonded to the polymer backbone.

2. The positive resist composition of claim 1 wherein the repeat units (a) have the formula (a): 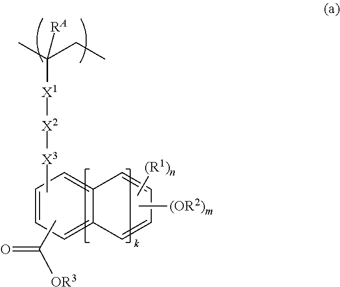
wherein k is 0 or 1, m is an integer of 1 to 4, n is an integer of 0 to 4,
R^{A} is hydrogen or methyl,
X¹ is a single bond or ester bond,
X² is a single bond, C₁-C₁₀ saturated hydrocarbylene group, phenylene group or naphthylene group,
X³ is a single bond, ester bond, ether bond or carbonyl group,
R¹ is a C₁-C₄ alkyl group or halogen,
R² is hydrogen, a C₁-C₆ saturated hydrocarbyl group, C₂-C₇ saturated hydrocarbylcarbonyl group, or C₂-C₇ saturated hydrocarbyloxycarbonyl group,
R³ is hydrogen, a C₁-C₁₂ saturated hydrocarbyl group, or C₂-C₁₂ unsaturated hydrocarbyl group, the saturated hydrocarbyl group and unsaturated hydrocarbyl group may have at least one moiety selected from hydroxy, C₁-C₈ saturated hydrocarbyloxy moiety, and halogen, with the proviso that one or both of R² and R³ are hydrogen when m=1, and at least one of plural R² and R³ is hydrogen when m=2, 3 or 4.

3. The positive resist composition of claim 1 wherein the repeat units (b) include repeat units of at least one type selected from repeat units (b1) having the formula (b1) and repeat units (b2) having the formula (b2): 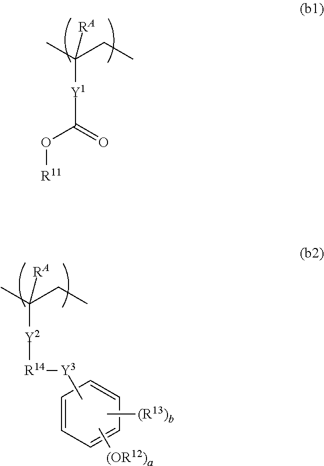
wherein R^{A} is each independently hydrogen or methyl,
Y¹ is a single bond, phenylene group, naphthylene group, or C₁-C₁₂ linking group containing at least one moiety selected from ester bond, ether bond and lactone ring, the phenylene group, naphthylene group, and linking group may contain at least one moiety selected from halogen, nitro, hydroxy, C₁-C₈ saturated hydrocarbyloxy moiety, C₂-C₈ saturated hydrocarbylcarbonyloxy moiety, and C₂-C₈ saturated hydrocarbyloxycarbonyloxy moiety,
Y² is a single bond, ester bond or amide bond,
Y³ is a single bond, ether bond or ester bond,
R¹¹ and R¹² each are an acid labile group,
R¹³ is fluorine, trifluoromethyl, cyano, or C₁-C₆ alkyl group,
R¹⁴ is a single bond or C₁-C₆ alkanediyl group in which some —CH₂— may be replaced by an ether bond or ester bond,
a is 1 or 2, b is an integer of 0 to 4, and a+b is from 1 to 5.

4. The positive resist composition of claim 1 wherein the repeat units (c) include repeat units of at least one type selected from repeat units having the formulae (c1) to (c5): 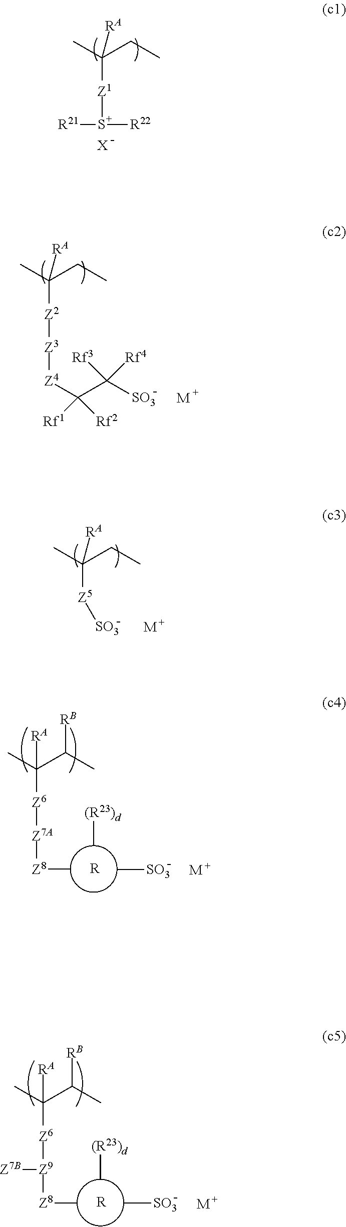
wherein R^{A} is each independently hydrogen or methyl,
R^{B} is each independently hydrogen or may form a ring with Z⁶,
Z¹ is a single bond, a C₁-C₆ aliphatic hydrocarbylene group, phenylene group, naphthylene group, or C₇-C₁₈ group obtained by combining the foregoing, or —O—Z¹¹—, —C(═O)—O—Z¹¹— or —C(═O)—NH—Z¹¹—, Z¹¹ is a C₁-C₆ aliphatic hydrocarbylene group, phenylene group, naphthylene group, or C₇-C₁₈ group obtained by combining the foregoing, which may contain carbonyl, ester bond, ether bond or hydroxy,
Z² is a single bond or ester bond,
Z³ is a single bond, —Z³¹—C(═O)—O— or —Z³¹—O—, Z³¹ is a C₁-C₁₂ hydrocarbylene group, phenylene group, or C₇-C₁₈ group obtained by combining the foregoing, which may contain carbonyl, nitro, cyano, ester bond, ether bond, urethane bond, fluorine, iodine or bromine,
Z⁴ is a single bond, methylene or ethylene,
Z⁵ is a single bond, methylene, ethylene, phenylene, methylphenylene, dimethylphenylene, fluorinated phenylene, trifluoromethyl-substituted phenylene group, —O—Z⁵¹—, —C(═O)—O—Z⁵¹— or —C(═O)—NH—Z⁵¹—, Z⁵¹ is a C₁-C₆ aliphatic hydrocarbylene, phenylene, methylphenylene, dimethylphenylene, fluorinated phenylene, or trifluoromethyl-substituted phenylene group, which may contain carbonyl, ester bond, ether bond, hydroxy or halogen,
Z⁶ is a single bond, phenylene, naphthylene, ester bond or amide bond,
Z^{7A} is a single bond or a C₁-C₂₄ divalent organic group which may contain at least one element selected from halogen, oxygen, nitrogen, and sulfur,
Z^{7B} is a C₁-C₁₀ monovalent organic group which may contain at least one element selected from halogen, oxygen, nitrogen, and sulfur,
Z⁸ is a single bond, ether bond, ester bond, thioether bond or C₁-C₆ alkanediyl group,
Z⁹ is a C₁-C₁₂ trivalent organic group which may contain at least one element selected from oxygen, nitrogen, and sulfur,
Rf¹ to Rf⁴ are each independently hydrogen, fluorine or trifluoromethyl, at least one thereof being fluorine or trifluoromethyl, and Rf¹ and Rf², taken together, may form a carbonyl group,
R²¹ and R²² are each independently halogen or a C₁-C₂₀ hydrocarbyl group which may contain a heteroatom,
R²³ is a C₁-C₁₀ saturated hydrocarbyl group, C₆-C₁₀ aryl group, fluorine, iodine, trifluoromethoxy, difluoromethoxy, cyano or nitro,
the circle R is a C₆-C₁₀ (d+2)-valent aromatic hydrocarbon group,
d is an integer of 0 to 5,
X⁻ is a non-nucleophilic counter ion, and
M⁺ is a sulfonium or iodonium cation.

5. The positive resist composition of claim 4 wherein Z³, Z^{7A}, Z^{7B} or M⁺ contains at least one iodine atom.

6. The positive resist composition of claim 1 wherein the base polymer further comprises repeat units (d) having an adhesive group which is selected from hydroxy, carboxy, lactone ring, carbonate, thiocarbonate, carbonyl, cyclic acetal, ether bond, ester bond, sulfonate ester bond, cyano, amide, —O—C(═O)—S—, and —O—C(═O)—NH—.

7. The positive resist composition of claim 1, further comprising an acid generator.

8. The positive resist composition of claim 1, further comprising an organic solvent.

9. The positive resist composition of claim 1, further comprising a quencher.

10. The positive resist composition of claim 1, further comprising a surfactant.

11. A pattern forming process comprising the steps of applying the positive resist composition of claim 1 onto a substrate to form a resist film thereon, exposing the resist film to high-energy radiation, and developing the exposed resist film in a developer.

12. The process of claim 11 wherein the high-energy radiation is i-line, KrF excimer laser, ArF excimer laser, EB or EUV of wavelength 3 to 15 nm.
